(19) United States
(12) Patent Application Publication
(10) Pub. No.: US 2024/0016050 A1
(43) Pub. Date: Jan. 11, 2024

(54) LIGHT EMITTING ELEMENT AND NITROGEN-CONTAINING COMPOUND FOR THE SAME

(71) Applicant: Samsung Display Co., Ltd., Yongin-si (KR)

(72) Inventors: SEOWON CHO, Yongin-si (KR); HYEONGMIN KIM, Yongin-si (KR); HEECHOON AHN, Yongin-si (KR); HYUNAH UM, Yongin-si (KR); Juhui YUN, Yongin-si (KR)

(21) Appl. No.: 18/320,859

(22) Filed: May 19, 2023

(30) Foreign Application Priority Data
Jul. 4, 2022 (KR) 10-2022-0081731

(51) Int. Cl. H10K 85/40; C07F 7/08; C09K 11/06

(52) U.S. Cl. CPC H10K 85/40; C07F 7/0812; C09K 11/06; H10K 50/121

(57) ABSTRACT

A light emitting element of one or more embodiments may include a first electrode, a second electrode provided on the first electrode, and an emission layer provided between the first electrode and the second electrode and including a first compound represented by Formula 1. Accordingly, the light emitting element of one or more embodiments may show long-life characteristics:

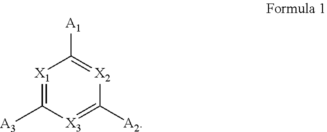

### CROSS-REFERENCE TO RELATED APPLICATIONS

This application claims priority to and the benefit of Korean Patent Application No. 10-2022-0081731, filed on Jul. 4, 2022, in the Korean Intellectual Property Office, the entire content of which is hereby incorporated by reference.

### BACKGROUND

### 1. Field

One or more aspects of embodiments of the present disclosure herein relate to a light emitting element and a nitrogen-containing compound used therein.

### 2. Description of the Related Art

Recently, the development of an organic electroluminescence display device as an image display device is being actively conducted. The organic electroluminescence display device is a display device including a self-luminescent-type (e.g., self-luminescent) light emitting element in which holes and electrons injected from a first electrode and a second electrode recombine in an emission layer so that a light emitting material in the emission layer emits light to achieve display of images.

In the application of a light emitting element to a display device, the increase of lifetime, etc. are required or desired, and development of materials for a light emitting element, capable of suitably achieving these characteristics is being consistently required or desired.

### SUMMARY

One or more aspects of embodiments of the present disclosure are directed toward a light emitting element having increased lifetime (lifespan).

One or more aspects of embodiments of the present disclosure are also directed toward a nitrogen-containing compound which is a material for a light emitting element having long-life characteristics. Additional aspects will be set forth in part in the description which follows and, in part, will be apparent from the description, or may be learned by practice of the presented embodiments of the disclosure.

One or more embodiments provide a light emitting element including: a first electrode; a second electrode disposed on the first electrode; and an emission layer provided between the first electrode and the second electrode, and including a first compound represented by Formula 1.

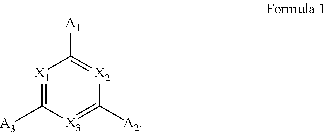

In Formula 1, at least one among X₁ to X₃ may be N, and the remainder may be CH, A₁ to A₃ may be each independently is a substituted or unsubstituted amine group, a substituted or unsubstituted aryl group of 6 to 60 ring-forming carbon atoms, or a substituted or unsubstituted heteroaryl group or 2 to 60 ring-forming carbon atoms, where at least one among A₁ to A₃ may include a substituted or unsubstituted silyl group as a first substituent, and at least one among hydrogen atoms in A₁ to A₃ and hydrogen atoms in X₁ to X₃, may be substituted with a deuterium atom.

In one or more embodiments, in Formula 1, if at least one among the hydrogen atoms in A₁ to A₃ is substituted with a deuterium atom, at least one among A₁ to A₃ substituted with the deuterium atom may include the first substituent, or at least one among the remainder excluding A₁ to A₃ substituted with the deuterium atom may include the first substituent.

In one or more embodiments, Formula 1 may be represented by Formula 1-1A or Formula 1-1B.

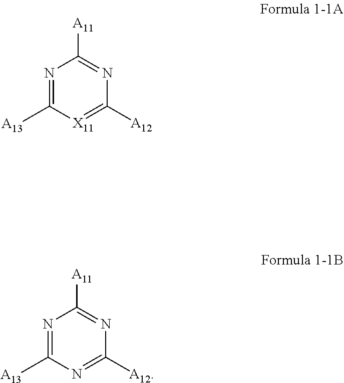

In Formula 1-1A and Formula 1-1B, A₁₁ to A₁₃ may be each independently a substituted or unsubstituted amine group, a substituted or unsubstituted aryl group of 6 to 60 ring-forming carbon atoms, or a substituted or unsubstituted heteroaryl group of 2 to 60 ring-forming carbon atoms, and at least one among A₁₁ to A₁₃ may include the first substituent. In Formula 1-1A, X₁₁ may be CH or CD, and if X₁₁ is CH, at least one among A₁₁ to A₁₃ may include a deuterium atom as a substituent, and in Formula 1-1B, at least one among A₁₁ to A₁₃ may include a deuterium atom as a substituent.

In one or more embodiments, in Formula 1, A₁ to A₃ may be each independently a substituted or unsubstituted aryl amine group, a substituted or unsubstituted phenyl group, a substituted or unsubstituted dibenzoazasiline group, a substituted or unsubstituted carbazole group, a substituted or unsubstituted dibenzofuran group, a substituted or unsubstituted dibenzothiophene group, a substituted or unsubstituted phenoxazine group, or a substituted or unsubstituted phenothiazine group, and if any one among A₁ to A₃ is a substituted phenyl group, a substituted carbazole group, a substituted dibenzofuran group, or a substituted dibenzothiophene group, any one among A₁ to A₃ may include a deuterium atom and the first substituent.

In one or more embodiments, in Formula 1, A₁ to A₃ may be each independently represented by any one among Formula A-1 to Formula A-4.

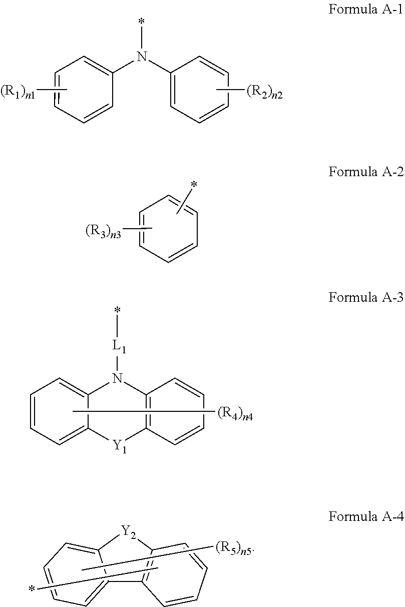

In Formula A-1 and Formula A-2, n1 to n3 may be each independently an integer of 0 to 5, in Formula A-3, L₁ may be a direct linkage, or a substituted or unsubstituted arylene group of 6 to 60 ring-forming carbon atoms, Y₁ may be a direct linkage, SiR₆R₇, O, or S, and n4 may be an integer of 0 to 8; in Formula A-4, Y₂ may be NRs, O or S, and n5 may be an integer of 0 to 7; in Formula A-1 to Formula A-4, R₁ to R₈ may be each independently a hydrogen atom, a deuterium atom, a cyano group, a substituted or unsubstituted silyl group, a substituted or unsubstituted alkyl group of 1 to 30 carbon atoms, a substituted or unsubstituted aryl group of 6 to 60 ring-forming carbon atoms, or a substituted or unsubstituted heteroaryl group of 2 to 60 ring-forming carbon atoms, and if any one among A₁ to A₃ is represented by any one among Formula A-2 to Formula A-4, at least one among R₃ to R₈ may include a deuterium atom.

In one or more embodiments, in Formula A-2, R₃ may be a deuterium atom, a substituted or unsubstituted silyl group, a substituted or unsubstituted cyclohexyl group, a substituted or unsubstituted phenyl group, a substituted or unsubstituted carbazole group, a substituted or unsubstituted dibenzofuran group, a substituted or unsubstituted dibenzo oxaborinine group, or a substituted or unsubstituted dibenzosilole group.

In one or more embodiments, Formula 1 may be represented by any one among Formula 1-2A to Formula 1-2C.

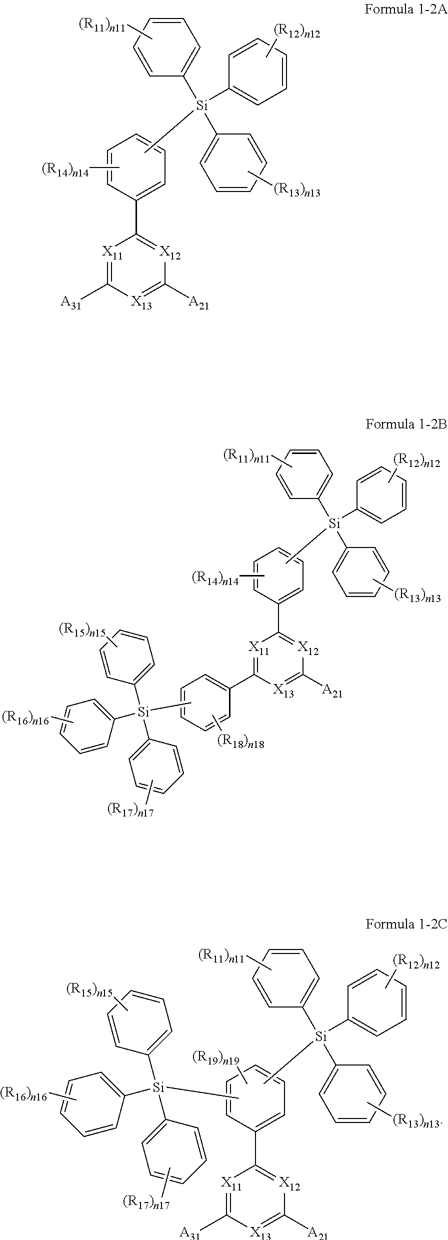

In Formula 1-2A to Formula 1-2C, n11 to n13, and n15 to n17 may be each independently an integer of 0 to 5, n14 and n18 may be each independently an integer of 0 to 4, n19 may be an integer of 0 to 3, R₁₁ to R₁₈ may be each independently a hydrogen atom, a deuterium atom, a cyano group, a substituted or unsubstituted silyl group, a substituted or unsubstituted alkyl group of 1 to 30 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring, at least one among X₁₁ to X₁₃ may be N, and the remainder are CH, A₂₁ and A₃₁ may be each independently a substituted or unsubstituted aryl group of 6 to 60 ring-forming carbon atoms, or a substituted or unsubstituted heteroaryl group of 2 to 60 ring-forming carbon atoms, and at least one among hydrogen atoms in A₂₁, hydrogen atoms in A₃₁, hydrogen atoms in X₁₁ to X₁₃, and hydrogen atoms in R₁₁ to R₁₈, may be substituted with a deuterium atom.

In one or more embodiments, Formula 1-2A may be represented by Formula 1-2AA or Formula 1-2AB.

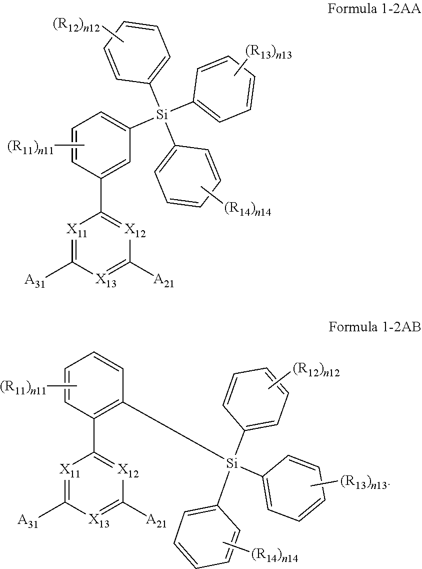

In Formula 1-2AA and Formula 1-2AB, n11 to n14, R₁₁ to R₁₄, A₂₁, A₃₁, and X₁₁ to X₁₃ are the same as defined in Formula 1-2A.

In one or more embodiments, Formula 1-2A may be represented by Formula 1-2AC.

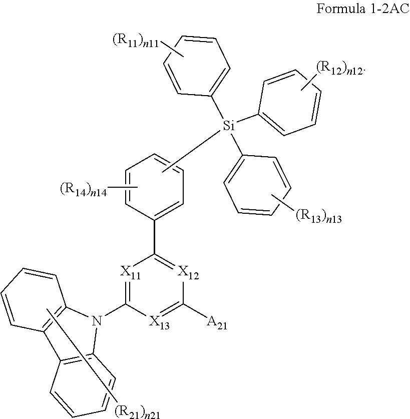

In Formula 1-2AC, n21 may be an integer of 0 to 8, R₂₁ may be a hydrogen atom, a deuterium atom, a cyano group, a substituted or unsubstituted silyl group, a substituted or unsubstituted alkyl group of 1 to 10 carbon atoms, a substituted or unsubstituted aryl group of 6 to 30 ring-forming carbon atoms, or a substituted or unsubstituted heteroaryl group of 2 to 30 ring-forming carbon atoms, at least one among hydrogen atoms in A₂₁, hydrogen atoms in X₁₁ to X₁₃, hydrogen atoms in R₁₁ to R₁₄, and hydrogen atoms in R₂₁, may be substituted with a deuterium atom, and n11 to n14, R₁₁ to R₁₄, A₂₁, and X₁₁ to X₁₃ are the same as defined in Formula 1-2A.

In one or more embodiments, in Formula 1, one or two among A₁ to A₃ may include triphenylsilyl groups substituted with deuterium atoms, and at least one among the remainder may include a carbazole group substituted with a deuterium atom.

In one or more embodiments, the emission layer may include a host and a dopant, and the host may include the first compound.

In one or more embodiments, the emission layer may further include a second compound represented by Formula HT-1.

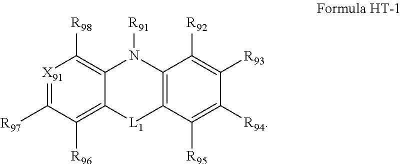

In Formula HT-1, L₁ may be a direct linkage, CR₉₉R₁₀₀, or SiR₁₀₁R₁₀₂, X₉₁ may be N or CR₁₀₃, and R₉₁ to R₁₀₃ may each independently be a hydrogen atom, a deuterium atom, a cyano group, a substituted or unsubstituted silyl group, a substituted or unsubstituted oxy group, a substituted or unsubstituted alkyl group having 1 to 60 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring.

In one or more embodiments, the emission layer may further include a third compound represented by Formula M-a.

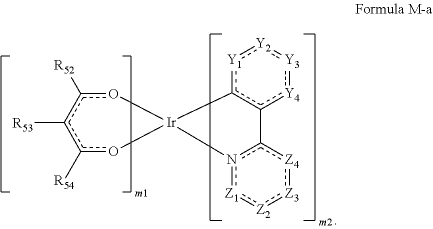

In Formula M-a, Y₁ to Y₄, and Z₁ to Z₄ may be each independently CR₅₁ or N, R₅₁ to R₅₄ may be each independently a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, m1 may be 0 or 1, m2 may be 2 or 3, if m1 is 0, m2 may be 3, and if m1 is 1, m2 may be 2.

According to one or more embodiments of the present disclosure, a nitrogen-containing compound represented by Formula 1 is provided.

### BRIEF DESCRIPTION OF THE DRAWINGS

The accompanying drawings are included to provide a further understanding of the present disclosure and are incorporated in and constitute a part of this specification. The drawings illustrate embodiments of the present disclosure and, together with the description, serve to explain principles of the present disclosure. In the drawings:

FIG. 1 is a plan view showing a display device according to one or more embodiments;

FIG. 2 is a cross-sectional view showing a part corresponding to line I-I′ in FIG. 1;

FIG. 3 is a cross-sectional view schematically showing a light emitting element of one or more embodiments;

FIG. 4 is a cross-sectional view schematically showing a light emitting element of one or more embodiments;

FIG. 5 is a cross-sectional view schematically showing a light emitting element of one or more embodiments;

FIG. 6 is a cross-sectional view schematically showing a light emitting element of one or more embodiments;

FIG. 7 is a cross-sectional view showing a display device according to one or more embodiments;

FIG. 8 is a cross-sectional view showing a display device according to one or more embodiments;

FIG. 9 is a cross-sectional view showing a display device according to one or more embodiments; and

FIG. 10 is a cross-sectional view showing a display device according to one or more embodiments.

### DETAILED DESCRIPTION

The present disclosure may have various modifications and may be embodied in different forms, and example embodiments will be explained in more detail with reference to the accompany drawings. The present disclosure may, however, be embodied in different forms and should not be construed as limited to the embodiments set forth herein. Rather, all modifications, equivalents, and substituents which are included in the spirit and technical scope of the present disclosure should be included in the present disclosure.

In the description, when an element (or a region, a layer, a part, etc.) is referred to as being “on”, “connected with” or “combined with” another element, it can be directly connected with/bonded on the other element (e.g., without any intervening elements therebetween), or intervening third elements may also be provided.

Like reference numerals refer to like elements throughout. In the drawings, the thicknesses, ratios, and dimensions of elements are exaggerated for effective explanation of technical contents.

As used herein, expressions such as “at least one of”, “one of”, and “selected from”, when preceding a list of elements, modify the entire list of elements and do not modify the individual elements of the list. For example, “at least one selected from a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

The term “and/or” may include one or more combinations that may define relevant elements. Further, the use of “may” when describing embodiments of the present disclosure refers to “one or more embodiments of the present disclosure”.

It will be understood that, although the terms first, second, etc. may be used herein to describe various elements, these elements should not be limited by these terms. These terms are only used to distinguish one element from another element.

For example, a first element could be termed a second element without departing from the scope of the present invention. Similarly, a second element could be termed a first element. As used herein, the singular forms are intended to include the plural forms as well, unless the context clearly indicates otherwise.

In addition, the terms “below”, “beneath”, “on” and “above” are used for explaining the relation of elements shown in the drawings. The terms are relative concept and are explained based on the direction shown in the drawing.

It will be further understood that the terms “comprises” and/or “comprising,” when used in this specification, specify the presence of stated features, numerals, steps, operations, elements, parts, or the combination thereof, but do not preclude the presence or addition of one or more other features, numerals, steps, operations, elements, parts, or the combination thereof.

Unless otherwise defined, all terms (including technical and scientific terms) used herein have the same meaning as commonly understood by one of ordinary skill in the art to which this present disclosure belongs. In addition, it will be further understood that terms, such as those defined in commonly used dictionaries, should be interpreted as having a meaning for example consistent with their meaning in the context of the relevant art and will not be interpreted in an idealized or overly formal sense unless expressly so defined herein.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The electronic device and/or any other relevant devices or components according to embodiments of the present invention described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

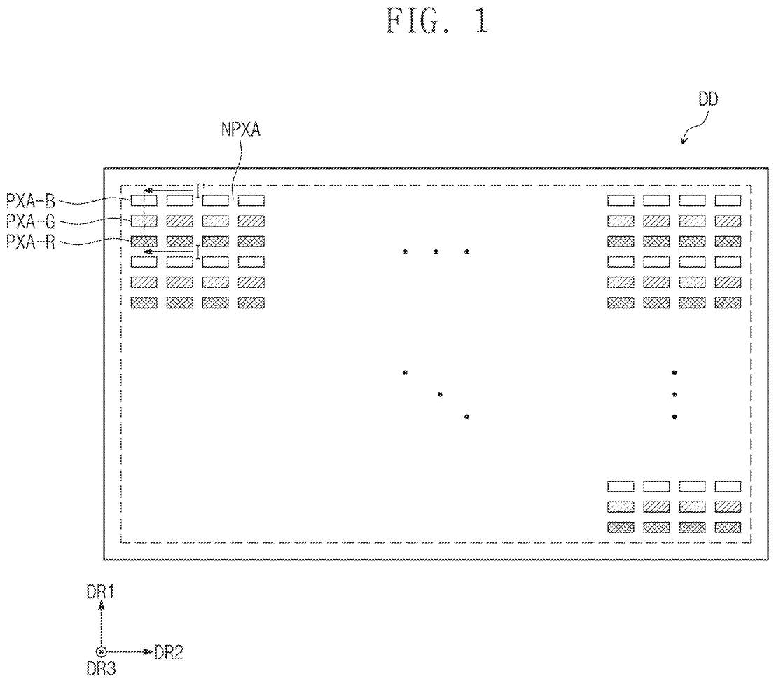

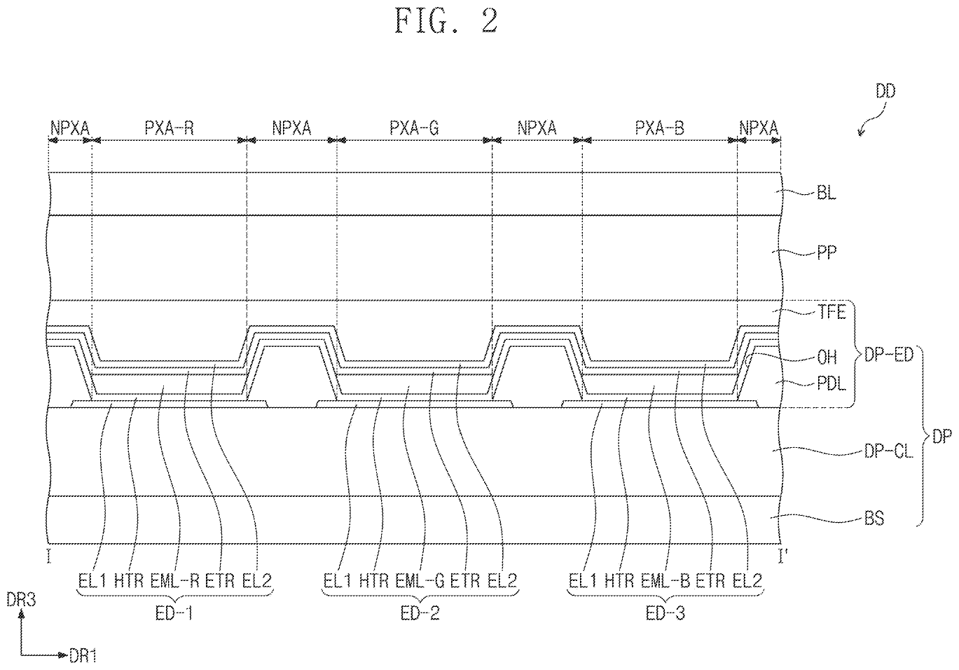

Hereinafter, embodiments of the present disclosure will be explained referring to the drawings. FIG. 1 is a plan view showing one or more embodiments of a display device DD. FIG. 2 is a cross-sectional view of a display device DD of one or more embodiments. FIG. 2 is a cross-sectional view showing a part corresponding to line I-I′ of FIG. 1.

The display device DD may include a display panel DP and an optical layer PP provided on the display panel DP. The display panel DP may include light emitting elements ED-1, ED-2 and ED-3. The display device DD may include multiple light emitting elements ED-1, ED-2 and ED-3. The optical layer PP may be provided on the display panel DP and control the reflection of external light at the display panel DP. The optical layer PP may include, for example, a polarization layer and/or a color filter layer. In some embodiments, the optical layer PP may be omitted (e.g., may not be provided) in the display device DD of one or more embodiments.

On the optical layer PP, a base substrate BL may be provided. The base substrate BL may be a member providing a base surface where the optical layer PP is provided. The base substrate BL may be a glass substrate, a metal substrate, a plastic substrate, etc. However, one or more embodiments of the present disclosure is not limited thereto, and the base substrate BL may be an inorganic layer, an organic layer, or a composite material layer (e.g., including an organic material and an inorganic material). In some embodiments, the base substrate BL may be omitted (e.g., may not be provided) in one or more embodiments.

The display device DD according to one or more embodiments may further include a plugging layer. The plugging layer may be provided between a display element layer DP-ED and a base substrate BL. The plugging layer may be an organic layer. The plugging layer may include at least one among an acrylic resin, a silicon-based resin and an epoxy-based resin.

The display panel DP may include a base layer BS, a circuit layer DP-CL provided on the base layer BS, and a display element layer DP-ED. The display element layer DP-ED may include a pixel definition layer PDL, light emitting elements ED-1, ED-2 and ED-3 provided in the pixel definition layer PDL, and an encapsulating layer TFE provided on the light emitting elements ED-1, ED-2 and ED-3.

The base layer BS may be a member providing a base surface where the display element layer DP-ED is provided. The base layer BS may be a glass substrate, a metal substrate, a plastic substrate, etc. However, one or more embodiments of the present disclosure is not limited thereto, and the base layer BS may be an inorganic layer, an organic layer, or a composite material layer.

In one or more embodiments, the circuit layer DP-CL is provided on the base layer BS, and the circuit layer DP-CL may include multiple transistors. Each of the transistors may include a control electrode, an input electrode, and an output electrode. For example, the circuit layer DP-CL may include switching transistors and driving transistors for driving the light emitting elements ED-1, ED-2 and ED-3 of the display element layer DP-ED.

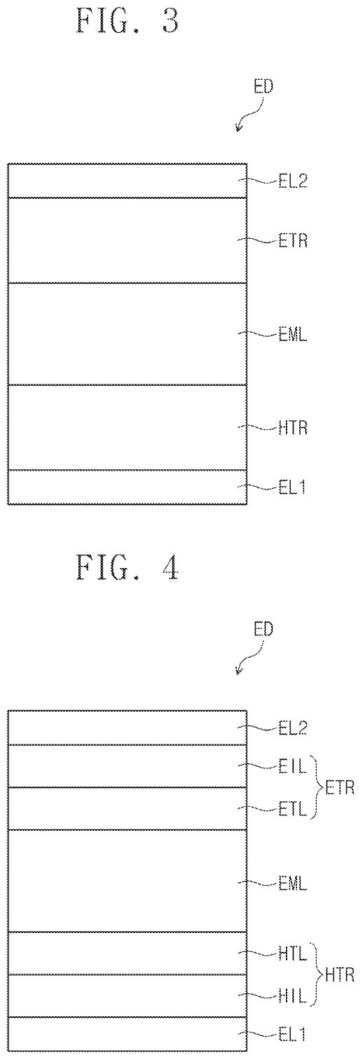

The light emitting elements ED-1, ED-2 and ED-3 may have the structures of the light emitting elements ED of embodiments according to FIG. 3 to FIG. 6, which will be explained in more detail herein below. The light emitting elements ED-1, ED-2 and ED-3 may include a first electrode EL₁, a hole transport region HTR, emission layers EML-R, EML-G and EML-B, an electron transport region ETR and a second electrode EL₂.

In FIG. 2, shown is an embodiment where the emission layers EML-R, EML-G and EML-B of light emitting elements ED-1, ED-2 and ED-3 are provided in opening portions OH defined in a pixel definition layer PDL, and a hole transport region HTR, an electron transport region ETR and a second electrode EL₂ are provided as common layers in all light emitting elements ED-1, ED-2 and ED-3. However, one or more embodiments of the present disclosure is not limited thereto. In some embodiments, the hole transport region HTR and the electron transport region ETR may be patterned and provided in the opening portions OH defined in the pixel definition layer PDL. For example, in one or more embodiments, the hole transport region HTR, the emission layers EML-R, EML-G and EML-B, and the electron transport region ETR of the light emitting elements ED-1, ED-2 and ED-3 may be patterned by an ink jet printing method and provided in the corresponding opening portions OH.

An encapsulating layer TFE may cover the light emitting elements ED-1, ED-2 and ED-3. The encapsulating layer TFE may encapsulate the display element layer DP-ED. The encapsulating layer TFE may be a thin film encapsulating layer. The encapsulating layer TFE may be one layer or a stacked layer of multiple layers. The encapsulating layer TFE includes at least one insulating layer. The encapsulating layer TFE according to one or more embodiments may include at least one inorganic layer (hereinafter, encapsulating inorganic layer). In addition, the encapsulating layer TFE according to one or more embodiments may include at least one organic layer (hereinafter, encapsulating organic layer) and at least one encapsulating inorganic layer.

The encapsulating inorganic layer may protect the display element layer DP-ED from moisture/oxygen, and the encapsulating organic layer may protect the display element layer DP-ED from foreign materials such as dust particles. The encapsulating inorganic layer may include silicon nitride, silicon oxy nitride, silicon oxide, titanium oxide, and/or aluminum oxide, without specific limitation. The encapsulating organic layer may include an acrylic compound, an epoxy-based compound, etc. The encapsulating organic layer may include a photopolymerizable organic material, without specific limitation.

The encapsulating layer TFE may be provided on the second electrode EL₂ and may be provided while filling the opening portion OH.

Referring to FIG. 1 and FIG. 2, the display device DD may include a non-luminous area NPXA and luminous areas PXA-R, PXA-G and PXA-B. The luminous areas PXA-R, PXA-G and PXA-B may be areas emitting (e.g., configured to emit) light produced from the light emitting elements ED-1, ED-2 and ED-3, respectively. The luminous areas PXA-R, PXA-G and PXA-B may be separated from each other on a plane (e.g., in a plan view).

The luminous areas PXA-R, PXA-G and PXA-B may be areas separated by the pixel definition layer PDL. The non-luminous areas NPXA may be areas between neighboring luminous areas PXA-R, PXA-G and PXA-B and may be areas corresponding to the pixel definition layer PDL. In the disclosure, each of the luminous areas PXA-R, PXA-G and PXA-B may correspond to each pixel. The pixel definition layer PDL may divide the light emitting elements ED-1, ED-2 and ED-3. The emission layers EML-R, EML-G and EML-B of the light emitting elements ED-1, ED-2 and ED-3 may be provided and divided in the opening portions OH defined in the pixel definition layer PDL.

The luminous areas PXA-R, PXA-G and PXA-B may be divided into multiple groups according to the color of light produced from the light emitting elements ED-1, ED-2 and ED-3. In the display device DD of one or more embodiments, shown in FIG. 1 and FIG. 2, three luminous areas PXA-R, PXA-G and PXA-B emitting (e.g., configured to emit) red light, green light and blue light are illustrated. For example, the display device DD of one or more embodiments may include a red luminous area PXA-R, a green luminous area PXA-G and a blue luminous area PXA-B, which are separated from each other.

In the display device DD according to one or more embodiments, multiple light emitting elements ED-1, ED-2 and ED-3 may emit light having different wavelength regions. For example, in one or more embodiments, the display device DD may include a first light emitting element ED-1 emitting red light, a second light emitting element ED-2 emitting green light, and a third light emitting element ED-3 emitting (e.g., configured to emit) blue light. For example, each of the red luminous area PXA-R, the green luminous area PXA-G, and the blue luminous area PXA-B of the display device DD may correspond to the first light emitting element ED-1, the second light emitting element ED-2, and the third light emitting element ED-3, respectively.

However, one or more embodiments of the present disclosure is not limited thereto, and the first to third light emitting elements ED-1, ED-2 and ED-3 may emit light in the same wavelength region, or at least one thereof may emit light in a different wavelength region. For example, all the first to third light emitting elements ED-1, ED-2 and ED-3 may emit blue light.

The luminous areas PXA-R, PXA-G and PXA-B in the display device DD according to one or more embodiments may be arranged in a stripe shape or pattern. Referring to FIG. 1, multiple red luminous areas PXA-R may be arranged with each other along a second directional axis DR2, multiple green luminous areas PXA-G may be arranged with each other along the second directional axis DR2, and multiple blue luminous areas PXA-B may be arranged with each other along the second directional axis DR2. In addition, the red luminous area PXA-R, the green luminous area PXA-G and the blue luminous area PXA-B may be arranged with each other by turns (e.g., alternatingly) along a first directional axis DR1.

In FIG. 1 and FIG. 2, the areas of the luminous areas PXA-R, PXA-G and PXA-B are shown similar, but one or more embodiments of the present disclosure is not limited thereto. The areas of the luminous areas PXA-R, PXA-G and PXA-B may be different from each other according to the wavelength region of light emitted.

Herein, the areas of the luminous areas PXA-R, PXA-G and PXA-B may mean areas on a plane defined by the first directional axis DR1 and the second directional axis DR2.

The arrangement type (or kind) of the luminous areas PXA-R, PXA-G and PXA-B is not limited to the configuration shown in FIG. 1, and the arrangement order of the red luminous areas PXA-R, the green luminous areas PXA-G and the blue luminous areas PXA-B may be provided in various suitable combinations according to the properties of display quality required or desired for the display device DD. For example, the arrangement type (or kind) of the luminous areas PXA-R, PXA-G and PXA-B may be a pentile (PENTILE®) arrangement (PENTILE® is a registered trademark owned by Samsung Display Co., Ltd.), and/or a diamond (Diamond Pixel™) arrangement.

In some embodiments, the areas of the luminous areas PXA-R, PXA-G and PXA-B may be different from each other. For example, in one or more embodiments, the area of the green luminous area PXA-G may be smaller than the area of the blue luminous area PXA-B, but one or more embodiments of the present disclosure is not limited thereto.

Hereinafter, FIG. 3 to FIG. 6 are cross-sectional views schematically showing light emitting elements according to embodiments. The light emitting element ED according to one or more embodiments may include a first electrode EL1, a hole transport region HTR, an emission layer EML, an electron transport region ETR, and a second electrode EL2, stacked in order.

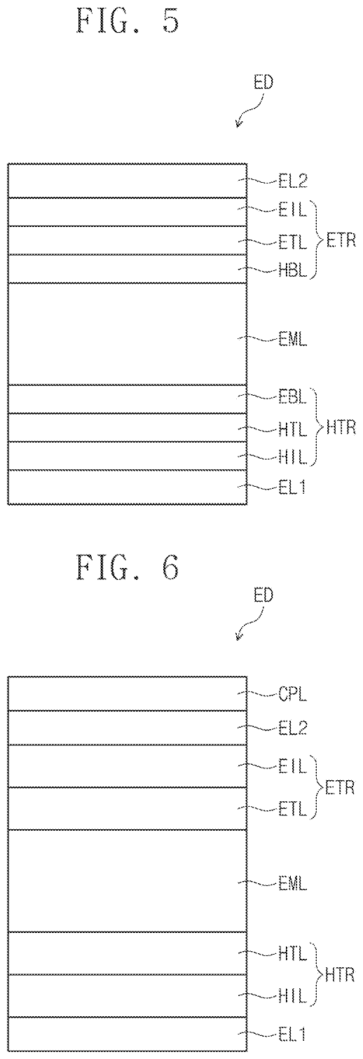

When compared to FIG. 3, FIG. 4 shows the cross-sectional view of a light emitting element ED of one or more embodiments, wherein a hole transport region HTR includes a hole injection layer HIL and a hole transport layer HTL, and an electron transport region ETR includes an electron injection layer EIL and an electron transport layer ETL. When compared to FIG. 3, FIG. 5 shows the cross-sectional view of a light emitting element ED of one or more embodiments, wherein a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. When compared to FIG. 4, FIG. 6 shows the cross-sectional view of a light emitting element ED of one or more embodiments, including a capping layer CPL provided on the second electrode EL2.

The emission layer EML may include the nitrogen-containing compound of one or more embodiments. In the description, the nitrogen-containing compound and the first compound are the same. The nitrogen-containing compound of one or more embodiments may include a hexagonal single ring including at least one N as a ring-forming atom, as a core structure. In some embodiments, the nitrogen-containing compound of one or more embodiments may include a deuterium atom and a substituted or unsubstituted silyl group. In the nitrogen-containing compound of one or more embodiments, the deuterium atom may directly or indirectly be bonded to the hexagonal single ring, and the substituted or unsubstituted silyl group may be indirectly bonded to the hexagonal single ring.

In the description, the term “substituted or unsubstituted” corresponds to a group that is unsubstituted or that is substituted with at least one substituent selected from the group consisting of a deuterium atom, a halogen atom, a cyano group, a nitro group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, a heterocyclic group, and combinations thereof. In some embodiments, each of the exemplified substituents may itself be substituted or unsubstituted. For example, a biphenyl group may be interpreted as an aryl group and/or a phenyl group substituted with a phenyl group.

In the description, the term “forming a ring via the combination with an adjacent group” may mean forming a substituted or unsubstituted hydrocarbon ring, or a substituted or unsubstituted heterocycle via the combination with an adjacent group. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may each independently be monocycles or polycycles. In some embodiments, the ring formed via the combination with an adjacent group may be combined with another ring to form a spiro structure.

In the description, the term “adjacent group” may refer to a pair of substituent groups where the first substituent is connected to an atom which is directly connected to another atom substituted with the second substituent; a pair of substituent groups connected to the same atom; or a pair of substituent groups where the first substituent is sterically positioned at the nearest position to the second substituent. For example, in 1,2-dimethylbenzene, two methyl groups may be interpreted as “adjacent groups” to each other, and in 1,1-diethylcyclopentene, two ethyl groups may be interpreted as “adjacent groups” to each other. For example, in 4,5-dimethylphenanthrene, two methyl groups may be interpreted as “adjacent groups” to each other.

In the description, a halogen atom may be a fluorine atom, a chlorine atom, a bromine atom and/or an iodine atom.

In the description, an alkyl group may be a linear, branched, or cyclic group. The carbon number of the alkyl group may be, for example, 1 to 60, 1 to 30, 1 to 20, 1 to 10, or 1 to 6. Examples of the alkyl group may include methyl, ethyl, n-propyl, isopropyl, n-butyl, s-butyl, t-butyl, i-butyl, 2-ethylbutyl, 3,3-dimethylbutyl, n-pentyl, i-pentyl, neopentyl, t-pentyl, cyclopentyl, 1-methylpentyl, 3-methylpentyl, 2-ethylpentyl, 4-methyl-2-pentyl, n-hexyl, 1-methylhexyl, 2-ethylhexyl, 2-butylhexyl, cyclohexyl, 4-methylcyclohexyl, 4-t-butylcyclohexyl, n-heptyl, 1-methylheptyl, 2,2-dimethylheptyl, 2-ethylheptyl, 2-butylheptyl, n-octyl, t-octyl, 2-ethyloctyl, 2-butyloctyl, 2-hexyloctyl, 3,7-dimethyloctyl, cyclooctyl, n-nonyl, n-decyl, adamantyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldodecyl, 2-octyldodecyl, n-tridecyl, n-tetradecyl, n-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyleicosyl, 2-butyleicosyl, 2-hexyleicosyl, 2-octyleicosyl, n-henicosyl, n-docosyl, n-tricosyl, n-tetracosyl, n-pentacosyl, n-hexacosyl, n-heptacosyl, n-octacosyl, n-nonacosyl, n-triacontyl, etc., without limitation.

In the description, an alkenyl group means a hydrocarbon group including one or more carbon double bonds in the middle and/or at the terminal of an alkyl group having a carbon number of 2 or more. The alkenyl group may be a linear chain or a branched chain. The carbon number is not specifically limited, but may be 2 to 60, 2 to 30, 2 to 20, or 2 to 10. Examples of the alkenyl group may include a vinyl group, a 1-butenyl group, a 1-pentenyl group, a 1,3-butadienyl aryl group, a styrenyl group, a styrylvinyl group, etc., without limitation.

In the description, an alkynyl group means a hydrocarbon group including one or more carbon triple bonds in the middle and/or at the terminal of an alkyl group having a carbon number of 2 or more. The alkynyl group may be a linear chain or a branched chain. The carbon number is not specifically limited, but may be 2 to 60, 2 to 30, 2 to 20, or 2 to 10. Particular examples of the alkynyl group may include an ethynyl group, a propynyl group, etc., without limitation.

In the description, a hydrocarbon ring group means an optional functional group or substituent derived from an aliphatic hydrocarbon ring. The hydrocarbon ring group may be a saturated hydrocarbon ring group of 5 to 30 ring-forming carbon atoms.

In the description, an aryl group means an optional functional group or substituent derived from an aromatic hydrocarbon ring. The aryl group may be a monocyclic aryl group or a polycyclic aryl group. The carbon number for forming rings in the aryl group may be 6 to 60, 6 to 30, 6 to 20, or 6 to 15. Examples of the aryl group may include phenyl, naphthyl, fluorenyl, anthracenyl, phenanthryl, biphenyl, terphenyl, quaterphenyl, quinquephenyl, sexiphenyl, triphenylenyl, pyrenyl, benzofluoranthenyl, chrysenyl, etc., without limitation.

In the description, a heterocyclic group means an optional functional group or substituent derived from a ring including one or more among B, O, N, P, Si, and S as heteroatoms. The heterocyclic group includes an aliphatic heterocyclic group and an aromatic heterocyclic group. The aromatic heterocyclic group may be a heteroaryl group. The aliphatic heterocyclic group and the aromatic heterocyclic group may each independently be a monocycle or a polycycle.

In the description, a heterocyclic group may include one or more among B, O, N, P, Si and S as heteroatoms. If the heterocyclic group includes two or more heteroatoms, two or more heteroatoms may be the same or different. The heterocyclic group may be a monocyclic heterocyclic group or polycyclic heterocyclic group and has concept including a heteroaryl group. The carbon number for forming rings of the heterocyclic group may be 2 to 60, 2 to 30, 2 to 20, or 2 to 10.

In the description, an aliphatic heterocyclic group may include one or more among B, O, N, P, Si, and S as heteroatoms. The number of ring-forming carbon atoms of the aliphatic heterocyclic group may be 2 to 60, 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., without limitation.

In the description, a heteroaryl group may include one or more among B, O, N, P, Si, and S as heteroatoms. If the heteroaryl group includes two or more heteroatoms, two or more heteroatoms may be the same or different. The heteroaryl group may be a monocyclic heterocyclic group or polycyclic heterocyclic group. The carbon number for forming rings of the heteroaryl group may be 2 to 60, 2 to 30, 2 to 20, or 2 to 10. Examples of the heteroaryl group may include thiophene, furan, pyrrole, imidazole, pyridine, bipyridine, pyrimidine, triazine, triazole, acridyl, pyridazine, pyrazinyl, quinoline, quinazoline, quinoxaline, phenoxazine, phthalazine, pyrido pyrimidine, pyrido pyrazine, pyrazino pyrazine, isoquinoline, indole, carbazole, N-arylcarbazole, N-heteroarylcarbazole, N-alkylcarbazole, benzoxazole, benzoimidazole, benzothiazole, benzocarbazole, benzothiophene, dibenzothiophene, thienothiophene, benzofuran, phenanthroline, thiazole, isooxazole, oxazole, oxadiazole, thiadiazole, phenothiazine, dibenzosilole, dibenzofuran, etc., without limitation.

In the description, the same explanation as for the above-described aryl group may be applied to an arylene group except that the arylene group is a divalent group. The same explanation as for the above-described heteroaryl group may be applied to a heteroarylene group except that the heteroarylene group is a divalent group.

In the description, a silyl group may mean the above-defined alkyl group or aryl group bonded to a silicon atom. The silyl group includes an alkyl silyl group and an aryl silyl group. Examples of the silyl group may include a trimethylsilyl group, a triethylsilyl group, a t-butyldimethylsilyl group, ethyldimethylsilyl group, a propyldimethylsilyl group, a triphenylsilyl group, a diphenylsilyl group, a phenylsilyl group, etc., without limitation.

In the description, a thio group may include an alkyl thio group and an aryl thio group. The thio group may mean the above-defined alkyl group or aryl group combined with a sulfur atom. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., without limitation.

In the description, an oxy group may mean the above-defined alkyl group or aryl group which is combined with an oxygen atom. The oxy group may include an alkoxy group and an aryl oxy group. The alkoxy group may be a linear, branched or cyclic chain. The carbon number of the alkoxy group is not specifically limited but may be, for example, 1 to 30, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, etc. However, one or more embodiments of the present disclosure is not limited thereto.

In the description, a boron group may mean the above-defined alkyl group or aryl group bonded to a boron atom. The boron group may include an alkyl boron group and an aryl boron group. Examples of the boron group may include a dimethylboron group, a diethylboron group, a t-butylmethylboron group, a diphenylboron group, a phenylboron group, or the like, without limitation.

In the description, the carbon number of an amine group is not specifically limited, but may be 1 to 30. The amine group may include an alkyl amine group and an aryl amine group. Examples of the amine group include a methylamine group, a dimethylamine group, a phenylamine group, a diphenylamine group, a naphthylamine group, a 9-methyl-anthracenylamine group, etc., without limitation.

In the description, the alkyl group(s) in an alkyl thio group, an alkyl sulfoxy group, an alkoxy group, an alkyl amino group, an alkyl boron group, an alkyl silyl group and an alkyl amine group may be the same as the examples of the above-described alkyl group.

In the description, the aryl group(s) in an aryl oxy group, an aryl thio group, an aryl sulfoxy group, an aryl amino group, an aryl boron group, an aryl silyl group, and an aryl amine group may be the same as the examples of the above-described aryl group.

In the description, a direct linkage may mean a single bond. In the description,

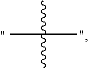

and [symbol]
mean positions to be connected (e.g., a bonding site).

The light emitting element ED of one or more embodiments may include the nitrogen-containing compound of one or more embodiments. The nitrogen-containing compound of one or more embodiments may be represented by Formula 1 below.

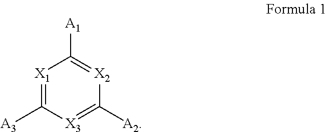

In Formula 1, at least one among X₁ to X₃ may be N, and the remainder may be CH. For example, if any one among X₁ to X₃ is N, and the remainder are CH, the nitrogen-containing compound may include pyridine as a core structure. If any two among X₁ to X₃ are N, and the remainder is CH, the nitrogen-containing compound may include pyrimidine as a core structure. If X₁ to X₃ are all N, the nitrogen-containing compound may include triazine as a core structure.

In Formula 1, A₁ to A₃ may be each independently a substituted or unsubstituted amine group, a substituted or unsubstituted aryl group of 6 to 60 ring-forming carbon atoms, or a substituted or unsubstituted heteroaryl group or 2 to 60 ring-forming carbon atoms. At least one among A₁ to A₃ may include a substituted or unsubstituted silyl group as a first substituent. In the description, the first substituent is a substituted or unsubstituted silyl group. For example, at least one among A₁ to A₃ may be an aryl group substituted with the first substituent, or a heteroaryl group substituted with the first substituent.

In one or more embodiments, at least one among hydrogen atoms in A₁ to A₃ and hydrogen atoms in X₁ to X₃ may be substituted with a deuterium atom. For example, at least one among A₁ to A₃ may include a deuterium atom as a substituent, and X₁ to X₃ may be each independently N or CH. In some embodiments, A₁ to A₃ may not include a deuterium atom as a substituent, and at least one among X₁ to X₃ may be CD. In CD, D is a deuterium atom. In some embodiments, at least one among A₁ to A₃ may include a deuterium atom as a substituent, and at least one among X₁ to X₃ may be CD.

For example, X₁ to X₃ may be all N, and at least one among A₁ to A₃ may include a deuterium atom as a substituent. For example, any one among X₁ to X₃ may be CD, and at least one among A₁ to A₃ may include a deuterium atom as a substituent.

In one or more embodiments, if at least one among the hydrogen atoms in A₁ to A₃ is substituted with a deuterium atom, at least one among A₁ to A₃ may include a deuterium atom and the first substituent as substituents. For example, if at least one among A₁ to A₃ may be a substituted aryl group, and the substituted aryl group may be substituted with a deuterium atom and the first substituent. In some embodiments, at least one among A₁ to A₃ may be a substituted heteroaryl group, and the substituted heteroaryl group may be substituted with a deuterium atom and the first substituent.

In one or more embodiments, if at least one among hydrogen atoms in A₁ to A₃ is substituted with a deuterium atom, the at least one among A₁ to A₃, substituted with the deuterium atom may include the first substituent. For example, at least one among A₁ to A₃ may include both a deuterium atom and the first substituent.

In one or more embodiments, if at least one among hydrogen atoms in A₁ to A₃ is substituted with a deuterium atom, at least one among the remainder of A₁ to A₃ (excluding the at least one among A₁ to A₃ substituted with the deuterium atom), may include the first substituent. For example, any one among A₁ to A₃ may include a deuterium atom, and at least one among the remaining two of A₁ to A₃ may include the first substituent. In some embodiments, any two among A₁ to A₃ may include deuterium atoms, and the remaining one may include the first substituent.

For example, any one among A₁ to A₃ may be a heterocycle of three rings including at least one among N, O and S as a ring-forming atom. In some embodiments, any two among A₁ to A₃ may each independently be a heterocycle of three rings including N as a ring-forming atom. The heterocycle of three rings may be substituted or unsubstituted. For example, one or two among A₁ to A₃ may be substituted or unsubstituted carbazole groups, substituted or unsubstituted dibenzofuran groups, substituted or unsubstituted dibenzothiophene groups, substituted or unsubstituted phenoxazine groups, or substituted or unsubstituted phenothiazine groups.

In one or more embodiments, A₁ to A₃ may be each independently a substituted or unsubstituted aryl amine group, a substituted or unsubstituted phenyl group, a substituted or unsubstituted dibenzoazasiline group, a substituted or unsubstituted carbazole group, a substituted or unsubstituted dibenzofuran group, a substituted or unsubstituted dibenzothiophene group, a substituted or unsubstituted phenoxazine group, or a substituted or unsubstituted phenothiazine group. For example, any one among A₁ to A₃ may be a substituted phenyl group, a substituted carbazole group, a substituted dibenzofuran group, or a substituted dibenzothiophene group, and the any one among A₁ to A₃ may include a deuterium atom and the first substituent. In some embodiments, any one among A₁ to A₃ may be a substituted phenyl group, a substituted carbazole group, a substituted dibenzofuran group, or a substituted dibenzothiophene group, and the any one may not include (e.g., may exclude) a deuterium atom as a substituent but may include the first substituent.

For example, one or two among A₁ to A₃ may include triphenylsilyl groups substituted with deuterium atoms, and at least one among the remainder may include a carbazole group substituted with a deuterium atom. Any one among A₁ to A₃ may include a triphenylsilyl group substituted with a deuterium atom, and at least one among the remaining two may include a carbazole group substituted with a deuterium atom. Any two among A₁ to A₃ may include triphenylsilyl groups substituted with deuterium atoms, and the remaining one may include a carbazole group substituted with a deuterium atom.

In one or more embodiments, A₁ to A₃ may be each independently represented by any one among Formula A-1 to Formula A-4. Formula A-1 represents a substituted or unsubstituted aryl amine group, and Formula A-2 represents a substituted or unsubstituted phenyl group.

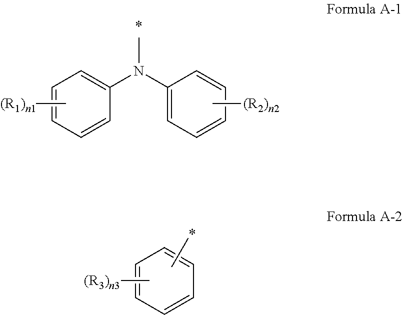

In Formula A-1 and Formula A-2, R₁ to R₃ may be each independently a hydrogen atom, a deuterium atom, a cyano group, a substituted or unsubstituted silyl group, a substituted or unsubstituted alkyl group of 1 to 30 carbon atoms, a substituted or unsubstituted aryl group of 6 to 60 ring-forming carbon atoms, or a substituted or unsubstituted heteroaryl group of 2 to 60 ring-forming carbon atoms.

In Formula A-1 and Formula A-2, n1 to n3 may be each independently an integer of 0 to 5. If n1 is an integer of 2 or more, multiple R₁ may be the same, or at least one may be different. If n2 is an integer of 2 or more, multiple R₂ may be the same, or at least one may be different. If n3 is an integer of 2 or more, multiple R₃ may be the same, or at least one may be different.

In Formula A-1, any one among n1 and n2 may be 1. n1 may be 0, n2 may be 1, and R₂ may be a substituted or unsubstituted phenyl group.

For example, in Formula A-2, R₃ may be a deuterium atom, a substituted or unsubstituted silyl group, a substituted or unsubstituted cyclohexyl group, a substituted or unsubstituted phenyl group, a substituted or unsubstituted carbazole group, a substituted or unsubstituted dibenzofuran group, a substituted or unsubstituted dibenzo oxaborinine group, or a substituted or unsubstituted dibenzosilole group. For example, n3 may be an integer of 2 or more, and multiple R₃ may be each independently a deuterium atom, a substituted or unsubstituted silyl group, a substituted or unsubstituted cyclohexyl group, a substituted or unsubstituted phenyl group, a substituted or unsubstituted carbazole group, a substituted or unsubstituted dibenzofuran group, a substituted or unsubstituted dibenzo oxaborinine group, or a substituted or unsubstituted dibenzosilole group. n3 may be 1, and R₃ may be a substituted or unsubstituted carbazole group, or a substituted or unsubstituted dibenzofuran group. n3 may be 5, four among five R₃ may be deuterium atoms, and the remaining one may be a substituted or unsubstituted silyl group. n3 may be 5, three among five R₃ may be deuterium atoms, and remaining two may be each independently a substituted or unsubstituted silyl group or a substituted or unsubstituted cyclohexyl group. However, these are illustrations, and one or more embodiments of the present disclosure is not limited thereto.

For example, Formula A-2 may be represented by any one among A-201 to A-250. In A-201 to A-250, R₃ is embodied.

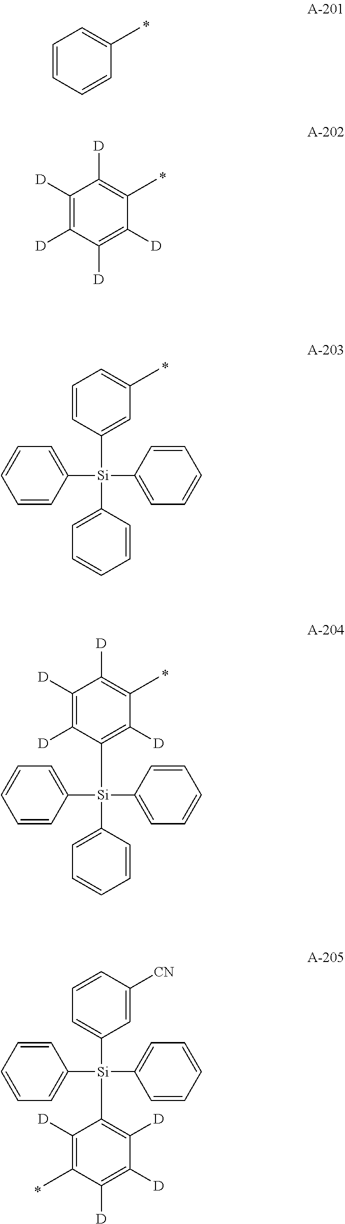

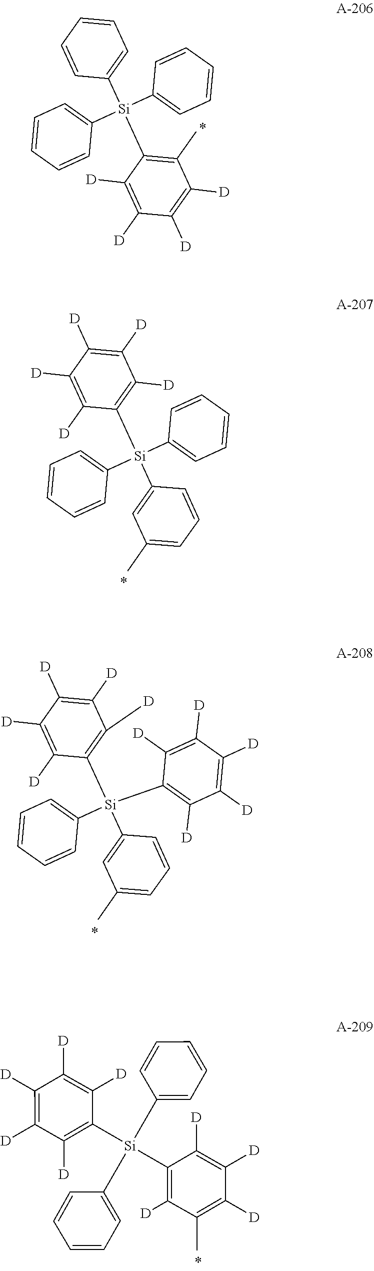 [SMILES: [2H]c1c([2H])c([2H])c([Si](c2ccccc2)(c2ccccc2)c2ccccc2)c(C)c1[2H] ; [2H]c1c([2H])c([2H])c([Si](c2ccccc2)(c2ccccc2)c2cccc(C)c2)c([2H])c1[2H] ; [2H]c1c([2H])c([2H])c([Si](c2ccccc2)(c2cccc(C)c2)c2c([2H])c([2H])c([2H])c([2H])c2[2H])c([2H])c1[2H] ; [2H]c1c([2H])c([2H])c([Si](c2ccccc2)(c2ccccc2)c2c([2H])c([2H])c([2H])c(C)c2[2H])c([2H])c1[2H]]

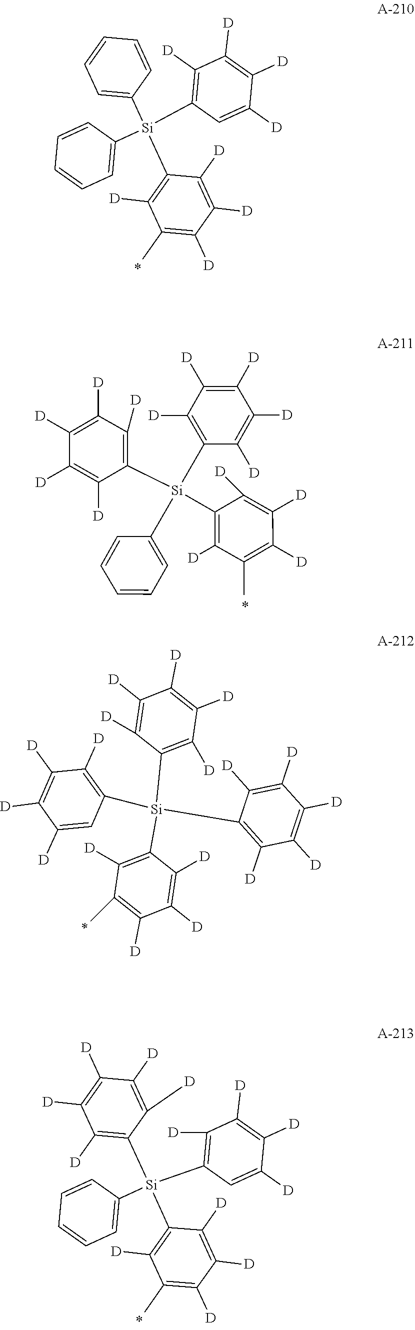 [SMILES: [2H]c1cc([Si](c2ccccc2)(c2ccccc2)c2c([2H])c([2H])c([2H])c(C)c2[2H])c([2H])c([2H])c1[2H] ; [2H]c1c([2H])c([2H])c([Si](c2ccccc2)(c2c([2H])c([2H])c([2H])c([2H])c2[2H])c2c([2H])c([2H])c([2H])c(C)c2[2H])c([2H])c1[2H] ; [2H]c1cc([Si](c2c([2H])c([2H])c([2H])c([2H])c2[2H])(c2c([2H])c([2H])c([2H])c([2H])c2[2H])c2c([2H])c([2H])c([2H])c(C)c2[2H])c([2H])c([2H])c1[2H] ; [2H]c1cc([Si](c2ccccc2)(c2c([2H])c([2H])c([2H])c([2H])c2[2H])c2c([2H])c([2H])c([2H])c(C)c2[2H])c([2H])c([2H])c1[2H]]

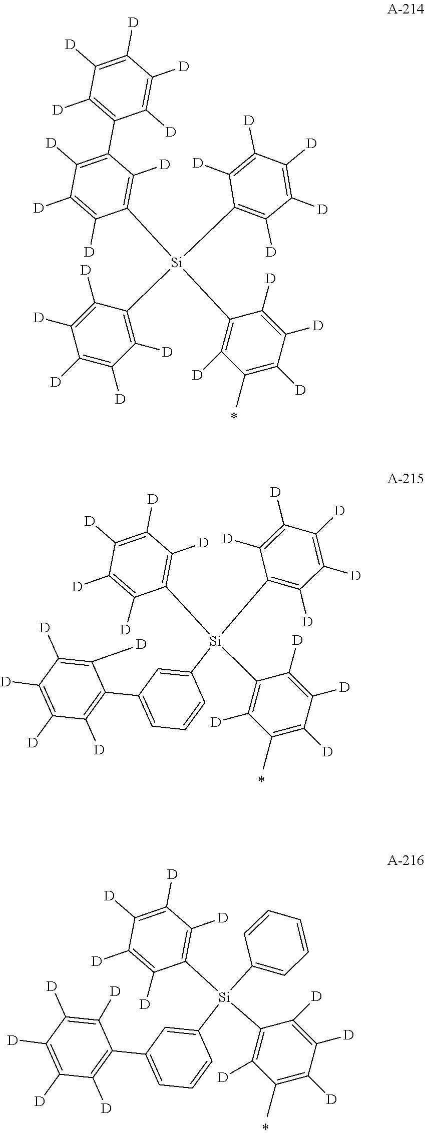 [SMILES: [2H]c1c([2H])c([2H])c(-c2c([2H])c([2H])c([2H])c([Si](c3c([2H])c([2H])c([2H])c([2H])c3[2H])(c3c([2H])c([2H])c([2H])c([2H])c3[2H])c3c([2H])c([2H])c([2H])c(C)c3[2H])c2[2H])c([2H])c1[2H] ; [2H]c1c([2H])c([2H])c(-c2cccc([Si](c3c([2H])c([2H])c([2H])c([2H])c3[2H])(c3c([2H])c([2H])c([2H])c([2H])c3[2H])c3c([2H])c([2H])c([2H])c(C)c3[2H])c2)c([2H])c1[2H] ; [2H]c1c([2H])c([2H])c(-c2cccc([Si](c3ccccc3)(c3c([2H])c([2H])c([2H])c([2H])c3[2H])c3c([2H])c([2H])c([2H])c(C)c3[2H])c2)c([2H])c1[2H]]

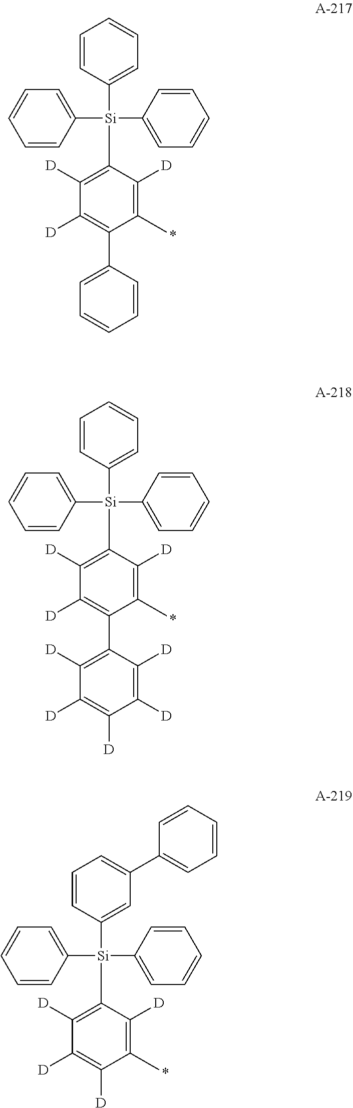 [SMILES: [2H]c1c([2H])c([Si](c2ccccc2)(c2ccccc2)c2ccccc2)c([2H])c(C)c1-c1ccccc1 ; [2H]c1c([2H])c([2H])c(-c2c([2H])c([2H])c([Si](c3ccccc3)(c3ccccc3)c3ccccc3)c([2H])c2C)c([2H])c1[2H] ; [2H]c1c([2H])c(C)c([2H])c([Si](c2ccccc2)(c2ccccc2)c2cccc(-c3ccccc3)c2)c1[2H]]

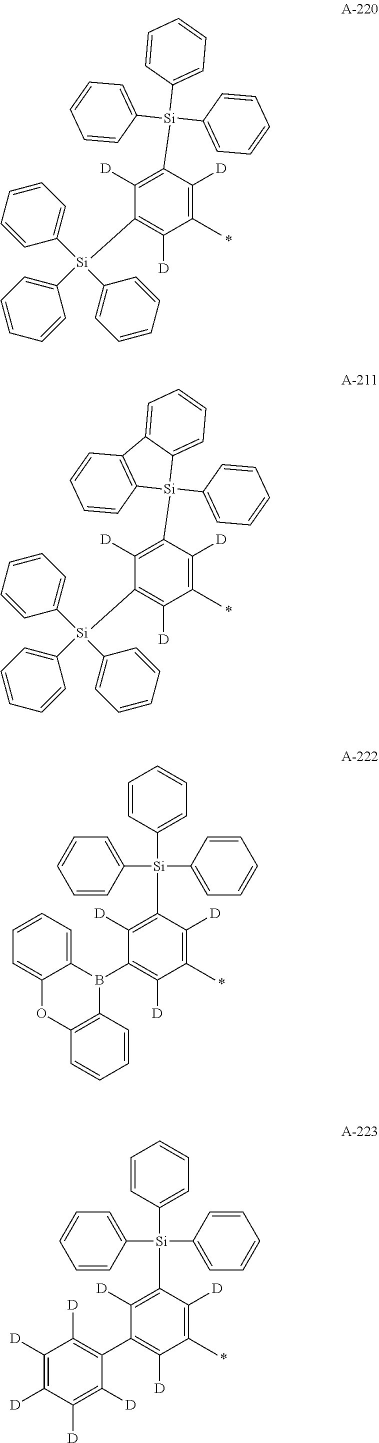 [SMILES: [2H]c1c(C)c([2H])c([Si](c2ccccc2)(c2ccccc2)c2ccccc2)c([2H])c1[Si](c1ccccc1)(c1ccccc1)c1ccccc1 ; [2H]c1c(C)c([2H])c([Si]2(c3ccccc3)c3ccccc3-c3ccccc32)c([2H])c1[Si](c1ccccc1)(c1ccccc1)c1ccccc1 ; [2H]c1c(C)c([2H])c([Si](c2ccccc2)(c2ccccc2)c2ccccc2)c([2H])c1B1c2ccccc2Oc2ccccc21 ; [2H]c1c([2H])c([2H])c(-c2c([2H])c(C)c([2H])c([Si](c3ccccc3)(c3ccccc3)c3ccccc3)c2[2H])c([2H])c1[2H]]

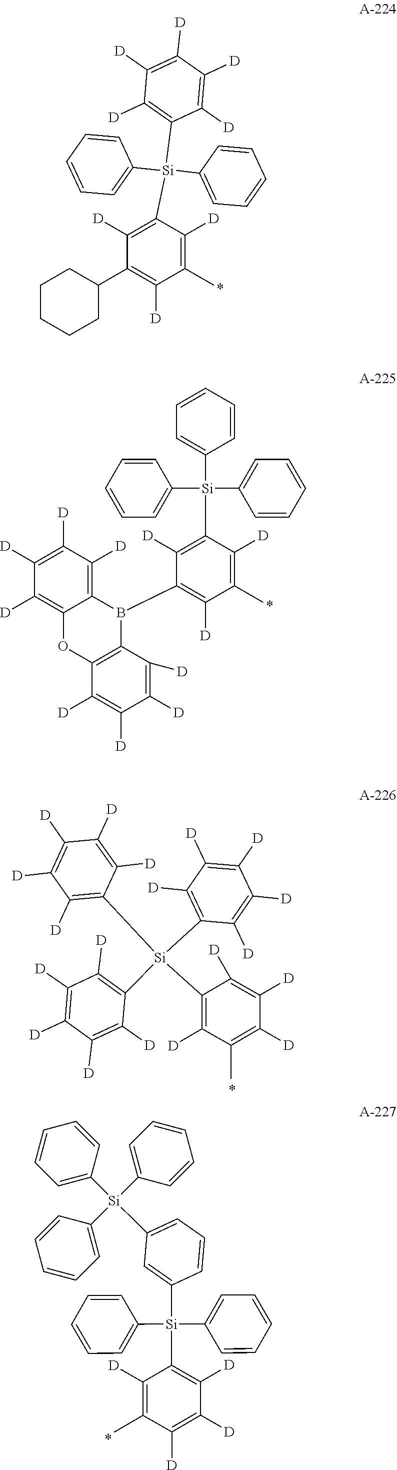 [SMILES: [2H]c1c([2H])c([2H])c([Si](c2ccccc2)(c2ccccc2)c2c([2H])c(C)c([2H])c(C3CCCCC3)c2[2H])c([2H])c1[2H] ; [2H]c1c([2H])c([2H])c2c(c1[2H])Oc1c([2H])c([2H])c([2H])c([2H])c1B2c1c([2H])c(C)c([2H])c([Si](c2ccccc2)(c2ccccc2)c2ccccc2)c1[2H] ; [2H]c1c([2H])c([2H])c([Si](c2c([2H])c([2H])c([2H])c([2H])c2[2H])(c2c([2H])c([2H])c([2H])c([2H])c2[2H])c2c([2H])c([2H])c([2H])c(C)c2[2H])c([2H])c1[2H] ; [2H]c1c([2H])c(C)c([2H])c([Si](c2ccccc2)(c2ccccc2)c2cccc([Si](c3ccccc3)(c3ccccc3)c3ccccc3)c2)c1[2H]]

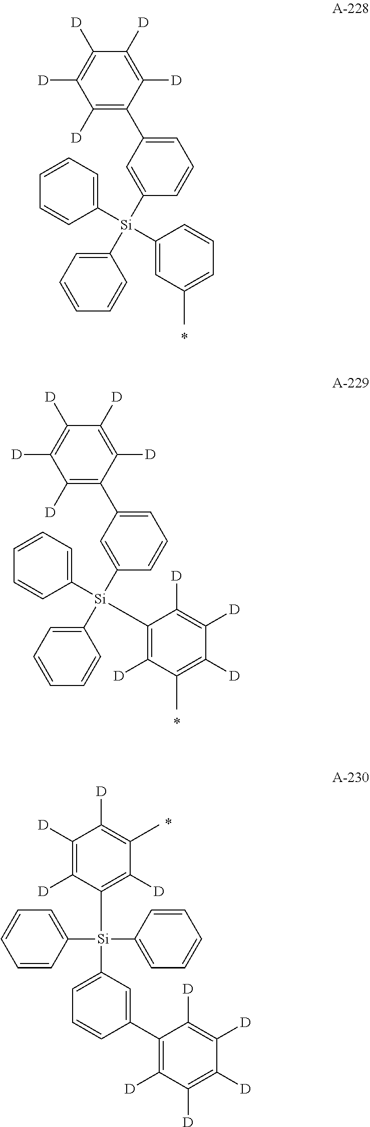 [SMILES: [2H]c1c([2H])c([2H])c(-c2cccc([Si](c3ccccc3)(c3ccccc3)c3cccc(C)c3)c2)c([2H])c1[2H] ; [2H]c1c([2H])c([2H])c(-c2cccc([Si](c3ccccc3)(c3ccccc3)c3c([2H])c([2H])c([2H])c(C)c3[2H])c2)c([2H])c1[2H] ; [2H]c1c([2H])c([2H])c(-c2cccc([Si](c3ccccc3)(c3ccccc3)c3c([2H])c([2H])c([2H])c(C)c3[2H])c2)c([2H])c1[2H]]

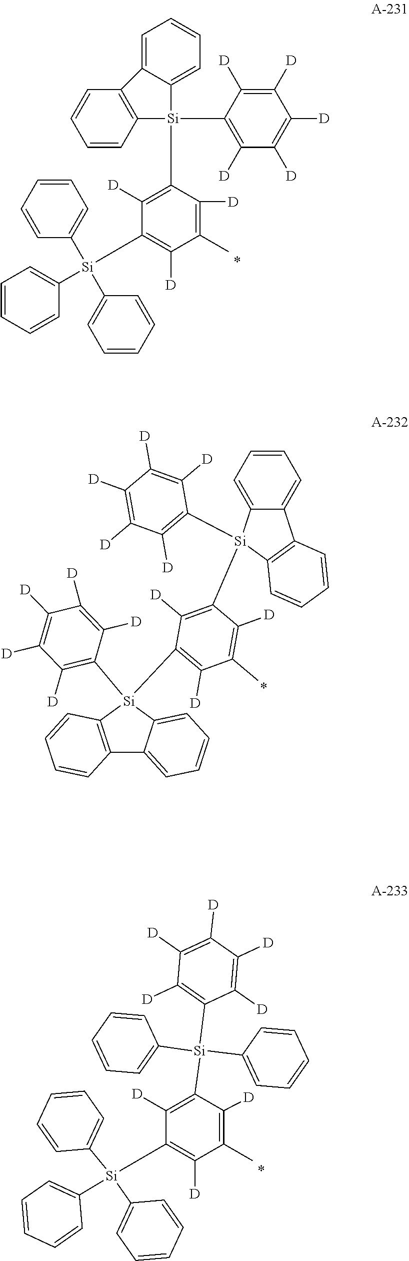 [SMILES: [2H]c1c([2H])c([2H])c([Si]2(c3c([2H])c(C)c([2H])c([Si](c4ccccc4)(c4ccccc4)c4ccccc4)c3[2H])c3ccccc3-c3ccccc32)c([2H])c1[2H] ; [2H]c1c([2H])c([2H])c([Si]2(c3c([2H])c(C)c([2H])c([Si]4(c5c([2H])c([2H])c([2H])c([2H])c5[2H])c5ccccc5-c5ccccc54)c3[2H])c3ccccc3-c3ccccc32)c([2H])c1[2H] ; [2H]c1c([2H])c([2H])c([Si](c2ccccc2)(c2ccccc2)c2c([2H])c(C)c([2H])c([Si](c3ccccc3)(c3ccccc3)c3ccccc3)c2[2H])c([2H])c1[2H]]

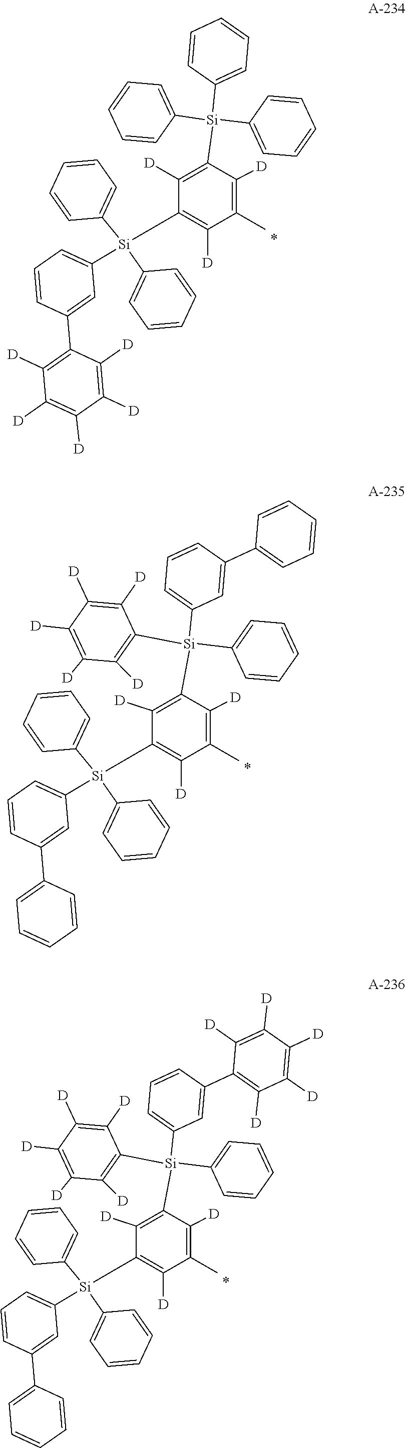 [SMILES: [2H]c1c([2H])c([2H])c(-c2cccc([Si](c3ccccc3)(c3ccccc3)c3c([2H])c(C)c([2H])c([Si](c4ccccc4)(c4ccccc4)c4ccccc4)c3[2H])c2)c([2H])c1[2H] ; [2H]c1c([2H])c([2H])c([Si](c2ccccc2)(c2cccc(-c3ccccc3)c2)c2c([2H])c(C)c([2H])c([Si](c3ccccc3)(c3ccccc3)c3cccc(-c4ccccc4)c3)c2[2H])c([2H])c1[2H] ; [2H]c1c([2H])c([2H])c(-c2cccc([Si](c3ccccc3)(c3c([2H])c([2H])c([2H])c([2H])c3[2H])c3c([2H])c(C)c([2H])c([Si](c4ccccc4)(c4ccccc4)c4cccc(-c5ccccc5)c4)c3[2H])c2)c([2H])c1[2H]]

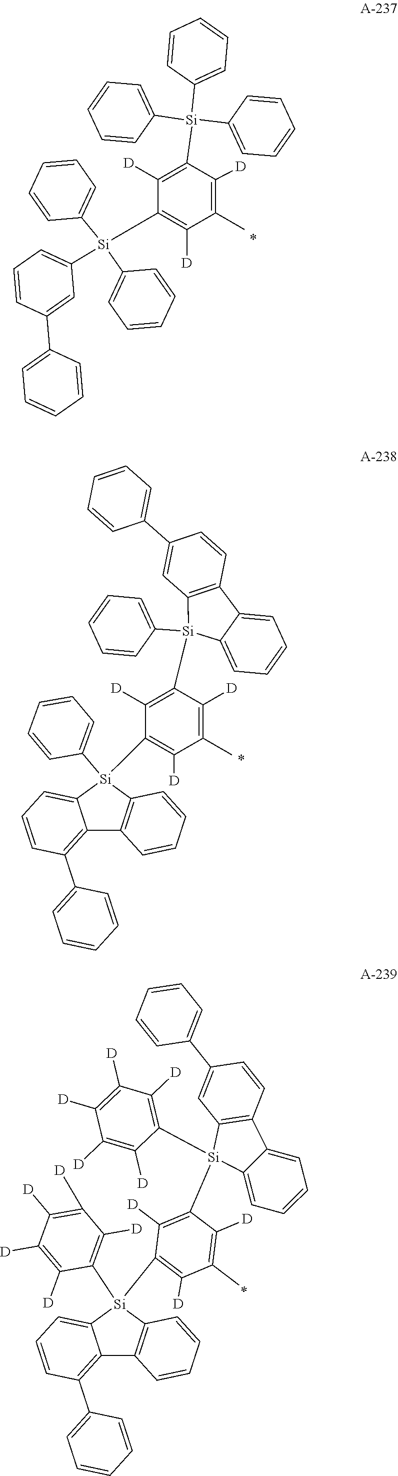 [SMILES: [2H]c1c(C)c([2H])c([Si](c2ccccc2)(c2ccccc2)c2cccc(-c3ccccc3)c2)c([2H])c1[Si](c1ccccc1)(c1ccccc1)c1ccccc1 ; [2H]c1c(C)c([2H])c([Si]2(c3ccccc3)c3ccccc3-c3c(-c4ccccc4)cccc32)c([2H])c1[Si]1(c2ccccc2)c2ccccc2-c2ccc(-c3ccccc3)cc21 ; [2H]c1c([2H])c([2H])c([Si]2(c3c([2H])c(C)c([2H])c([Si]4(c5c([2H])c([2H])c([2H])c([2H])c5[2H])c5ccccc5-c5c(-c6ccccc6)cccc54)c3[2H])c3ccccc3-c3ccc(-c4ccccc4)cc32)c([2H])c1[2H]]

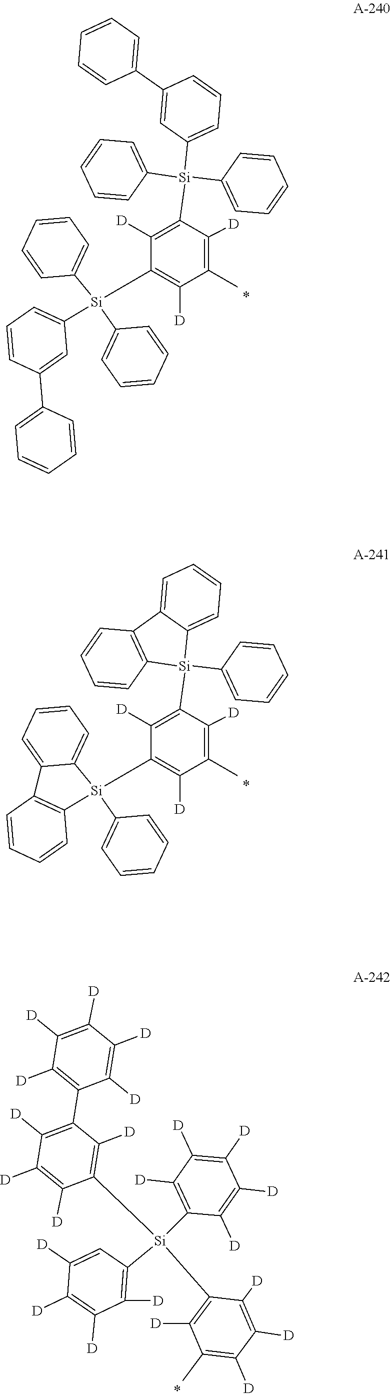 [SMILES: [2H]c1c(C)c([2H])c([Si](c2ccccc2)(c2ccccc2)c2cccc(-c3ccccc3)c2)c([2H])c1[Si](c1ccccc1)(c1ccccc1)c1cccc(-c2ccccc2)c1 ; [2H]c1c(C)c([2H])c([Si]2(c3ccccc3)c3ccccc3-c3ccccc32)c([2H])c1[Si]1(c2ccccc2)c2ccccc2-c2ccccc21 ; [2H]c1cc([Si](c2c([2H])c([2H])c([2H])c([2H])c2[2H])(c2c([2H])c([2H])c([2H])c(C)c2[2H])c2c([2H])c([2H])c([2H])c(-c3c([2H])c([2H])c([2H])c([2H])c3[2H])c2[2H])c([2H])c([2H])c1[2H]]

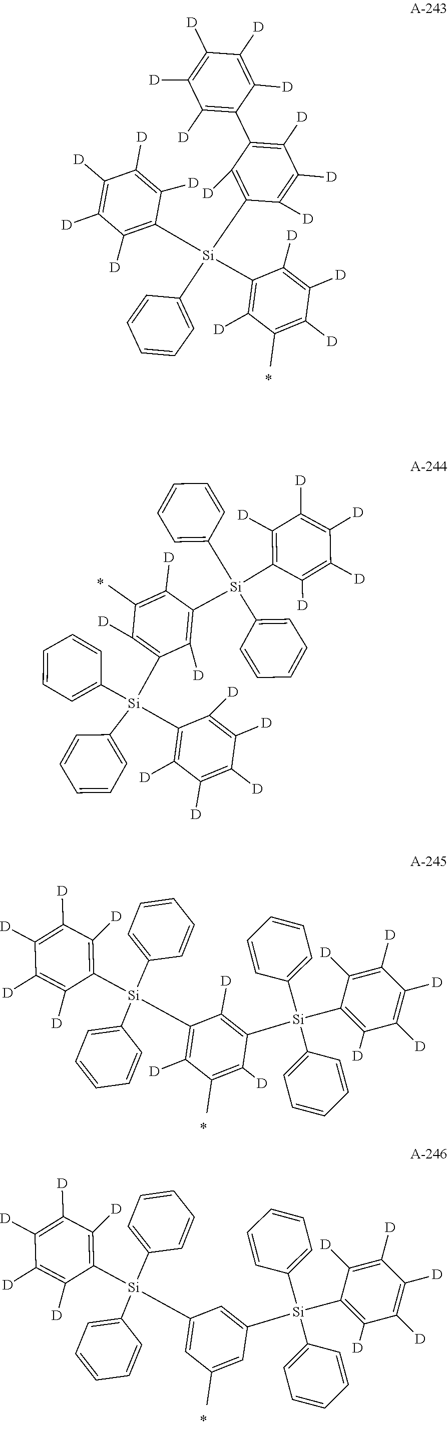

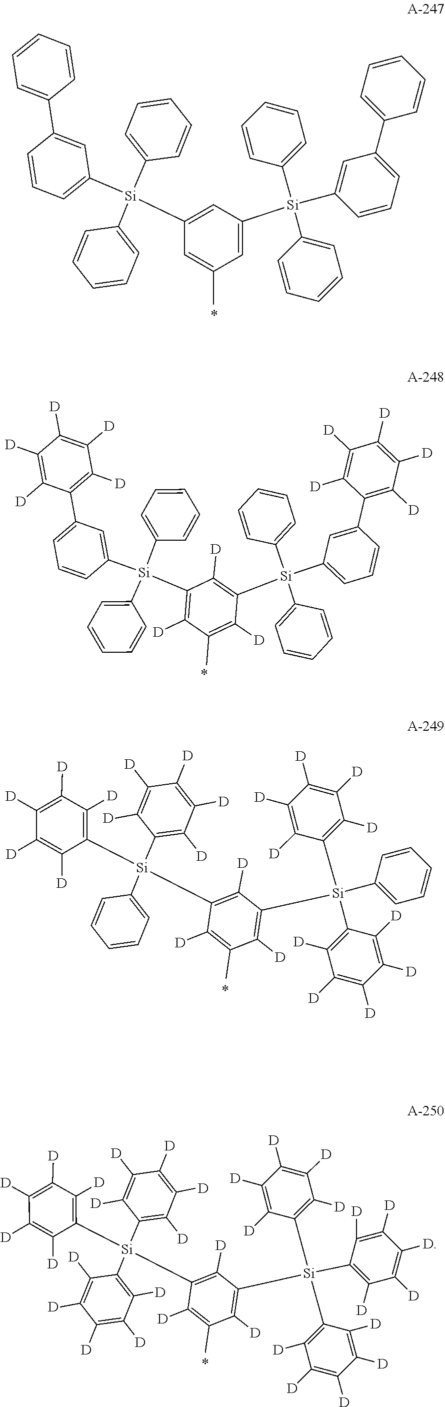

Formula A-3 represents a substituted or unsubstituted heterocycle of three rings, including N as a ring-forming atom, wherein N is a position directly or indirectly bonded to Formula 1. Formula A-4 represents a heterocycle of three rings, including N, O or S as a ring-forming atom, wherein carbon atom (rather than N, O, or S) is a position bonded to Formula 1.

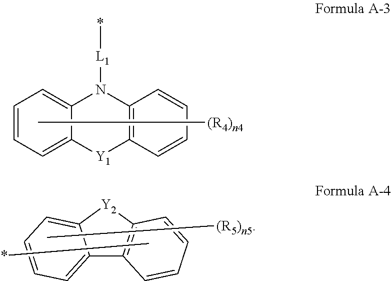

In Formula A-3, n4 may be an integer of 0 to 8. If n4 is an integer of 2 or more, multiple R₄ may be the same, or at least one may be different.

In Formula A-3, L₁ may be a direct linkage or a substituted or unsubstituted arylene group of 6 to 60 ring-forming carbon atoms. If L₁ is a direct linkage, N in Formula A-3 may be a position directly bonded to Formula 1. If L₁ is an arylene group, L₁ in Formula A-3 may be a position directly bonded to Formula 1.

In Formula A-3, Y₁ may be a direct linkage, SiR₆R₇, O, or S. If Y₁ is a direct linkage, Formula A-3 may be a substituted or unsubstituted carbazole group. If Y₁ is SiR₆R₇, Formula A-3 may be a substituted or unsubstituted dibenzoazasiline group. If Y₁ is O, Formula A-3 may be a substituted or unsubstituted phenoxazine group. If Y₁ is S, Formula A-3 may be a substituted or unsubstituted phenothiazine group.

In Formula A-3, Y₁ may be SiR₆R₇, R₆ and R₇ may be each independently a substituted or unsubstituted aryl group of 6 to 20 ring-forming carbon atoms. In Formula A-3, Y₁ may be a direct linkage, and R₄ may be a deuterium atom or a substituted or unsubstituted silyl group. In Formula A-3, Y₁ may be O or S, and R₄ may be a hydrogen atom.

In Formula A-3 and Formula A-4, R₄ to R₈ may be each independently a hydrogen atom, a deuterium atom, a cyano group, a substituted or unsubstituted silyl group, a substituted or unsubstituted alkyl group of 1 to 30 carbon atoms, a substituted or unsubstituted aryl group of 6 to 60 ring-forming carbon atoms, or a substituted or unsubstituted heteroaryl group of 2 to 60 ring-forming carbon atoms. If any one among A₁ to A₃ is represented by any one among Formula A-2 to Formula A-4, at least one among R₃ to R₈ may include a deuterium atom. For example, any one among A₁ to A₃ may be represented by any one among Formula A-2 to Formula A-4, and at least one among R₃ to R₈ may be a deuterium atom. In some embodiments, any one among A₁ to A₃ may be represented by any one among Formula A-2 to Formula A-4, and at least one among R₃ to R₈ may include a deuterium atom as a substituent. For example, Formula A-3 may be represented by any one among A-31 to A-38.

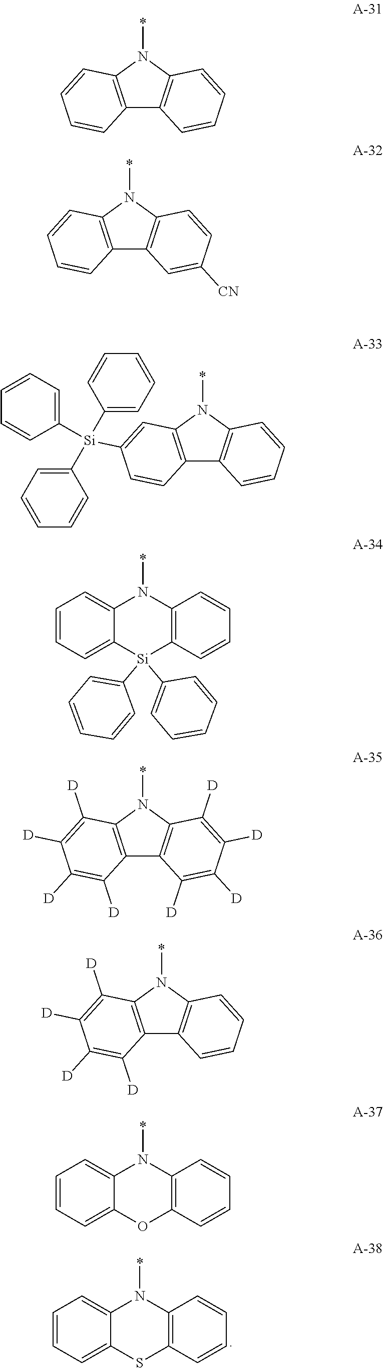

In Formula A-4, n5 may be an integer of 0 to 7. If n5 is an integer of 2 or more, multiple R₅ may be the same, or at least one may be different.

In Formula A-4, Y₂ may be NRs, O or S. If Y₂ is NRs, Formula A-4 may be a substituted or unsubstituted carbazole group. If Y₂ is O, Formula A-4 may be a substituted or unsubstituted dibenzofuran group. If Y₂ is S, Formula A-4 may be a substituted or unsubstituted dibenzothiophene group.

In Formula A-4, Y₂ may be S, and R₅ may be a deuterium atom or a substituted or unsubstituted silyl group. In Formula A-4, Y₂ may be O, and R₅ may be a deuterium atom or a substituted and unsubstituted silyl group. For example, Formula A-4 may be represented by any one among A-41 to A-43.

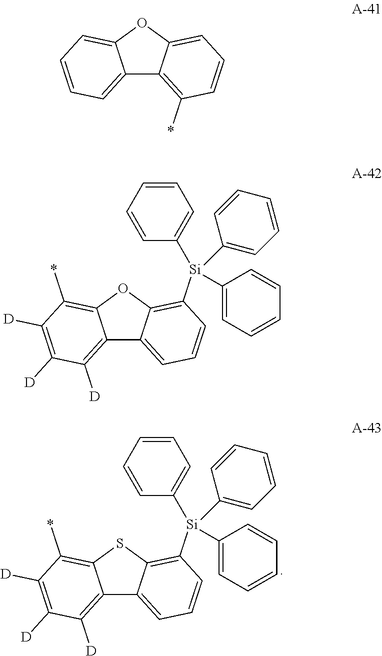 [SMILES: *c1cccc2oc3ccccc3c12 ; *c1c([2H])c([2H])c([2H])c2c1oc1c([Si](c3ccccc3)(c3ccccc3)c3ccccc3)cccc12 ; *c1c([2H])c([2H])c([2H])c2c1sc1c([Si](c3ccccc3)(c3ccccc3)c3ccccc3)cccc12]

In one or more embodiments, Formula 1 may be represented by Formula 1-1A or Formula 1-11B. Formula 1-1A represents a case of Formula 1 where any two among X₁ to X₃ are N. Formula 1-1B represents a case of Formula 1 where all among X₁ to X₃ are N.

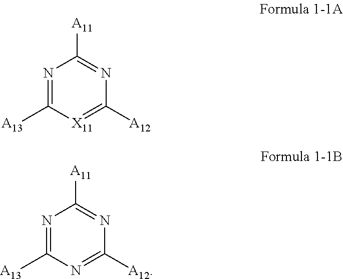

In Formula 1-1A and Formula 1-1B, A₁₁ to A₁₃ may be each independently a substituted or unsubstituted amine group, a substituted or unsubstituted aryl group of 6 to 60 ring-forming carbon atoms, or a substituted or unsubstituted heteroaryl group of 2 to 60 ring-forming carbon atoms. According to one or more embodiments, at least one among A₁₁ to A₁₃ may include the first substituent.

In Formula 1-1A, X₁₁ may be CH or CD. In Formula 1-1A, if X₁₁ is CH, at least one among A₁₁ to A₁₃ may include a deuterium atom. For example, at least one among A₁₁ to A₁₃ may be a substituted aryl group, and the substituted aryl group may be substituted with the first substituent. At least one among A₁₁ to A₁₃ may be a substituted heteroaryl group, and the substituted heteroaryl group may be substituted with the first substituent.

In Formula 1-1B, at least one among A₁₁ to A₁₃ may include a deuterium atom as a substituent. For example, at least one among A₁₁ to A₁₃ may include a deuterium atom and the first substituent. In some embodiments, at least one among A₁₁ to A₁₃ may include a deuterium atom as a substituent, and at least one among the remainder of A₁₁ to A₁₃ (excluding the A₁₁ to A₁₃, including a deuterium atom as a substituent), may include the first substituent.

In one or more embodiments, Formula 1 may be represented by any one among Formula 1-2A to Formula 1-2C. Formula 1-2A to Formula 1-2C represent cases of Formula 1 where one or two among A₁ to A₃ include the first substituent. In Formula 1-2A to Formula 1-2C, the first substituent may be a substituted or unsubstituted silyl group including R₁₂ to R₁₄.

Formula 1-2A represents a case of Formula 1 where any one among A₁ to A₃ is a substituted phenyl group, and the substituted phenyl group is substituted with the first substituent. Formula 1-2B represents a case of Formula 1 where any two among A₁ to A₃ are substituted phenyl groups, and the substituted phenyl groups are each independently substituted with the first substituent. Formula 1-2C represents a case of Formula 1 where any one among A₁ to A₃ is a substituted phenyl group, and the substituted phenyl group is substituted with two first substituents.

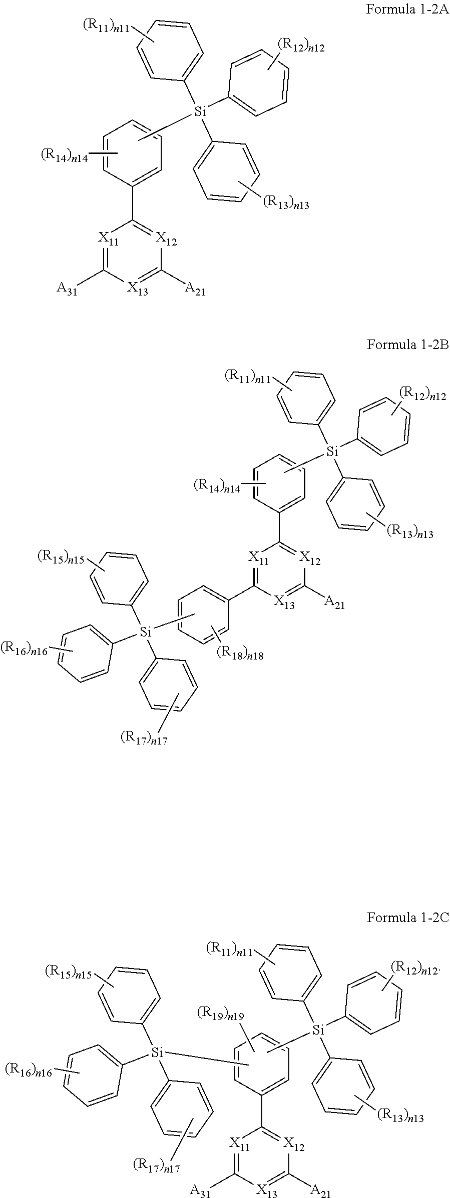

In Formula 1-2A to Formula 1-2C, at least one among hydrogen atoms in A₂₁, hydrogen atoms in A₃₁, hydrogen atoms in X₁₁ to X₁₃, and hydrogen atoms in R₁₁ to R₁₈, may be substituted with a deuterium atom.

In Formula 1-2A to Formula 1-2C, at least one among X₁₁ to X₁₃ may be N, and the remainder may be CH. X₁₁ to X₁₃ may correspond to X₁ to X₃ of Formula 1. For X₁₁ to X₁₃, the same explanation on X₁ to X₃ of Formula 1 may be applied.

In Formula 1-2A to Formula 1-2C, A₂₁ and A₃₁ may be each independently a substituted or unsubstituted aryl group of 6 to 60 ring-forming carbon atoms, or a substituted or unsubstituted heteroaryl group of 2 to 60 ring-forming carbon atoms. A₂₁ and A₃₁ may correspond to any two among A₁ to A₃ of Formula 1. A₂₁ and/or A₃₁ may include substituted or unsubstituted silyl groups as substituents. In some embodiments, A₂₁ and/or A₃₁ may not include a substituted or unsubstituted silyl group.

n11 to n13 and n15 to n17 may be each independently an integer of 0 to 5. n14 and n18 may be each independently an integer of 0 to 4, and n19 may be an integer of 0 to 3. If n11 is an integer of 2 or more, multiple R₁₁ may be the same, or at least one may be different. For n12 to n19 and R₁₂ to R₁₉, the same explanation as for n11 and R₁₁, respectively, may be applied.

In Formula 1-2A to Formula 1-2C, R₁₁ to R₁₈ may be each independently a hydrogen atom, a deuterium atom, a cyano group, a substituted or unsubstituted silyl group, a substituted or unsubstituted alkyl group of 1 to 30 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring. For example, R₁₁ to R₁₈ may be each independently a deuterium atom, a cyano group, a substituted or unsubstituted phenyl group, a substituted or unsubstituted silyl group, a substituted or unsubstituted dibenzoazasiline group, or an unsubstituted cyclohexyl group. In some embodiments, adjacent R₁₁ and R₁₂ may be combined to form a substituted or unsubstituted dibenzosilole group. Adjacent R₁₅ and R₁₆ may be combined to form a substituted or unsubstituted dibenzosilole group.

In one or more embodiments, Formula 1-2A may be represented by Formula 1-2AA or Formula 1-2AB. Formula 1-2AA and Formula 1-2AB correspond to Formula 1-2A where the bonding position of the first substituent is embodied.

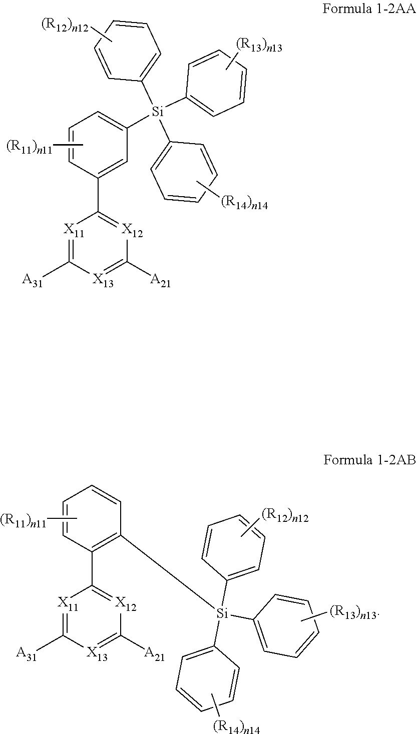

In Formula 1-2AA, on a phenyl group including R₁₁, the first substituent and a ring group including X₁₁ and X₁₃ are bonded at meta positions. In Formula 1-2AB, on a phenyl group including R₁₁, the first substituent and a ring group including X₁₁ and X₁₃ are bonded at ortho positions. In Formula 1-2AA and Formula 1-2AB, for n11 to n14, R₁₁ to R₁₄, A₂₁, A₃₁, and X₁₁ to X₁₃, the same explanations as those provided in connection with Formula 1-2A may be applied.

In one or more embodiments, Formula 1-2A may be represented by Formula 1-2AC. Formula 1-2AC represents a case of Formula 1-2A where A₃₁ is a substituted or unsubstituted carbazole group.

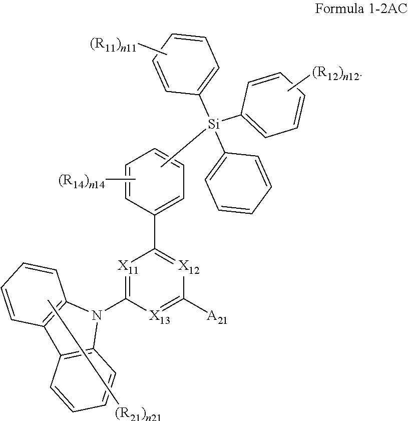

In Formula 1-2AC, n21 may be an integer of 0 to 8. If n21 is an integer of 2 or more, multiple R₂₁ may be the same, or at least one may be different.

In Formula 1-2AC, R₂₁ may be a hydrogen atom, a deuterium atom, a cyano group, a substituted or unsubstituted silyl group, a substituted or unsubstituted alkyl group of 1 to 10 carbon atoms, a substituted or unsubstituted aryl group of 6 to 30 ring-forming carbon atoms, or a substituted or unsubstituted heteroaryl group of 2 to 30 ring-forming carbon atoms. For example, R₂₁ may be a hydrogen atom, a deuterium atom, a cyano group, or a triphenylsilyl group.

In Formula 1-2AC, at least one among hydrogen atoms in A₂₁, hydrogen atoms in X₁₁ to X₁₃, hydrogen atoms in R₁₁ to R₁₄, and hydrogen atoms in R₂₁ may be substituted with a deuterium atom. For n11 to n14, R₁₁ to R₁₄, A₂₁, and X₁₁ to X₁₃, the same explanations as those provided in connection with Formula 1-2A may be applied.

The nitrogen-containing compound of one or more embodiments may be represented by any one among the compounds in Compound Group 1. The light emitting element ED of one or more embodiments may include at least one among the compounds in Compound Group 1. In Compound Group 1, D is a deuterium atom.

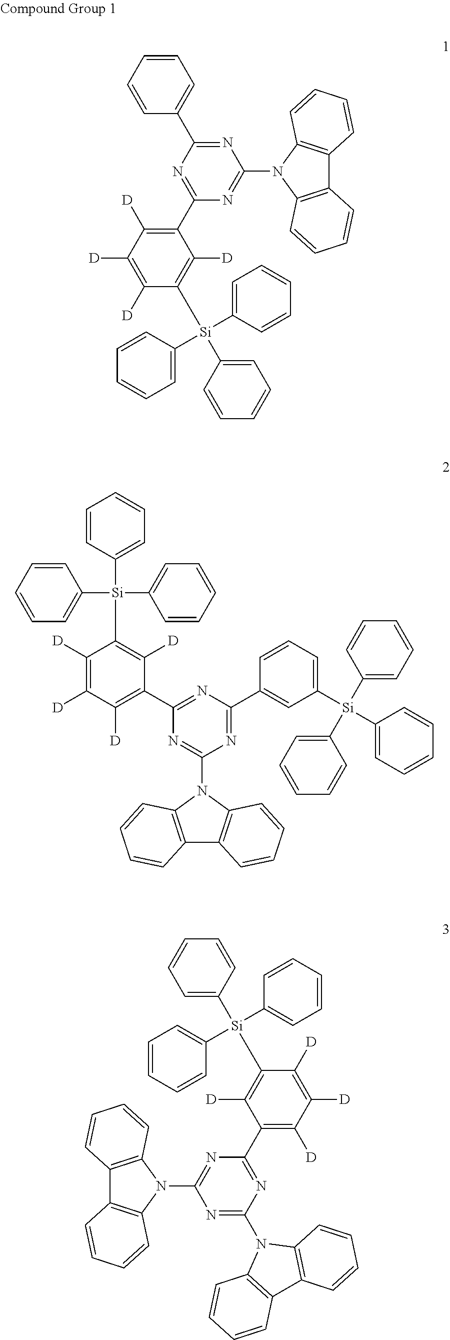 [SMILES: [2H]c1c([2H])c(-c2nc(-c3ccccc3)nc(-n3c4ccccc4c4ccccc43)n2)c([2H])c([Si](c2ccccc2)(c2ccccc2)c2ccccc2)c1[2H] ; [2H]c1c([2H])c(-c2nc(-c3cccc([Si](c4ccccc4)(c4ccccc4)c4ccccc4)c3)nc(-n3c4ccccc4c4ccccc43)n2)c([2H])c([Si](c2ccccc2)(c2ccccc2)c2ccccc2)c1[2H] ; [2H]c1c([2H])c(-c2nc(-n3c4ccccc4c4ccccc43)nc(-n3c4ccccc4c4ccccc43)n2)c([2H])c([Si](c2ccccc2)(c2ccccc2)c2ccccc2)c1[2H]]

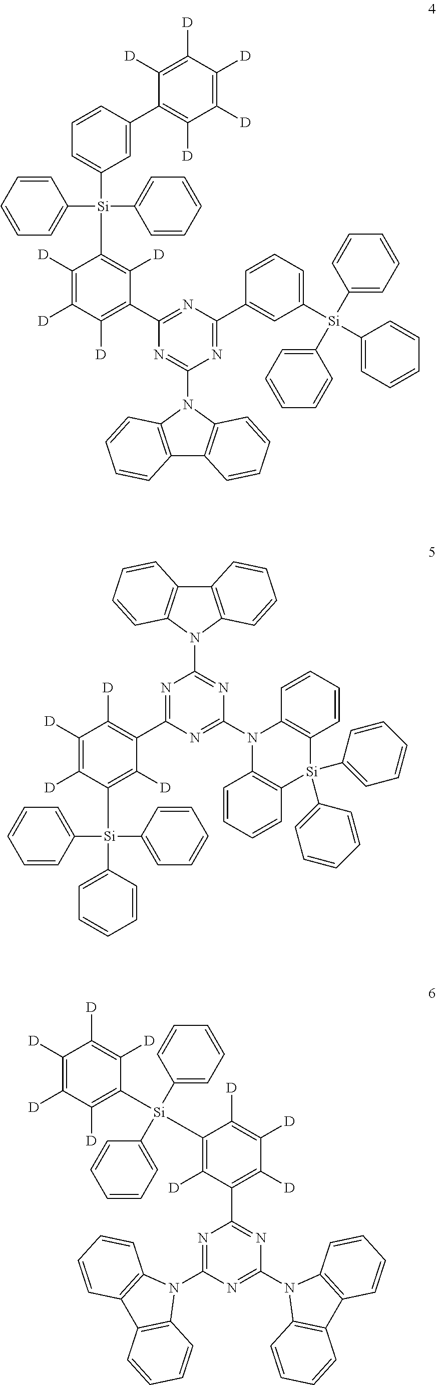 [SMILES: [2H]c1c([2H])c([2H])c(-c2cccc([Si](c3ccccc3)(c3ccccc3)c3c([2H])c([2H])c([2H])c(-c4nc(-c5cccc([Si](c6ccccc6)(c6ccccc6)c6ccccc6)c5)nc(-n5c6ccccc6c6ccccc65)n4)c3[2H])c2)c([2H])c1[2H] ; [2H]c1c([2H])c(-c2nc(N3c4ccccc4[Si](c4ccccc4)(c4ccccc4)c4ccccc43)nc(-n3c4ccccc4c4ccccc43)n2)c([2H])c([Si](c2ccccc2)(c2ccccc2)c2ccccc2)c1[2H] ; [2H]c1c([2H])c([2H])c([Si](c2ccccc2)(c2ccccc2)c2c([2H])c([2H])c([2H])c(-c3nc(-n4c5ccccc5c5ccccc54)nc(-n4c5ccccc5c5ccccc54)n3)c2[2H])c([2H])c1[2H]]

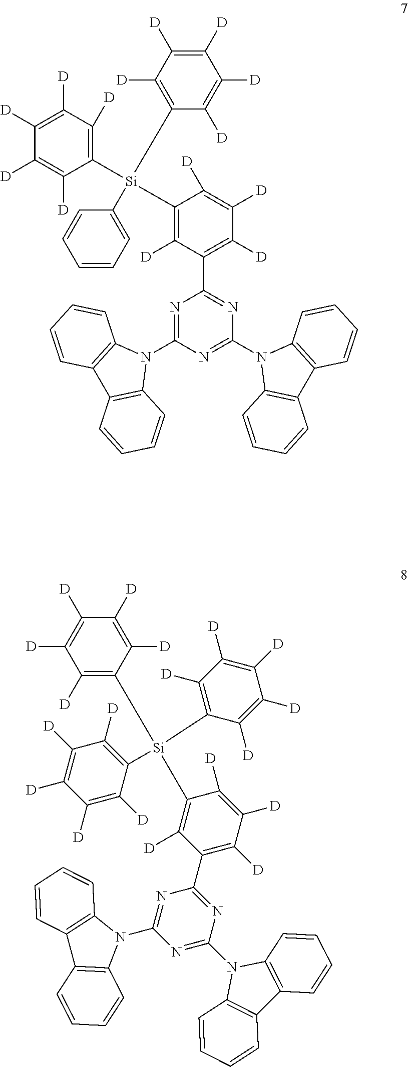 [SMILES: [2H]c1c([2H])c([2H])c([Si](c2ccccc2)(c2c([2H])c([2H])c([2H])c([2H])c2[2H])c2c([2H])c([2H])c([2H])c(-c3nc(-n4c5ccccc5c5ccccc54)nc(-n4c5ccccc5c5ccccc54)n3)c2[2H])c([2H])c1[2H] ; [2H]c1c([2H])c([2H])c([Si](c2c([2H])c([2H])c([2H])c([2H])c2[2H])(c2c([2H])c([2H])c([2H])c([2H])c2[2H])c2c([2H])c([2H])c([2H])c(-c3nc(-n4c5ccccc5c5ccccc54)nc(-n4c5ccccc5c5ccccc54)n3)c2[2H])c([2H])c1[2H]]

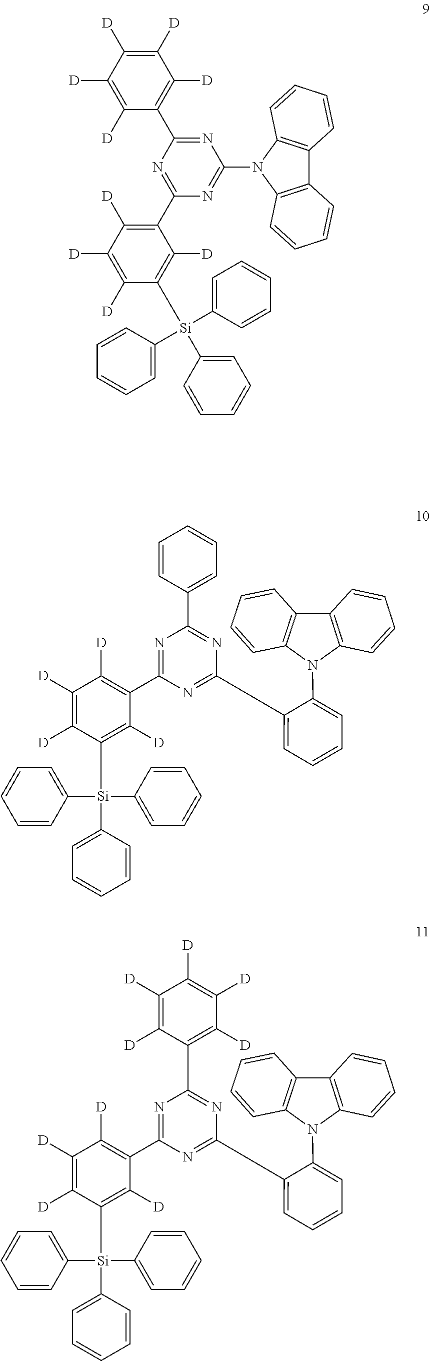 [SMILES: [2H]c1c([2H])c([2H])c(-c2nc(-c3c([2H])c([2H])c([2H])c([Si](c4ccccc4)(c4ccccc4)c4ccccc4)c3[2H])nc(-n3c4ccccc4c4ccccc43)n2)c([2H])c1[2H] ; [2H]c1c([2H])c(-c2nc(-c3ccccc3)nc(-c3ccccc3-n3c4ccccc4c4ccccc43)n2)c([2H])c([Si](c2ccccc2)(c2ccccc2)c2ccccc2)c1[2H] ; [2H]c1c([2H])c([2H])c(-c2nc(-c3ccccc3-n3c4ccccc4c4ccccc43)nc(-c3c([2H])c([2H])c([2H])c([Si](c4ccccc4)(c4ccccc4)c4ccccc4)c3[2H])n2)c([2H])c1[2H]]

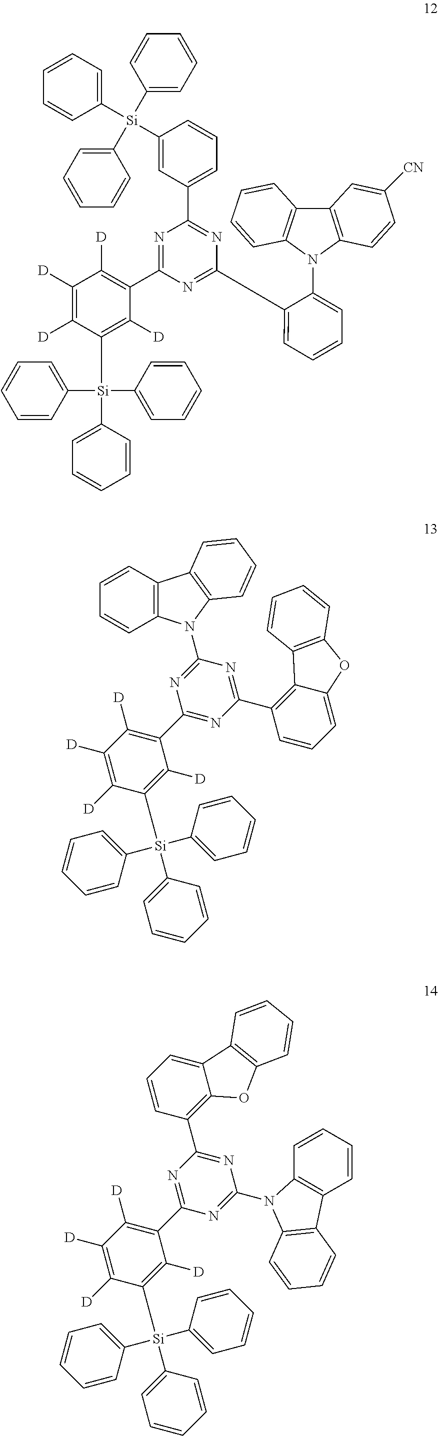 [SMILES: [2H]c1c([2H])c(-c2nc(-c3cccc([Si](c4ccccc4)(c4ccccc4)c4ccccc4)c3)nc(-c3ccccc3-n3c4ccccc4c4cc(C#N)ccc43)n2)c([2H])c([Si](c2ccccc2)(c2ccccc2)c2ccccc2)c1[2H] ; [2H]c1c([2H])c(-c2nc(-c3cccc4oc5ccccc5c34)nc(-n3c4ccccc4c4ccccc43)n2)c([2H])c([Si](c2ccccc2)(c2ccccc2)c2ccccc2)c1[2H] ; [2H]c1c([2H])c(-c2nc(-c3cccc4c3oc3ccccc34)nc(-n3c4ccccc4c4ccccc43)n2)c([2H])c([Si](c2ccccc2)(c2ccccc2)c2ccccc2)c1[2H]]

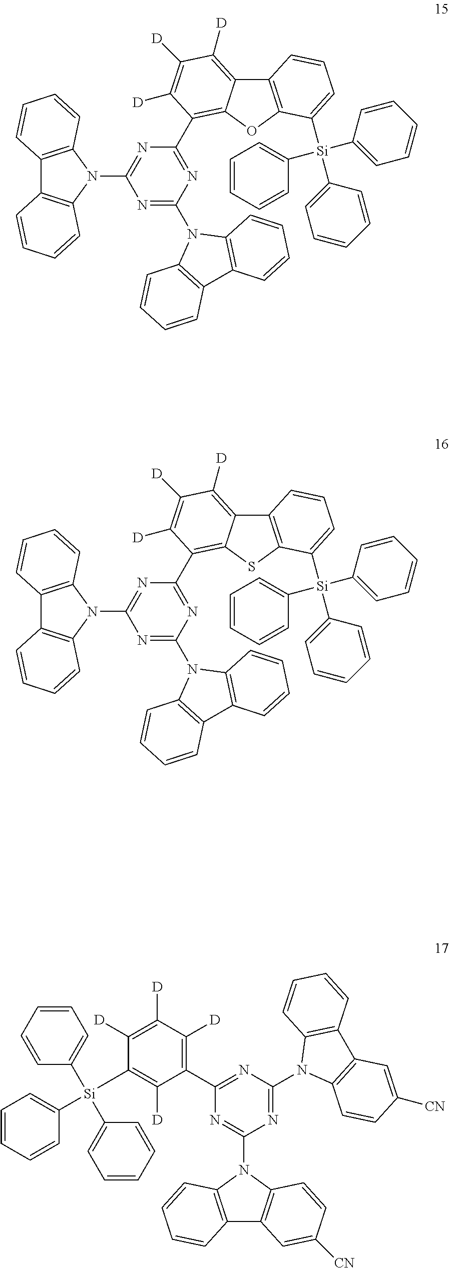 [SMILES: [2H]c1c([2H])c([2H])c2c(oc3c([Si](c4ccccc4)(c4ccccc4)c4ccccc4)cccc32)c1-c1nc(-n2c3ccccc3c3ccccc32)nc(-n2c3ccccc3c3ccccc32)n1 ; [2H]c1c([2H])c([2H])c2c(sc3c([Si](c4ccccc4)(c4ccccc4)c4ccccc4)cccc32)c1-c1nc(-n2c3ccccc3c3ccccc32)nc(-n2c3ccccc3c3ccccc32)n1 ; [2H]c1c([2H])c(-c2nc(-n3c4ccccc4c4cc(C#N)ccc43)nc(-n3c4ccccc4c4cc(C#N)ccc43)n2)c([2H])c([Si](c2ccccc2)(c2ccccc2)c2ccccc2)c1[2H]]

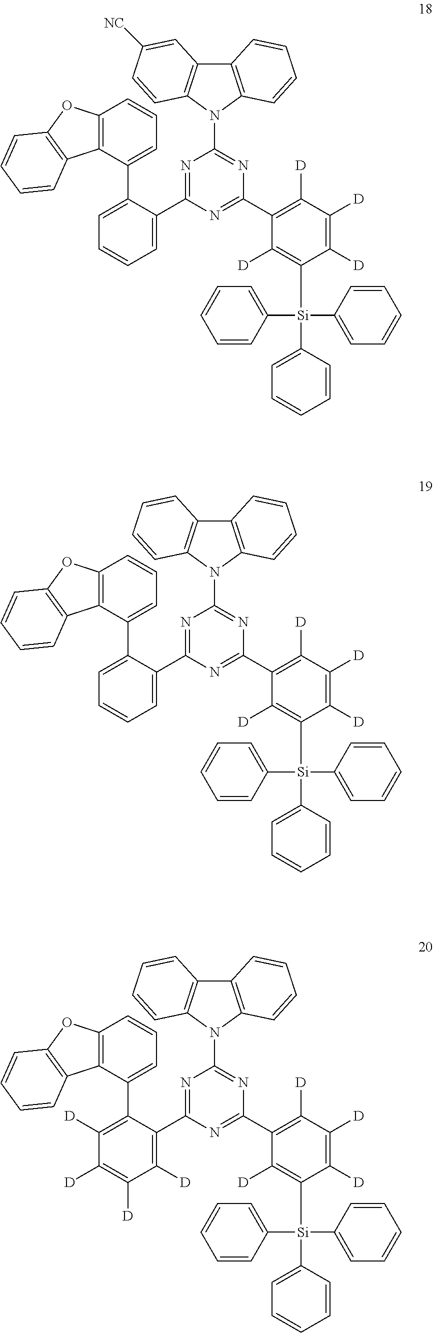 [SMILES: [2H]c1c([2H])c(-c2nc(-c3ccccc3-c3cccc4oc5ccccc5c34)nc(-n3c4ccccc4c4cc(C#N)ccc43)n2)c([2H])c([Si](c2ccccc2)(c2ccccc2)c2ccccc2)c1[2H] ; [2H]c1c([2H])c(-c2nc(-c3ccccc3-c3cccc4oc5ccccc5c34)nc(-n3c4ccccc4c4ccccc43)n2)c([2H])c([Si](c2ccccc2)(c2ccccc2)c2ccccc2)c1[2H] ; [2H]c1c([2H])c([2H])c(-c2cccc3oc4ccccc4c23)c(-c2nc(-c3c([2H])c([2H])c([2H])c([Si](c4ccccc4)(c4ccccc4)c4ccccc4)c3[2H])nc(-n3c4ccccc4c4ccccc43)n2)c1[2H]]

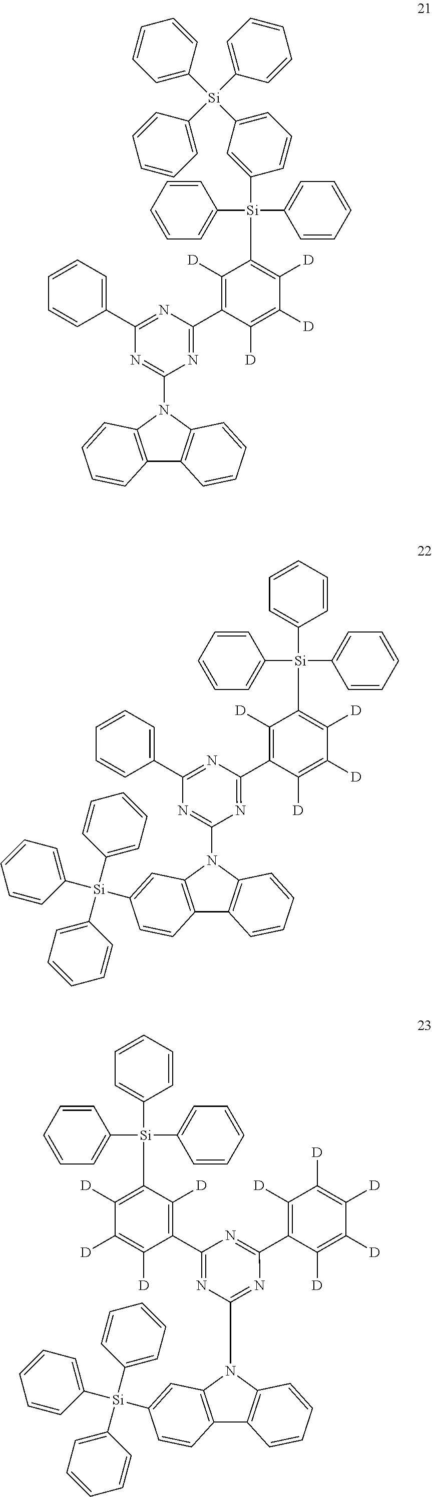 [SMILES: [2H]c1c([2H])c(-c2nc(-c3ccccc3)nc(-n3c4ccccc4c4ccccc43)n2)c([2H])c([Si](c2ccccc2)(c2ccccc2)c2cccc([Si](c3ccccc3)(c3ccccc3)c3ccccc3)c2)c1[2H] ; [2H]c1c([2H])c(-c2nc(-c3ccccc3)nc(-n3c4ccccc4c4ccc([Si](c5ccccc5)(c5ccccc5)c5ccccc5)cc43)n2)c([2H])c([Si](c2ccccc2)(c2ccccc2)c2ccccc2)c1[2H] ; [2H]c1c([2H])c([2H])c(-c2nc(-c3c([2H])c([2H])c([2H])c([Si](c4ccccc4)(c4ccccc4)c4ccccc4)c3[2H])nc(-n3c4ccccc4c4ccc([Si](c5ccccc5)(c5ccccc5)c5ccccc5)cc43)n2)c([2H])c1[2H]]

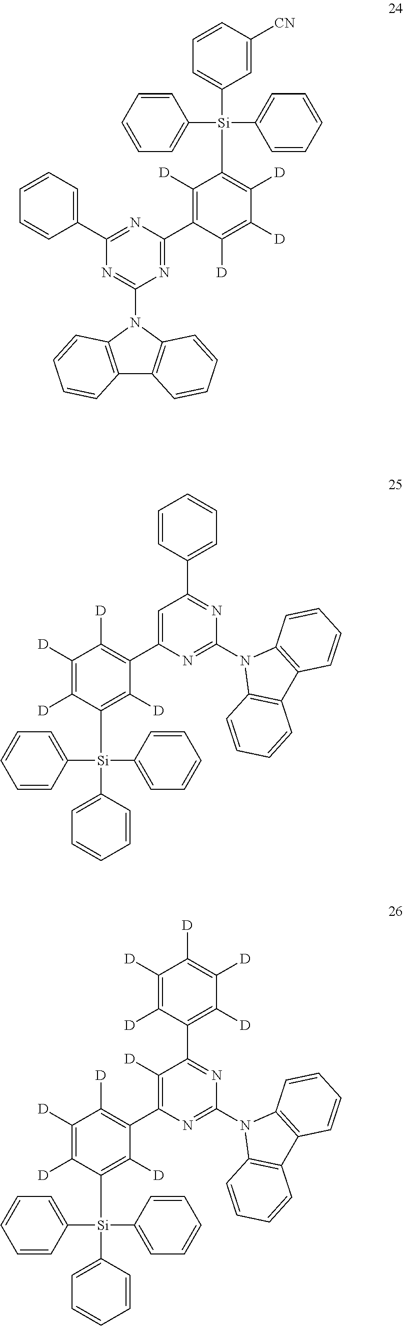 [SMILES: [2H]c1c([2H])c(-c2nc(-c3ccccc3)nc(-n3c4ccccc4c4ccccc43)n2)c([2H])c([Si](c2ccccc2)(c2ccccc2)c2cccc(C#N)c2)c1[2H] ; [2H]c1c([2H])c(-c2cc(-c3ccccc3)nc(-n3c4ccccc4c4ccccc43)n2)c([2H])c([Si](c2ccccc2)(c2ccccc2)c2ccccc2)c1[2H] ; [2H]c1c(-c2c([2H])c([2H])c([2H])c([2H])c2[2H])nc(-n2c3ccccc3c3ccccc32)nc1-c1c([2H])c([2H])c([2H])c([Si](c2ccccc2)(c2ccccc2)c2ccccc2)c1[2H]]

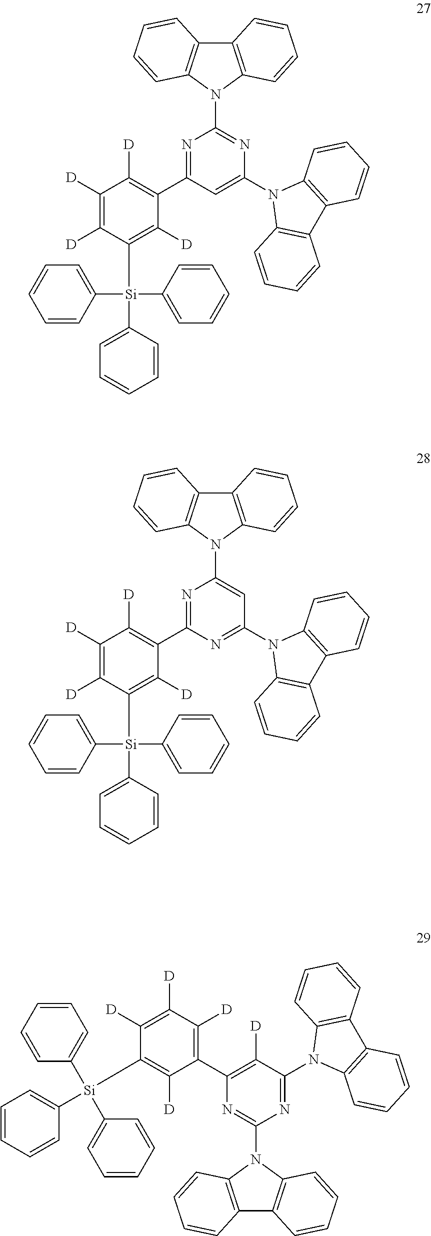 [SMILES: [2H]c1c([2H])c(-c2cc(-n3c4ccccc4c4ccccc43)nc(-n3c4ccccc4c4ccccc43)n2)c([2H])c([Si](c2ccccc2)(c2ccccc2)c2ccccc2)c1[2H] ; [2H]c1c([2H])c(-c2nc(-n3c4ccccc4c4ccccc43)cc(-n3c4ccccc4c4ccccc43)n2)c([2H])c([Si](c2ccccc2)(c2ccccc2)c2ccccc2)c1[2H] ; [2H]c1c(-c2c([2H])c([2H])c([2H])c([Si](c3ccccc3)(c3ccccc3)c3ccccc3)c2[2H])nc(-n2c3ccccc3c3ccccc32)nc1-n1c2ccccc2c2ccccc21]

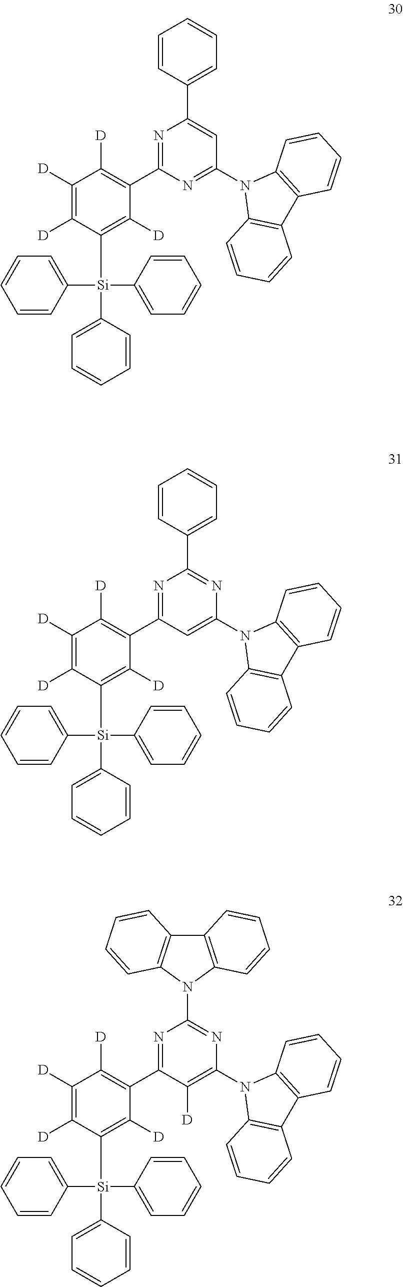 [SMILES: [2H]c1c([2H])c(-c2nc(-c3ccccc3)cc(-n3c4ccccc4c4ccccc43)n2)c([2H])c([Si](c2ccccc2)(c2ccccc2)c2ccccc2)c1[2H] ; [2H]c1c([2H])c(-c2cc(-n3c4ccccc4c4ccccc43)nc(-c3ccccc3)n2)c([2H])c([Si](c2ccccc2)(c2ccccc2)c2ccccc2)c1[2H] ; [2H]c1c(-c2c([2H])c([2H])c([2H])c([Si](c3ccccc3)(c3ccccc3)c3ccccc3)c2[2H])nc(-n2c3ccccc3c3ccccc32)nc1-n1c2ccccc2c2ccccc21]

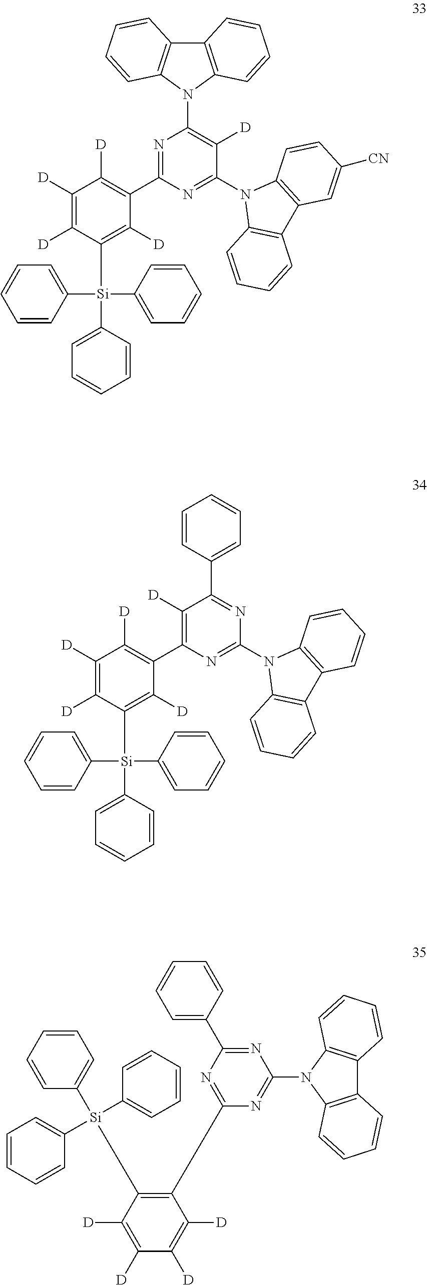 [SMILES: [2H]c1c(-n2c3ccccc3c3ccccc32)nc(-c2c([2H])c([2H])c([2H])c([Si](c3ccccc3)(c3ccccc3)c3ccccc3)c2[2H])nc1-n1c2ccccc2c2cc(C#N)ccc21 ; [2H]c1c(-c2ccccc2)nc(-n2c3ccccc3c3ccccc32)nc1-c1c([2H])c([2H])c([2H])c([Si](c2ccccc2)(c2ccccc2)c2ccccc2)c1[2H] ; [2H]c1c([2H])c([2H])c([Si](c2ccccc2)(c2ccccc2)c2ccccc2)c(-c2nc(-c3ccccc3)nc(-n3c4ccccc4c4ccccc43)n2)c1[2H]]

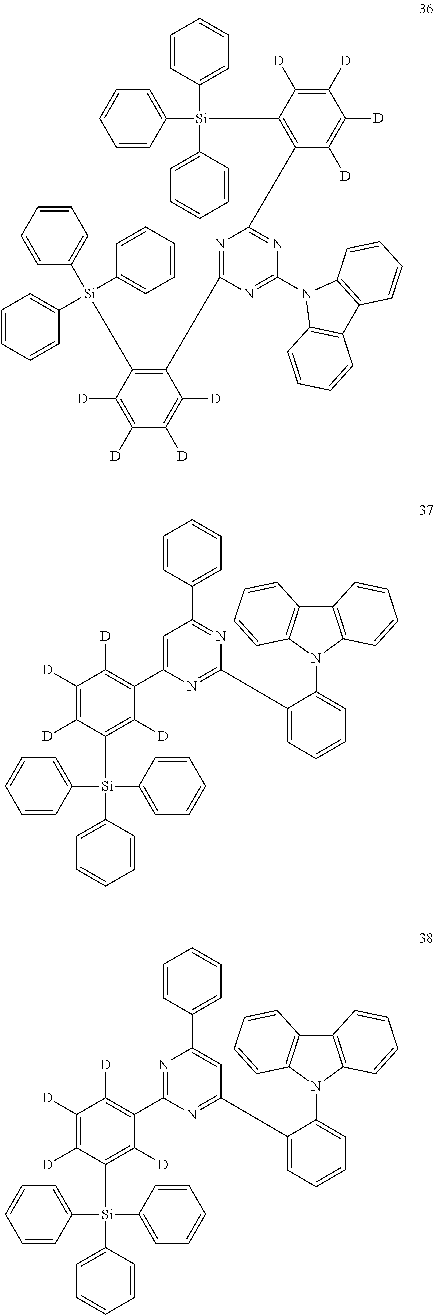 [SMILES: [2H]c1c([2H])c([2H])c([Si](c2ccccc2)(c2ccccc2)c2ccccc2)c(-c2nc(-c3c([2H])c([2H])c([2H])c([2H])c3[Si](c3ccccc3)(c3ccccc3)c3ccccc3)nc(-n3c4ccccc4c4ccccc43)n2)c1[2H] ; [2H]c1c([2H])c(-c2cc(-c3ccccc3)nc(-c3ccccc3-n3c4ccccc4c4ccccc43)n2)c([2H])c([Si](c2ccccc2)(c2ccccc2)c2ccccc2)c1[2H] ; [2H]c1c([2H])c(-c2nc(-c3ccccc3)cc(-c3ccccc3-n3c4ccccc4c4ccccc43)n2)c([2H])c([Si](c2ccccc2)(c2ccccc2)c2ccccc2)c1[2H]]

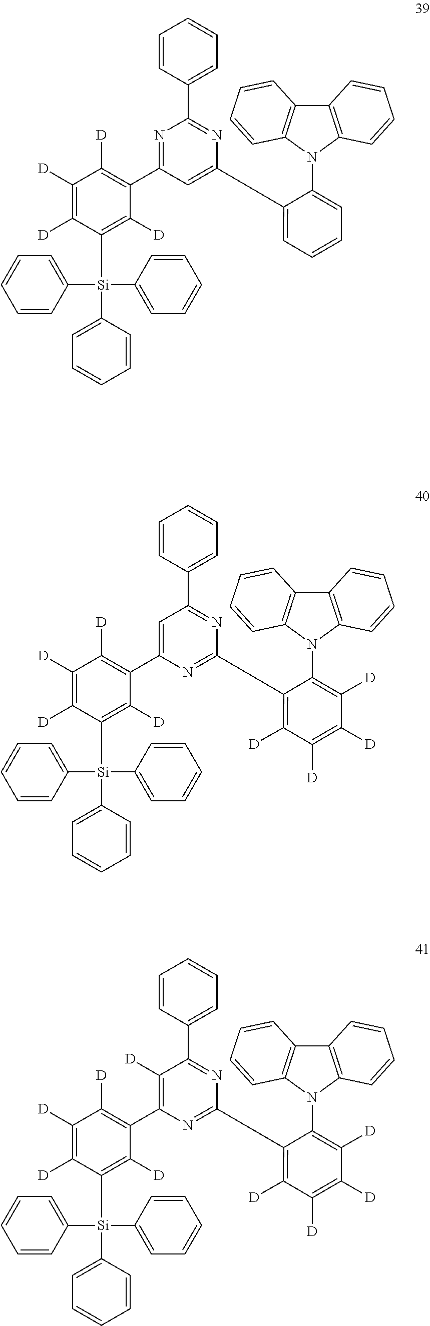 [SMILES: [2H]c1c([2H])c(-c2cc(-c3ccccc3-n3c4ccccc4c4ccccc43)nc(-c3ccccc3)n2)c([2H])c([Si](c2ccccc2)(c2ccccc2)c2ccccc2)c1[2H] ; [2H]c1c([2H])c([2H])c(-n2c3ccccc3c3ccccc32)c(-c2nc(-c3ccccc3)cc(-c3c([2H])c([2H])c([2H])c([Si](c4ccccc4)(c4ccccc4)c4ccccc4)c3[2H])n2)c1[2H] ; [2H]c1c(-c2ccccc2)nc(-c2c([2H])c([2H])c([2H])c([2H])c2-n2c3ccccc3c3ccccc32)nc1-c1c([2H])c([2H])c([2H])c([Si](c2ccccc2)(c2ccccc2)c2ccccc2)c1[2H]]

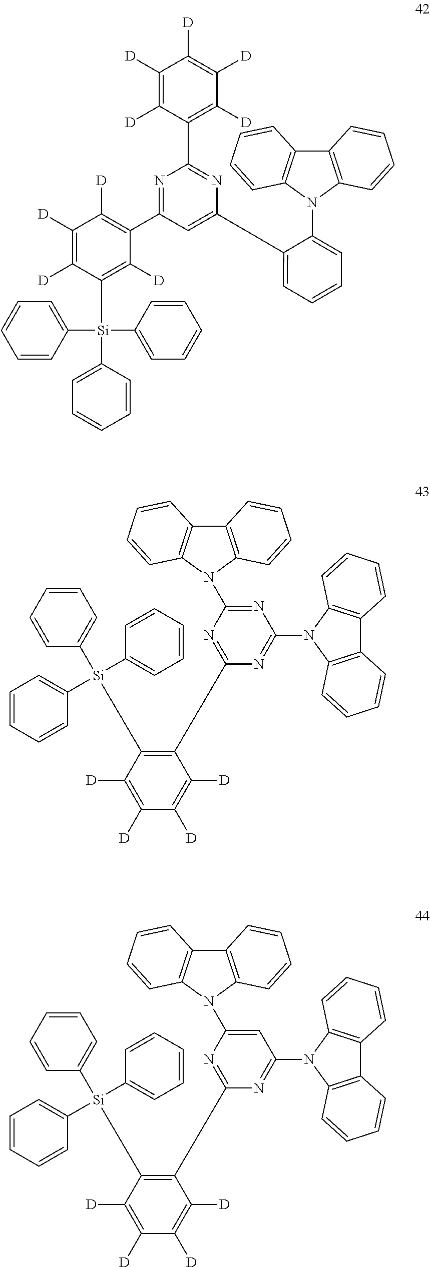 [SMILES: [2H]c1c([2H])c([2H])c(-c2nc(-c3ccccc3-n3c4ccccc4c4ccccc43)cc(-c3c([2H])c([2H])c([2H])c([Si](c4ccccc4)(c4ccccc4)c4ccccc4)c3[2H])n2)c([2H])c1[2H] ; [2H]c1c([2H])c([2H])c([Si](c2ccccc2)(c2ccccc2)c2ccccc2)c(-c2nc(-n3c4ccccc4c4ccccc43)nc(-n3c4ccccc4c4ccccc43)n2)c1[2H] ; [2H]c1c([2H])c([2H])c([Si](c2ccccc2)(c2ccccc2)c2ccccc2)c(-c2nc(-n3c4ccccc4c4ccccc43)cc(-n3c4ccccc4c4ccccc43)n2)c1[2H]]

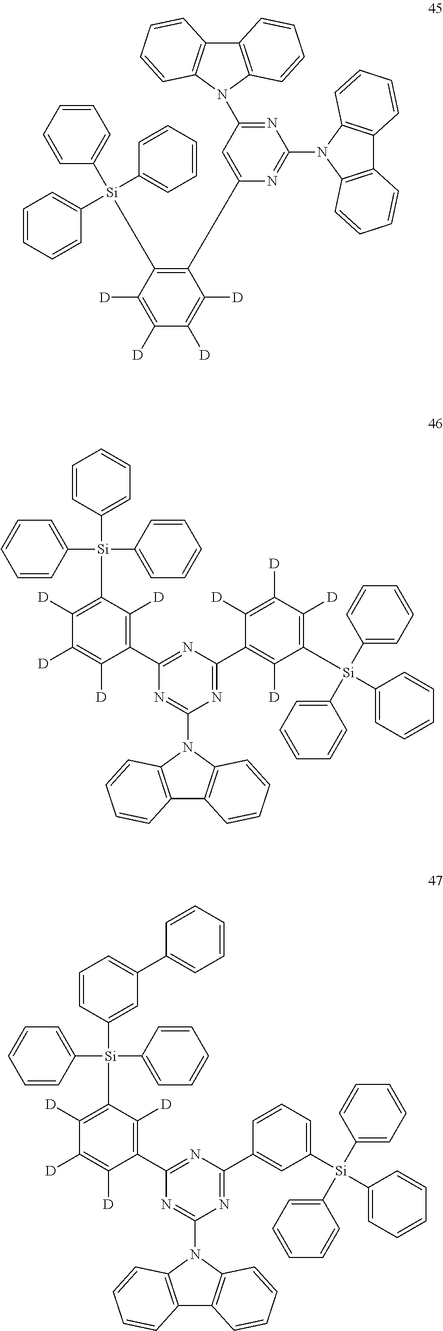 [SMILES: [2H]c1c([2H])c([2H])c([Si](c2ccccc2)(c2ccccc2)c2ccccc2)c(-c2cc(-n3c4ccccc4c4ccccc43)nc(-n3c4ccccc4c4ccccc43)n2)c1[2H] ; [2H]c1c([2H])c(-c2nc(-c3c([2H])c([2H])c([2H])c([Si](c4ccccc4)(c4ccccc4)c4ccccc4)c3[2H])nc(-n3c4ccccc4c4ccccc43)n2)c([2H])c([Si](c2ccccc2)(c2ccccc2)c2ccccc2)c1[2H] ; [2H]c1c([2H])c(-c2nc(-c3cccc([Si](c4ccccc4)(c4ccccc4)c4ccccc4)c3)nc(-n3c4ccccc4c4ccccc43)n2)c([2H])c([Si](c2ccccc2)(c2ccccc2)c2cccc(-c3ccccc3)c2)c1[2H]]

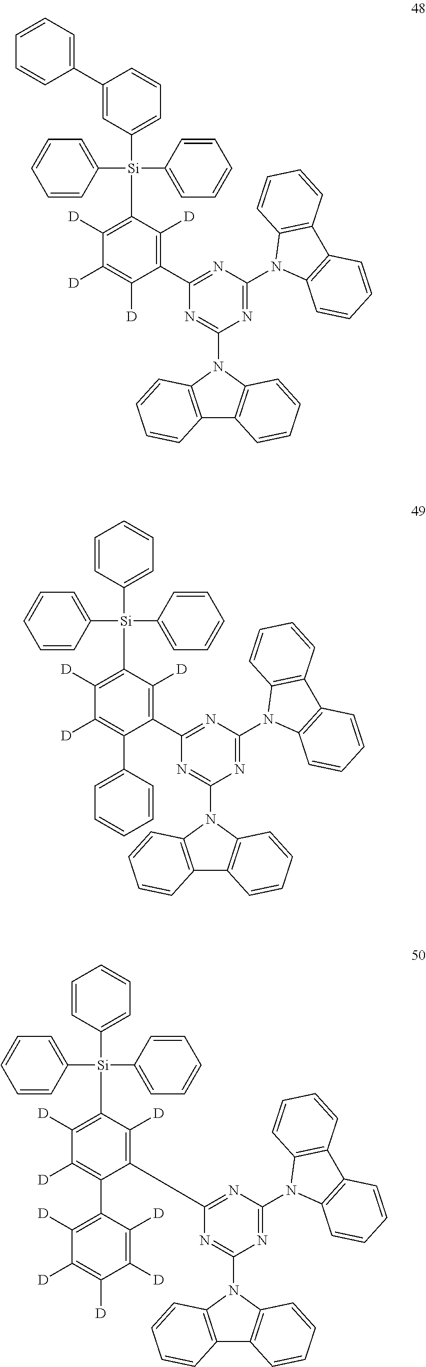 [SMILES: [2H]c1c([2H])c(-c2nc(-n3c4ccccc4c4ccccc43)nc(-n3c4ccccc4c4ccccc43)n2)c([2H])c([Si](c2ccccc2)(c2ccccc2)c2cccc(-c3ccccc3)c2)c1[2H] ; [2H]c1c([2H])c([Si](c2ccccc2)(c2ccccc2)c2ccccc2)c([2H])c(-c2nc(-n3c4ccccc4c4ccccc43)nc(-n3c4ccccc4c4ccccc43)n2)c1-c1ccccc1 ; [2H]c1c([2H])c([2H])c(-c2c([2H])c([2H])c([Si](c3ccccc3)(c3ccccc3)c3ccccc3)c([2H])c2-c2nc(-n3c4ccccc4c4ccccc43)nc(-n3c4ccccc4c4ccccc43)n2)c([2H])c1[2H]]

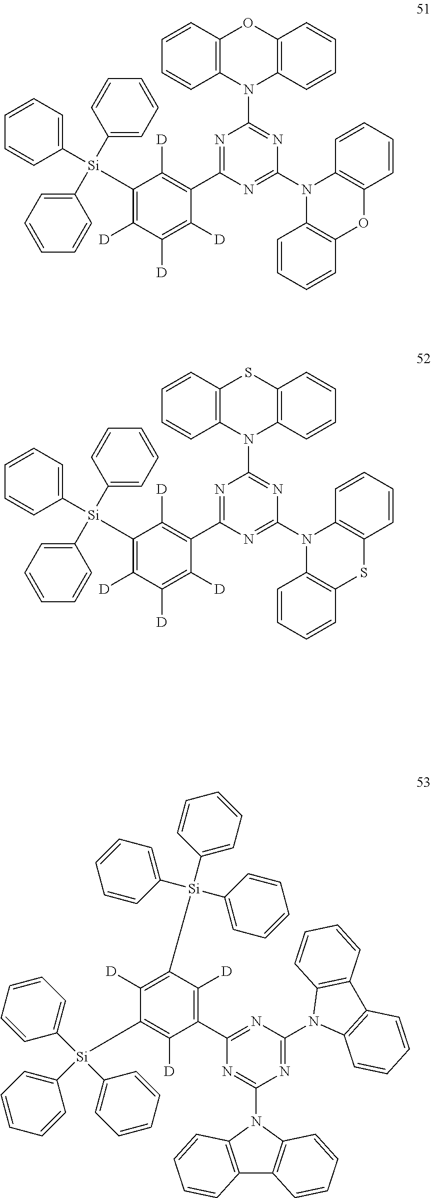 [SMILES: [2H]c1c([2H])c(-c2nc(N3c4ccccc4Oc4ccccc43)nc(N3c4ccccc4Oc4ccccc43)n2)c([2H])c([Si](c2ccccc2)(c2ccccc2)c2ccccc2)c1[2H] ; [2H]c1c([2H])c(-c2nc(N3c4ccccc4Sc4ccccc43)nc(N3c4ccccc4Sc4ccccc43)n2)c([2H])c([Si](c2ccccc2)(c2ccccc2)c2ccccc2)c1[2H] ; [2H]c1c(-c2nc(-n3c4ccccc4c4ccccc43)nc(-n3c4ccccc4c4ccccc43)n2)c([2H])c([Si](c2ccccc2)(c2ccccc2)c2ccccc2)c([2H])c1[Si](c1ccccc1)(c1ccccc1)c1ccccc1]

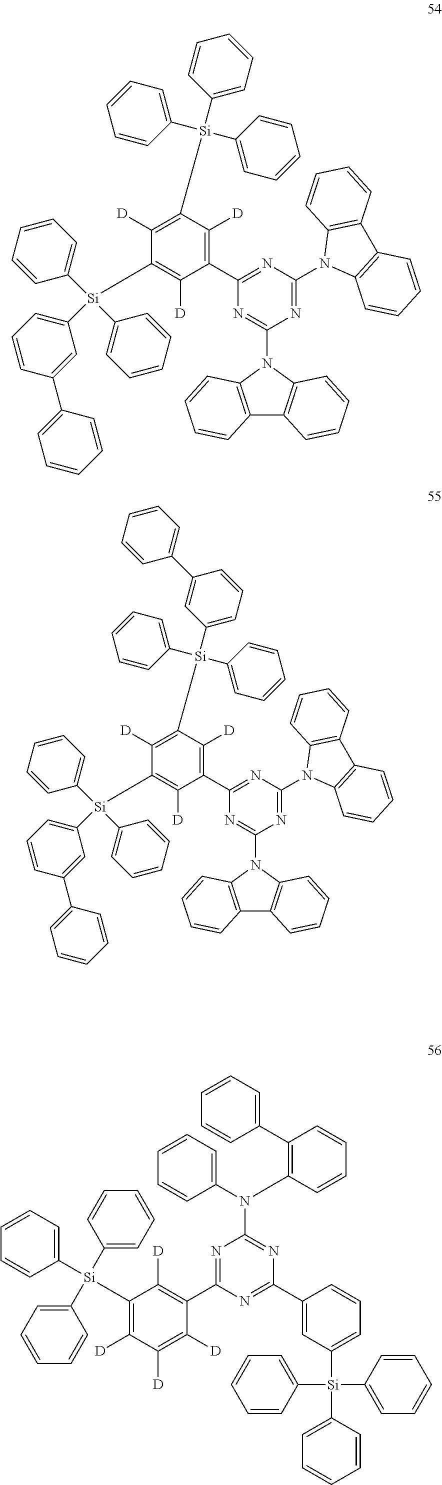 [SMILES: [2H]c1c(-c2nc(-n3c4ccccc4c4ccccc43)nc(-n3c4ccccc4c4ccccc43)n2)c([2H])c([Si](c2ccccc2)(c2ccccc2)c2cccc(-c3ccccc3)c2)c([2H])c1[Si](c1ccccc1)(c1ccccc1)c1ccccc1 ; [2H]c1c(-c2nc(-n3c4ccccc4c4ccccc43)nc(-n3c4ccccc4c4ccccc43)n2)c([2H])c([Si](c2ccccc2)(c2ccccc2)c2cccc(-c3ccccc3)c2)c([2H])c1[Si](c1ccccc1)(c1ccccc1)c1cccc(-c2ccccc2)c1 ; [2H]c1c([2H])c(-c2nc(-c3cccc([Si](c4ccccc4)(c4ccccc4)c4ccccc4)c3)nc(N(c3ccccc3)c3ccccc3-c3ccccc3)n2)c([2H])c([Si](c2ccccc2)(c2ccccc2)c2ccccc2)c1[2H]]

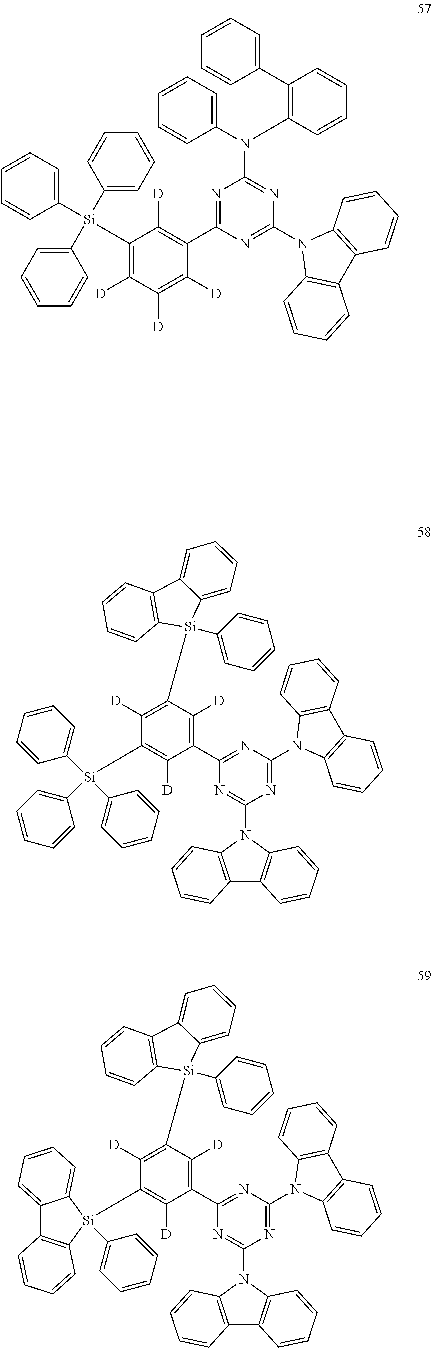 [SMILES: [2H]c1c([2H])c(-c2nc(N(c3ccccc3)c3ccccc3-c3ccccc3)nc(-n3c4ccccc4c4ccccc43)n2)c([2H])c([Si](c2ccccc2)(c2ccccc2)c2ccccc2)c1[2H] ; [2H]c1c(-c2nc(-n3c4ccccc4c4ccccc43)nc(-n3c4ccccc4c4ccccc43)n2)c([2H])c([Si]2(c3ccccc3)c3ccccc3-c3ccccc32)c([2H])c1[Si](c1ccccc1)(c1ccccc1)c1ccccc1 ; [2H]c1c(-c2nc(-n3c4ccccc4c4ccccc43)nc(-n3c4ccccc4c4ccccc43)n2)c([2H])c([Si]2(c3ccccc3)c3ccccc3-c3ccccc32)c([2H])c1[Si]1(c2ccccc2)c2ccccc2-c2ccccc21]

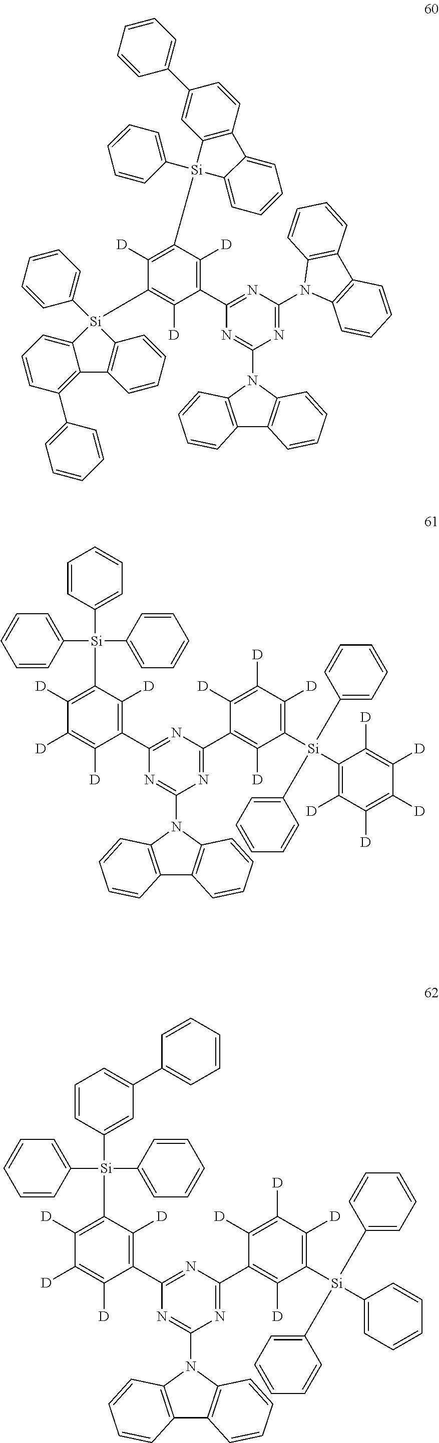

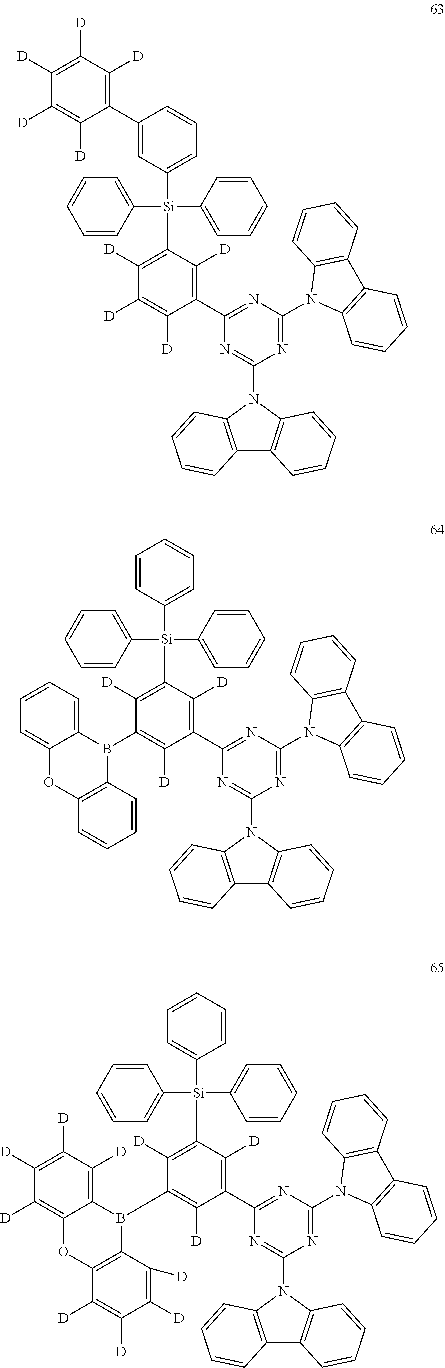 [SMILES: [2H]c1c([2H])c([2H])c(-c2cccc([Si](c3ccccc3)(c3ccccc3)c3c([2H])c([2H])c([2H])c(-c4nc(-n5c6ccccc6c6ccccc65)nc(-n5c6ccccc6c6ccccc65)n4)c3[2H])c2)c([2H])c1[2H] ; [2H]c1c(B2c3ccccc3Oc3ccccc32)c([2H])c([Si](c2ccccc2)(c2ccccc2)c2ccccc2)c([2H])c1-c1nc(-n2c3ccccc3c3ccccc32)nc(-n2c3ccccc3c3ccccc32)n1 ; [2H]c1c([2H])c([2H])c2c(c1[2H])Oc1c([2H])c([2H])c([2H])c([2H])c1B2c1c([2H])c(-c2nc(-n3c4ccccc4c4ccccc43)nc(-n3c4ccccc4c4ccccc43)n2)c([2H])c([Si](c2ccccc2)(c2ccccc2)c2ccccc2)c1[2H]]

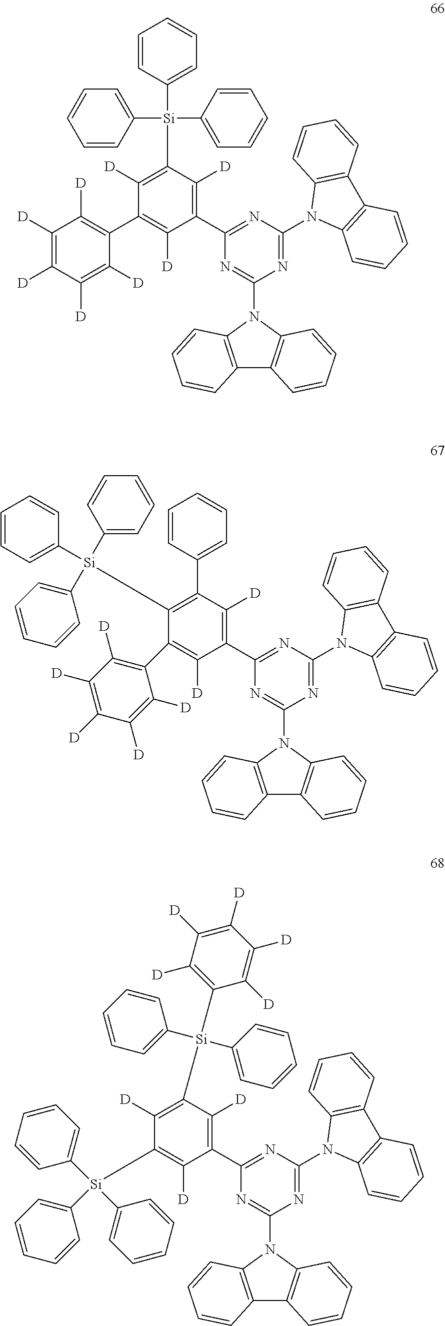 [SMILES: [2H]c1c([2H])c([2H])c(-c2c([2H])c(-c3nc(-n4c5ccccc5c5ccccc54)nc(-n4c5ccccc5c5ccccc54)n3)c([2H])c([Si](c3ccccc3)(c3ccccc3)c3ccccc3)c2[2H])c([2H])c1[2H] ; [2H]c1c([2H])c([2H])c(-c2c([2H])c(-c3nc(-n4c5ccccc5c5ccccc54)nc(-n4c5ccccc5c5ccccc54)n3)c([2H])c(-c3ccccc3)c2[Si](c2ccccc2)(c2ccccc2)c2ccccc2)c([2H])c1[2H] ; [2H]c1c([2H])c([2H])c([Si](c2ccccc2)(c2ccccc2)c2c([2H])c(-c3nc(-n4c5ccccc5c5ccccc54)nc(-n4c5ccccc5c5ccccc54)n3)c([2H])c([Si](c3ccccc3)(c3ccccc3)c3ccccc3)c2[2H])c([2H])c1[2H]]

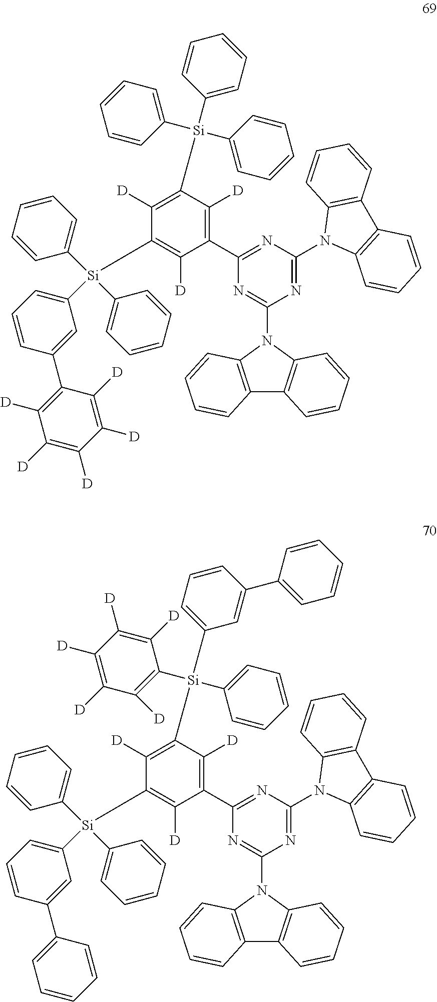 [SMILES: [2H]c1c([2H])c([2H])c(-c2cccc([Si](c3ccccc3)(c3ccccc3)c3c([2H])c(-c4nc(-n5c6ccccc6c6ccccc65)nc(-n5c6ccccc6c6ccccc65)n4)c([2H])c([Si](c4ccccc4)(c4ccccc4)c4ccccc4)c3[2H])c2)c([2H])c1[2H] ; [2H]c1c([2H])c([2H])c([Si](c2ccccc2)(c2cccc(-c3ccccc3)c2)c2c([2H])c(-c3nc(-n4c5ccccc5c5ccccc54)nc(-n4c5ccccc5c5ccccc54)n3)c([2H])c([Si](c3ccccc3)(c3ccccc3)c3cccc(-c4ccccc4)c3)c2[2H])c([2H])c1[2H]]

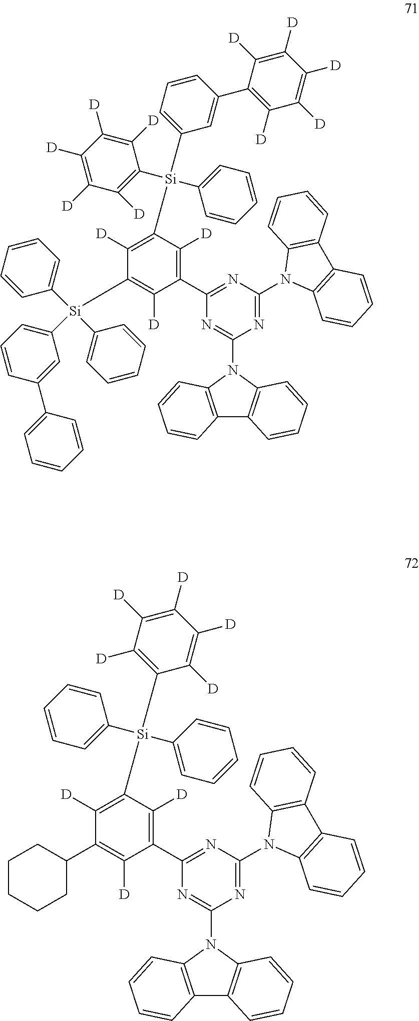 [SMILES: [2H]c1c([2H])c([2H])c(-c2cccc([Si](c3ccccc3)(c3c([2H])c([2H])c([2H])c([2H])c3[2H])c3c([2H])c(-c4nc(-n5c6ccccc6c6ccccc65)nc(-n5c6ccccc6c6ccccc65)n4)c([2H])c([Si](c4ccccc4)(c4ccccc4)c4cccc(-c5ccccc5)c4)c3[2H])c2)c([2H])c1[2H] ; [2H]c1c([2H])c([2H])c([Si](c2ccccc2)(c2ccccc2)c2c([2H])c(-c3nc(-n4c5ccccc5c5ccccc54)nc(-n4c5ccccc5c5ccccc54)n3)c([2H])c(C3CCCCC3)c2[2H])c([2H])c1[2H]]

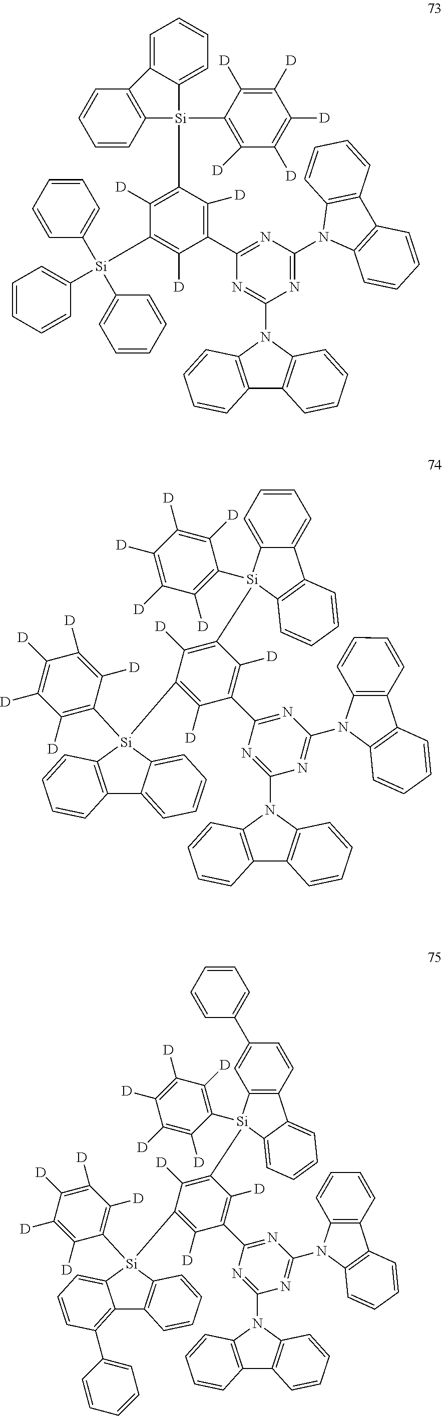

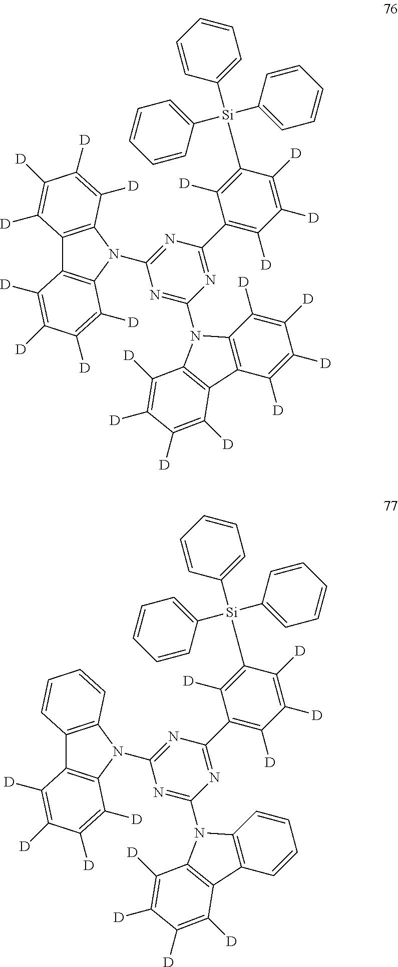 [SMILES: [2H]c1c([2H])c(-c2nc(-n3c4c([2H])c([2H])c([2H])c([2H])c4c4c([2H])c([2H])c([2H])c([2H])c43)nc(-n3c4c([2H])c([2H])c([2H])c([2H])c4c4c([2H])c([2H])c([2H])c([2H])c43)n2)c([2H])c([Si](c2ccccc2)(c2ccccc2)c2ccccc2)c1[2H] ; [2H]c1c([2H])c(-c2nc(-n3c4ccccc4c4c([2H])c([2H])c([2H])c([2H])c43)nc(-n3c4ccccc4c4c([2H])c([2H])c([2H])c([2H])c43)n2)c([2H])c([Si](c2ccccc2)(c2ccccc2)c2ccccc2)c1[2H]]

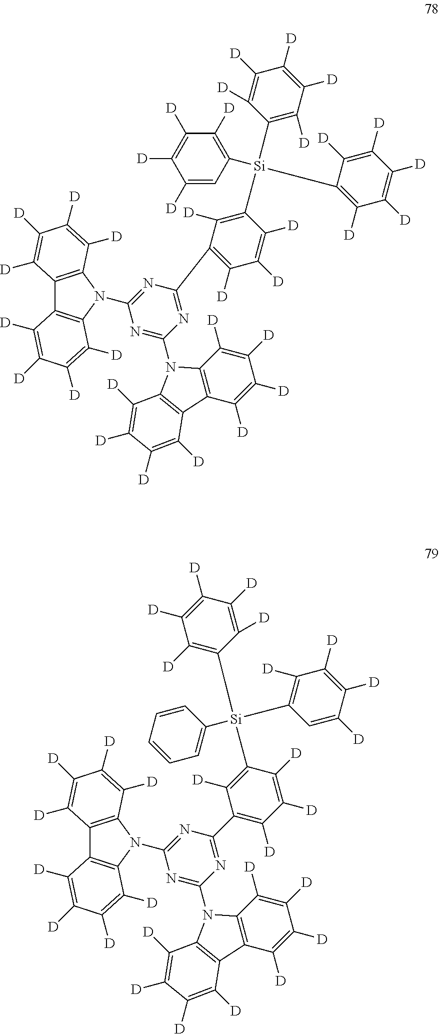

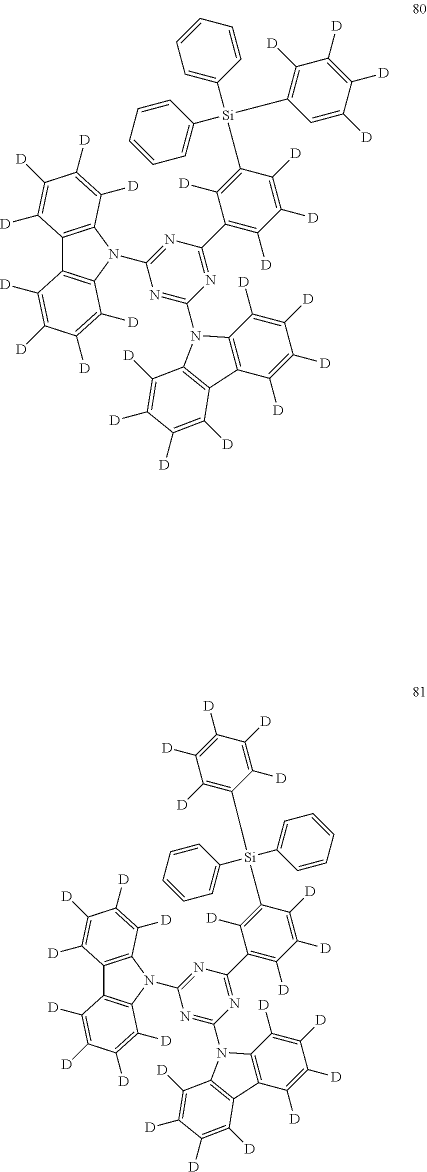 [SMILES: [2H]c1cc([Si](c2ccccc2)(c2ccccc2)c2c([2H])c([2H])c([2H])c(-c3nc(-n4c5c([2H])c([2H])c([2H])c([2H])c5c5c([2H])c([2H])c([2H])c([2H])c54)nc(-n4c5c([2H])c([2H])c([2H])c([2H])c5c5c([2H])c([2H])c([2H])c([2H])c54)n3)c2[2H])c([2H])c([2H])c1[2H] ; [2H]c1c([2H])c([2H])c([Si](c2ccccc2)(c2ccccc2)c2c([2H])c([2H])c([2H])c(-c3nc(-n4c5c([2H])c([2H])c([2H])c([2H])c5c5c([2H])c([2H])c([2H])c([2H])c54)nc(-n4c5c([2H])c([2H])c([2H])c([2H])c5c5c([2H])c([2H])c([2H])c([2H])c54)n3)c2[2H])c([2H])c1[2H]]

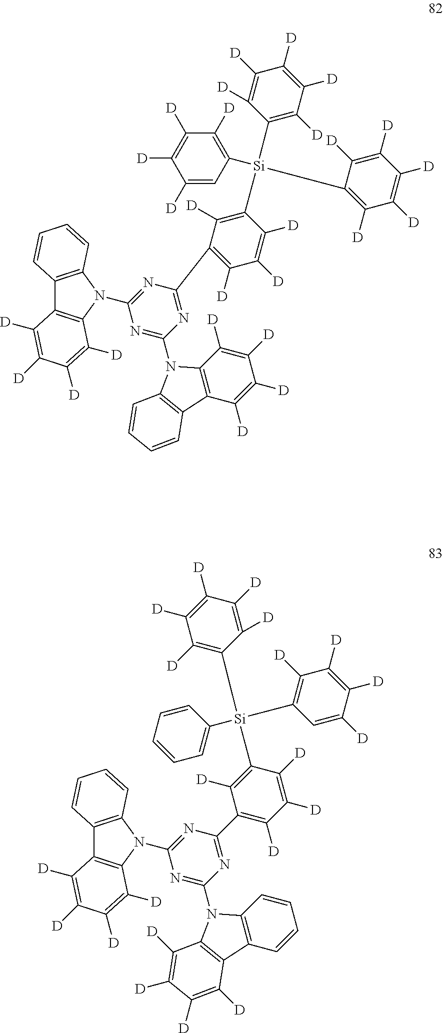 [SMILES: [2H]c1cc([Si](c2c([2H])c([2H])c([2H])c([2H])c2[2H])(c2c([2H])c([2H])c([2H])c([2H])c2[2H])c2c([2H])c([2H])c([2H])c(-c3nc(-n4c5ccccc5c5c([2H])c([2H])c([2H])c([2H])c54)nc(-n4c5ccccc5c5c([2H])c([2H])c([2H])c([2H])c54)n3)c2[2H])c([2H])c([2H])c1[2H] ; [2H]c1cc([Si](c2ccccc2)(c2c([2H])c([2H])c([2H])c([2H])c2[2H])c2c([2H])c([2H])c([2H])c(-c3nc(-n4c5ccccc5c5c([2H])c([2H])c([2H])c([2H])c54)nc(-n4c5ccccc5c5c([2H])c([2H])c([2H])c([2H])c54)n3)c2[2H])c([2H])c([2H])c1[2H]]

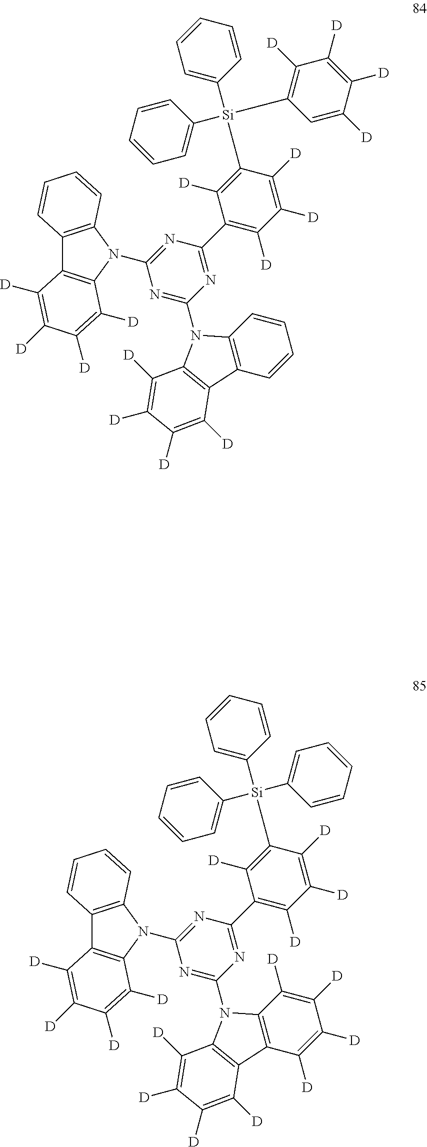 [SMILES: [2H]c1cc([Si](c2ccccc2)(c2ccccc2)c2c([2H])c([2H])c([2H])c(-c3nc(-n4c5ccccc5c5c([2H])c([2H])c([2H])c([2H])c54)nc(-n4c5ccccc5c5c([2H])c([2H])c([2H])c([2H])c54)n3)c2[2H])c([2H])c([2H])c1[2H] ; [2H]c1c([2H])c(-c2nc(-n3c4ccccc4c4c([2H])c([2H])c([2H])c([2H])c43)nc(-n3c4c([2H])c([2H])c([2H])c([2H])c4c4c([2H])c([2H])c([2H])c([2H])c43)n2)c([2H])c([Si](c2ccccc2)(c2ccccc2)c2ccccc2)c1[2H]]

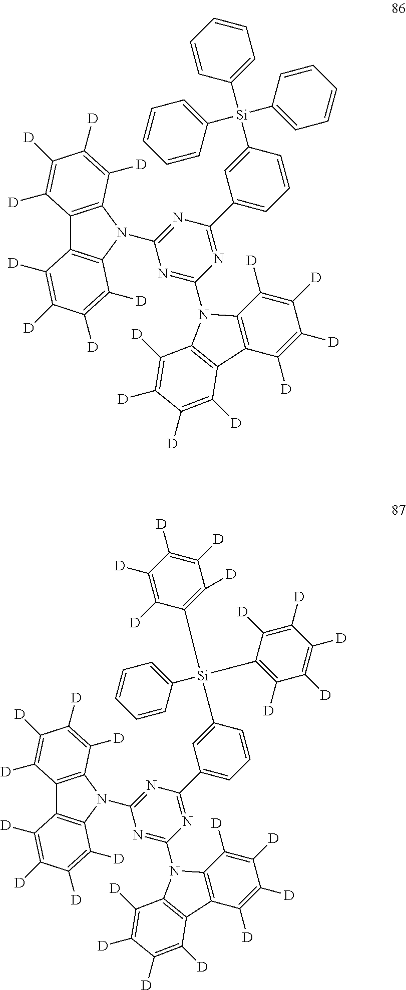 [SMILES: [2H]c1c([2H])c([2H])c2c(c1[2H])c1c([2H])c([2H])c([2H])c([2H])c1n2-c1nc(-c2cccc([Si](c3ccccc3)(c3ccccc3)c3ccccc3)c2)nc(-n2c3c([2H])c([2H])c([2H])c([2H])c3c3c([2H])c([2H])c([2H])c([2H])c32)n1 ; [2H]c1c([2H])c([2H])c([Si](c2ccccc2)(c2cccc(-c3nc(-n4c5c([2H])c([2H])c([2H])c([2H])c5c5c([2H])c([2H])c([2H])c([2H])c54)nc(-n4c5c([2H])c([2H])c([2H])c([2H])c5c5c([2H])c([2H])c([2H])c([2H])c54)n3)c2)c2c([2H])c([2H])c([2H])c([2H])c2[2H])c([2H])c1[2H]]

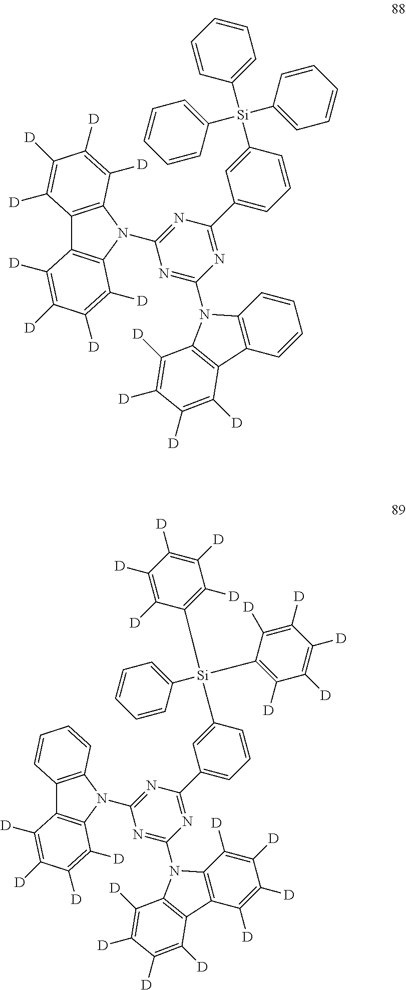 [SMILES: [2H]c1c([2H])c([2H])c2c(c1[2H])c1ccccc1n2-c1nc(-c2cccc([Si](c3ccccc3)(c3ccccc3)c3ccccc3)c2)nc(-n2c3c([2H])c([2H])c([2H])c([2H])c3c3c([2H])c([2H])c([2H])c([2H])c32)n1 ; [2H]c1c([2H])c([2H])c([Si](c2ccccc2)(c2cccc(-c3nc(-n4c5ccccc5c5c([2H])c([2H])c([2H])c([2H])c54)nc(-n4c5c([2H])c([2H])c([2H])c([2H])c5c5c([2H])c([2H])c([2H])c([2H])c54)n3)c2)c2c([2H])c([2H])c([2H])c([2H])c2[2H])c([2H])c1[2H]]

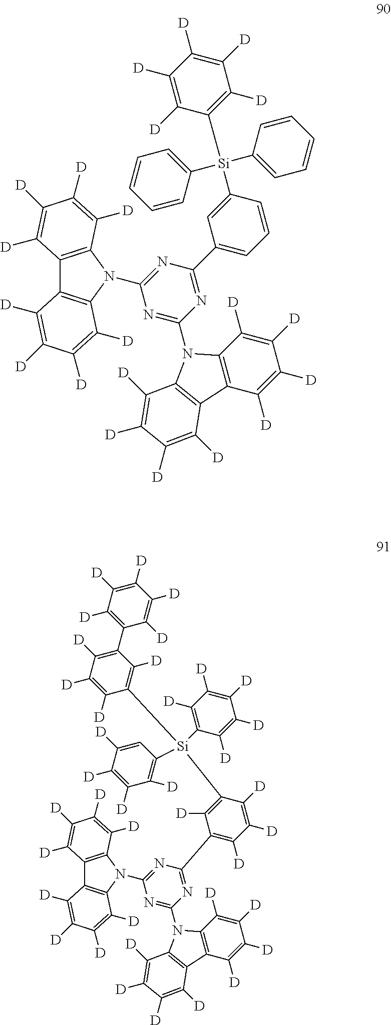

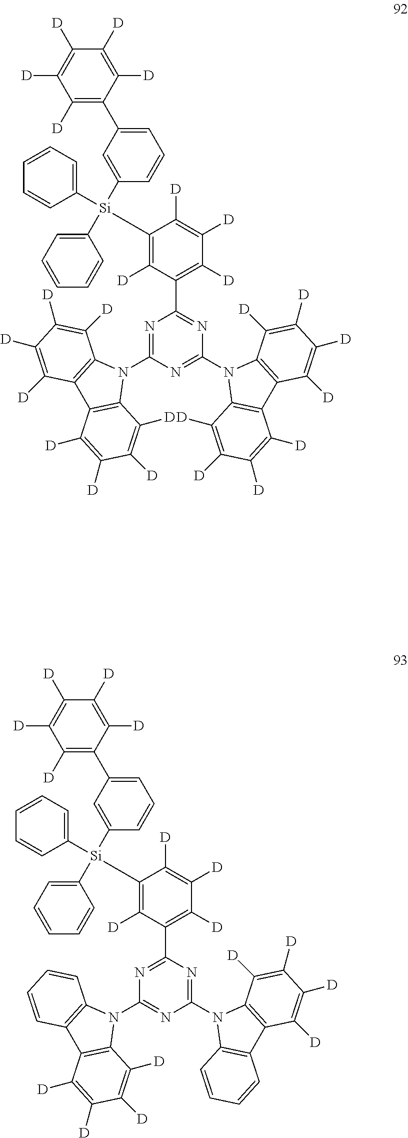 [SMILES: [2H]c1c([2H])c([2H])c(-c2cccc([Si](c3ccccc3)(c3ccccc3)c3c([2H])c([2H])c([2H])c(-c4nc(-n5c6c([2H])c([2H])c([2H])c([2H])c6c6c([2H])c([2H])c([2H])c([2H])c65)nc(-n5c6c([2H])c([2H])c([2H])c([2H])c6c6c([2H])c([2H])c([2H])c([2H])c65)n4)c3[2H])c2)c([2H])c1[2H] ; [2H]c1c([2H])c([2H])c(-c2cccc([Si](c3ccccc3)(c3ccccc3)c3c([2H])c([2H])c([2H])c(-c4nc(-n5c6ccccc6c6c([2H])c([2H])c([2H])c([2H])c65)nc(-n5c6ccccc6c6c([2H])c([2H])c([2H])c([2H])c65)n4)c3[2H])c2)c([2H])c1[2H]]

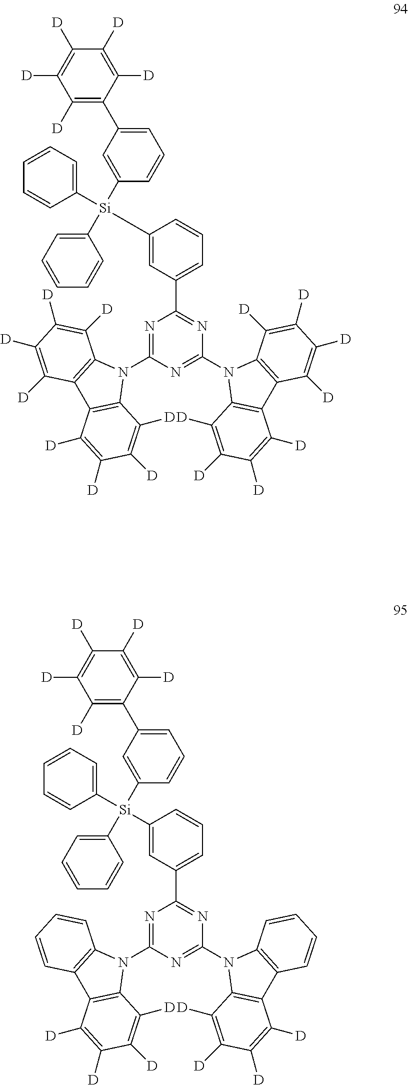 [SMILES: [2H]c1c([2H])c([2H])c(-c2cccc([Si](c3ccccc3)(c3ccccc3)c3cccc(-c4nc(-n5c6c([2H])c([2H])c([2H])c([2H])c6c6c([2H])c([2H])c([2H])c([2H])c65)nc(-n5c6c([2H])c([2H])c([2H])c([2H])c6c6c([2H])c([2H])c([2H])c([2H])c65)n4)c3)c2)c([2H])c1[2H] ; [2H]c1c([2H])c([2H])c(-c2cccc([Si](c3ccccc3)(c3ccccc3)c3cccc(-c4nc(-n5c6ccccc6c6c([2H])c([2H])c([2H])c([2H])c65)nc(-n5c6ccccc6c6c([2H])c([2H])c([2H])c([2H])c65)n4)c3)c2)c([2H])c1[2H]]

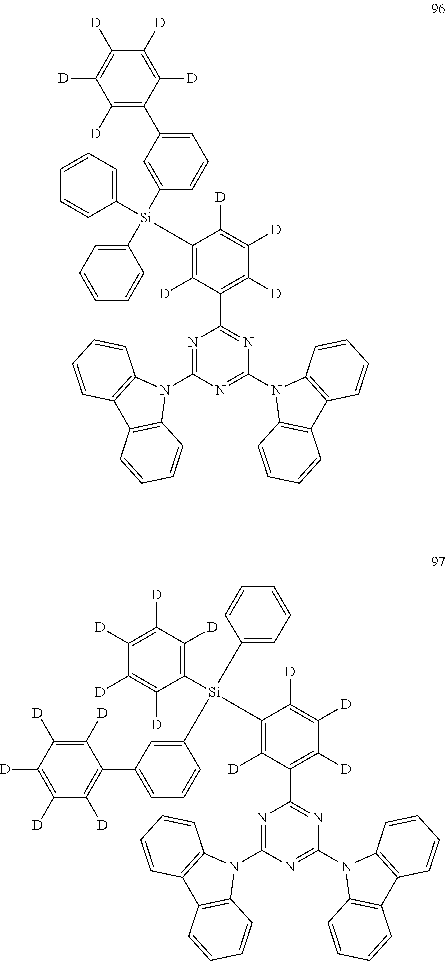 [SMILES: [2H]c1c([2H])c([2H])c(-c2cccc([Si](c3ccccc3)(c3ccccc3)c3c([2H])c([2H])c([2H])c(-c4nc(-n5c6ccccc6c6ccccc65)nc(-n5c6ccccc6c6ccccc65)n4)c3[2H])c2)c([2H])c1[2H] ; [2H]c1c([2H])c([2H])c(-c2cccc([Si](c3ccccc3)(c3c([2H])c([2H])c([2H])c([2H])c3[2H])c3c([2H])c([2H])c([2H])c(-c4nc(-n5c6ccccc6c6ccccc65)nc(-n5c6ccccc6c6ccccc65)n4)c3[2H])c2)c([2H])c1[2H]]

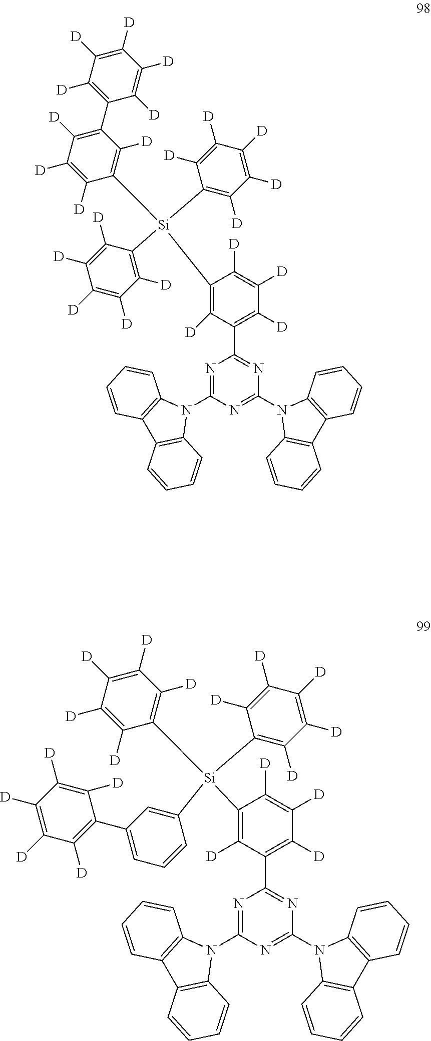 [SMILES: [2H]c1c([2H])c([2H])c(-c2c([2H])c([2H])c([2H])c([Si](c3c([2H])c([2H])c([2H])c([2H])c3[2H])(c3c([2H])c([2H])c([2H])c([2H])c3[2H])c3c([2H])c([2H])c([2H])c(-c4nc(-n5c6ccccc6c6ccccc65)nc(-n5c6ccccc6c6ccccc65)n4)c3[2H])c2[2H])c([2H])c1[2H] ; [2H]c1c([2H])c([2H])c(-c2cccc([Si](c3c([2H])c([2H])c([2H])c([2H])c3[2H])(c3c([2H])c([2H])c([2H])c([2H])c3[2H])c3c([2H])c([2H])c([2H])c(-c4nc(-n5c6ccccc6c6ccccc65)nc(-n5c6ccccc6c6ccccc65)n4)c3[2H])c2)c([2H])c1[2H]]

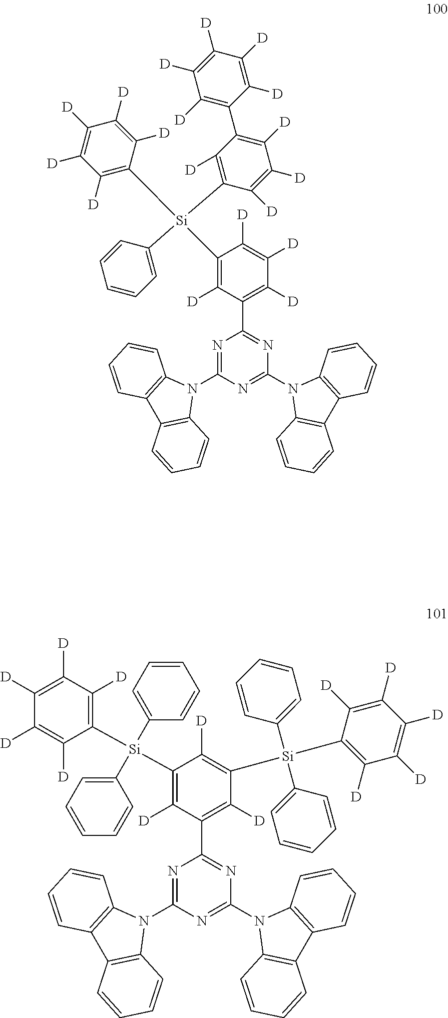 [SMILES: [2H]c1c([2H])c([2H])c(-c2c([2H])c([2H])c([2H])c([Si](c3ccccc3)(c3c([2H])c([2H])c([2H])c([2H])c3[2H])c3c([2H])c([2H])c([2H])c(-c4nc(-n5c6ccccc6c6ccccc65)nc(-n5c6ccccc6c6ccccc65)n4)c3[2H])c2[2H])c([2H])c1[2H] ; [2H]c1c([2H])c([2H])c([Si](c2ccccc2)(c2ccccc2)c2c([2H])c(-c3nc(-n4c5ccccc5c5ccccc54)nc(-n4c5ccccc5c5ccccc54)n3)c([2H])c([Si](c3ccccc3)(c3ccccc3)c3c([2H])c([2H])c([2H])c([2H])c3[2H])c2[2H])c([2H])c1[2H]]

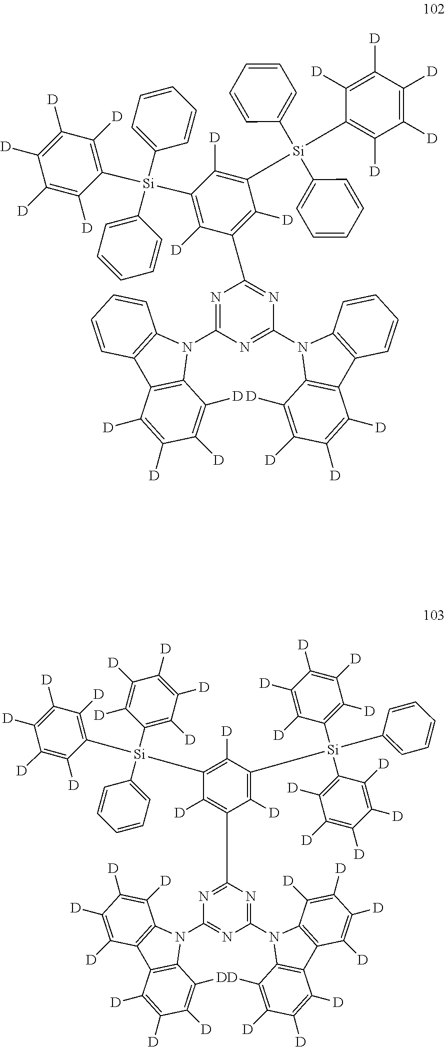

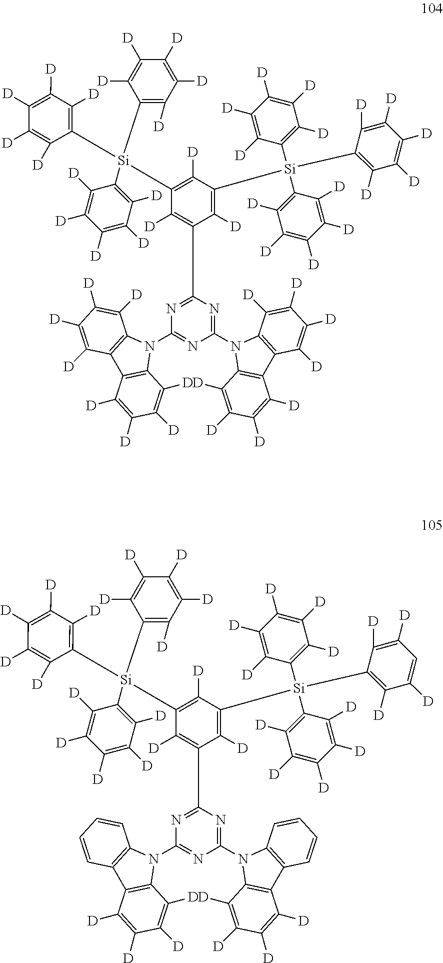

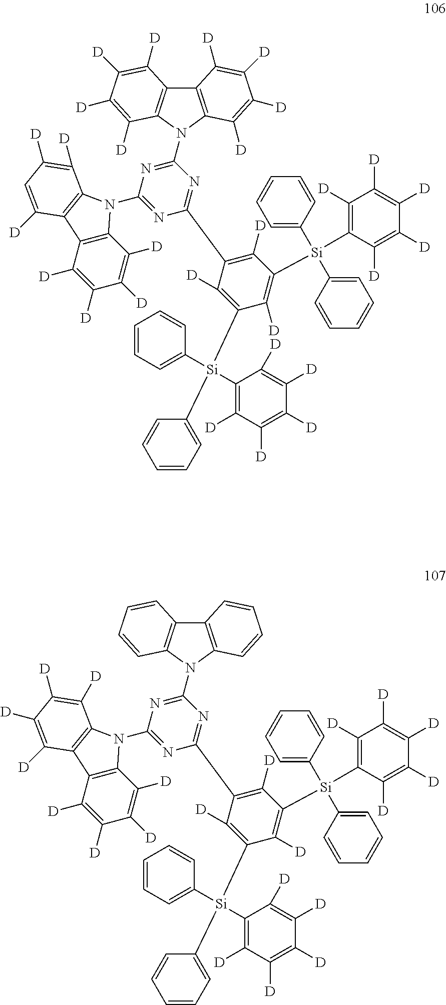

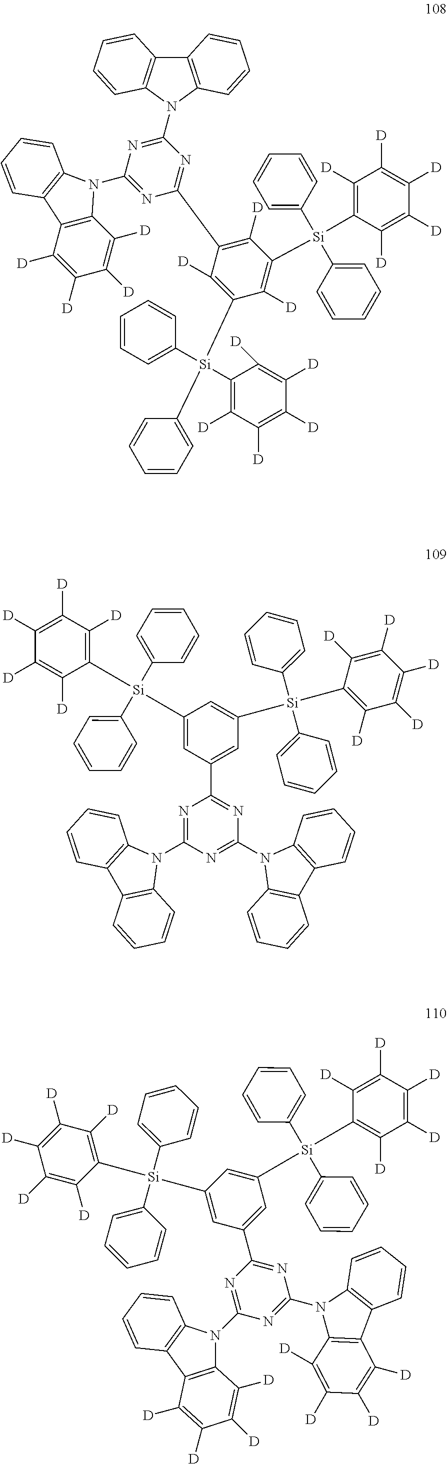

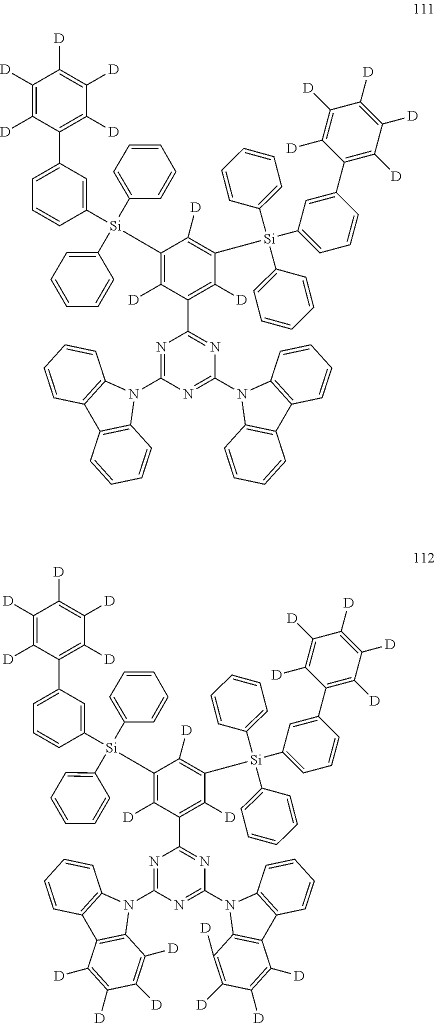 [SMILES: [2H]c1c([2H])c([2H])c(-c2cccc([Si](c3ccccc3)(c3ccccc3)c3c([2H])c(-c4nc(-n5c6ccccc6c6ccccc65)nc(-n5c6ccccc6c6ccccc65)n4)c([2H])c([Si](c4ccccc4)(c4ccccc4)c4cccc(-c5c([2H])c([2H])c([2H])c([2H])c5[2H])c4)c3[2H])c2)c([2H])c1[2H] ; [2H]c1c([2H])c([2H])c(-c2cccc([Si](c3ccccc3)(c3ccccc3)c3c([2H])c(-c4nc(-n5c6ccccc6c6c([2H])c([2H])c([2H])c([2H])c65)nc(-n5c6ccccc6c6c([2H])c([2H])c([2H])c([2H])c65)n4)c([2H])c([Si](c4ccccc4)(c4ccccc4)c4cccc(-c5c([2H])c([2H])c([2H])c([2H])c5[2H])c4)c3[2H])c2)c([2H])c1[2H]]

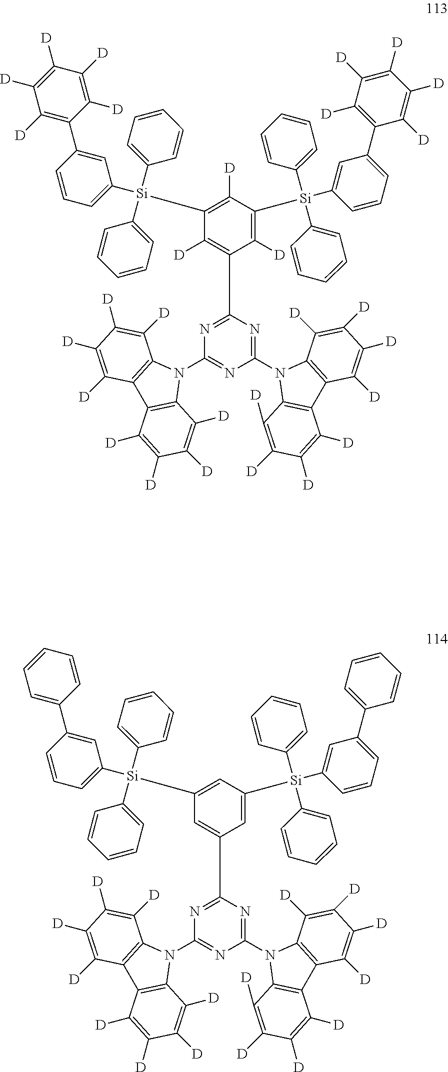

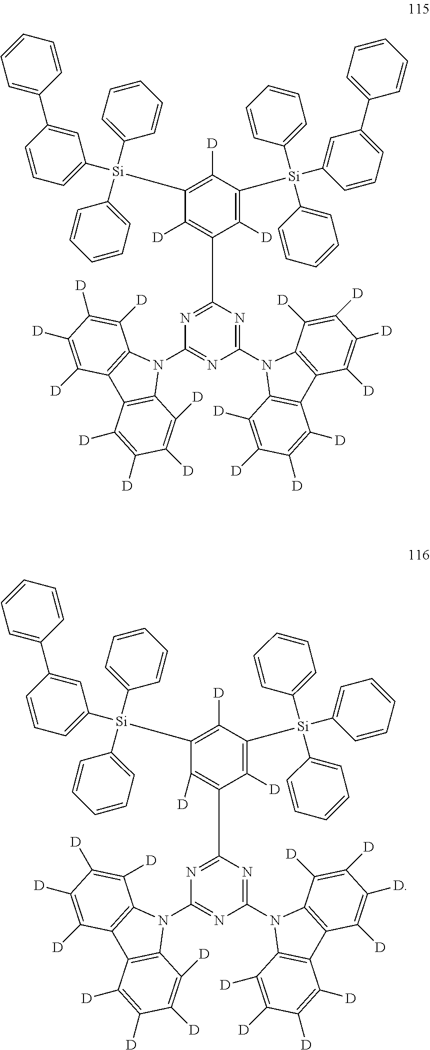

The nitrogen-containing compound of one or more embodiments may include a hexagonal single ring including at least one N as a ring-forming atom, as a core structure. The nitrogen-containing compound of one or more embodiments may include at least one deuterium atom and at least one substituted or unsubstituted silyl group (i.e., the first substitutent) as substitutents. The deuterium atom and the first substitutent may be bonded to the core structure of the hexagonal single ring directly or indirectly. The first substituent may be substituent of a substituted aryl group and/or a substituted heteroaryl group, and the nitrogen-containing compound of one or more embodiments may include a substituted aryl group and/or a substituted heteroaryl group.

The nitrogen-containing compound of one or more embodiments may include a deuterium atom as a substituent, and intermolecular interaction may be reduced, and heat resistance may be improved. Accordingly, a light emitting element including the nitrogen-containing compound of one or more embodiments may show long-life characteristics.

An emission layer EML of one or more embodiments may include a host and a dopant. For example, the emission layer EML may include one host and one dopant. In some embodiments, the emission layer EML may include two or more hosts, a sensitizer and a dopant. For example, the emission layer EML may include a hole transport host and an electron transport host. The emission layer EML of one or more embodiments may include the nitrogen-containing compound of one or more embodiments as the host. The nitrogen-containing compound of one or more embodiments may be used as a material for an electron transport host.

The emission layer EML may include a phosphorescence sensitizer and/or a thermally activated delayed fluorescence (TADF) sensitizer, as the sensitizer. If the emission layer EML includes a hole transport host, an electron transport host, a sensitizer and a dopant, the hole transport host and the electron transport host may form exciplexes, and energy transfer may occur from the exciplex to the sensitizer, and from the sensitizer to the dopant. However, this is an illustration, and the material included in the emission layer EML is not limited thereto.

In the emission layer EML, the hole transport host and the electron transport host may form exciplexes. In this case, the triplet energy of the exciplex formed by the hole transport host and the electron transport host may correspond to the difference between the lowest unoccupied molecular orbital (LUMO) energy level of the electron transport host and the highest occupied molecular orbital (HOMO) energy level of the hole transport host.

For example, the absolute value of the triplet energy level (T1) of the exciplex formed by the hole transport host and the electron transport host may be about 2.4 eV to about 3.0 eV. In some embodiments, the triplet energy of the exciplex may be a smaller value than the energy gap of the host materials. The exciplex may have a triplet energy of about 3.0 eV or less, for example, the energy gap between the hole transport host and the electron transport host. However, these are illustrations, and one or more embodiments of the present disclosure is not limited thereto.

The emission layer EML of one or more embodiments may further include a second compound represented by Formula HT-1. The second compound may be used as the hole transport host.

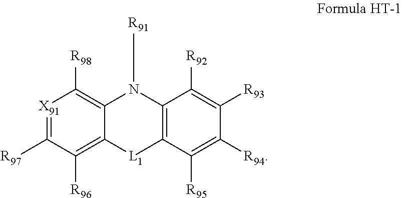

In Formula HT-1, L₁ may be a direct linkage, CR₉₉R₁₀₀, or SiR₁₀₁R₁₀₂. In Formula HT-1, X₉₁ may be N or CR₁₀₃. When L₁ is a direct linkage and X₉1 is CR₁₀₃, the second compound represented by Formula HT-1 may include a carbazole group.

In Formula HT-1, R₉₁ to R₁₀₃ may each independently be a hydrogen atom, a deuterium atom, a cyano group, a substituted or unsubstituted silyl group, a substituted or unsubstituted oxy group, a substituted or unsubstituted alkyl group having 1 to 60 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring.

For example, R₉₁ may be a substituted phenyl group, an unsubstituted dibenzofuran group, or a substituted fluorenyl group. Any one among R₉₂ to R₉₈ may be a substituted or unsubstituted carbazole group. R₉₄ and R₉₅ may be bonded to each other to form a ring. However, this is presented as an example, and the embodiment of the inventive concept is not limited thereto.

The second compound may be represented by any one among the compounds in Compound Group 2. In Compound Group 2, D is a deuterium atom, and Ph is a phenyl group.

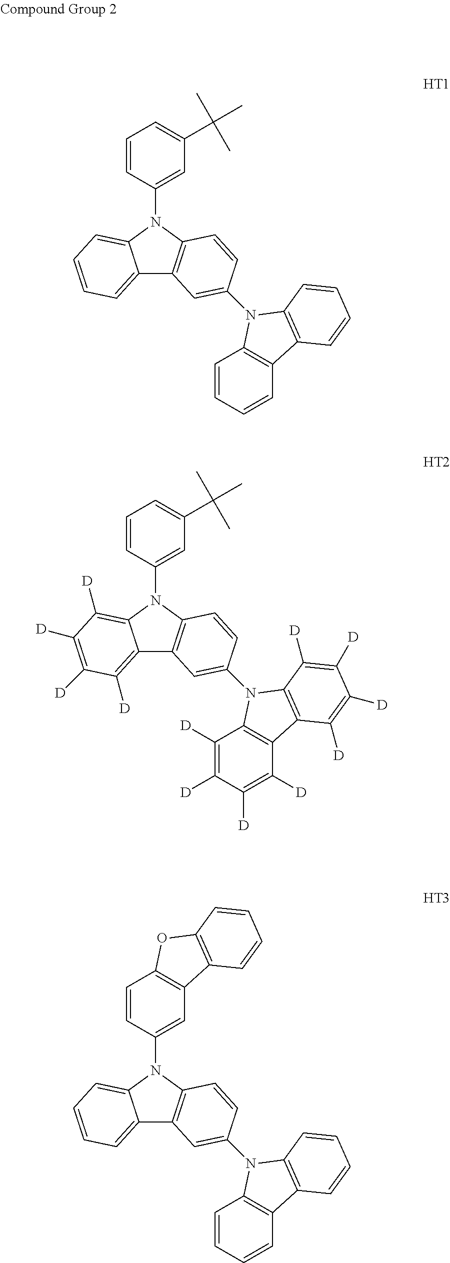 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

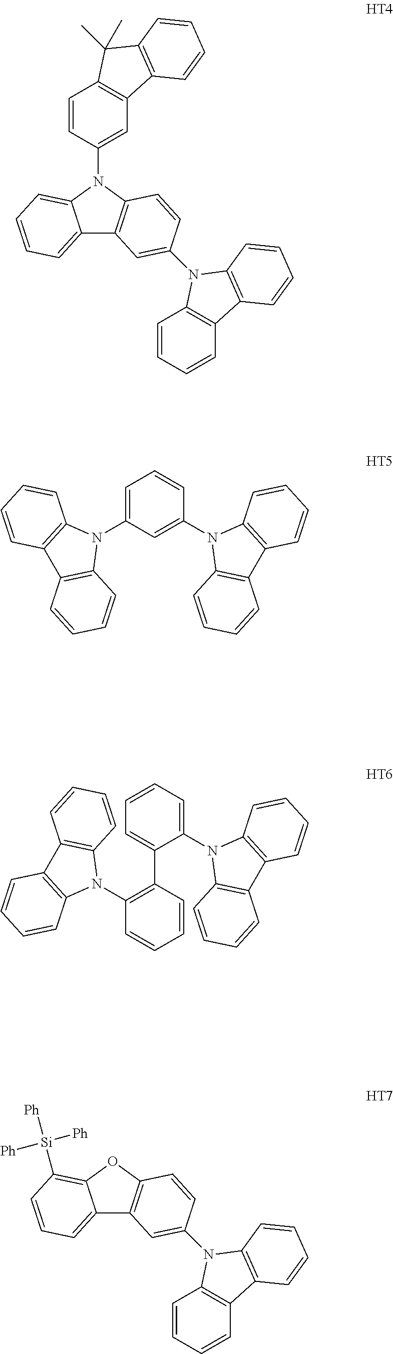 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

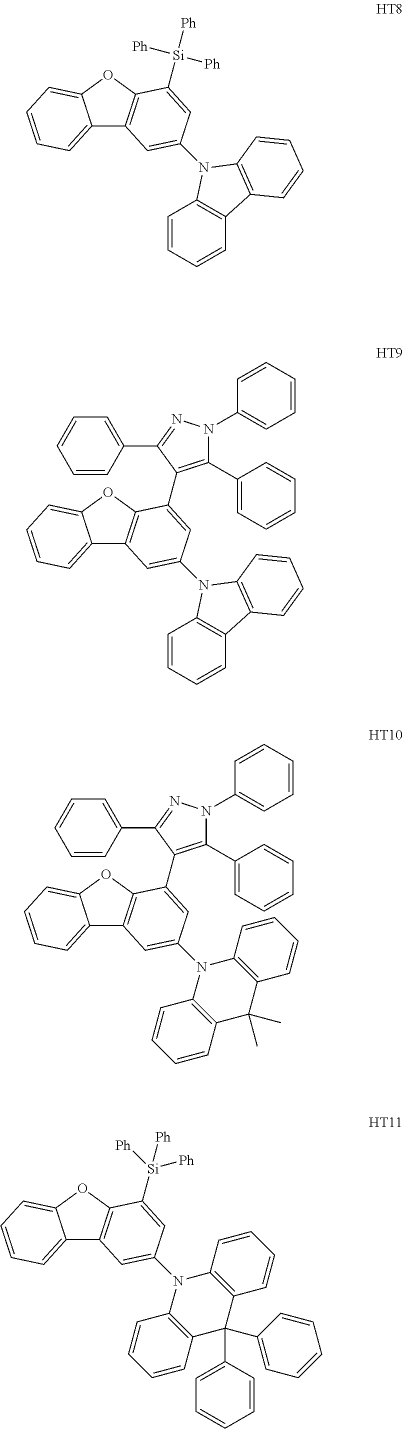 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1]

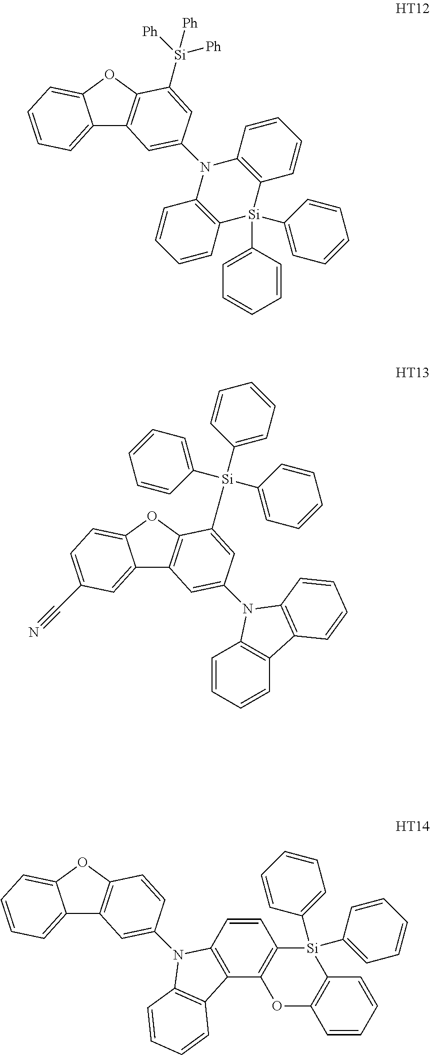 [SMILES: c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1]

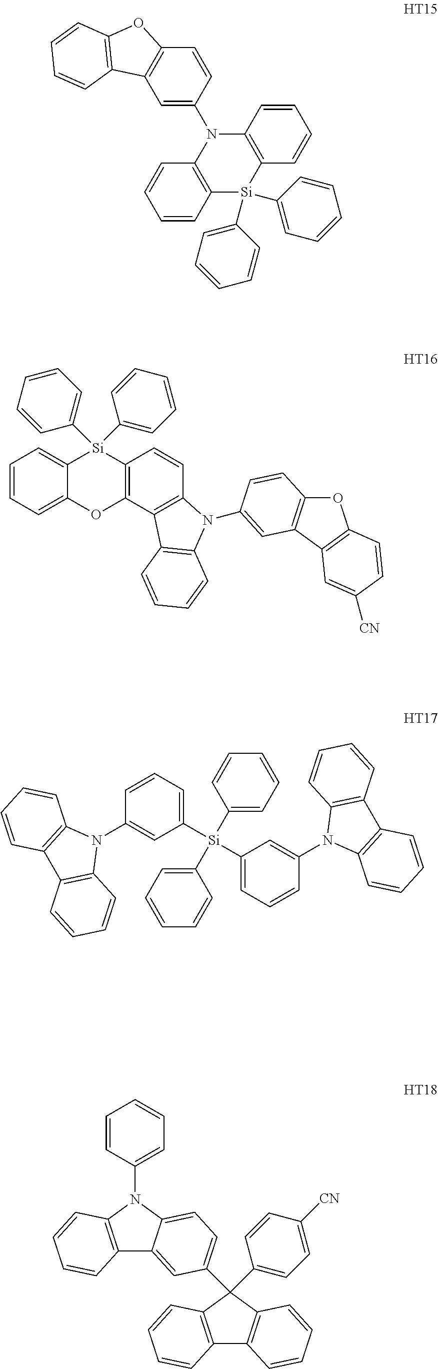 [SMILES: c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1]

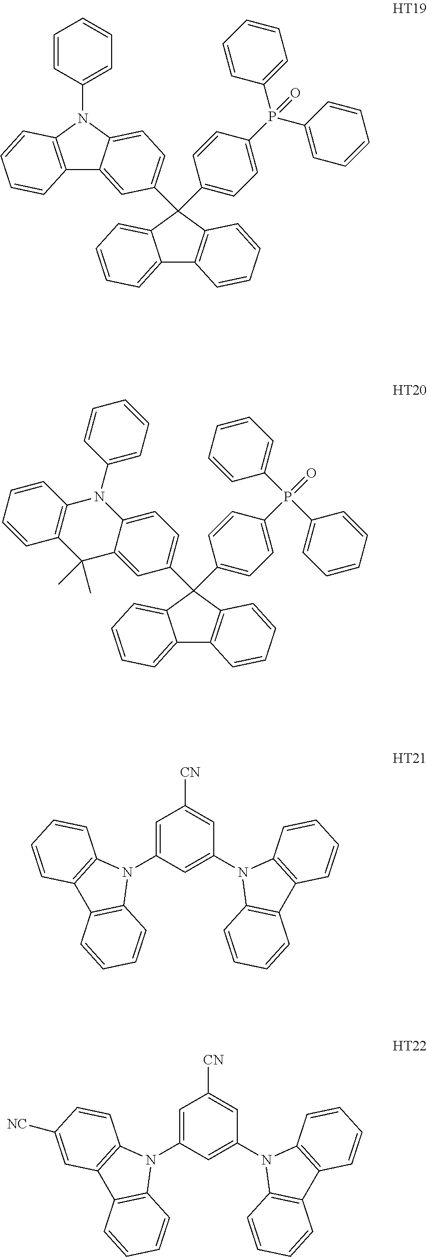 [SMILES: O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1]

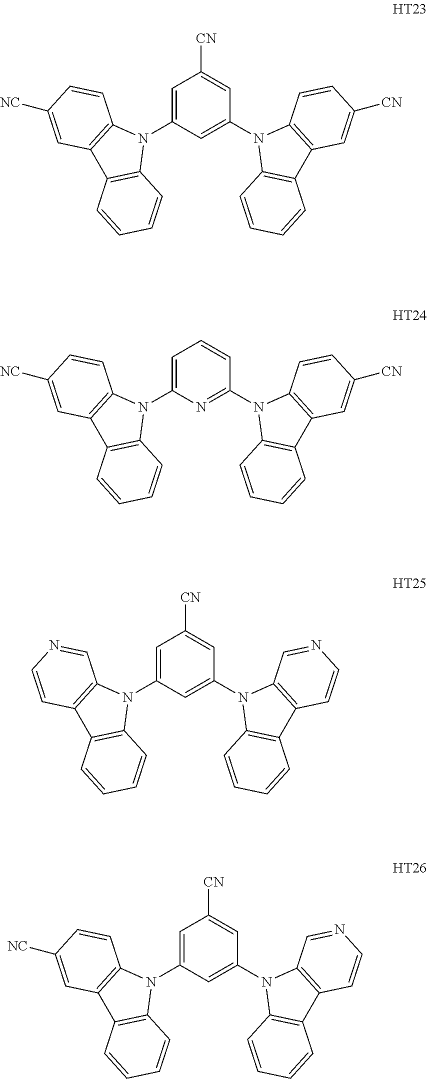 [SMILES: N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1]

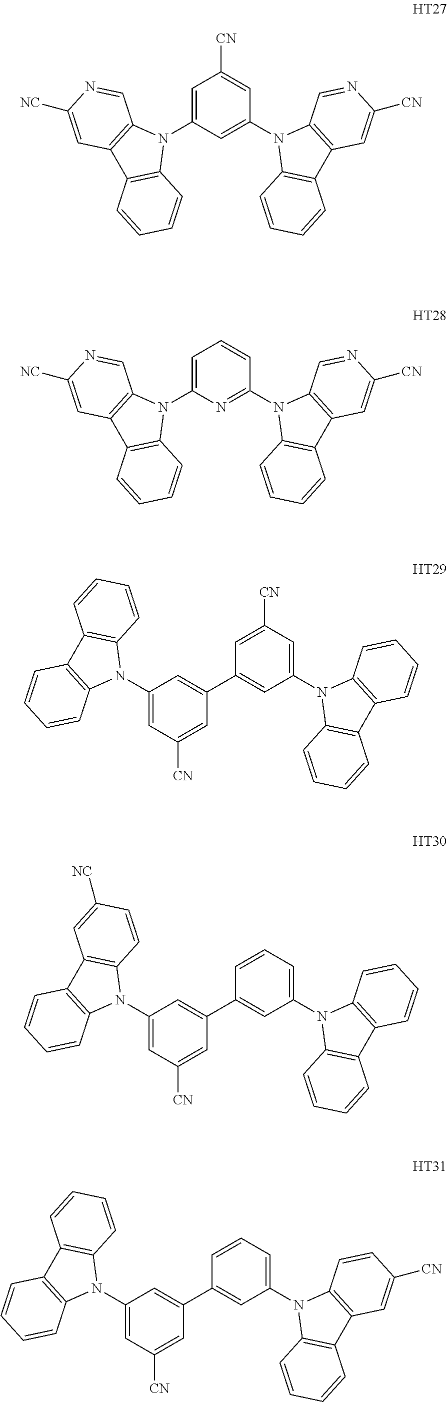 [SMILES: N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1]

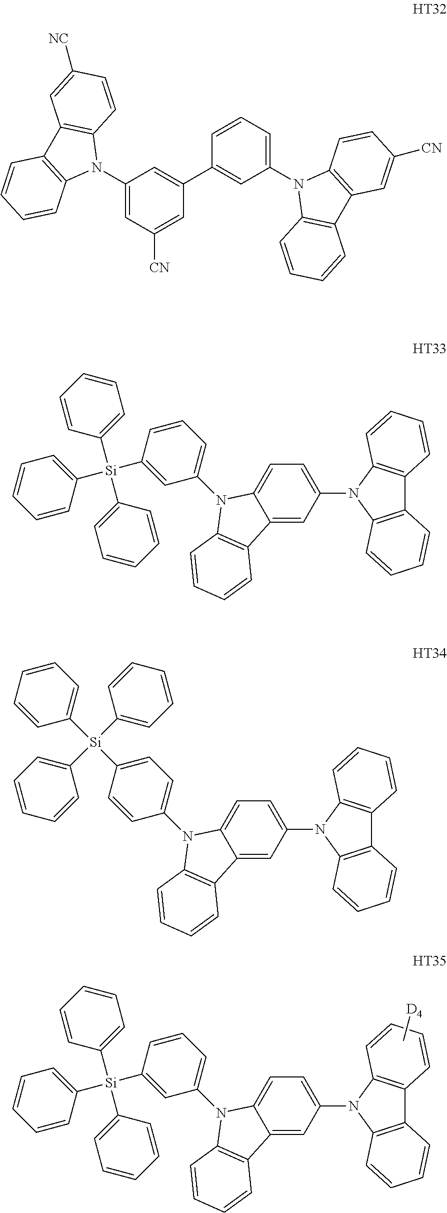

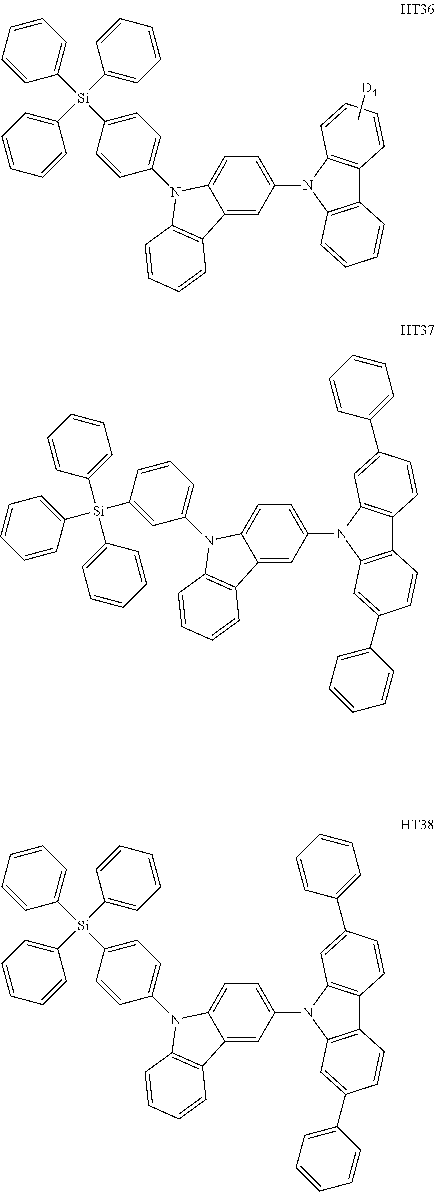

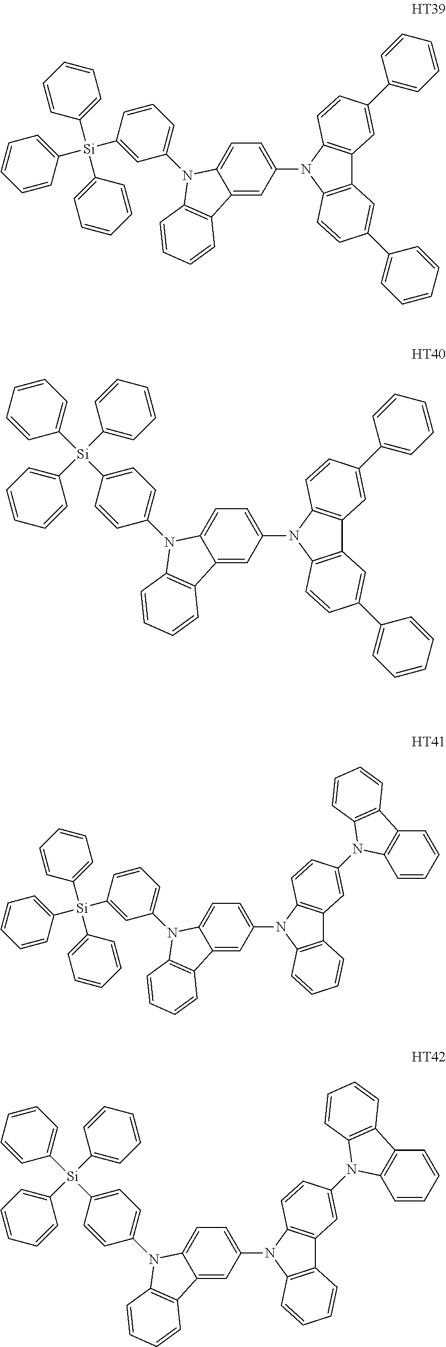 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

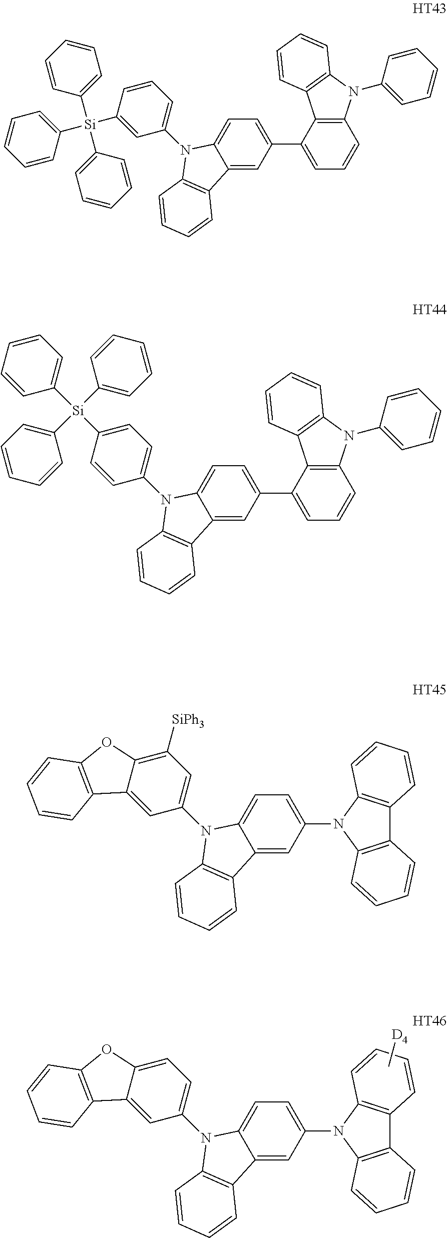

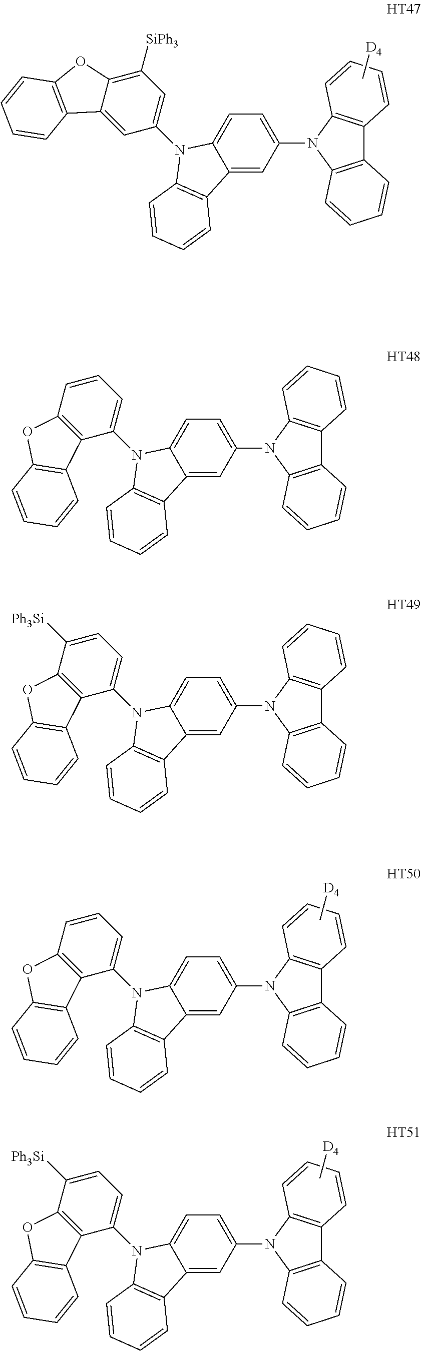

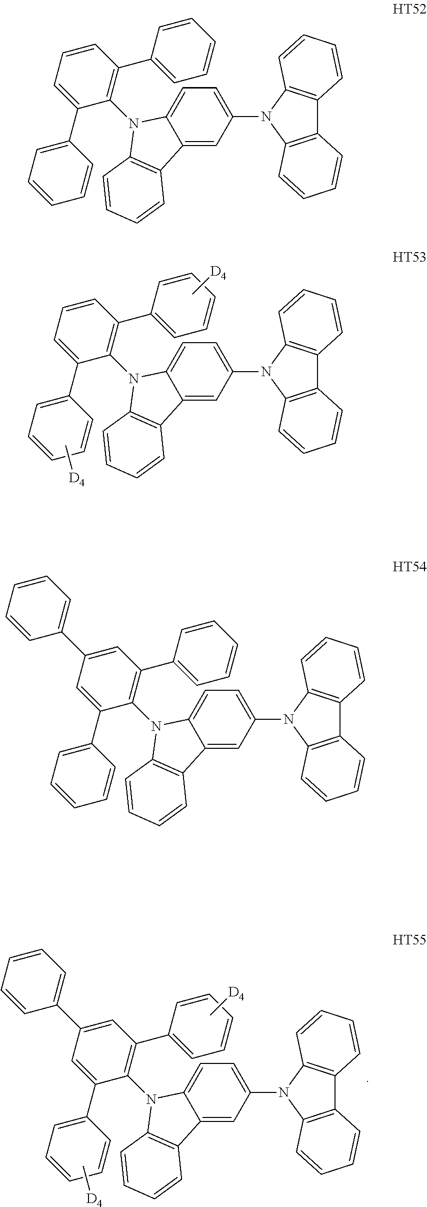

The emission layer EML of one or more embodiments may further include a third compound represented by Formula M-a. The third compound may be used as a phosphorescence dopant material.

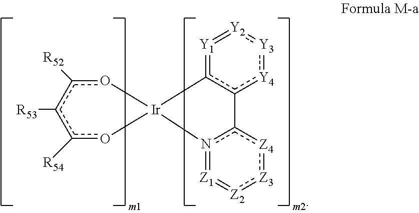

In Formula M-a, Y₁ to Y₄, and Z₁ to Z₄ may be each independently CR₅₁ or N. R₅₁ to R₅₄ may be each independently a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring.

In Formula M-a, m1 may be 0 or 1, and m2 may be 2 or 3. If m1 is 0, m2 may be 3, and if m1 is 1, m2 may be 2.

The compound represented by Formula M-a may be represented by any one among Compounds M-a1 to M-a25 below. However, Compounds M-a1 to M-a25 are illustrations, and the compound represented by Formula M-a is not limited to those represented by Compounds M-a1 to M-a25.

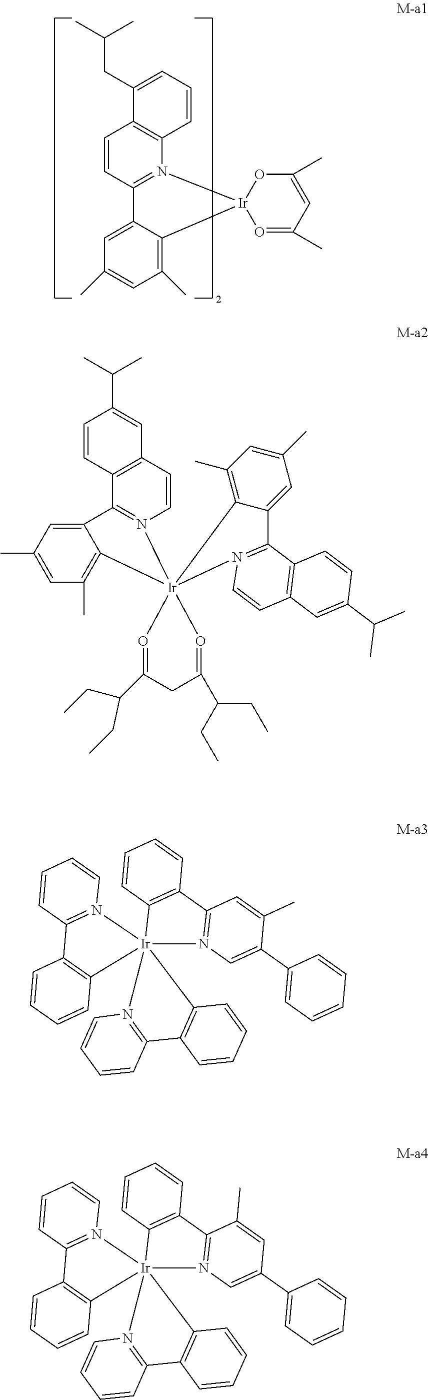

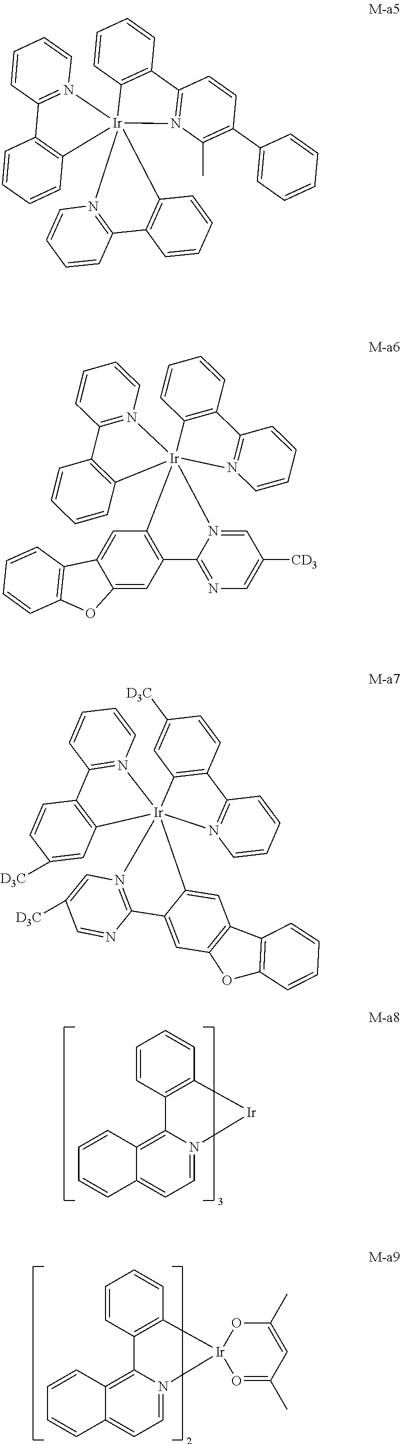

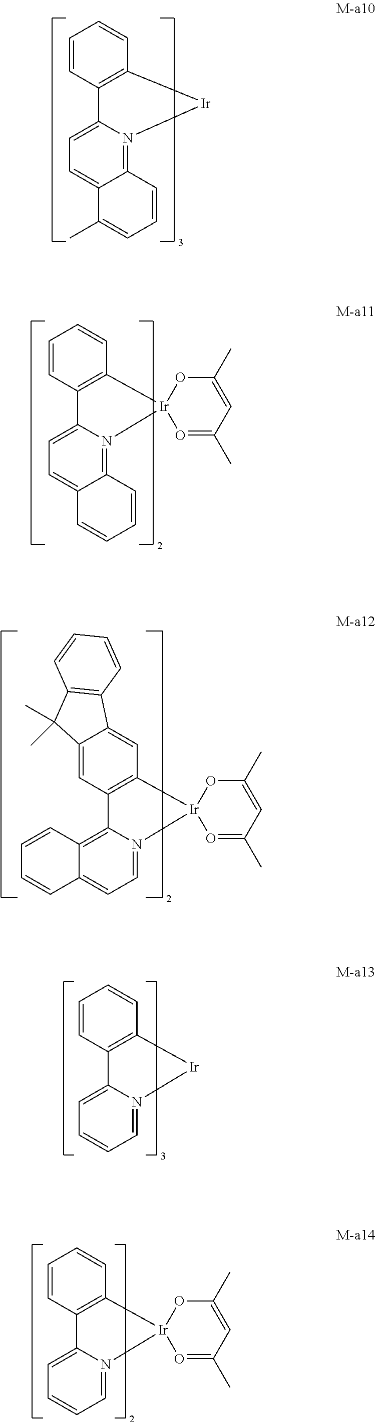

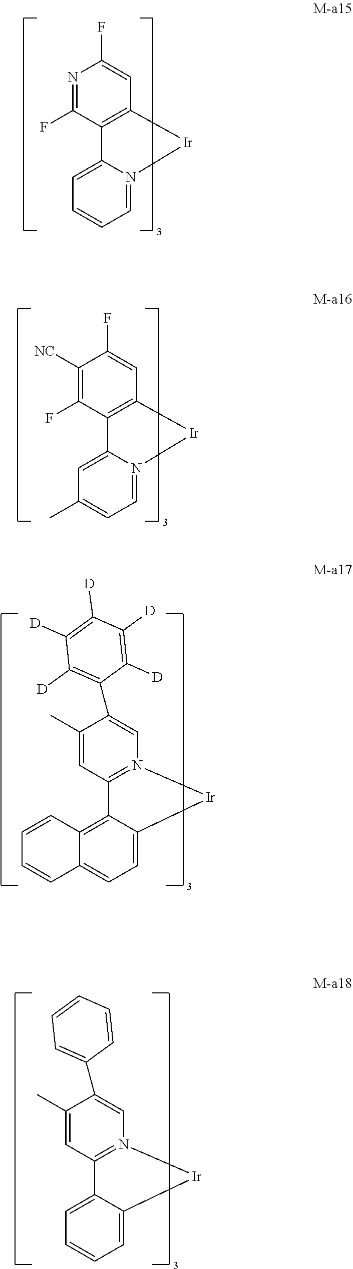

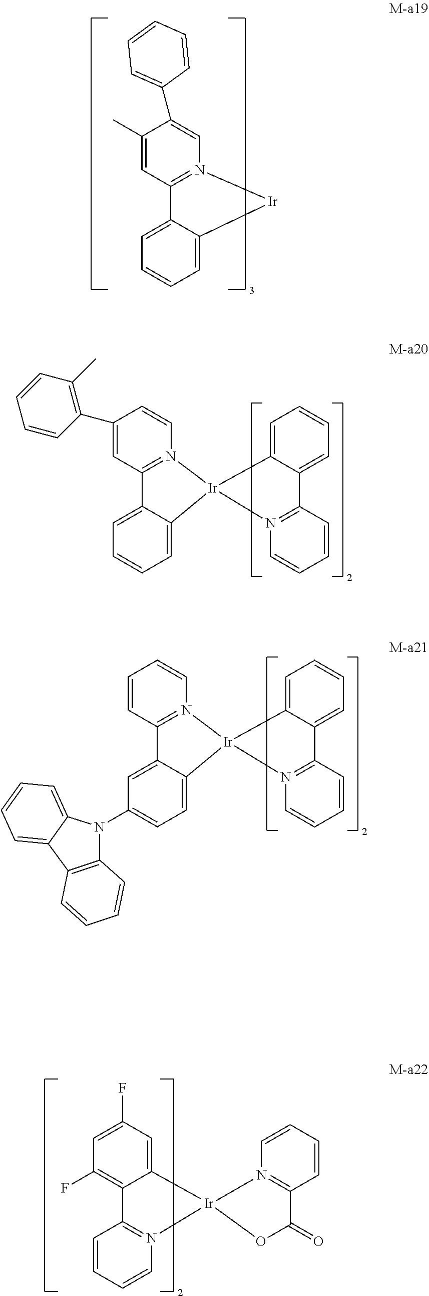

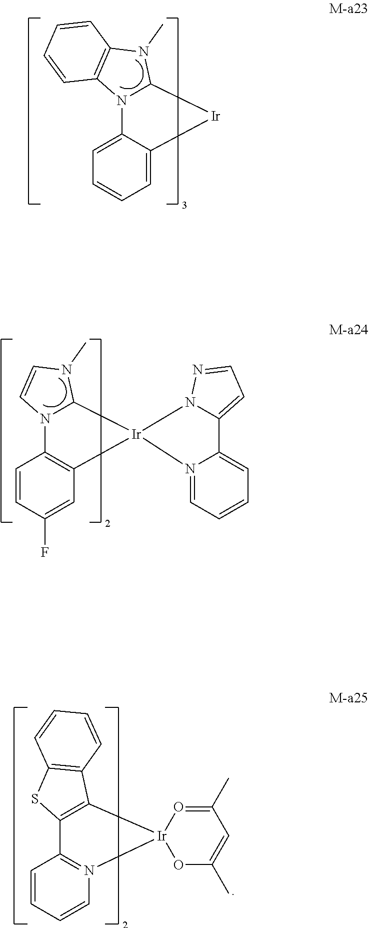

Compound M-a1 and Compound M-a2 may be used as red dopant materials. Compound M-a3 to Compound M-a7 may be used as green dopant materials.

The emission layer EML is provided on the hole transport region HTR. The emission layer EML may have a thickness of, for example, about 100 Å to about 1,000 Å or about 100 Å to about 300 Å. The emission layer EML may have a single layer formed using a single material, a single layer formed using multiple different materials, or a multilayer structure having multiple layers formed using multiple different materials.

The emission layer EML may further include the compounds explained in more detail herein below in addition to the nitrogen-containing compound of one or more embodiments, the second compound and the third compound.

In the light emitting element ED of one or more embodiments, the emission layer EML may include one or more selected from anthracene derivatives, pyrene derivatives, fluoranthene derivatives, chrysene derivatives, dihydrobenzanthracene derivatives, and/or triphenylene derivatives. For example, the emission layer EML may include anthracene derivatives and/or pyrene derivatives.

The emission layer EML may include a compound represented by Formula E-1 below. The compound represented by Formula E-1 below may be used as a fluorescence host material.

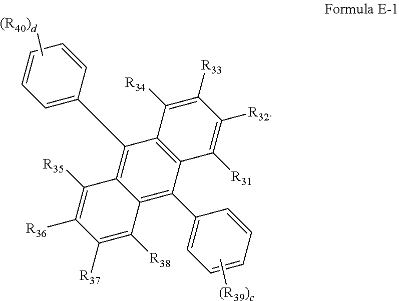

In Formula E-1, R₃₁ to R₄₀ may be each independently a hydrogen atom, a deuterium atom, a halogen atom, a substituted or unsubstituted silyl group, a substituted or unsubstituted thio group, a substituted or unsubstituted oxy group, a substituted or unsubstituted alkyl group of 1 to 10 carbon atoms, a substituted or unsubstituted alkenyl group of 2 to 10 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. In some embodiments, R₃₁ to R₄₀ may be combined with an adjacent group to form a saturated hydrocarbon ring, an unsaturated hydrocarbon ring, a saturated heterocycle, or an unsaturated heterocycle.

In Formula E-1, “c” and “d” may be each independently an integer of 0 to 5.

Formula E-1 may be represented by any one among Compound E1 to Compound E19 below.

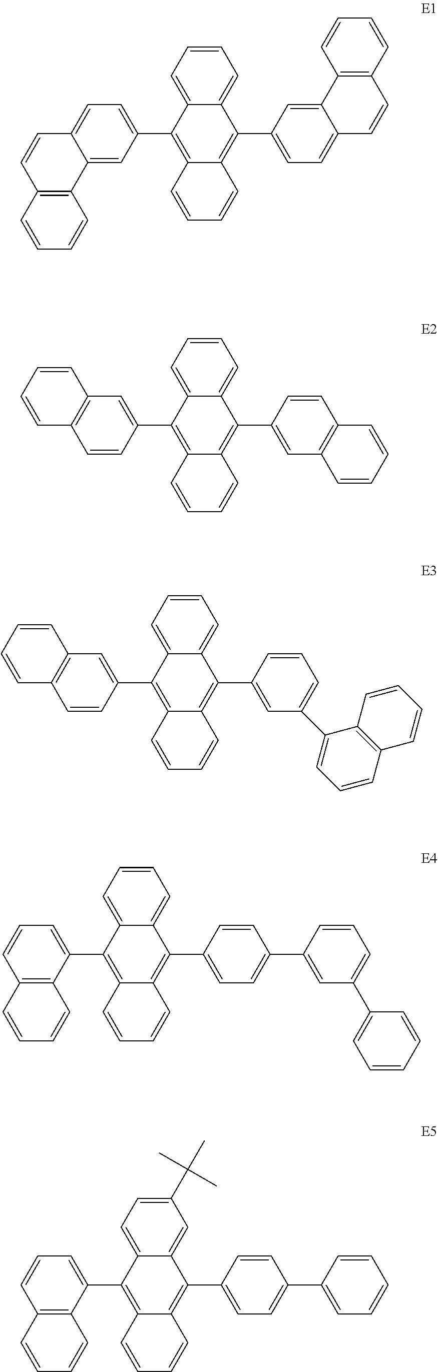

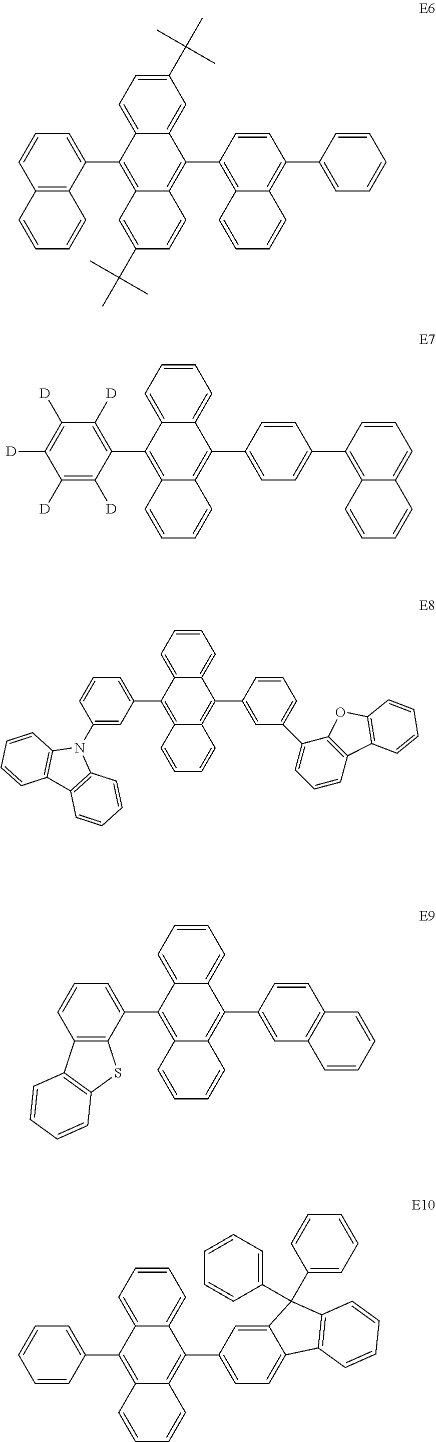

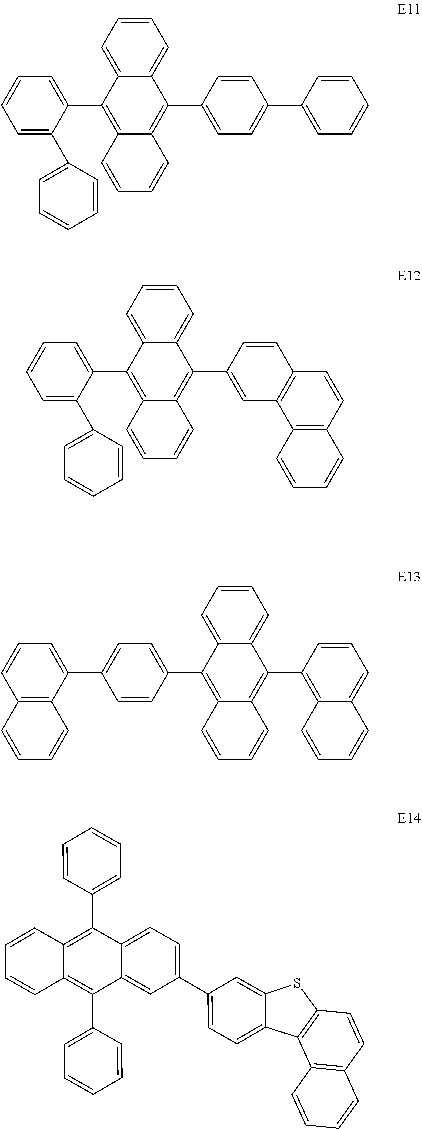

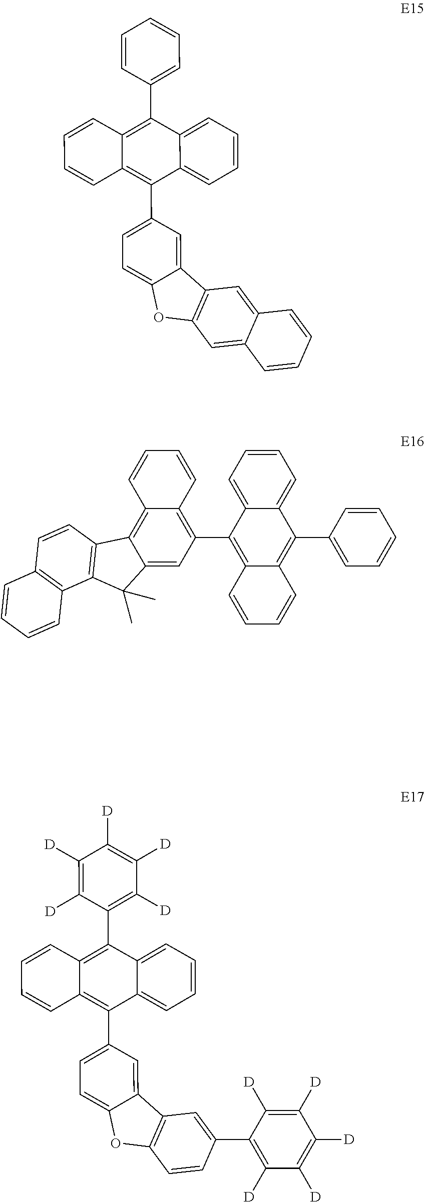

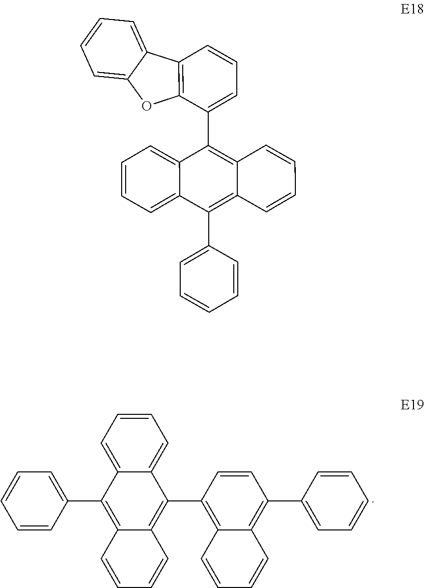

In one or more embodiments, the emission layer EML may include a compound represented by Formula E-2a or Formula E-2b below. The compound represented by Formula E-2a or Formula E-2b may be used as a phosphorescence host material.

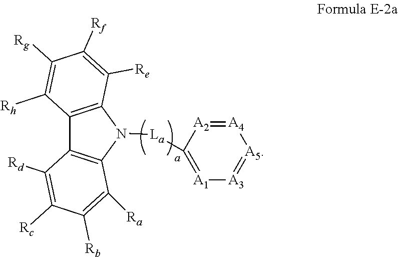

In Formula E-2a, “a” may be an integer of 0 to 10, Lₐ may be a direct linkage, a substituted or unsubstituted arylene group of 6 to 30 ring-forming carbon atoms, or a substituted or unsubstituted heteroarylene group of 2 to 30 ring-forming carbon atoms.

If “a” is an integer of 2 or more, multiple Lₐ may be each independently a substituted or unsubstituted arylene group of 6 to 30 ring-forming carbon atoms, or a substituted or unsubstituted heteroarylene group of 2 to 30 ring-forming carbon atoms.

In some embodiments, in Formula E-2a, A₁ to A₅ may be each independently N or CRᵢ. Rₐ to Rᵢ may be each independently a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. Rₐ to Rᵢ may be combined with an adjacent group to form a hydrocarbon ring or a heterocycle including N, O, S, etc. as a ring-forming atom.

In Formula E-2a, two or three selected from A₁ to A₅ may be N, and the remainder may be CRᵢ.

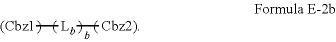

In Formula E-2b, Cbz1 and Cbz2 may be each independently an unsubstituted carbazole group, or a carbazole group substituted with an aryl group of 6 to 30 ring-forming carbon atoms. L_{b} may be a direct linkage, a substituted or unsubstituted arylene group of 6 to 30 ring-forming carbon atoms, or a substituted or unsubstituted heteroarylene group of 2 to 30 ring-forming carbon atoms. “b” is an integer of 0 to 10, and if “b” is an integer of 2 or more, multiple L_{b} may be each independently a substituted or unsubstituted arylene group of 6 to 30 ring-forming carbon atoms, or a substituted or unsubstituted heteroarylene group of 2 to 30 ring-forming carbon atoms.

The compound represented by Formula E-2a or Formula E-2b may be represented by any one among the compounds in Compound Group E-2 below. However, the compounds listed in Compound Group E-2 below are only illustrations, and the compound represented by Formula E-2a or Formula E-2b is not limited to the compounds represented in Compound Group E-2 below.

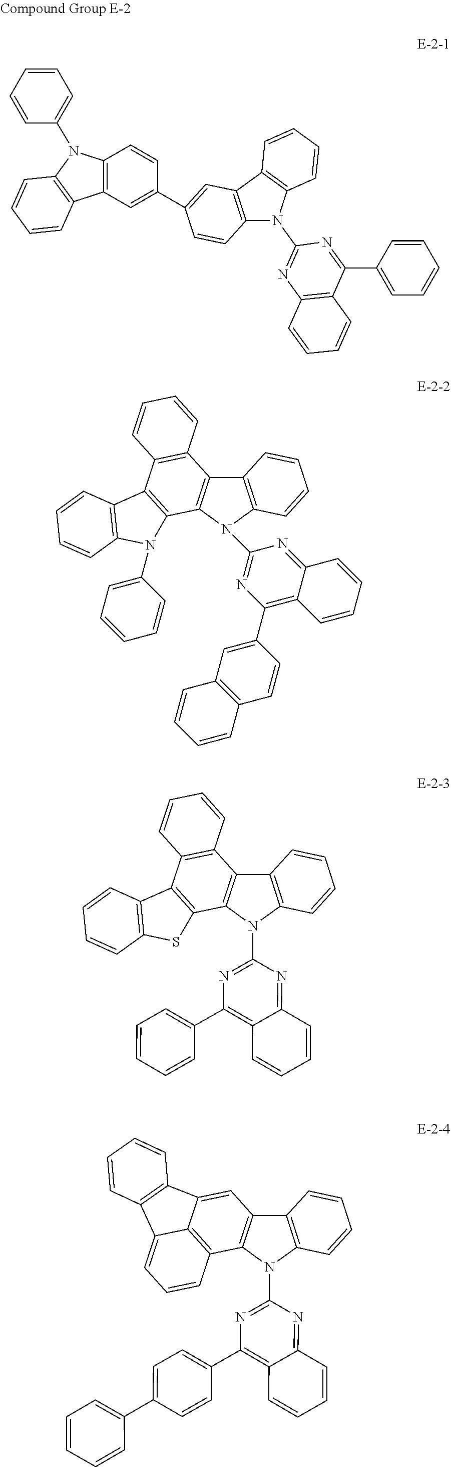 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1 ; c1ccc(-c2ccc(-c3nc(-n4c5ccccc5c5cc6c7c(cccc7c54)-c4ccccc4-6)nc4ccccc34)cc2)cc1]

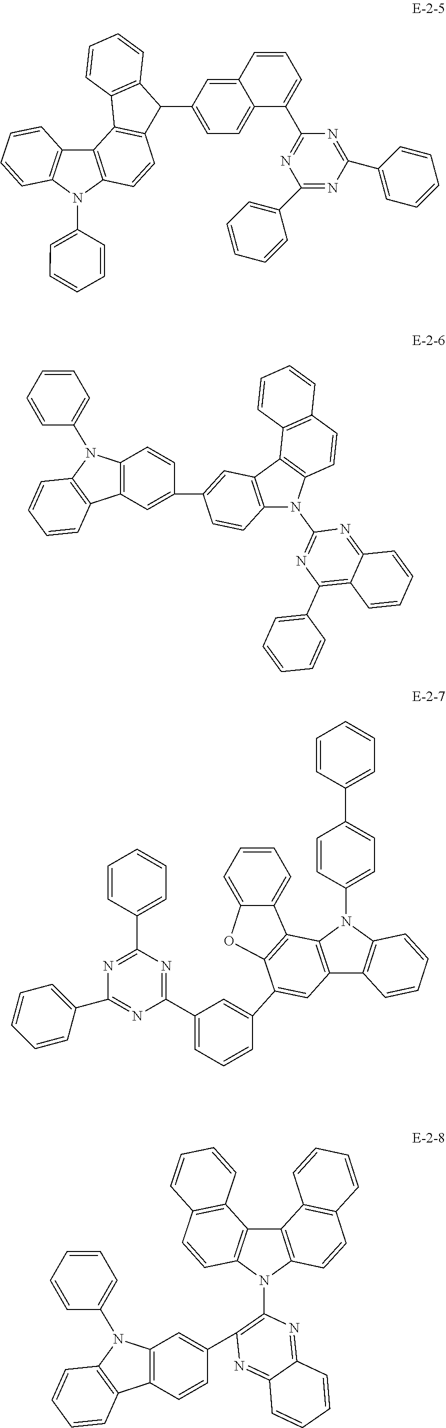 [SMILES: c1ccc(-c2nc(-c3ccccc3)nc(-c3cccc4cc(C5c6ccccc6-c6c5ccc5c6c6ccccc6n5-c5ccccc5)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

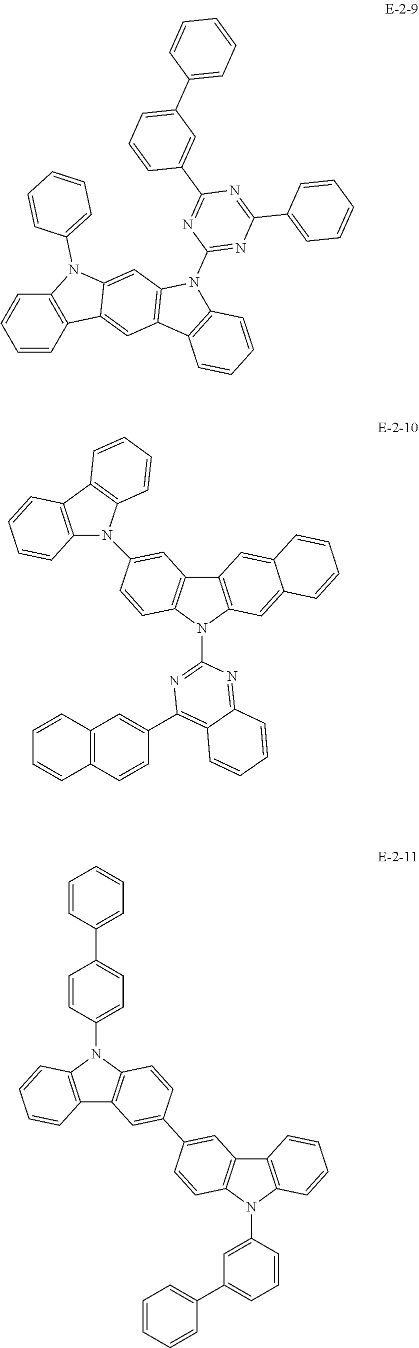 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1]

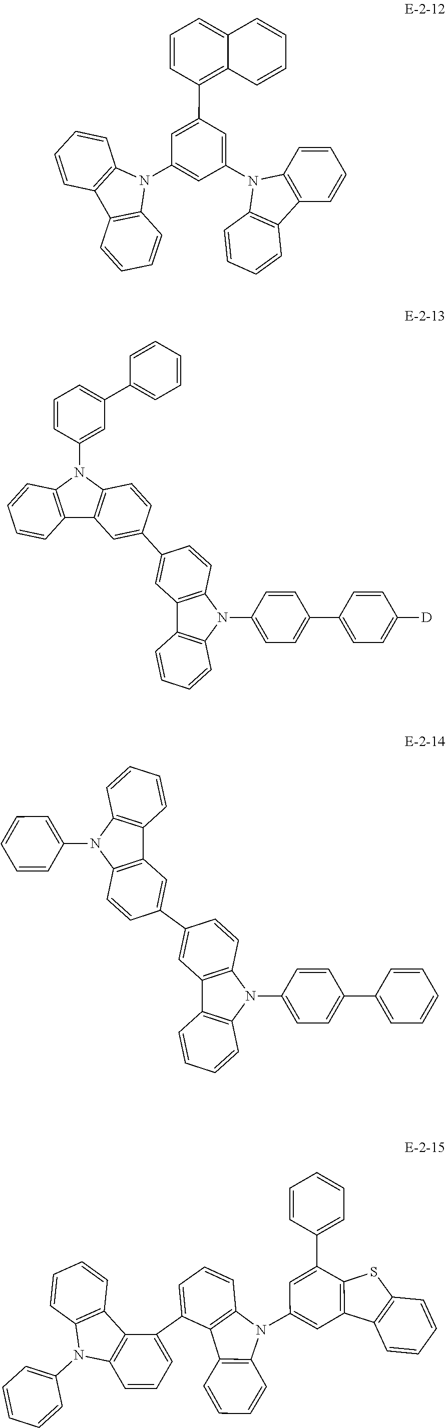 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

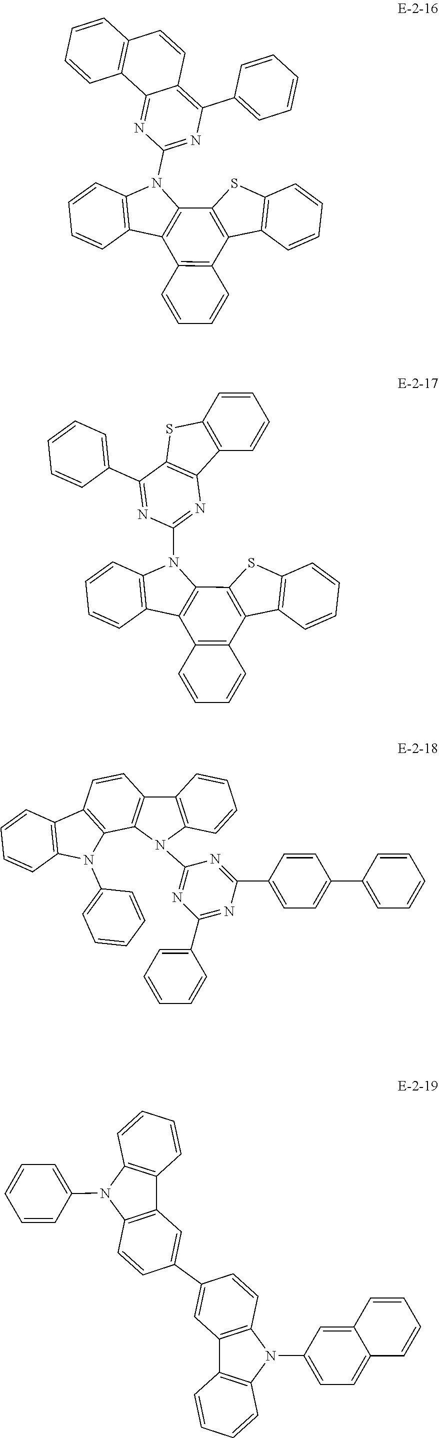 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1]

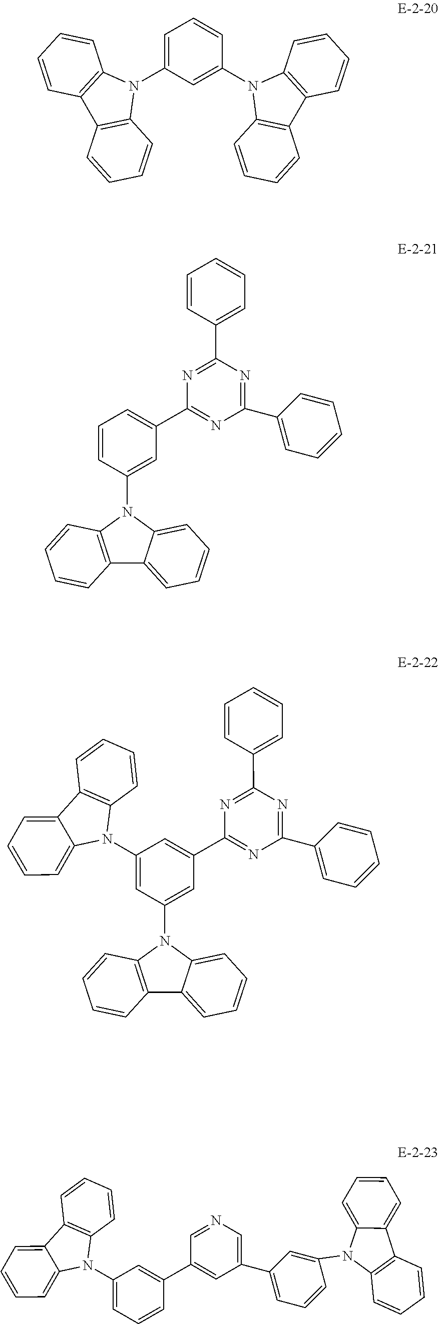 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

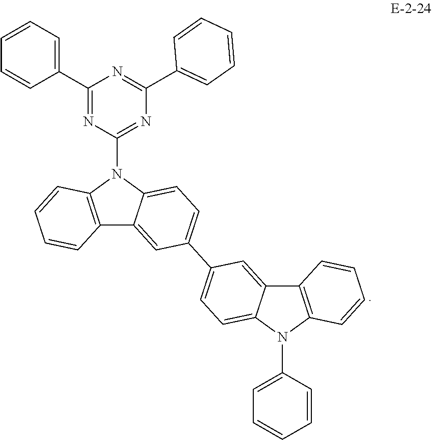 [SMILES: c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include any suitable material as a host material. For example, the emission layer EML may include as a host material, at least one of bis (4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl] ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, one or more embodiments of the present disclosure is not limited thereto. For example, tris(8-hydroxyquinolino)aluminum (Alq3), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO3), octaphenylcyclotetra siloxane (DPSiO4), etc. may be used as the host material.

The emission layer EML may include a compound represented by Formula M-b below. The compound represented by Formula M-b may be used as a phosphorescence dopant material.

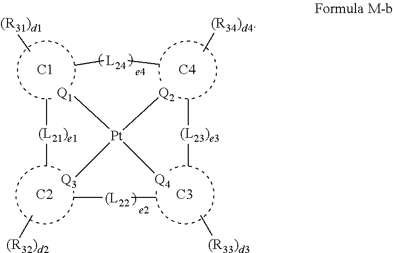

In Formula M-b, Q₁ to Q₄ may be each independently C or N, C1 to C4 may be each independently a substituted or unsubstituted hydrocarbon ring of 5 to 30 ring-forming carbon atoms, or a substituted or unsubstituted heterocycle of 2 to 30 ring-forming carbon atoms. L₂₁ to L₂₄ may be each independently a direct linkage,

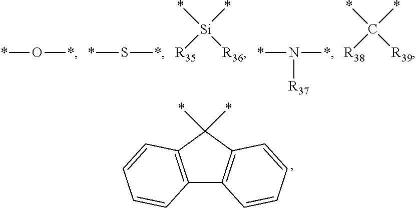

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms, and e1 to e4 may be each independently 0 or 1.

In Formula M-b, R₃₁ to R₃₉ may be each independently a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, and d1 to d4 may be each independently an integer of 0 to 4.

The compound represented by Formula M-b may be used as a blue phosphorescence dopant or a green phosphorescence dopant. The compound represented by Formula M-b may be represented by any one among the compounds below. However, the compounds below are illustrations, and the compound represented by Formula M-b is not limited to the compounds represented below.

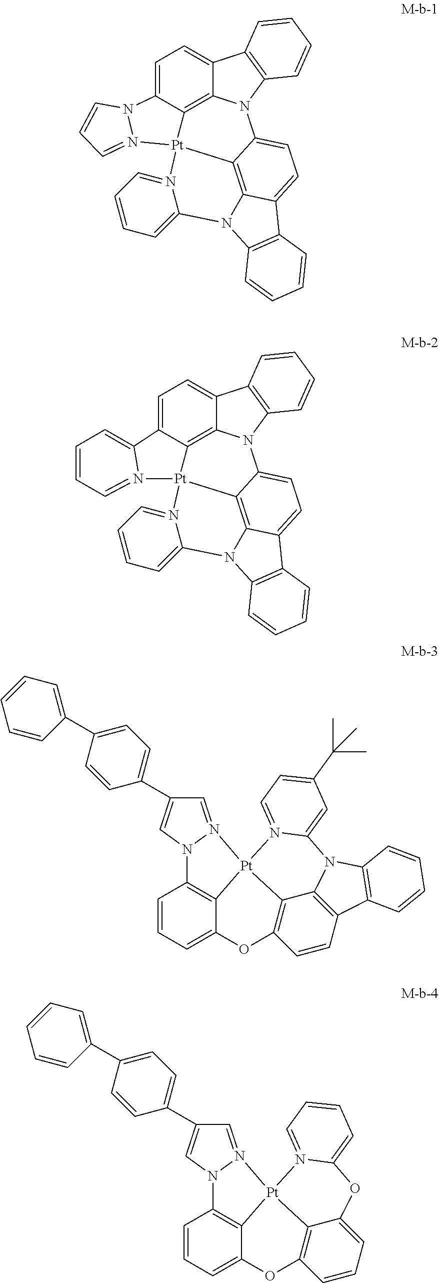

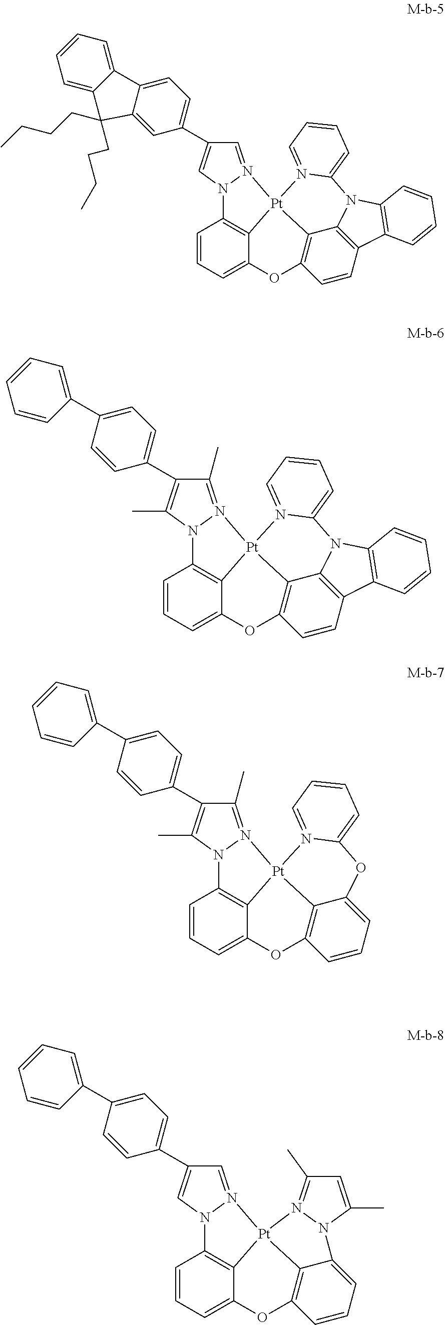

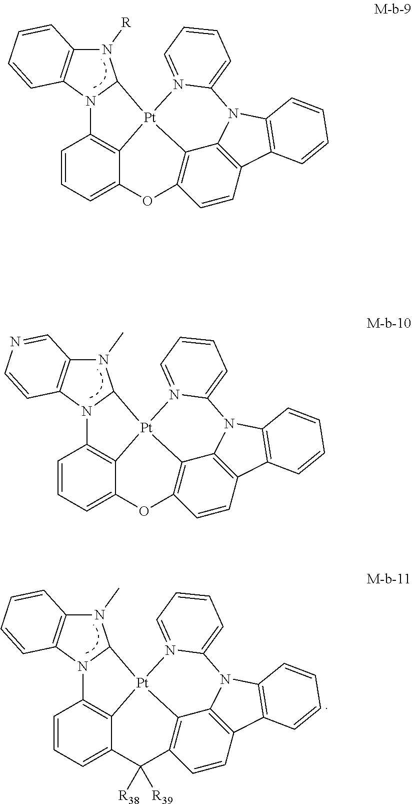

In the compounds above, R, R₃₈, and R₃₉ may be each independently a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

The emission layer EML may further include a compound represented by any one among Formula F-a to Formula F-c below. The compounds represented by Formula F-a to Formula F-c may be used as fluorescence dopant materials.

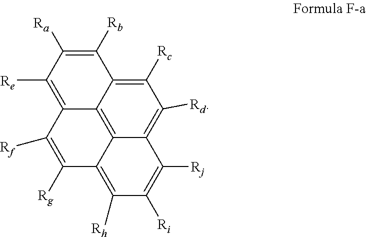

In Formula F-a, two selected from Rₐ to Rⱼ may be each independently substituted with *—NAr₁Ar₂. The remainder not substituted with *—NAr₁Ar₂ among Rₐ to Rⱼ may be each independently a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In *—NAr₁Ar₂, Ar₁ and Ar₂ may be each independently a substituted or unsubstituted aryl group of 6 to 30 ring-forming carbon atoms, or a substituted or unsubstituted heteroaryl group of 2 to 30 ring-forming carbon atoms. For example, at least one among Ar₁ and Ar₂ may be a heteroaryl group including O or S as a ring-forming atom.

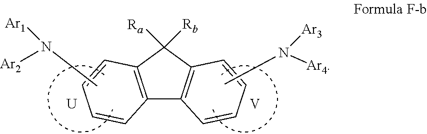

In Formula F-b, Rₐ and R_{b} may be each independently a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. Ar₁ to Ar₄ may be each independently a substituted or unsubstituted aryl group of 6 to 30 ring-forming carbon atoms, or a substituted or unsubstituted heteroaryl group of 2 to 30 ring-forming carbon atoms. In Formula F-b, U and V may be each independently a substituted or unsubstituted hydrocarbon ring of 5 to 30 ring-forming carbon atoms, or a substituted or unsubstituted heterocycle of 2 to 30 ring-forming carbon atoms. In Formula F-b, the number of rings represented by U and V may be each independently 0 or 1.

For example, in Formula F-b, if the number of U or V is 1, one ring forms a fused ring at the designated part by U or V, and if the number of U or V is 0, a ring is not present at the designated part by U or V. For example, if the number of U is 0, and the number of V is 1, or if the number of U is 1, and the number of V is 0, a fused ring having the fluorene core of Formula F-b may be a ring compound with four rings. If the number of both U and V is 0, the fused ring having a fluorene core of Formula F-b may be a ring compound with three rings. If the number of both U and V is 1, a fused ring having the fluorene core of Formula F-b may be a ring compound with five rings.

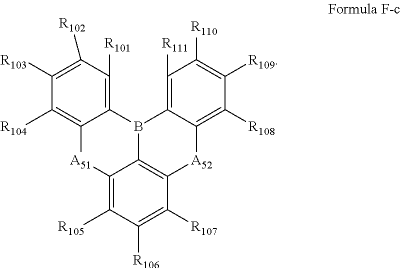

In Formula F-c, A₅₁ and A₅₂ may be each independently 0, S, Se, or NRₘ, and Rₘ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. R₁₀₁ to R₁₁₁ may be each independently a hydrogen atom, a deuterium atom, a halogen atom, a cyano group, a substituted or unsubstituted amine group, a substituted or unsubstituted boron group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring.

In Formula F-c, A₅₁ and A₅₂ may be each independently combined with the substituents of an adjacent ring to form a fused ring. For example, if A₅₁ and A₅₂ may be each independently NRₘ, A₅₁ may be combined with R₁₀₄ or R₁₀₅ to form a ring. In some embodiments, A₅₂ may be combined with R₁₀₇ or R₁₀₈ to form a ring.

In one or more embodiments, the emission layer EML may include as a suitable dopant material, styryl derivatives (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and/or 4,4′-bis[2-(4-(N,N-diphenylamino)phenyl)vinyl]biphenyl (DPAVBi)), perylene and/or the derivatives thereof (for example, 2,5,8,11-tetra-t-butylperylene (TBP)), pyrene and/or the derivatives thereof (for example, 1,1-dipyrene, 1,4-dipyrenylbenzene, and/or 1,4-bis(N,N-diphenylamino)pyrene), etc.

The emission layer EML may include a suitable phosphorescence dopant material. For example, the phosphorescence dopant may use a metal complex including iridium (Ir), platinum (Pt), osmium (Os), gold (Au), titanium (Ti), zirconium (Zr), hafnium (Hf), europium (Eu), terbium (Tb) and/or thulium (Tm). For example, iridium(Ill) bis(4,6-difluorophenylpyridinato-N,C2′)picolinate (Flrpic), bis(2,4-difluorophenylpyridinato)-tetrakis(1-pyrazolyl)borate iridium(III) (FIr6), and/or platinum octaethyl porphyrin (PtOEP) may be used as the phosphorescence dopant. However, one or more embodiments of the present disclosure is not limited thereto.

The emission layer EML may include a quantum dot material. The core of the quantum dot may be selected from II-VI group compounds, III-VI group compounds, I-III-VI group compounds, III-V group compounds, III-II-V group compounds, IV-VI group compounds, IV group elements, IV group compounds, and combinations thereof.

The II-VI group compound may be selected from the group consisting of: a binary compound selected from the group consisting of CdSe, CdTe, CdS, ZnS, ZnSe, ZnTe, ZnO, HgS, HgSe, HgTe, MgSe, MgS, and mixtures thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and mixtures thereof.

The III-V group compound may include a binary compound such as In₂S₃ and/or In₂Se₃; a ternary compound such as InGaS₃ and/or InGaSe₃; and/or optional combinations thereof.

The I-III-VI group compound may be selected from a ternary compound selected from the group consisting of AgInS, AgInS₂, CuInS, CulnS₂, AgGaS₂, CuGaS₂, CuGaO₂, AgGaO₂, AgAlO₂ and mixtures thereof; and a quaternary compound such as AgInGaS₂ and/or CulnGaS₂.

The III-V group compound may be selected from the group consisting of a binary compound selected from the group consisting of GaN, GaP, GaAs, GaSb, AlN, AlP, AlAs, AlSb, InN, InP, InAs, InSb, and mixtures thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof; and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof. In some embodiments, the III-V group compound may further include a II group metal. For example, InZnP, etc. may be selected as a III-II-V group compound.

The IV-VI group compound may be selected from the group consisting of a binary compound selected from the group consisting of SnS, SnSe, SnTe, PbS, PbSe, PbTe, and mixtures thereof; a ternary compound selected from the group consisting of SnSeS, SnSeTe, SnSTe, PbSeS, PbSeTe, PbSTe, SnPbS, SnPbSe, SnPbTe, and mixtures thereof; and a quaternary compound selected from the group consisting of SnPbSSe, SnPbSeTe, SnPbSTe, and mixtures thereof. The IV group element may be selected from the group consisting of Si, Ge, and a mixture thereof. The IV group compound may be a binary compound selected from the group consisting of SiC, SiGe, and a mixture thereof.

In this case, the binary compound, the ternary compound and/or the quaternary compound may be present at a substantially uniform concentration in a particle or may be present at a partially different concentration distribution state in the same particle. In some embodiments, a core/shell structure in which one quantum dot wraps another quantum dot may be possible. The interface of the core and the shell may have a concentration gradient in which the concentration of an element present in the shell is decreased toward the center.

In some embodiments, the quantum dot may have the above-described core-shell structure including a core including a nanocrystal and a shell wrapping the core. The shell of the quantum dot may play the role of a protection layer for preventing or reducing the chemical deformation of the core to maintain semiconductor properties and/or a charging layer for imparting the quantum dot with electrophoretic properties. The shell may have a single layer or a multilayer. Examples of the shell of the quantum dot may include a metal oxide, a non-metal oxide, a semiconductor compound, and combinations thereof.

For example, the metal oxide and the non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, CO₃O₄ and/or NiO; and/or a ternary compound such as MgAl₂O₄, CoFe₂O₄, NiFe₂O₄ and/or CoMn₂O₄, but one or more embodiments of the present disclosure is not limited thereto.

In some embodiments, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but one or more embodiments of the present disclosure is not limited thereto.

The quantum dot may have a full width of half maximum (FWHM) of emission wavelength spectrum of about 45 nm or less, for example, about 40 nm or less, or about 30 nm or less. Within any of these ranges, color purity and/or color reproducibility may be improved. In some embodiments, light emitted via such quantum dot is emitted in all directions, and light view angle properties may be improved.

In some embodiments, any suitable shape of the quantum dot may be used, without specific limitation. For example, the shape of spherical, pyramidal, multi-arm, and/or cubic nanoparticle, nanotube, nanowire, nanofiber, nanoplate particle, etc. may be used.

The quantum dot may control the color of light emitted according to the particle size, and accordingly, the quantum dot may have various suitable emission colors such as blue, red and green.

Referring to FIG. 3 to FIG. 6 again, the first electrode EL1 has conductivity. The first electrode EL1 may be formed using a metal material, a metal alloy and/or a conductive compound. The first electrode EL1 may be an anode or a cathode. However, one or more embodiments of the present disclosure is not limited thereto. In some embodiments, the first electrode EL1 may be a pixel electrode. The first electrode EL1 may be a transmissive electrode, a transflective electrode, or a reflective electrode. The first electrode EL1 may include at least one selected among Ag, Mg, Cu, Al, Pt, Pd, Au, Ni, Nd, Ir, Cr, Li, Ca, LiF, Mo, Ti, W, In, Sn and Zn, compounds of two or more thereof, mixtures of two or more thereof, and oxides thereof.

If the first electrode EL1 is the transmissive electrode, the first electrode EL1 may include a transparent metal oxide such as indium tin oxide (ITO), indium zinc oxide (IZO), zinc oxide (ZnO), and/or indium tin zinc oxide (ITZO). If the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, compounds thereof, or mixtures thereof (for example, a mixture of Ag and Mg). Also, the first electrode EL1 may have a structure including multiple layers including a reflective layer or a transflective layer formed using any of the above materials, and a transmissive conductive layer formed using ITO, IZO, ZnO, and/or ITZO. For example, the first electrode EL1 may have a three-layer structure of ITO/Ag/ITO, without limitation. In some embodiments, the first electrode EL1 may include the above-described metal materials, combinations of two or more metal materials selected from the above-described metal materials, and/or oxides of the above-described metal materials. However, one or more embodiments of the present disclosure is not limited thereto. The thickness of the first electrode EL1 may be from about 700 Å to about 10,000 Å. For example, the thickness of the first electrode EL1 may be from about 1,000 Å to about 3,000 Å.

The hole transport region HTR is provided on the first electrode EL1. The hole transport region HTR may include at least one of a hole injection layer HIL, a hole transport layer HTL, a buffer layer or an emission auxiliary layer, or an electron blocking layer EBL. The thickness of the hole transport region HTR may be, for example, from about 50 Å to about 15,000 Å.

The hole transport region HTR may have a single layer formed using a single material, a single layer formed using multiple different materials, or a multilayer structure including multiple layers formed using multiple different materials. For example, the hole transport region HTR may have the structure of a single layer of a hole injection layer HIL or a hole transport layer HTL, and may have a structure of a single layer formed using a hole injection material and a hole transport material.

In some embodiments, the hole transport region HTR may have a structure of a single layer formed using multiple different materials, or a structure stacked from the first electrode EL1 of hole injection layer HIL/hole transport layer HTL, hole injection layer HTL/hole transport layer HTL/buffer layer, hole injection layer HIL/buffer layer, hole transport layer HTL/buffer layer, or hole injection layer HIL/hole transport layer HTL/electron blocking layer EBL, without limitation.

The hole transport region HTR may be formed using one or more suitable methods such as a vacuum deposition method, a spin coating method, a cast method, a Langmuir-Blodgett (LB) method, an inkjet printing method, a laser printing method, and/or a laser induced thermal imaging (LITI) method.

The hole transport region HTR may include a compound represented by Formula H-1 below.

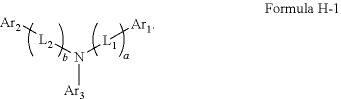

In Formula H-1 above, L₁ and L₂ may be each independently a direct linkage, a substituted or unsubstituted arylene group of 6 to 30 ring-forming carbon atoms, or a substituted or unsubstituted heteroarylene group of 2 to 30 ring-forming carbon atoms. “a” and “b” may be each independently an integer of 0 to 10. Meanwhile, if “a” or “b” is an integer of 2 or more, multiple L₁ and L₂ may be each independently a substituted or unsubstituted arylene group of 6 to 30 ring-forming carbon atoms, or a substituted or unsubstituted heteroarylene group of 2 to 30 ring-forming carbon atoms.

In Formula H-1, Ar₁ and Ar₂ may be each independently a substituted or unsubstituted aryl group of 6 to 30 ring-forming carbon atoms, or a substituted or unsubstituted heteroaryl group of 2 to 30 ring-forming carbon atoms. In some embodiments, in Formula H-1, Ar₃ may be a substituted or unsubstituted aryl group of 6 to 30 ring-forming carbon atoms.

The compound represented by Formula H-1 may be a monoamine compound. In some embodiments, the compound represented by Formula H-1 may be a diamine compound in which at least one among Ar₁ to Ar₃ includes an amine group as a substituent. In some embodiments, the compound represented by Formula H-1 may be a carbazole-based compound in which at least one among Ar₁ and Ar₂ includes a substituted or unsubstituted carbazole group, or a fluorene-based compound in which at least one among Ar₁ and Ar₂ includes a substituted or unsubstituted fluorene group.

The compound represented by Formula H-1 may be represented by any one among the compounds in Compound Group H below. However, the compounds listed in Compound Group H are only illustrations, and the compound represented by Formula H-1 is not limited to the compounds represented in Compound Group H below.

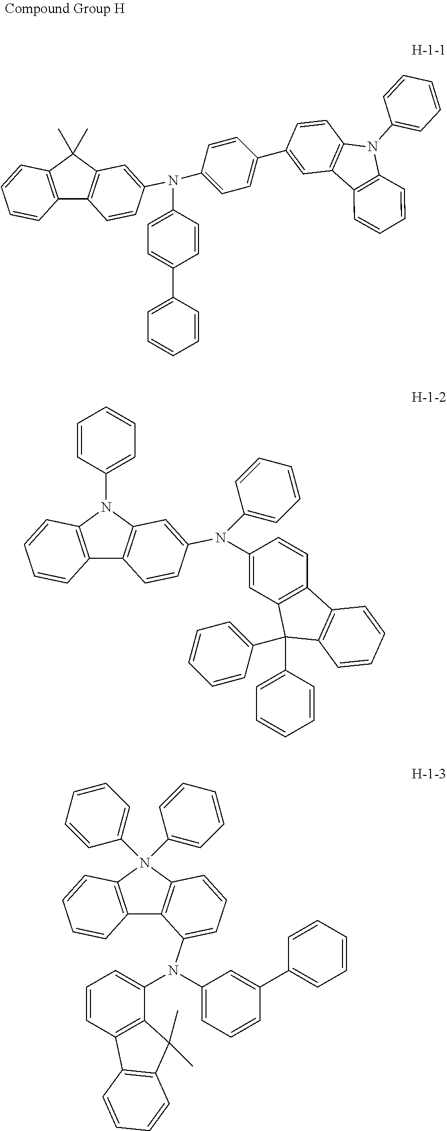

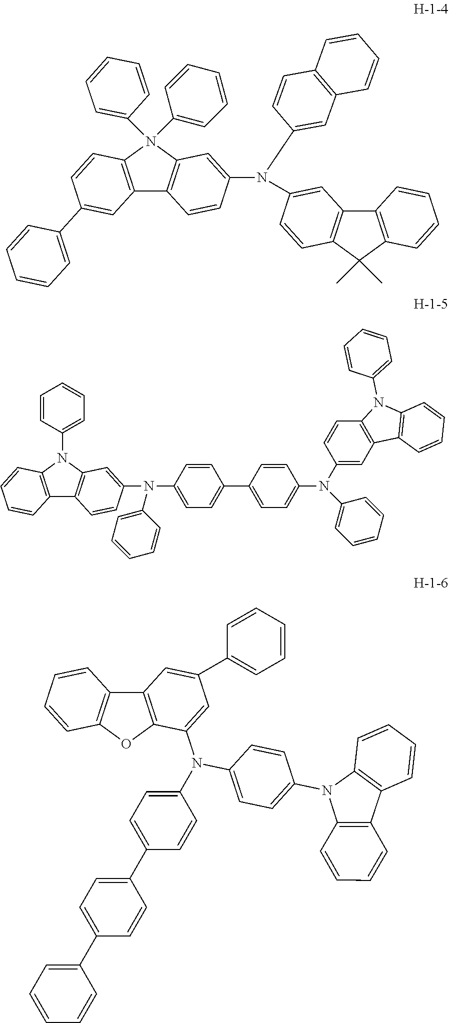

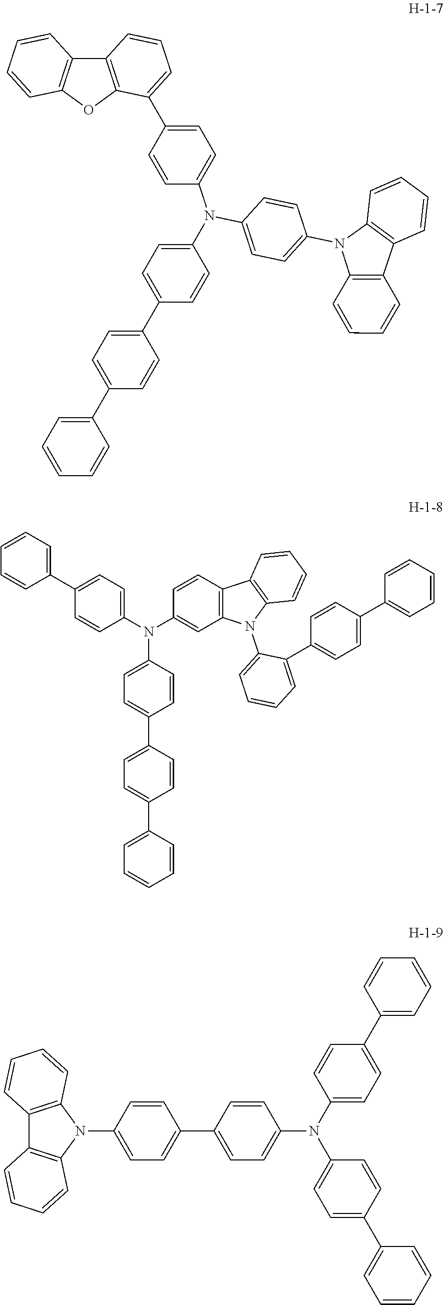 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

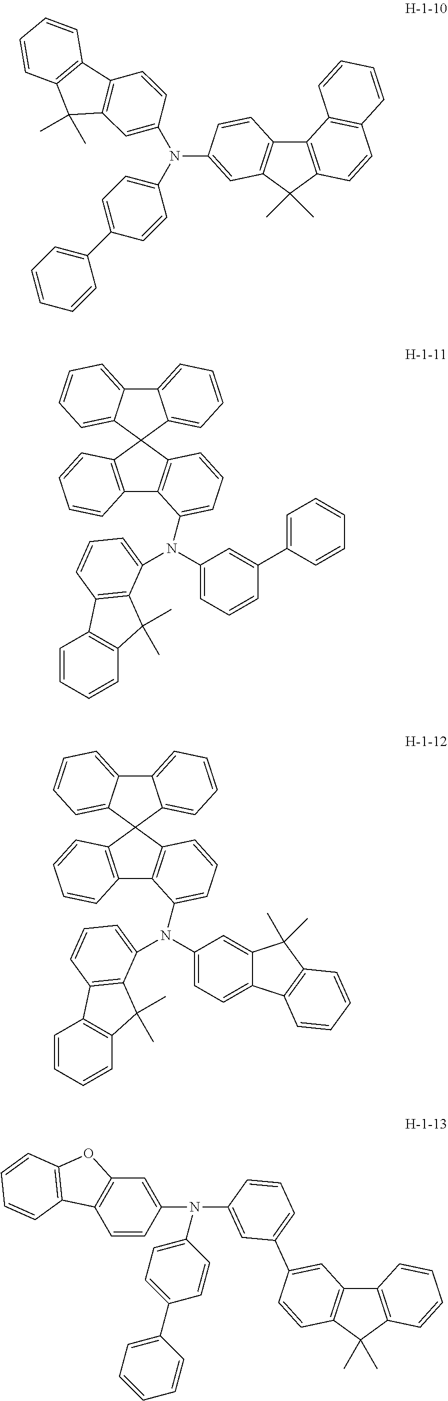 [SMILES: CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

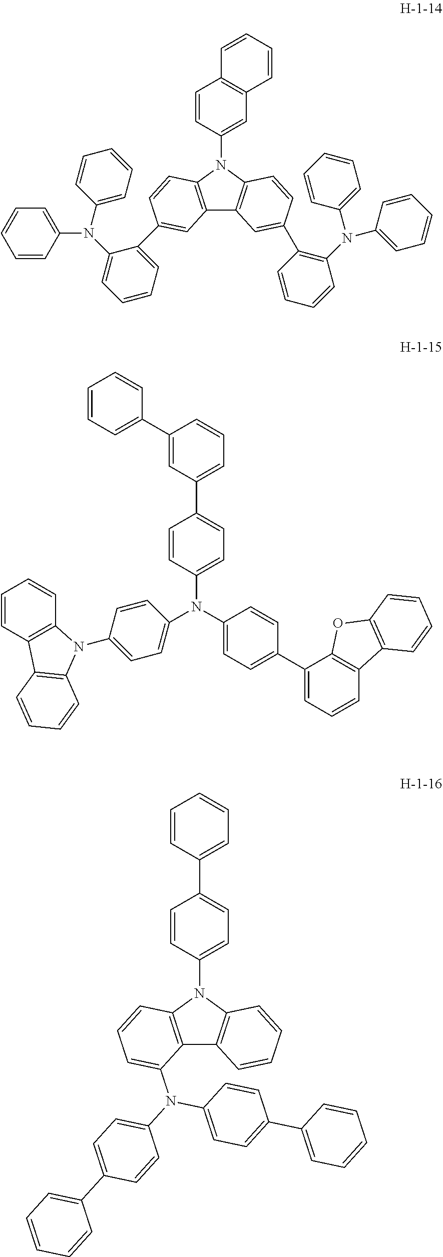 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

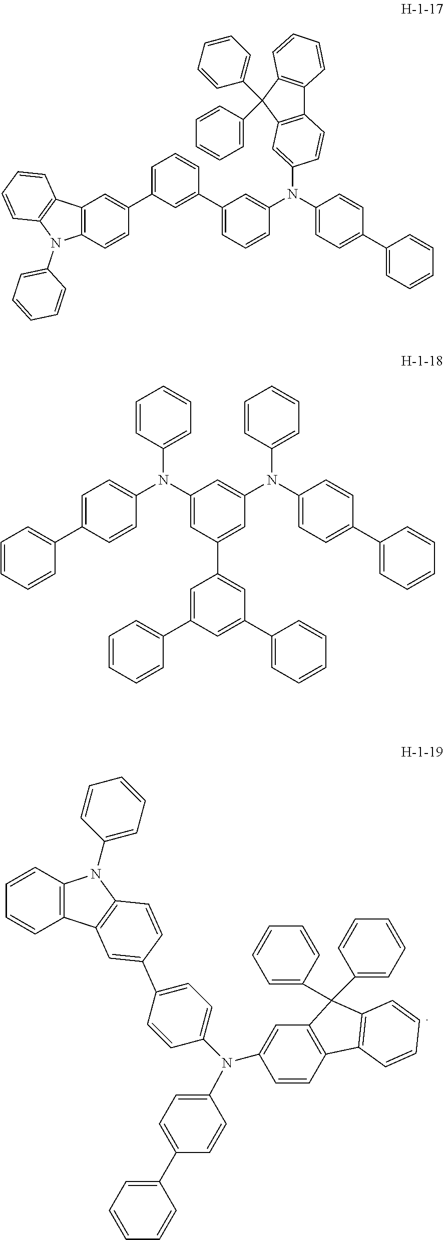 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(1-naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], and/or dipyrazino[2,3-f:2′,3′-h] quinoxaline-2,3,6,7,10,11-hexacarbonitrile (HATCN).

In some embodiments, the hole transport region HTR may include carbazole derivatives (such as N-phenyl carbazole and/or polyvinyl carbazole), fluorene-based derivatives, N,N′-bis(3-methylphenyl)-N,N′-diphenyl-[1,1′-biphenyl]-4,4′-diamine (TPD), triphenylamine-based derivatives such as 4,4′,4″-tris(N-carbazolyl)triphenylamine (TCTA), 4,4′-cyclohexylidene bis[N,N-bis(4-methylphenyl)benzeneamine] (TAPC), 4,4′-bis[N,N′-(3-tolyl)amino]-3,3′-dimethylbiphenyl (HMTPD), 9-(4-tert-butylphenyl)-3,6-bis(triphenylsilyl)-9H-carbazole (CzSi), 9-phenyl-9H-3,9′-bicarbazole (CCP), 1,3-bis(N-carbazolyl)benzene (mCP), and/or 1,3-bis(1,8-dimethyl-9H-carbazol-9-yl)benzene (mDCP), etc.

The hole transport region HTR may include the compounds of the hole transport region in at least one among the hole injection layer HIL, hole transport layer HTL, and electron blocking layer EBL.

The thickness of the hole transport region HTR may be from about 100 Å to about 10,000 Å, for example, from about 100 Å to about 5,000 Å. In case where the hole transport region HTR includes a hole injection layer HIL, the thickness of the hole injection layer HIL may be, for example, from about 30 Å to about 1,000 Å. In case where the hole transport region HTR includes a hole transport layer HTL, the thickness of the hole transport layer HTL may be from about 30 Å to about 1,000 Å. For example, in case where the hole transport region HTR includes an electron blocking layer EBL, the thickness of the electron blocking layer EBL may be from about 10 Å to about 1,000 Å. If the thicknesses of the hole transport region HTR, the hole injection layer HIL, the hole transport layer HTL and/or the electron blocking layer EBL satisfy the above-described respective ranges, satisfactory or suitable hole transport properties may be achieved without substantial increase of a driving voltage.

The hole transport region HTR may further include a charge generating material to increase conductivity, in addition to the above-described materials. The charge generating material may be dispersed substantially uniformly or substantially non-uniformly in the hole transport region HTR. The charge generating material may be, for example, a p-dopant. The p-dopant may include at least one selected from metal halide compounds, quinone derivatives, metal oxides, and cyano group-containing compounds, without limitation. For example, the p-dopant may include metal halide compounds such as CuI and/or RbI, quinone derivatives such as tetracyanoquinodimethane (TCNQ) and/or 2,3,5,6-tetrafluoro-7,7,8,8-tetracyanoquinodimethane (F4-TCNQ), metal oxides such as tungsten oxide and/or molybdenum oxide, cyano group-containing compounds such as dipyrazino[2,3-f: 2′,3′-h] quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., without limitation.

As described above, the hole transport region HTR may further include at least one among a buffer layer and an electron blocking layer EBL in addition to the hole injection layer HIL and the hole transport layer HTL. The buffer layer may compensate resonance distance according to the wavelength of light emitted from an emission layer EML and may increase emission efficiency. As materials included in the buffer layer, any of the materials which may be included in the hole transport region HTR may be used. The electron blocking layer EBL is a layer playing the role of preventing or reducing the injection of electrons from the electron transport region ETR to the hole transport region HTR.

In the light emitting elements ED of embodiments, as shown in FIG. 3 to FIG. 6, the electron transport region ETR is provided on the emission layer EML. The electron transport region ETR may include at least one of a hole blocking layer HBL, an electron transport layer ETL, or an electron injection layer EIL. However, one or more embodiments of the present disclosure is not limited thereto.

The electron transport region ETR may have a single layer formed using a single material, a single layer formed using multiple different materials, or a multilayer structure having multiple layers formed using multiple different materials.

For example, the electron transport region ETR may have a single layer structure of an electron injection layer EIL or an electron transport layer ETL, or a single layer structure formed using an electron injection material and an electron transport material. In some embodiments, the electron transport region ETR may have a single layer structure formed using multiple different materials, or a structure stacked from the emission layer EML of electron transport layer ETL/electron injection layer EIL, or hole blocking layer HBL/electron transport layer ETL/electron injection layer EIL, without limitation. The thickness of the electron transport region ETR may be, for example, from about 1,000 Å to about 1,500 Å.

The electron transport region ETR may be formed using one or more suitable methods such as a vacuum deposition method, a spin coating method, a cast method, a Langmuir-Blodgett (LB) method, an inkjet printing method, a laser printing method, and/or a laser induced thermal imaging (LITI) method.

The electron transport region ETR may include a compound represented by Formula ET-1.

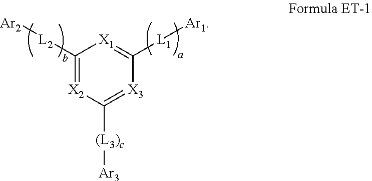

In Formula ET-1, at least one among X₁ to X₃ may be N, and the remainder may be CRₐ, and Rₐ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. Ar₁ to Ar₃ may be each independently a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-1, “a” to “c” may be each independently an integer of 0 to 10. In Formula ET-1, L₁ to L₃ may be each independently a direct linkage, a substituted or unsubstituted arylene group of 6 to 30 ring-forming carbon atoms, or a substituted or unsubstituted heteroarylene group of 2 to 30 ring-forming carbon atoms. If “a” to “c” are integers of 2 or more, L₁ to L₃ may be each independently a substituted or unsubstituted arylene group of 6 to 30 ring-forming carbon atoms, or a substituted or unsubstituted heteroarylene group of 2 to 30 ring-forming carbon atoms.

The electron transport region ETR may include an anthracene-based compound. However, one or more embodiments of the present disclosure is not limited thereto. The electron transport region ETR may include, for example, tris(8-hydroxyquinolinato)aluminum (Alq3), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalene-2-yl)anthracene (ADN), 1,3-bis[3,5-di(pyridin-3-yl)phenyl]benzene (BmPyPhB), and/or one or more mixtures thereof, without limitation.

In some embodiments, the electron transport region ETR may include a metal halide such as LiF, NaCl, CsF, RbCl, RbI, CuI and/or KI, a metal in lanthanoides such as Yb, or a co-depositing material of the metal halide and the metal in lanthanoides. For example, the electron transport region ETR may include KI:Yb, RbI:Yb, LiF:Yb, etc., as the co-depositing material. The electron transport region ETR may use a metal oxide such as Li₂O and/or BaO, and/or 8-hydroxy-lithium quinolate (Liq). However, one or more embodiments of the present disclosure is not limited thereto. The electron transport region ETR also may be formed using a mixture material of an electron transport material and an insulating organo metal salt. The organo metal salt may be a material having an energy band gap of about 4 eV or more. For example, the organo metal salt may include, for example, one or more of metal acetates, metal benzoates, metal acetoacetates, metal acetylacetonates, and/or metal stearates.

The electron transport region ETR may include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the aforementioned materials. However, one or more embodiments of the present disclosure is not limited thereto.

The electron transport region ETR may include the compounds of the electron transport region in at least one among an electron injection layer EIL, an electron transport layer ETL, and a hole blocking layer HBL.

If the electron transport region ETR includes the electron transport layer ETL, the thickness of the electron transport layer ETL may be from about 100 Å to about 1,000 Å, for example, from about 150 Å to about 500 Å. If the thickness of the electron transport layer ETL satisfies any of the above-described ranges, satisfactory (or suitable) electron transport properties may be obtained without substantial increase of a driving voltage. If the electron transport region ETR includes the electron injection layer EIL, the thickness of the electron injection layer EIL may be from about 1 Å to about 100 Å, and from about 3 Å to about 90 Å. If the thickness of the electron injection layer EIL satisfies any of the above described ranges, satisfactory or suitable electron injection properties may be obtained without inducing substantial increase of a driving voltage.

The second electrode EL2 is provided on the electron transport region ETR. The second electrode EL2 may be a common electrode. The second electrode EL2 may be a cathode or an anode, but one or more embodiments of the present disclosure is not limited thereto. For example, if the first electrode EL1 is an anode, the second cathode EL2 may be a cathode, and if the first electrode EL1 is a cathode, the second electrode EL2 may be an anode. The second electrode EL2 may include at least one selected among Ag, Mg, Cu, A₁, Pt, Pd, Au, Ni, Nd, Ir, Cr, Li, Ca, LiF, Mo, Ti, W, In, Sn, and Zn, compounds of two or more thereof, mixtures of two or more thereof, and oxides thereof.

The second electrode EL2 may be a transmissive electrode, a transflective electrode or a reflective electrode. If the second electrode EL2 is the transmissive electrode, the second electrode EL2 may include a transparent metal oxide, for example, ITO, IZO, ZnO, ITZO, etc.

If the second electrode EL2 is the transflective electrode or the reflective electrode, the second electrode EL2 may include Ag, Mg, Cu, A₁, Pt, Pd, Au, Ni, Nd, Ir, Cr, Li, Ca, LiF/Ca, LiF/Al, Mo, Ti, Yb, W, one or more compounds including thereof, and/or one or more mixtures thereof (for example, AgMg, AgYb, and/or MgYb). In some embodiments, the second electrode EL2 may have a multilayered structure including a reflective layer or a transflective layer formed using any of the above-described materials and a transparent conductive layer formed using ITO, IZO, ZnO, ITZO, etc. For example, the second electrode EL2 may include one or more of the aforementioned metal materials, combinations of two or more metal materials selected from the aforementioned metal materials, and/or oxides of the aforementioned metal materials.

In one or more embodiments, the second electrode EL2 may be connected with an auxiliary electrode. If the second electrode EL2 is connected with the auxiliary electrode, the resistance of the second electrode EL2 may decrease.

On the second electrode EL2 in the light emitting element ED of one or more embodiments, a capping layer CPL may be further provided. The capping layer CPL may include a multilayer or a single layer.

In one or more embodiments, the capping layer CPL may be an organic layer or an inorganic layer. For example, if the capping layer CPL includes an inorganic material, the inorganic material may include an alkali metal compound such as LiF, an alkaline earth metal compound such as SiON, SiNₓ, SiO_{y}, etc.

For example, if the capping layer CPL includes an organic material, the organic material may include α-NPD, NPB, TPD, m-MTDATA, Alq3, CuPc, N4,N4,N4′,N4′-tetra(biphenyl-4-yl) biphenyl-4,4′-diamine (TPD15), 4,4′,4″-tris(carbazol-9-yl) triphenylamine (TCTA), etc., and/or may include an epoxy resin, and/or acrylate such as methacrylate. In some embodiments, a capping layer CPL may include at least one among Compounds P1 to P5 below, but one or more embodiments of the present disclosure is not limited thereto.

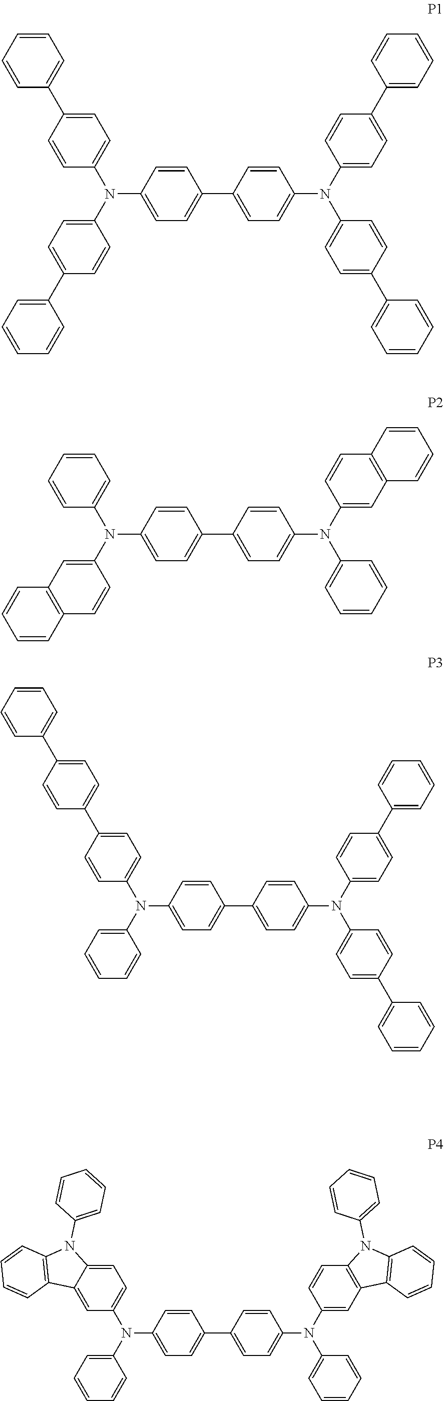 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

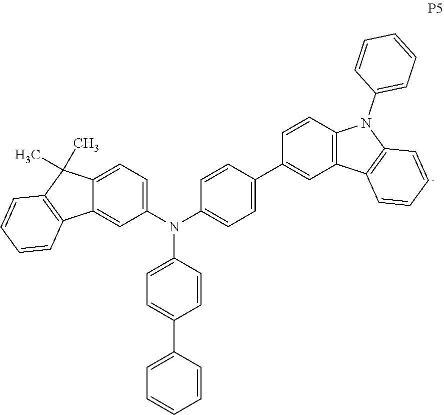 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

The refractive index of the capping layer CPL may be about 1.6 or more. For example, the refractive index of the capping layer CPL with respect to light in a wavelength range of about 550 nm to about 660 nm may be about 1.6 or more.

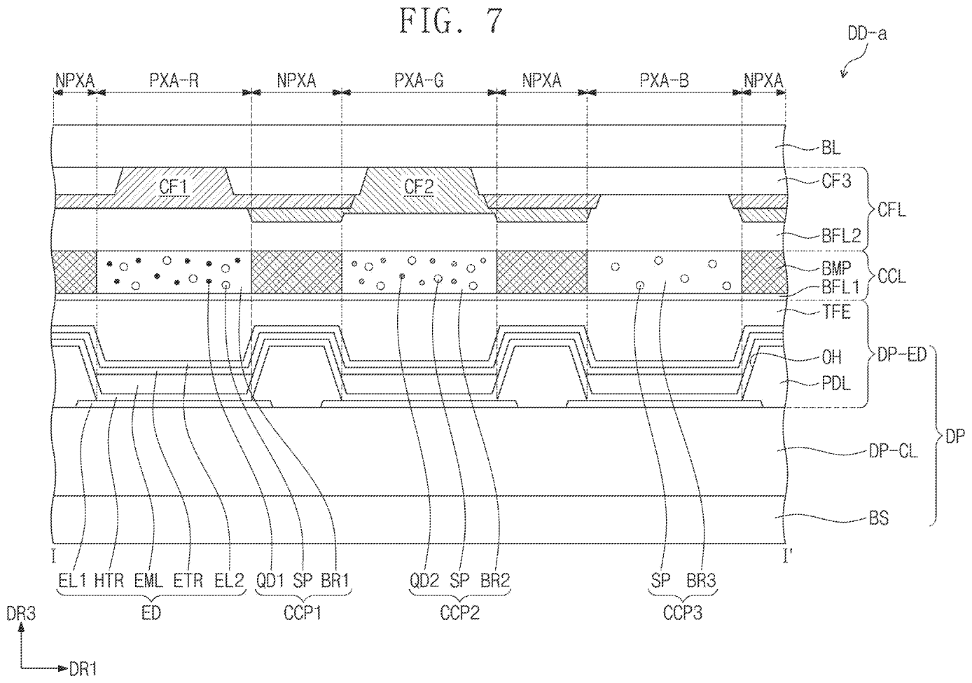

FIG. 7 to FIG. 10 are cross-sectional views of display devices according to embodiments. Hereinafter, in the explanation on the display devices of embodiments, referring to FIG. 7 to FIG. 10, the overlapping parts with the explanations provided in connection with FIG. 1 to FIG. 6 will not be explained again, and the different features will be explained chiefly.

Referring to FIG. 7, a display device DD according to one or more embodiments may include a display panel DP including a display element layer DP-ED, a light controlling layer CCL provided on the display panel DP, and a color filter layer CFL. In one or more embodiments shown in FIG. 7, the display panel DP includes a base layer BS, a circuit layer DP-CL provided on the base layer BS and a display element layer DP-ED, and the display element layer DP-ED may include a light emitting element ED.

The light emitting element ED may include a first electrode EL1, a hole transport region HTR provided on the first electrode EL1, an emission layer EML provided on the hole transport region HTR, an electron transport region ETR provided on the emission layer EML, and a second electrode EL2 provided on the electron transport region ETR. Here, the structures of the light emitting elements of FIG. 3 to FIG. 6 may be applied to the structure of the light emitting element ED shown in FIG. 7.

In FIG. 7, the light emitting element ED may include the nitrogen-containing compound of one or more embodiments. The emission layer EML may include the nitrogen-containing compound of one or more embodiments as a host material.

Referring to FIG. 7, the emission layer EML may be provided in an opening portion OH defined in a pixel definition layer PDL. For example, the emission layer EML divided by the pixel definition layer PDL and correspondingly provided to each of luminous areas PXA-R, PXA-G and PXA-B may emit light in the same wavelength region. In the display device DD-a of one or more embodiments, the emission layer EML may emit blue light. In one or more embodiments, the emission layer EML may be provided as a common layer for all luminous areas PXA-R, PXA-G and PXA-B.

The light controlling layer CCL may be provided on the display panel DP. The light controlling layer CCL may include a light converter. The light converter may be a quantum dot and/or a phosphor. The light converter may transform the wavelength of light provided and then emit the converted light. For example, the light controlling layer CCL may be a layer including a quantum dot and/or a layer including a phosphor.

The light controlling layer CCL may include multiple light controlling parts CCP1, CCP2 and CCP3. The light controlling parts CCP1, CCP2 and CCP3 may be separated from one another.

Referring to FIG. 7, a partition pattern BMP may be provided between the separated light controlling parts CCP1, CCP2 and CCP3, but one or more embodiments of the present disclosure is not limited thereto. In FIG. 7, the partition pattern BMP is shown not to be overlapped with the light controlling parts CCP1, CCP2 and CCP3, but at least a portion of the edge of the light controlling parts CCP1, CCP2 and CCP3 may be overlapped with the partition pattern BMP.

The light controlling layer CCL may include a first light controlling part CCP1 including a first quantum dot QD1 converting (e.g., configured to convert) first color light provided from the light emitting element ED into second color light, a second light controlling part CCP2 including a second quantum dot QD2 converting (e.g., configured to convert) first color light into third color light, and a third light controlling part CCP3 transmitting (e.g., configured to transmit) first color light.

In one or more embodiments, the first light controlling part CCP1 may provide red light which is the second color light, and the second light controlling part CCP2 may provide green light which is the third color light. The third color controlling part CCP3 may transmit and provide blue light which is the first color light provided from the light emitting element ED. For example, the first quantum dot QD1 may be a red quantum dot, and the second quantum dot QD2 may be a green quantum dot. On the quantum dots QD1 and QD2, the same contents as those described above may be applied.

In some embodiments, the light controlling layer CCL may further include a scatterer SP. The first light controlling part CCP1 may include the first quantum dot QD1 and the scatterer SP, the second light controlling part CCP2 may include the second quantum dot QD2 and the scatterer SP, and the third light controlling part CCP3 may not include a quantum dot but include the scatterer SP.

The scatterer SP may be an inorganic particle. For example, the scatterer SP may include at least one among TiO₂, ZnO, Al₂O₃, SiO₂, and hollow silica. The scatterer SP may include at least one among TiO₂, ZnO, Al₂O₃, SiO₂, and hollow silica, or may be a mixture of two or more materials selected among TiO₂, ZnO, Al₂O₃, SiO₂, and hollow silica.

The first light controlling part CCP1, the second light controlling part CCP2, and the third light controlling part CCP3 may respectively include base resins BR1, BR2 and BR3, respectively dispersing the quantum dots QD1 and QD2 and the scatterer SP. In one or more embodiments, the first light controlling part CCP1 may include the first quantum dot QD1 and the scatterer SP dispersed in the first base resin BR1, the second light controlling part CCP2 may include the second quantum dot QD2 and the scatterer SP dispersed in the second base resin BR2, and the third light controlling part CCP3 may include the scatterer particle SP dispersed in the third base resin BR3.

The base resins BR1, BR2 and BR3 are mediums in which the quantum dots QD1 and QD2 and the scatterer SP are dispersed, and may be composed of one or more suitable resin compositions which may be generally referred to as a binder. For example, the base resins BR1, BR2 and BR3 may be acrylic resins, urethane-based resins, silicone-based resins, epoxy-based resins, etc. The base resins BR1, BR2 and BR3 may be transparent resins. In one or more embodiments, the first base resin BR1, the second base resin BR2 and the third base resin BR3 may be the same or different from each other.

The light controlling layer CCL may include a barrier layer BFL1. The barrier layer BFL1 may play the role of blocking or reducing the penetration of moisture and/or oxygen (hereinafter, will be referred to as “humidity/oxygen”). The barrier layer BFL1 may block or reduce the exposure of the light controlling parts CCP1, CCP2 and CCP3 to humidity/oxygen. In some embodiments, the barrier layer BFL1 may cover the light controlling parts CCP1, CCP2 and CCP3. In some embodiments, the barrier layer BFL2 may be provided between a color filter layer CFL and the light controlling parts CCP1, CCP2 and CCP3.

The barrier layers BFL1 and BFL2 may include at least one inorganic layer. For example, the barrier layers BFL1 and BFL2 may be formed by including an inorganic material. For example, the barrier layers BFL1 and BFL2 may be formed by including silicon nitride, aluminum nitride, zirconium nitride, titanium nitride, hafnium nitride, tantalum nitride, silicon oxide, aluminum oxide, titanium oxide, tin oxide, cerium oxide and/or silicon oxynitride, and/or a metal thin film securing light transmittance. The barrier layers BFL1 and BFL2 may further include an organic layer. The barrier layers BFL1 and BFL2 may be composed of a single layer of multiple layers.

In the display device DD-a of one or more embodiments, the color filter layer CFL may be provided on the light controlling layer CCL. For example, the color filter layer CFL may be provided directly on the light controlling layer CCL. In this case, the barrier layer BFL2 may be omitted (e.g., may not be provided).

The color filter layer CFL may include filters CF1, CF2 and CF3. The color filter layer CFL may include a first filter CF1 transmitting (configured to transmit) second color light, a second filter CF2 transmitting (configured to transmit) third color light, and a third filter CF3 transmitting (configured to transmit) first color light. For example, the first filter CF1 may be a red filter, the second filter CF2 may be a green filter, and the third filter CF3 may be a blue filter. Each of the filters CF1, CF2 and CF3 may include a polymer photosensitive resin and a pigment and/or dye. The first filter CF1 may include a red pigment and/or dye, the second filter CF2 may include a green pigment and/or dye, and the third filter CF3 may include a blue pigment and/or dye. However, one or more embodiments of the present disclosure is not limited thereto, and the third filter CF3 may not include the pigment or dye. The third filter CF3 may include a polymer photosensitive resin and not include a pigment or dye. The third filter CF3 may be transparent. The third filter CF3 may be formed using a transparent photosensitive resin.

In some embodiments, in one or more embodiments, the first filter CF1 and the second filter CF2 may be yellow filters. The first filter CF1 and the second filter CF2 may be provided in one body without distinction (e.g., integrally with each other).

The first to third filters CF1, CF2 and CF3 may be provided corresponding to the red luminous area PXA-R, the green luminous area PXA-G and the blue luminous area PXA-B, respectively.

In some embodiments, the color filter layer CFL may further include a light blocking part. The light blocking part may be a black matrix. The light blocking part may be formed by including an organic light blocking material and/or an inorganic light blocking material, including a black pigment and/or black dye. The light blocking part may prevent or reduce light leakage and may divide the boundaries among adjacent filters CF1, CF2 and CF3.

On the color filter layer CFL, a base substrate BL may be provided. The base substrate BL may be a member providing a base surface on which the color filter layer CFL, the light controlling layer CCL, etc. are provided. The base substrate BL may be a glass substrate, a metal substrate, a plastic substrate, etc. However, one or more embodiments of the present disclosure is not limited thereto, and the base substrate BL may be an inorganic layer, an organic layer or a composite material layer.

In some embodiments, the base substrate BL may be omitted (e.g., may not be provided).

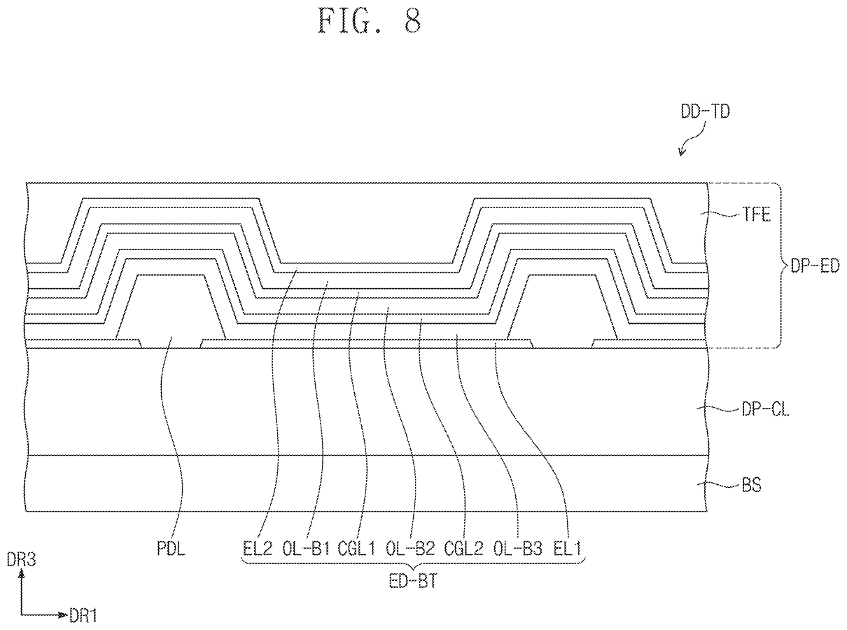

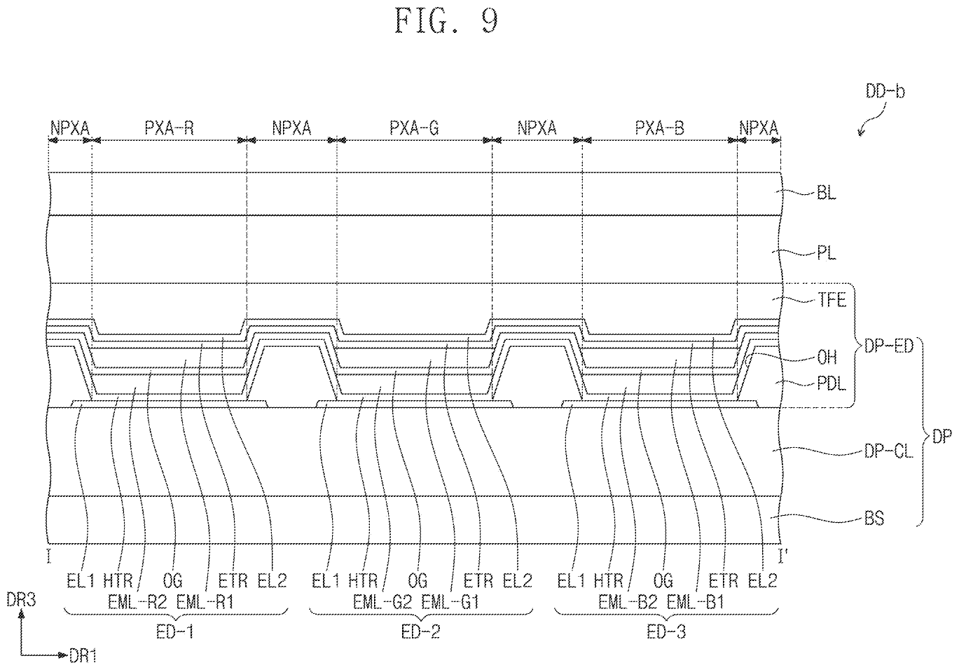

FIG. 8 is a cross-sectional view showing a portion of the display device according to one or more embodiments. FIG. 8 shows another embodiment of a portion corresponding to the display panel DP in FIG. 7. In a display device DD-TD of one or more embodiments, the light emitting element ED-BT may include multiple light emitting structures OL-B1, OL-B2 and OL-B3. The light emitting element ED-BT may include oppositely provided first electrode EL1 and second electrode EL2, and the multiple light emitting structures OL-B1, OL-B2 and OL-B3 stacked in order in a thickness direction and provided between the first electrode EL1 and the second electrode EL2. At least one among the light emitting structures OL-B1, OL-B2 and OL-B 3 may include the nitrogen-containing compound of one or more embodiments.

Each of the light emitting structures OL-B1, OL-B2 and OL-B3 may include an emission layer EML (FIG. 7), and a hole transport region HTR and an electron transport region ETR provided with the emission layer EML (FIG. 7) therebetween. For example, the light emitting element ED-BT included in the display device DD-TD of one or more embodiments may be a light emitting element of a tandem structure including multiple emission layers.

In one or more embodiments shown in FIG. 8, light emitted from the light emitting structures OL-B1, OL-B2 and OL-B3 may be all blue light. However, one or more embodiments of the present disclosure is not limited thereto, and the wavelength regions of light emitted from the light emitting structures OL-B1, OL-B2 and OL-B3 may be different from each other. For example, the light emitting element ED-BT including the multiple light emitting structures OL-B1, OL-B2 and OL-B3 emitting light in different wavelength regions may emit white light.

Between neighboring light emitting structures OL-B1, OL-B2 and OL-B3, charge generating layers CGL1 and CGL2 may be provided. The charge generating layers CGL1 and CGL2 may include a p-type charge generating (e.g., P-charge generating) layer and/or an n-type charge generating (e.g., N-charge generating) layer.

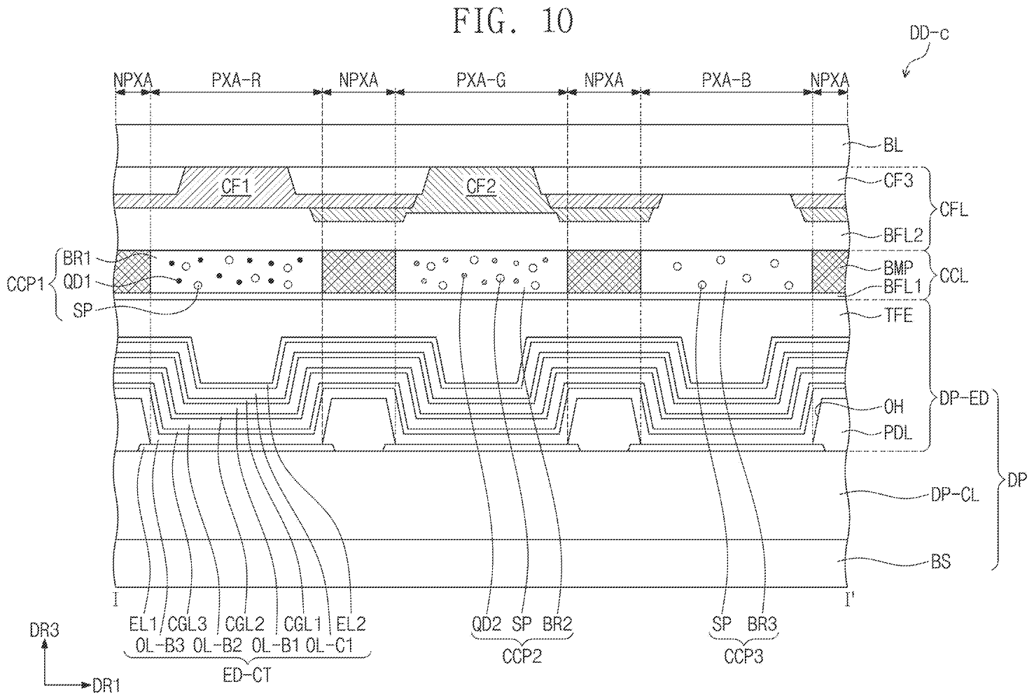

Referring to FIG. 9, a display device DD-b according to one or more embodiments may include light emitting elements ED-1, ED-2 and ED-3, formed by stacking two emission layers. Compared to the display device DD of one or more embodiments, shown in FIG. 2, FIG. 9 is different in that first to third light emitting elements ED-1, ED-2 and ED-3 include two emission layers stacked in a thickness direction, each. In the first to third light emitting elements ED-1, ED-2 and ED-3, two emission layers may emit light in the same wavelength region.

The first light emitting element ED-1 may include a first red emission layer EML-R₁ and a second red emission layer EML-R₂. The second light emitting element ED-2 may include a first green emission layer EML-G1 and a second green emission layer EML-G2. In some embodiments, the third light emitting element ED-3 may include a first blue emission layer EML-B1 and a second blue emission layer EML-B2.

Between the first red emission layer EML-R₁ and the second red emission layer EML-R2, between the first green emission layer EML-G1 and the second green emission layer EML-G2, and between the first blue emission layer EML-B1 and the second blue emission layer EML-B2, an emission auxiliary part OG may be provided.

The emission auxiliary part OG may include a single layer or a multilayer. The emission auxiliary part OG may include a charge generating layer. For example, the emission auxiliary part OG may include an electron transport region, a charge generating layer, and a hole transport region stacked in order. The emission auxiliary part OG may be provided as a common layer in all of the first to third light emitting elements ED-1, ED-2 and ED-3. However, one or more embodiments of the present disclosure is not limited thereto, and the emission auxiliary part OG may be patterned and provided in an opening portion OH defined in a pixel definition layer PDL.

The first red emission layer EML-R1, the first green emission layer EML-G1 and the first blue emission layer EML-B1 may be provided between the emission auxiliary part OG and the electron transport region ETR. The second red emission layer EML-R2, the second green emission layer EML-G2 and the second blue emission layer EML-B2 may be provided between the hole transport region HTR and the emission auxiliary part OG.

For example, the first light emitting element ED-1 may include a first electrode EL1, a hole transport region HTR, a second red emission layer EML-R₂, an emission auxiliary part OG, a first red emission layer EML-R₁, an electron transport region ETR, and a second electrode EL2, stacked in order. The second light emitting element ED-2 may include a first electrode EL1, a hole transport region HTR, a second green emission layer EML-G2, an emission auxiliary part OG, a first green emission layer EML-G1, an electron transport region ETR, and a second electrode EL2, stacked in order. The third light emitting element ED-3 may include a first electrode EL1, a hole transport region HTR, a second blue emission layer EML-B2, an emission auxiliary part OG, a first blue emission layer EML-B1, an electron transport region ETR, and a second electrode EL2, stacked in order. At least one among the first to third light emitting elements ED-1, ED-2 and ED-3 may include the nitrogen-containing compound of one or more embodiments. For example, at least one among the first blue emission layer EML-B1 and the second blue emission layer EML-B2 may include the nitrogen-containing compound of one or more embodiments. However, this in an illustration, and the configuration including the nitrogen-containing compound in the first to third light emitting elements ED-1, ED-2 and ED-3 is not limited thereto.

An optical auxiliary layer PL may be provided on a display element layer DP-ED. The optical auxiliary layer PL may include a polarization layer. The optical auxiliary layer PL may be provided on a display panel DP and may control the reflection at the display panel DP of external light. In some embodiments, the optical auxiliary layer PL may be omitted from (e.g., may not be provided in) the display device according to one or more embodiments.

Different from FIG. 8 and FIG. 9, a display device DD-c in FIG. 10 is shown to include four light emitting structures OL-B1, OL-B2, OL-B3 and OL-C1. A light emitting element ED-CT may include oppositely provided first electrode EL1 and second electrode EL2, and first to fourth light emitting structures OL-B1, OL-B2, OL-B3 and OL-C1 stacked in order in a thickness direction between the first electrode EL1 and the second electrode EL2. At least one among the first to fourth light emitting structures OL-B1, OL-B2, OL-B3 and OL-C1 may include the nitrogen-containing compound of one or more embodiments.

Between the first to fourth light emitting structures OL-B1, OL-B2, OL-B3 and OL-C1, charge generating layers CGL1, CGL2 and CGL3 may be provided. Among the four light emitting structures, the first to third light emitting structures OL-B1, OL-B2 and OL-B3 may emit blue light, and the fourth light emitting structure OL-C1 may emit green light. However, one or more embodiments of the present disclosure is not limited thereto, and the first to fourth light emitting structures OL-B1, OL-B2, OL-B3 and OL-C1 may emit different wavelengths of light.

The charge generating layers CGL1, CGL2 and CGL3 provided between the first to fourth light emitting structures OL-B1, OL-B2, OL-B3 and OL-C1 may include a p-type charge generating layer and/or an n-type charge generating layer.

Hereinafter, referring examples and comparative examples, the nitrogen-containing compound according to one or more embodiments and the light emitting element according to one or more embodiments of the present disclosure will be explained in more detail. However, the examples below are illustrations to assist the understanding of the present disclosure, and the scope of the present disclosure is not limited thereto.

### EXAMPLES

### 1. Synthesis of Nitrogen-Containing Compounds of Embodiments

First, the synthetic method of the nitrogen-containing compound according to one or more embodiments will be explained in more detail by illustrating the synthetic methods of Compounds 3, 4, 8, 18, 22, 116, 76 and 101. However, the synthetic methods of the nitrogen-containing compounds explained hereinafter are embodiments, and the synthetic method of the compound according to one or more embodiments of the present disclosure is not limited to the Examples below.

### (1) Synthesis of Nitrogen-Containing Compound 3

Nitrogen-containing Compound 3 according to one or more embodiments may be synthesized by, for example, the steps of Reaction 1 below.

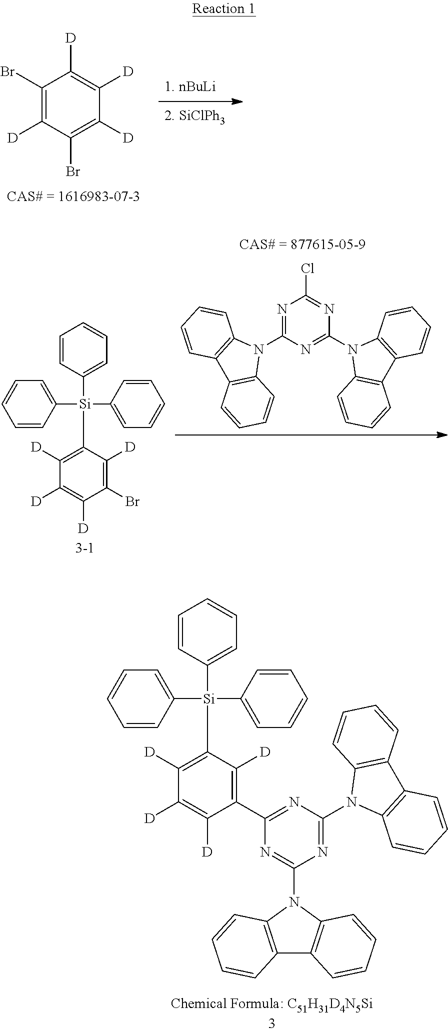 [SMILES: [2H]c1c([2H])c(Br)c([2H])c(Br)c1[2H] ; [2H]c1c([2H])c(Br)c([2H])c([Si](c2ccccc2)(c2ccccc2)c2ccccc2)c1[2H] ; Clc1nc(-n2c3ccccc3c3ccccc32)nc(-n2c3ccccc3c3ccccc32)n1 ; [2H]c1c([2H])c(-c2nc(-n3c4ccccc4c4ccccc43)nc(-n3c4ccccc4c4ccccc43)n2)c([2H])c([Si](c2ccccc2)(c2ccccc2)c2ccccc2)c1[2H]]

### Synthesis of Intermediate 3-1

4,6-Dibromobenzene-1,2,3,5-d4 (CAS #=1616983-07-3, 1 eq) was reacted with nBuLi (1 eq) under conditions of about −78° C., and after about 60 minutes, chlorotriphenylsilane (1 eq) was slowly added dropwisely thereto. Then, the reaction solution was slowly heated to room temperature and reacted overnight to obtain Intermediate 3-1. Intermediate 3-1 was identified by LC-MS (C₂₄H₁₅D₄BrSi M+1: 420.07).

### Synthesis of Compound 3

9,9′-(6-Chloro-1,3,5-triazine-2,4-diyl)bis(9H-carbazole) (CAS #=877615-05-9, 2.9 g), Intermediate 3-1 (5.3 g), tetrakis(triphenylphosphine)palladium (0.30 g), and potassium carbonate (2.3 g) were added to a reaction container, and dissolved in 80 ml of toluene, 20 ml of ethanol and 20 ml of distilled water, followed by refluxing for about 24 hours. After finishing the reaction, the reaction solution was extracted with ethyl acetate, a collected organic layer was dried over magnesium sulfate, and the solvent was distilled to obtain a residue. The residue was separated by silica gel column chromatography to obtain 7.5 g of Compound 3 (yield: 67%). Compound 3 was identified by LC-MS (C₅₁H₃₁D₄N₅Si M+1: 749.29).

### (2) Synthesis of Nitrogen-Containing Compound 4

Nitrogen-containing Compound 4 according to one or more embodiments may be synthesized by, for example, the steps of Reaction 2 below.

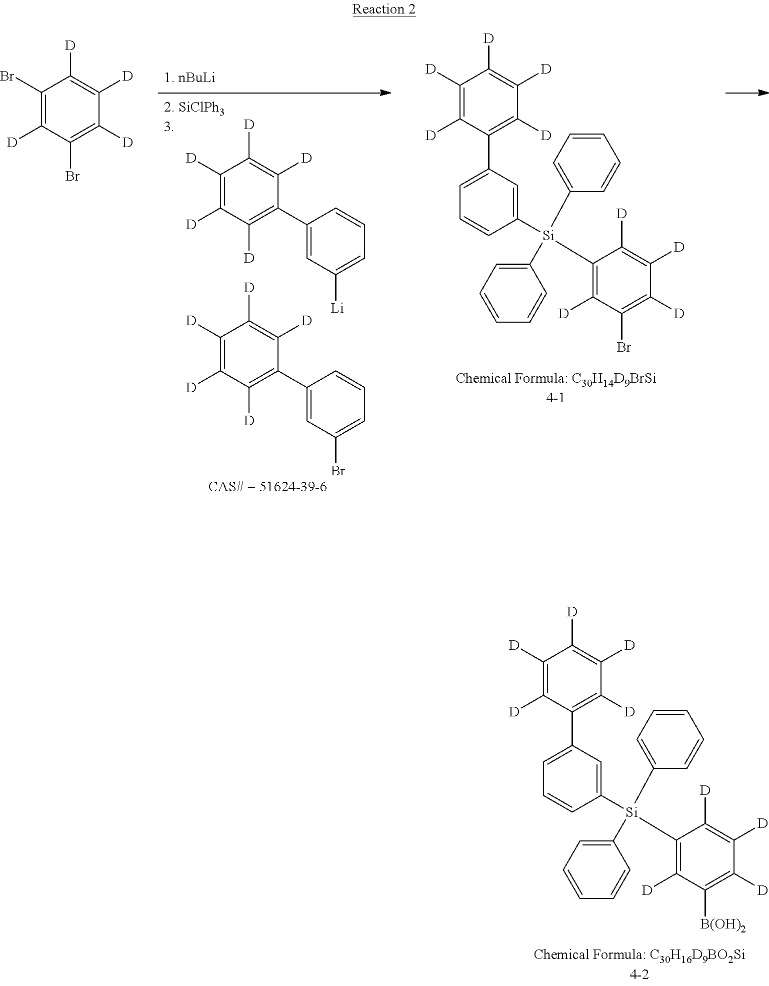

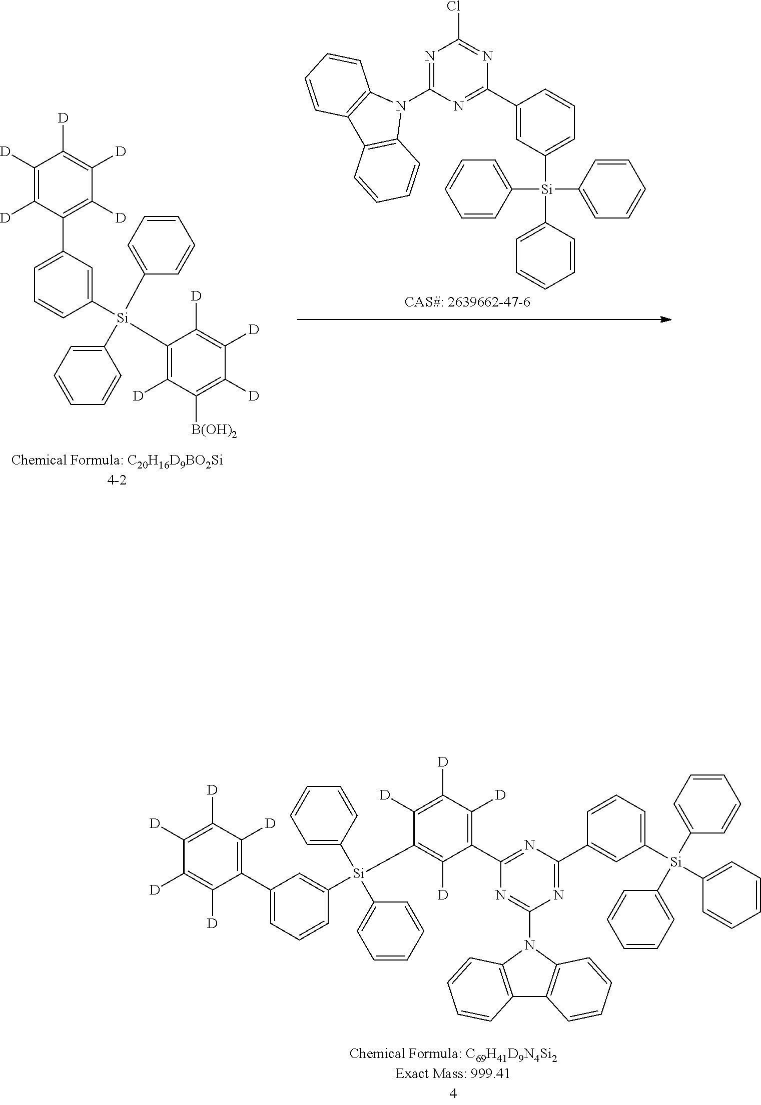 [SMILES: [2H]c1c([2H])c([2H])c(-c2cccc([Si](c3ccccc3)(c3ccccc3)c3c([2H])c([2H])c([2H])c(B(O)O)c3[2H])c2)c([2H])c1[2H] ; Clc1nc(-c2cccc([Si](c3ccccc3)(c3ccccc3)c3ccccc3)c2)nc(-n2c3ccccc3c3ccccc32)n1 ; [2H]c1c([2H])c([2H])c(-c2cccc([Si](c3ccccc3)(c3ccccc3)c3c([2H])c([2H])c([2H])c(-c4nc(-c5cccc([Si](c6ccccc6)(c6ccccc6)c6ccccc6)c5)nc(-n5c6ccccc6c6ccccc65)n4)c3[2H])c2)c([2H])c1[2H]]

### Synthesis of Intermediate 4-1

4,6-Dibromobenzene-1,2,3,5-d4 (CAS #=1616983-07-3, 1 eq) was reacted with nBuLi (1 eq) under conditions of about −78° C., and after about 60 minutes, dichlorodiphenylsilane (SiCl₂Ph₂, 1 eq) was slowly added dropwisely thereto. Then, after about 60 minutes, ([1,1′-biphenyl]-3-yl-2′,3′,4′,5′,6′-d5)lithium obtained by the reaction of 3-bromo-1,1′-biphenyl-2′,3′,4′,5′,6′-d5 (CAS #=51624-39-6, 1 eq) and nBuLi (1 eq) under conditions of about −78° C. was slowly added dropwisely. The reaction solution was slowly heated to room temperature and reacted overnight to obtain Intermediate 4-1. Intermediate 4-1 was identified by LC-MS (C₃₀H₁₄D₉BrSi M+1: 501.1).

### Synthesis of Intermediate 4-2

Intermediate 4-1 was reacted with nBuLi under conditions of about −78° C., and after about 60 minutes, trimethylborate was slowly added dropwisely thereto. Then, the reaction solution was slowly heated to room temperature and reacted overnight to obtain Intermediate 4-2. Intermediate 4-2 was identified by LC-MS (C₃₀H₁₆D₉BO₂Si M+1: 465.23).

### Synthesis of Compound 4

9H-Carbazole, 9-[4-chloro-6-[3-(triphenylsilyl)phenyl]-1,3,5-triazin-2-yl](CAS #=2639662-47-6, 3.4 g), Intermediate 4-2 (7.4 g), tetrakis(triphenylphosphine)palladium (0.35 g), and potassium carbonate (2.6 g) were added to a reaction container, and dissolved in 40 ml of toluene, 10 ml of ethanol and 10 ml of distilled water, followed by refluxing for about 24 hours. After finishing the reaction, the reaction solution was extracted with ethyl acetate, a collected organic layer was dried over magnesium sulfate, and the solvent was distilled to obtain a residue. The residue thus obtained was separated by silica gel column chromatography to obtain 4.2 g of Compound 4 (yield: 53%). Compound 4 was identified by LC-MS (C₆₉H₄₁D₉N₄Si₂ M+1: 999.41).

### (3) Synthesis of Nitrogen-Containing Compound 8

Nitrogen-containing Compound 8 according to one or more embodiments may be synthesized by, for example, the steps of Reaction 3 below.

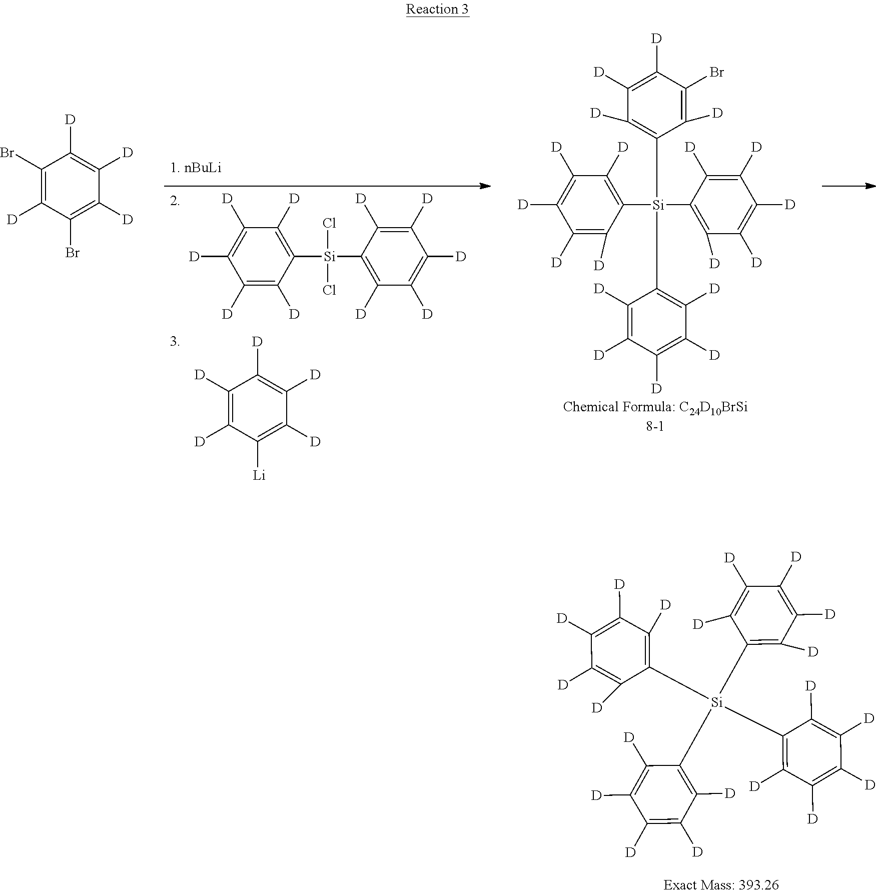

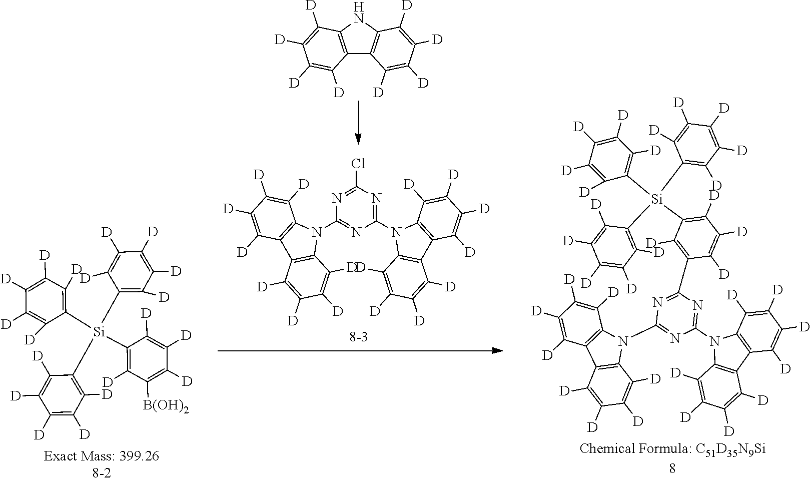

### Synthesis of Intermediate 8-1

4,6-Dibromobenzene-1,2,3,5-d4 (CAS #=1616983-07-3, 1 eq) was reacted with nBuLi (1 eq) under conditions of about −78° C., and after about 60 minutes, dichlorobis(phenyl-d5)silane (CAS #=59620-14-3, 1 eq) was slowly added dropwisely thereto. Then, after about 60 minutes, (phenyl-d5)lithium was slowly added dropwisely. The reaction solution was slowly heated to room temperature and reacted overnight to obtain Intermediate 8-1. Intermediate 8-1 was identified by LC-MS (C₂₄D₁₉BrSi M+1: 435.1).

### Synthesis of Intermediate 8-2

Intermediate 8-1 was reacted with nBuLi under conditions of about −78° C., and after about 60 minutes, trimethylborate was slowly added dropwisely. Then, the reaction solution was slowly heated to room temperature and reacted overnight to obtain Intermediate 8-2. Intermediate 8-2 was identified by LC-MS (C₂₄H₂D₁₉BO₂Si₂ M+1: 400.26).

### Synthesis of Intermediate 8-3

9H-carbazole-1,2,3,4,5,6,7,8-d8 (CAS #=38537-24-5, 2 eq) was reacted with nBuLi (2 eq) at room temperature. After about 15 minutes, cyanuric chloride (1 eq) was slowly added dropwisely and reacted at about 70° C. overnight to obtain Intermediate 8-3. Intermediate 8-3 was identified by LC-MS (C₂₇D₁₆ClN₅ M+1: 462.1).

### Synthesis of Compound 8

Intermediate 8-3 (2.9 g), Intermediate 8-2 (5.1 g), tetrakis(triphenylphosphine)palladium (0.29 g), and potassium carbonate (2.2 g) were added to a reaction container, and dissolved in 40 ml of toluene, 10 ml of ethanol and 10 ml of distilled water, followed by refluxing for about 24 hours. After finishing the reaction, the reaction solution was extracted with ethyl acetate, and organic layers were collected. The collected organic layer was dried over magnesium sulfate, and the solvent was distilled to obtain a residue. The residue thus obtained was separated by silica gel column chromatography to obtain 3.9 g of Compound 8 (yield: 59%). Compound 8 was identified by LC-MS (C₅₁D₃₅N₅Si M+1: 780.49).

### (4) Synthesis of Nitrogen-Containing Compound 18

Nitrogen-containing Compound 18 according to one or more embodiments may be synthesized by, for example, the steps of Reaction 4 below.

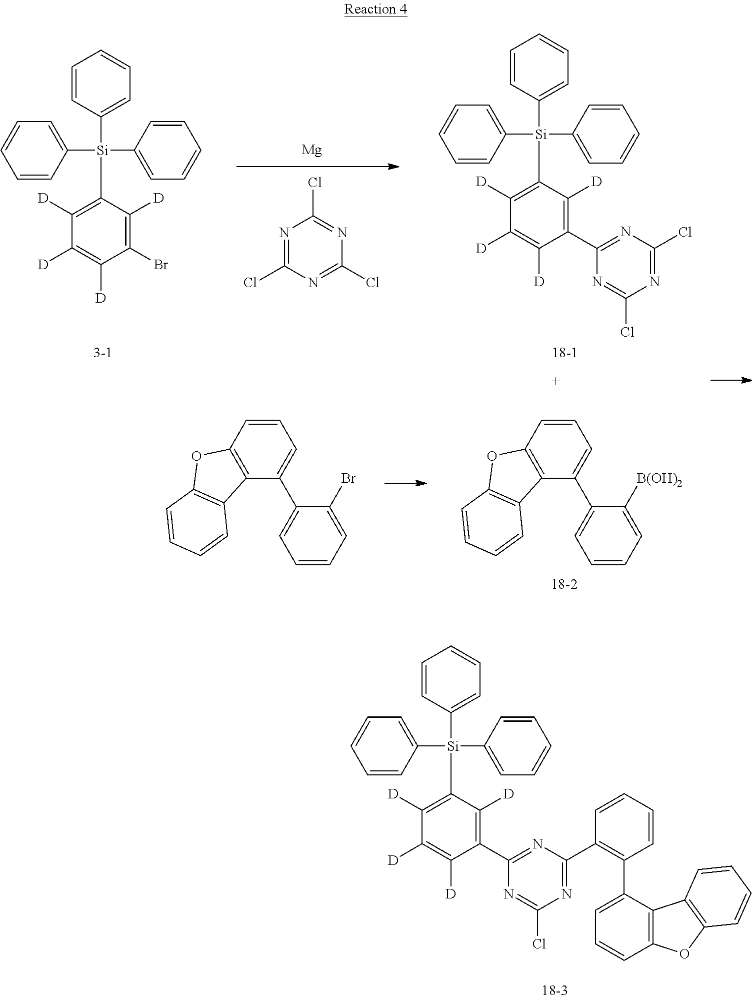

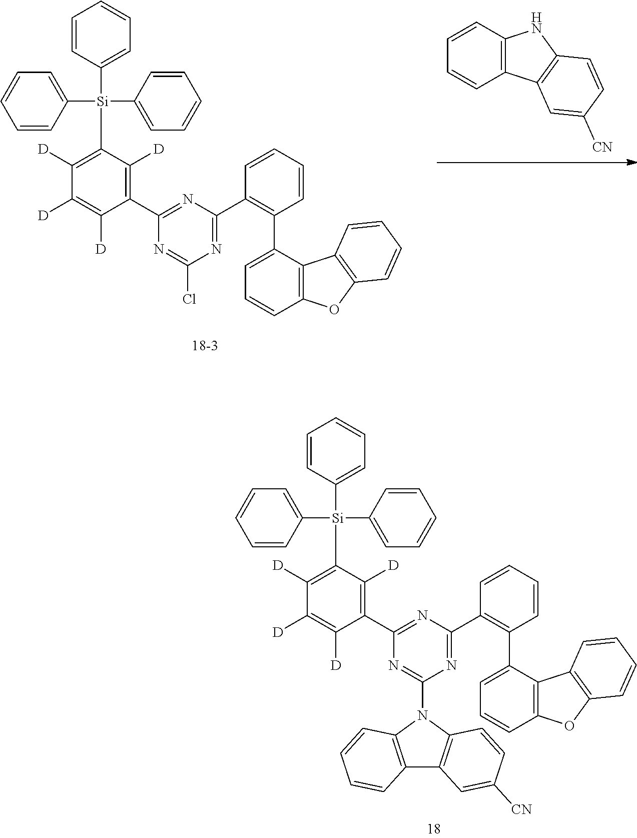 [SMILES: [2H]c1c([2H])c(-c2nc(Cl)nc(-c3ccccc3-c3cccc4oc5ccccc5c34)n2)c([2H])c([Si](c2ccccc2)(c2ccccc2)c2ccccc2)c1[2H] ; N#Cc1ccc2[nH]c3ccccc3c2c1 ; [2H]c1c([2H])c(-c2nc(-c3ccccc3-c3cccc4oc5ccccc5c34)nc(-n3c4ccccc4c4cc(C#N)ccc43)n2)c([2H])c([Si](c2ccccc2)(c2ccccc2)c2ccccc2)c1[2H]]

### Synthesis of Intermediate 18-1

Intermediate 3-1 (1 eq) was reacted with magnesium (1 eq) at about 0° C., and then reacted with cyanuric chloride (1 eq) to obtain Intermediate 18-1. Intermediate 18-1 was identified by LC-MS (C₂₇H₁₅D₄Cl₂N₃Si: M+1 487.10).

### Synthesis of Intermediate 18-2

1-(2-Bromophenyl)dibenzo[b,d]furan (CAS #=1659313-53-7) (1 eq.) was reacted with nBuLi (1.2 eq) at about −78° C., and then reacted with trimethylborate (1.4 eq) to obtain Intermediate 18-2. Intermediate 18-2 was identified by LC-MS (C₁₈H₁₃BO₃: M+1 289.12).

### Synthesis of Intermediate 18-3

Suzuki coupling of Intermediate 18-1 (1 eq) and Intermediate 18-2 (1.2 eq) was performed at about 120° C. under conditions of Pd(PPh₃)₄ (0.05 eq) to obtain Intermediate 18-3. Intermediate 18-3 was identified by LC-MS (C₄₅H₂₆D₄ClN₃OSi: M+1 695.21).

### Synthesis of Compound 18

Intermediate 18-3 (1.9 g), 9H-carbazol-3-carbonitrile (CAS #=57102-93-9, 0.53 g), potassium phosphate (1.2 g), and N,N-dimethylformamide (DMF, 20 ml) were added to a reaction container, and refluxed under about 160° C. conditions for about 24 hours. After finishing the reaction, the reaction solution was extracted with ethyl acetate, and organic layers were collected. The collected organic layer was dried over magnesium sulfate, and the solvent was distilled to obtain a residue. The residue thud obtained was separated by silica gel column chromatography to obtain 1.4 g of Compound 18 (yield: 59%). Compound 18 was identified by LC-MS (C₅₈H₃₃D₄N₅OSi M+1: 851.3).

### (5) Synthesis of Nitrogen-Containing Compound 22

Nitrogen-containing Compound 22 according to one or more embodiments may be synthesized by, for example, the steps of Reaction 5 below.

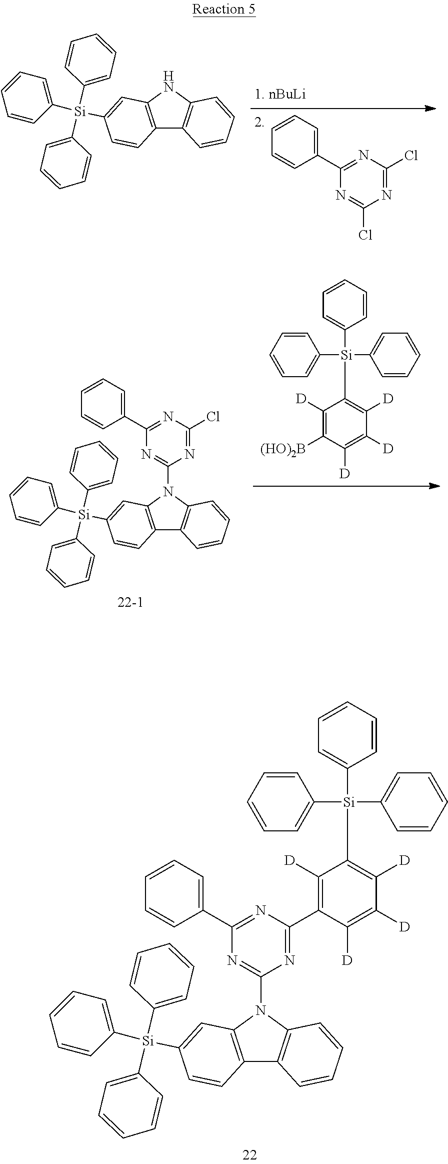 [SMILES: c1ccc([Si](c2ccccc2)(c2ccccc2)c2ccc3c(c2)[nH]c2ccccc23)cc1 ; Clc1nc(Cl)nc(-c2ccccc2)n1 ; Clc1nc(-c2ccccc2)nc(-n2c3ccccc3c3ccc([Si](c4ccccc4)(c4ccccc4)c4ccccc4)cc32)n1 ; [2H]c1c([2H])c(B(O)O)c([2H])c([Si](c2ccccc2)(c2ccccc2)c2ccccc2)c1[2H] ; [2H]c1c([2H])c(-c2nc(-c3ccccc3)nc(-n3c4ccccc4c4ccc([Si](c5ccccc5)(c5ccccc5)c5ccccc5)cc43)n2)c([2H])c([Si](c2ccccc2)(c2ccccc2)c2ccccc2)c1[2H]]

### Synthesis of Intermediate 22-1

2-(Triphenylsilyl)-9H-carbazole (CAS #=1262866-95-4, 1 eq) was reacted with nBuLi (1 eq) at about −78° C., and then reacted with 2,4-dichloro-6-phenyltriazine (CAS #=1700-02-3, 1 eq) to obtain Intermediate 22-1 (C₃₉H₂₇ClN₄Si M+1: 615.18).

### Synthesis of Compound 22

Intermediate 22-1 (2.3 g), (3-(triphenylsilyl)phenyl)boronic acid (CAS #=1253912-58-1, 1.71 g), tetrakis(triphenylphosphine)palladium (0.17 g), and potassium carbonate (1.3 g) were added to a reaction container, and dissolved in 40 ml of toluene, 10 ml of ethanol and 10 ml of distilled water, followed by refluxing for about 24 hours. After finishing the reaction, the reaction solution was extracted with ethyl acetate, an organic layer collected was dried over magnesium sulfate, and the solvent was distilled to obtain a residue. The residue thus obtained was separated by silica gel column chromatography to obtain 1.95 g of Compound 22 (yield: 57%). Compound 22 was identified by LC-MS (C₆₃H₄₂D₄N₄Si₂ M+1: 919.35).

### (6) Synthesis of Nitrogen-Containing Compound 116

Nitrogen-containing Compound 116 according to one or more embodiments may be synthesized by, for example, the steps of Reaction 6 below.

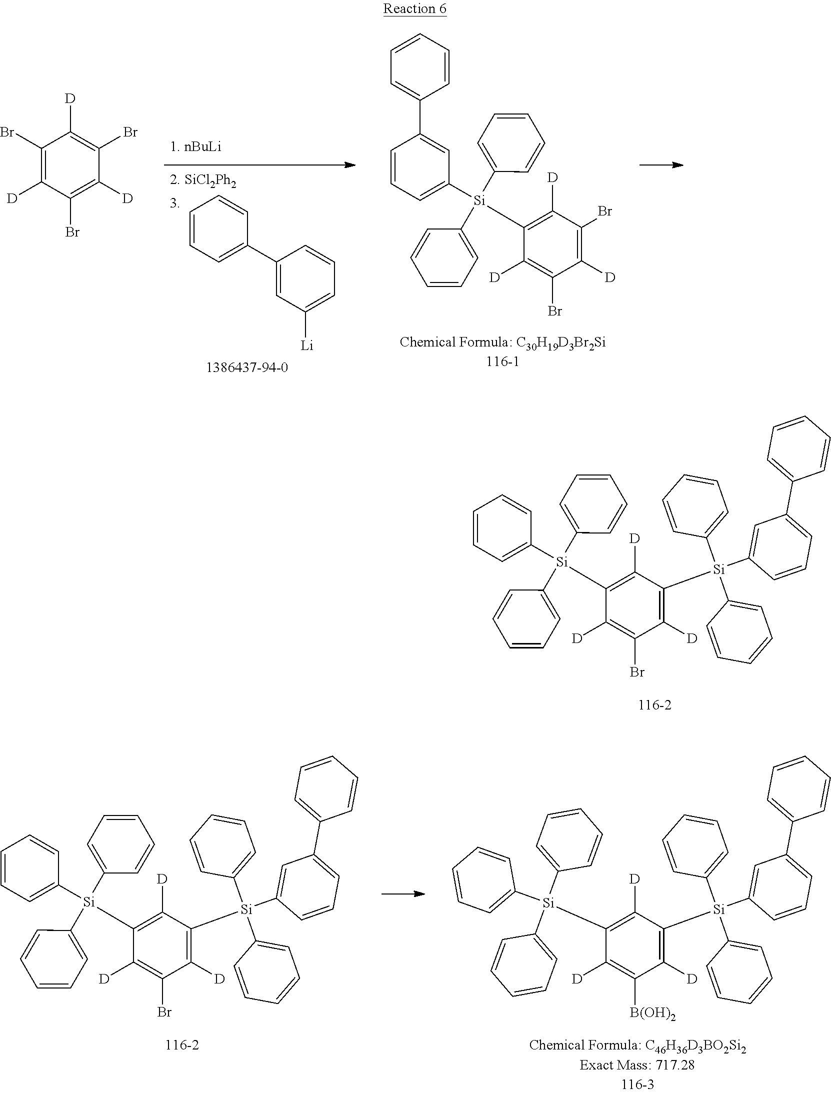

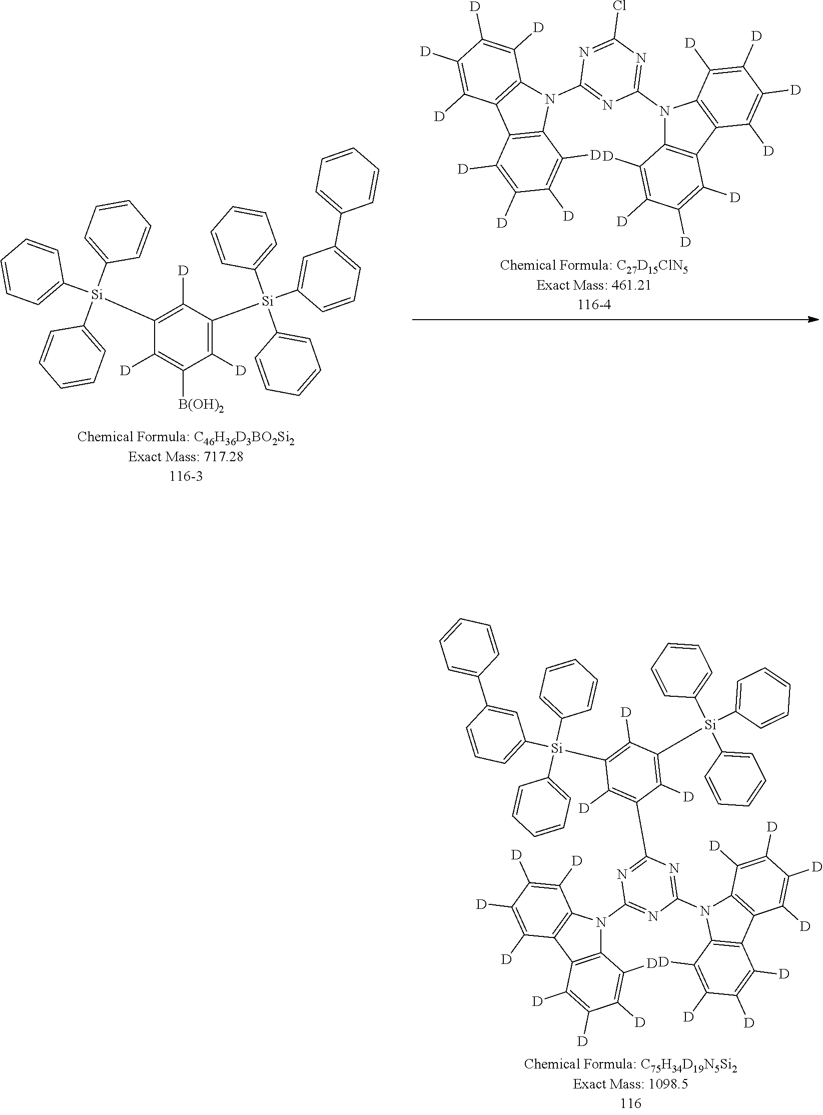

### Synthesis of Intermediate 116-1

1,3,5-Dibromobenzene-2,4,6-d3 (CAS #=52921-77-4, 1 eq) was reacted with nBuLi (2 eq) under conditions of about −78° C., and after about 60 minutes, dichlorodiphenylsilane (SiCl₂Ph₂, 1 eq) was slowly added dropwisely thereto. After about 60 minutes, [1,1′-biphenyl]-3-yllithium (CAS #=1386437-94-0, 2 eq) was slowly added dropwisely. The reaction solution was slowly heated to room temperature and reacted overnight to obtain Intermediate 116-1. Intermediate 116-1 was identified by LC-MS (C₃₀H₁₉D₃Br₂Si M+1: 573.0).

### Synthesis of Intermediate 116-2

Intermediate 116-1 was reacted with nBuLi (1 eq) under conditions of about −78° C., and after about 60 minutes, dichlorodiphenylsilane (1 eq) was slowly added dropwisely. After about 60 minutes, (phenyl)lithium was slowly added dropwisely. The reaction solution was slowly heated to room temperature and reacted overnight to obtain Intermediate 116-2. Intermediate 116-2 was identified by LC-MS (C₄₈H₃₄D₃BrSi₂ M+1: 753.2).

### Synthesis of Intermediate 116-3

Intermediate 116-2 was reacted with nBuLi under conditions of about −78° C., and after about 60 minutes, trimethylborate was slowly added dropwisely. The reaction solution was slowly heated to room temperature and reacted overnight to obtain Intermediate 116-3. Intermediate 116-3 was identified by LC-MS (C₄₈H₃₆D₃BO₂Si₂ M+1: 717.3).

### Synthesis of Compound 116

Intermediate 116-4 (4.8 g), Intermediate 116-3 (9.9 g), tetrakis(triphenylphosphine)palladium (0.48 g), and potassium carbonate (3.6 g) were added to a reaction container, and dissolved in 80 ml of toluene, 20 ml of ethanol and 20 ml of distilled water, followed by refluxing for about 24 hours. After finishing the reaction, the reaction solution was extracted with ethyl acetate, and organic layers were collected. The collected organic layer was dried over magnesium sulfate, and the solvent was distilled to obtain a residue. The residue thus obtained was separated by silica gel column chromatography to obtain 7.5 g of Compound 116 (yield: 61%). Compound 116 was identified by LC-MS (C₇₅H₃₄D₁₉N₅Si₂ M+1: 1198.5).

### (7) Synthesis of Nitrogen-Containing Compound 76

Nitrogen-containing Compound 76 according to one or more embodiments may be synthesized by, for example, the steps of Reaction 7 below.

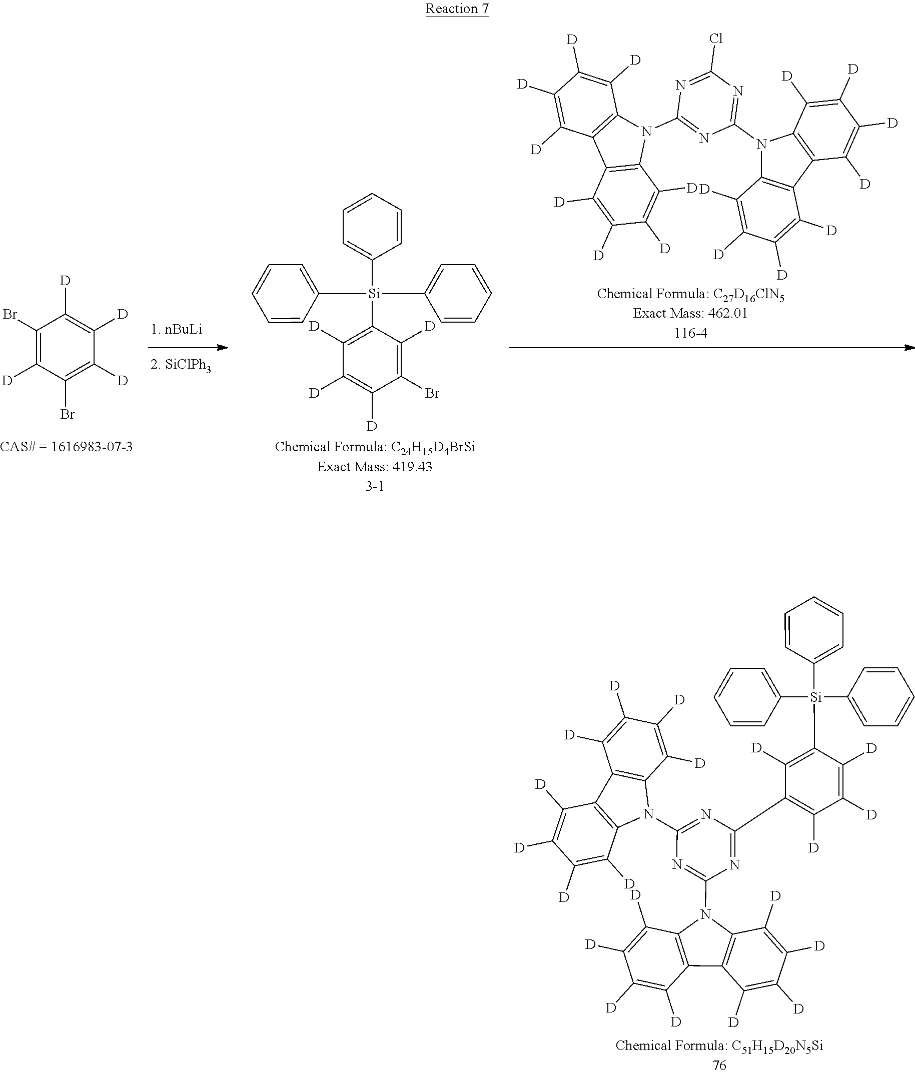 [SMILES: [2H]c1c([2H])c(Br)c([2H])c(Br)c1[2H] ; [2H]c1c([2H])c(Br)c([2H])c([Si](c2ccccc2)(c2ccccc2)c2ccccc2)c1[2H] ; [2H]c1c([2H])c([2H])c2c(c1[2H])c1c([2H])c([2H])c([2H])c([2H])c1n2-c1nc(Cl)nc(-n2c3c([2H])c([2H])c([2H])c([2H])c3c3c([2H])c([2H])c([2H])c([2H])c32)n1 ; [2H]c1c([2H])c(-c2nc(-n3c4c([2H])c([2H])c([2H])c([2H])c4c4c([2H])c([2H])c([2H])c([2H])c43)nc(-n3c4c([2H])c([2H])c([2H])c([2H])c4c4c([2H])c([2H])c([2H])c([2H])c43)n2)c([2H])c([Si](c2ccccc2)(c2ccccc2)c2ccccc2)c1[2H]]

### Synthesis of Compound 76

Intermediate 3-1 (6.72 g), Intermediate 116-4 (7.4 g), tetrakis(triphenylphosphine)palladium (0.45 g) and potassium carbonate (5.7 g) were added and dissolved in 80 ml of toluene, 20 ml of ethanol and 20 ml of distilled water, followed by refluxing for about 24 hours. After finishing the reaction, the reaction solution was extracted with ethyl acetate, and a collected organic layer was dried over magnesium sulfate. The solvent was distilled to obtain a residue. The residue thus obtained was separated by silica gel column chromatography to obtain 7.5 g of Compound 76 (yield: 61%). Compound 76 was identified by LC-MS (C₅₁H₁₅D20N₅Si M+1: 766.40).

### (8) Synthesis of Nitrogen-Containing Compound 101

Nitrogen-containing Compound 101 according to one or more embodiments may be synthesized by, for example, the steps of Reaction 8 below.

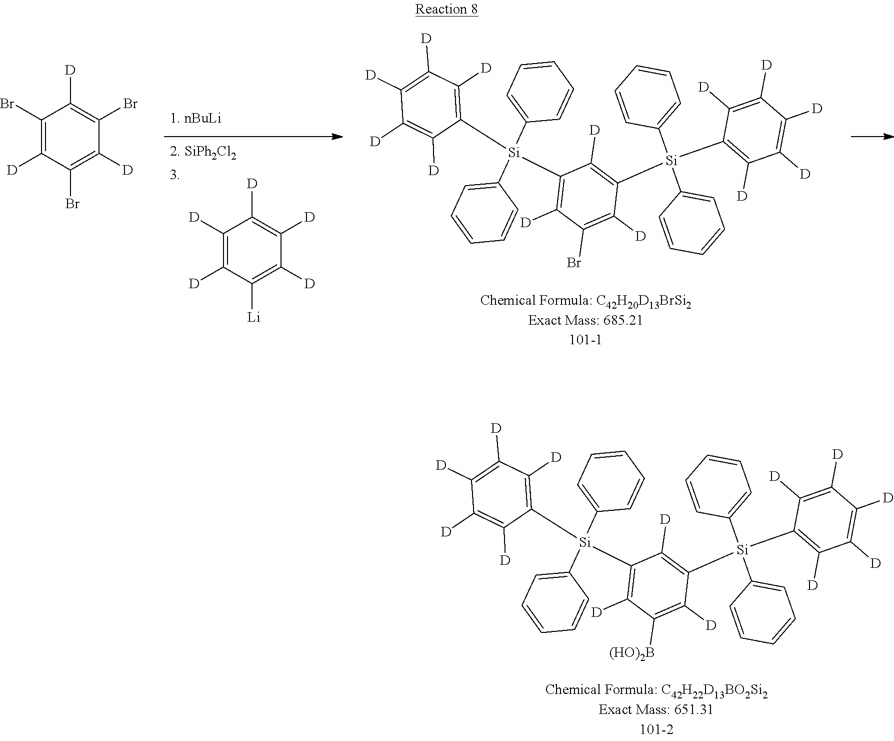

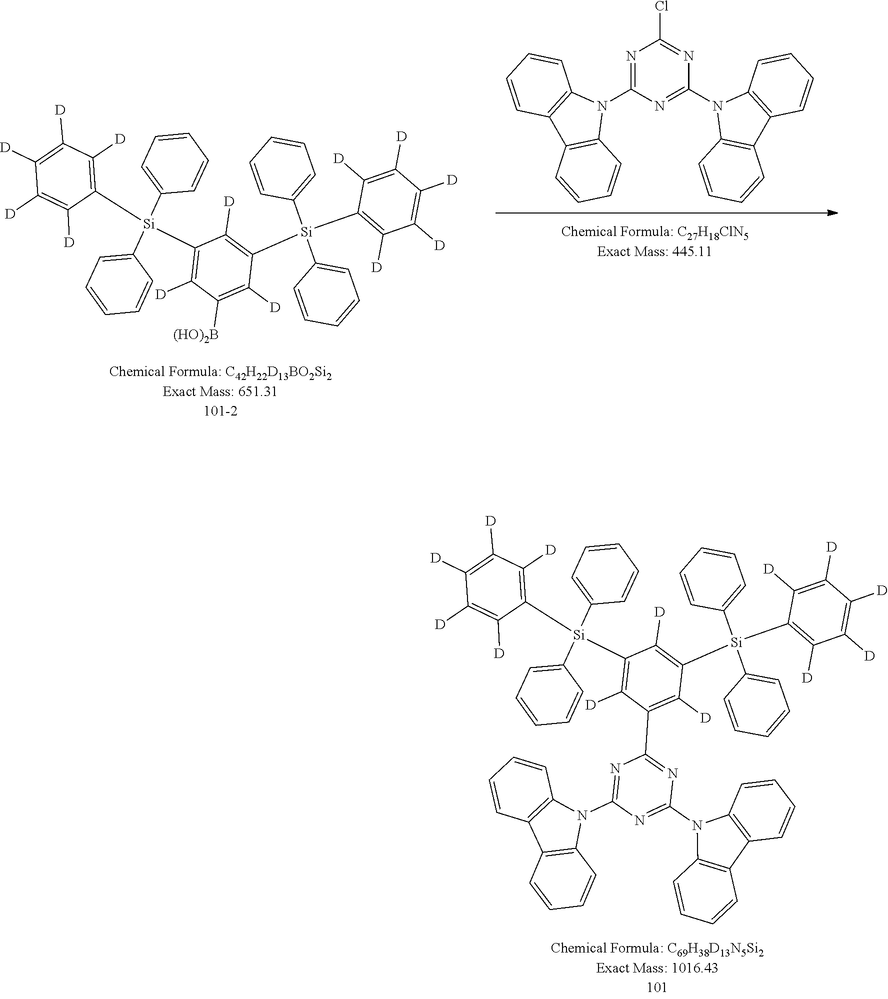 [SMILES: [2H]c1c([2H])c([2H])c([Si](c2ccccc2)(c2ccccc2)c2c([2H])c(B(O)O)c([2H])c([Si](c3ccccc3)(c3ccccc3)c3c([2H])c([2H])c([2H])c([2H])c3[2H])c2[2H])c([2H])c1[2H] ; Clc1nc(-n2c3ccccc3c3ccccc32)nc(-n2c3ccccc3c3ccccc32)n1 ; [2H]c1c([2H])c([2H])c([Si](c2ccccc2)(c2ccccc2)c2c([2H])c(-c3nc(-n4c5ccccc5c5ccccc54)nc(-n4c5ccccc5c5ccccc54)n3)c([2H])c([Si](c3ccccc3)(c3ccccc3)c3c([2H])c([2H])c([2H])c([2H])c3[2H])c2[2H])c([2H])c1[2H]]

### Synthesis of Intermediate 101-1

1,3,5-Dibromobenzene-2,4,6-d3 (CAS #=52921-77-4, 1 eq) was reacted with nBuLi (2 eq) under conditions of about −787C, and after about 60 minutes, dichlorodiphenylsilane was slowly added dropwisely thereto. After about 60 minutes, (phenyl-d5)lithium (CAS #=35088-79-0) was slowly added dropwisely to the reaction solution. The reaction solution was slowly heated to room temperature and reacted overnight to obtain Intermediate 101-1. Intermediate 101-1 was identified by LC-MS (C₄₂H₂₀D₁₃BrSi₂ M+1: 686.2).

### Synthesis of Intermediate 101-2

Intermediate 101-1 was reacted with nBuLi under conditions of about −78C, and after about 60 minutes, trimethylborate was slowly added dropwisely. The reaction solution was slowly heated to room temperature and reacted overnight to obtain Intermediate 101-2. Intermediate 101-2 was identified by LC-MS (C₄₂H₂₂D₁₃BO₂Si₂ M+1: 652.3).

### Synthesis of Compound 101

9,9′-(6-Chloro-1,3,5-triazine-2,4-diyl)bis(9H-carbazole) (CAS #=877615-05-9, 3.1 g), Intermediate 101-2 (5.4 g), tetrakis(triphenylphosphine)palladium (0.32 g), and potassium carbonate (2.4 g) were added to a reaction container, and dissolved in 40 ml of toluene, 10 ml of ethanol and 10 ml of distilled water, followed by refluxing for about 24 hours. After finishing the reaction, the reaction solution was extracted with ethyl acetate, and a collected organic layer was dried over magnesium sulfate. The solvent was distilled to obtain a residue. The residue thus obtained was separated by silica gel column chromatography to obtain 5.0 g of Compound 101 (yield: 71%). Compound 101 was identified by LC-MS (C₆₉H₃₆D₁₃N₅Si₂ M+1: 1017.4).

### 2. Manufacture and Evaluation of Light Emitting Elements

### (1) Manufacture of Light Emitting Elements

Light emitting elements including the nitrogen-containing compounds of embodiments or comparative compounds in an emission layer were manufactured by a method below. Light emitting elements of Example 1 to Example 9 were manufactured using the nitrogen-containing compounds of Compounds 3, 4, 8, 18, 22, 116, 59, 76 and 101, respectively as the host materials of an emission layer. The light emitting elements of Comparative Examples 1 to 6 were manufactured using Comparative Compounds CX1 to CX6, respectively, as the host materials of an emission layer.

An ITO substrate with a thickness of about 1200 Å was used as a first electrode. The ITO substrate was washed by ultrasonic waves using isopropyl alcohol and pure water for about 5 minutes each, and cleansed by irradiating ultraviolet rays for about 30 minutes and exposing to ozone. The ITO substrate thus cleansed was installed in a vacuum deposition apparatus.

On the ITO substrate cleansed and prepared, N,N′-di(1-naphthyl)-N,N′-diphenylbenzidine (NPB) was vacuum deposited to form a hole injection layer. The hole injection layer was formed into a thickness of about 300 Å. On the hole injection layer, mCP was vacuum deposited to form a hole transport layer. The hole transport layer was formed into a thickness of about 200 Å.

On the hole transport layer, an emission layer including the nitrogen-containing compound of one or more embodiments or the Comparative Compound was formed. A host and a dopant were co-deposited in a weight ratio of about 92:8 to form an emission layer with a thickness of about 250 Å. Ir(pmp)3 was used as the dopant.

On the emission layer, 3-(4-biphenylyl)-4-phenyl-5-tert-butylphenyl-1,2,4-triazole (TAZ) was deposited to a thickness of about 200 Å as an electron transport layer. On the electron transport layer, an alkali metal halide of LiF was deposited to a thickness of about 10 Å as an electron injection layer, and A₁ was vacuum deposited to a thickness of about 100 Å to form a second electrode.

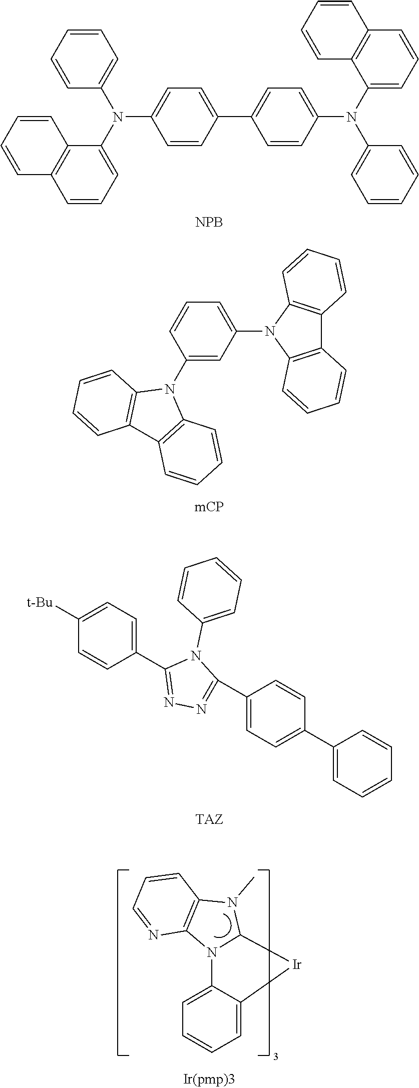

The Example Compounds and Comparative Compounds used in Examples 1 to 9 and Comparative Examples 1 to 6 are shown in Table 1.

TABLE 1

| | |
|---|---|
| Comparative Compound CX1 | 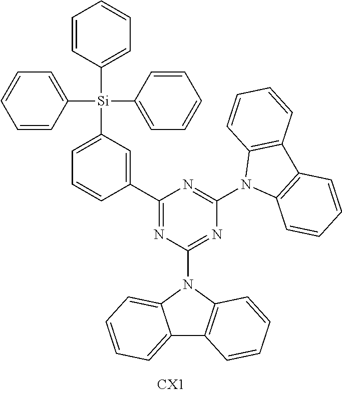 [SMILES: c1ccc([Si](c2ccccc2)(c2ccccc2)c2cccc(-c3nc(-n4c5ccccc5c5ccccc54)nc(-n4c5ccccc5c5ccccc54)n3)c2)cc1] |
| Comparative Compound CX2 | 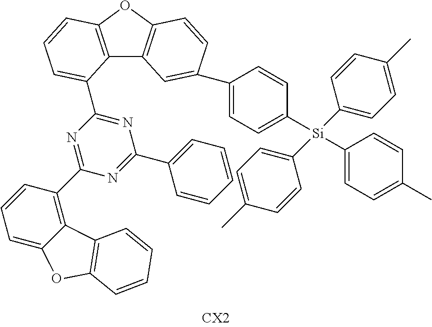 [SMILES: Cc1ccc([Si](c2ccc(C)cc2)(c2ccc(C)cc2)c2ccc(-c3ccc4oc5cccc(-c6nc(-c7ccccc7)nc(-c7cccc8oc9ccccc9c78)n6)c5c4c3)cc2)cc1] |
| Comparative Compound CX3 | 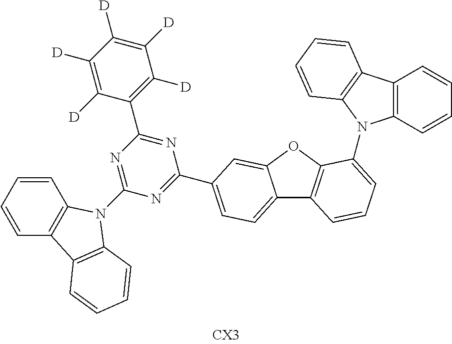 [SMILES: [2H]c1c([2H])c([2H])c(-c2nc(-c3ccc4c(c3)oc3c(-n5c6ccccc6c6ccccc65)cccc34)nc(-n3c4ccccc4c4ccccc43)n2)c([2H])c1[2H]] |
| Comparative Compound CX4 | 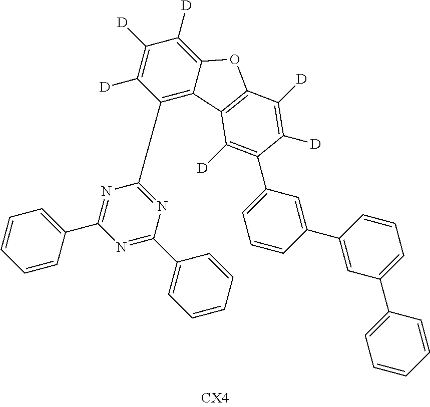 [SMILES: [2H]c1c(-c2cccc(-c3cccc(-c4ccccc4)c3)c2)c([2H])c2c(oc3c([2H])c([2H])c([2H])c(-c4nc(-c5ccccc5)nc(-c5ccccc5)n4)c32)c1[2H]] |
| Comparative Compound CX5 | 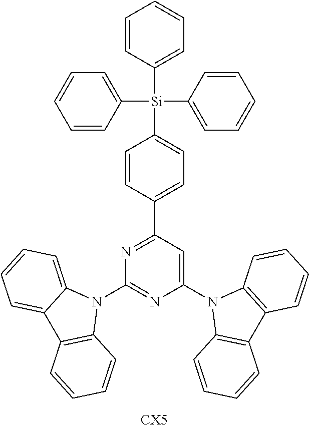 [SMILES: c1ccc([Si](c2ccccc2)(c2ccccc2)c2ccc(-c3cc(-n4c5ccccc5c5ccccc54)nc(-n4c5ccccc5c5ccccc54)n3)cc2)cc1] |
| Comparative Compound CX6 | 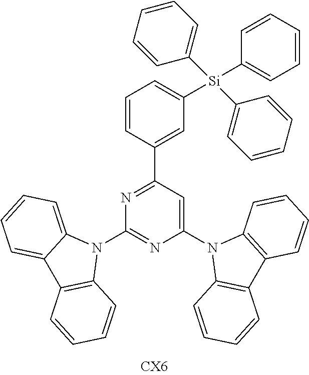 [SMILES: c1ccc([Si](c2ccccc2)(c2ccccc2)c2cccc(-c3cc(-n4c5ccccc5c5ccccc54)nc(-n4c5ccccc5c5ccccc54)n3)c2)cc1] |
| Compound 3 | 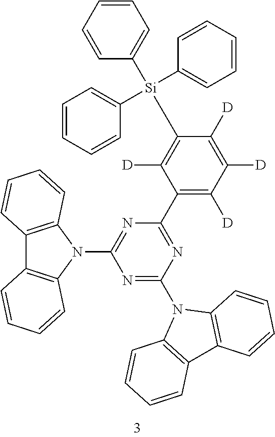 [SMILES: [2H]c1c([2H])c(-c2nc(-n3c4ccccc4c4ccccc43)nc(-n3c4ccccc4c4ccccc43)n2)c([2H])c([Si](c2ccccc2)(c2ccccc2)c2ccccc2)c1[2H]] |
| Compound 4 | 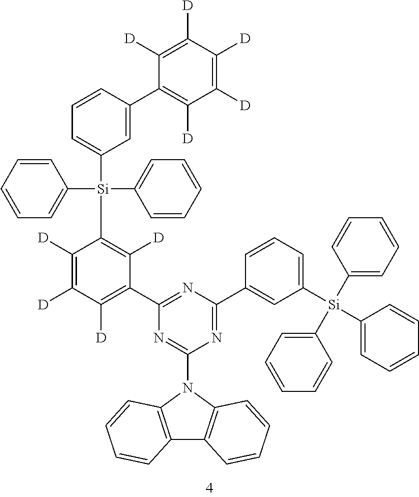 [SMILES: [2H]c1c([2H])c([2H])c(-c2cccc([Si](c3ccccc3)(c3ccccc3)c3c([2H])c([2H])c([2H])c(-c4nc(-c5cccc([Si](c6ccccc6)(c6ccccc6)c6ccccc6)c5)nc(-n5c6ccccc6c6ccccc65)n4)c3[2H])c2)c([2H])c1[2H]] |
| Compound 8 | 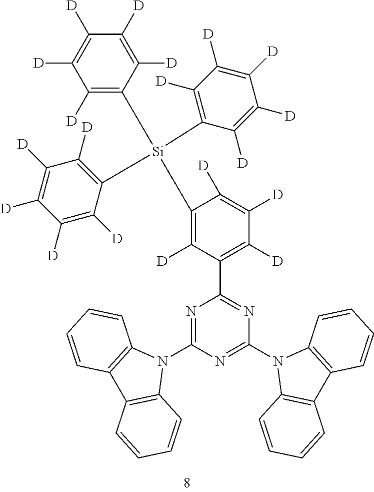 [SMILES: [2H]c1c([2H])c([2H])c([Si](c2c([2H])c([2H])c([2H])c([2H])c2[2H])(c2c([2H])c([2H])c([2H])c([2H])c2[2H])c2c([2H])c([2H])c([2H])c(-c3nc(-n4c5ccccc5c5ccccc54)nc(-n4c5ccccc5c5ccccc54)n3)c2[2H])c([2H])c1[2H]] |
| Compound 18 | 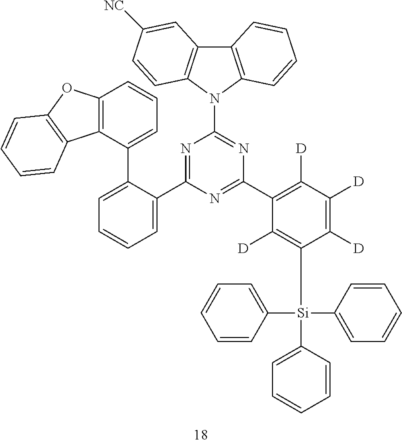 [SMILES: [2H]c1c([2H])c(-c2nc(-c3ccccc3-c3cccc4oc5ccccc5c34)nc(-n3c4ccccc4c4cc(C#N)ccc43)n2)c([2H])c([Si](c2ccccc2)(c2ccccc2)c2ccccc2)c1[2H]] |
| Compound 22 | 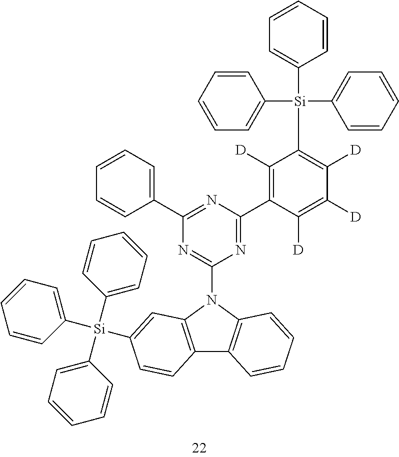 [SMILES: [2H]c1c([2H])c(-c2nc(-c3ccccc3)nc(-n3c4ccccc4c4ccc([Si](c5ccccc5)(c5ccccc5)c5ccccc5)cc43)n2)c([2H])c([Si](c2ccccc2)(c2ccccc2)c2ccccc2)c1[2H]] |
| Compound 116 | 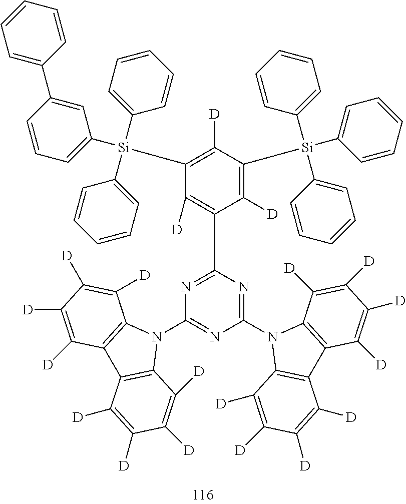 [SMILES: [2H]c1c(-c2nc(-n3c4c([2H])c([2H])c([2H])c([2H])c4c4c([2H])c([2H])c([2H])c([2H])c43)nc(-n3c4c([2H])c([2H])c([2H])c([2H])c4c4c([2H])c([2H])c([2H])c([2H])c43)n2)c([2H])c([Si](c2ccccc2)(c2ccccc2)c2cccc(-c3ccccc3)c2)c([2H])c1[Si](c1ccccc1)(c1ccccc1)c1ccccc1] |
| Compound 59 | 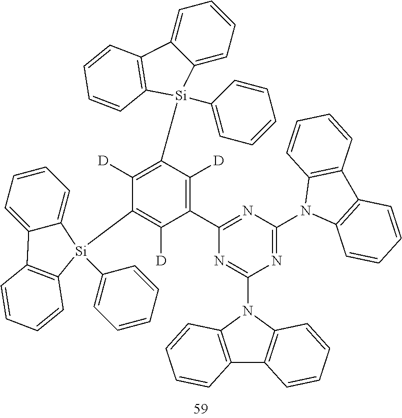 [SMILES: [2H]c1c(-c2nc(-n3c4ccccc4c4ccccc43)nc(-n3c4ccccc4c4ccccc43)n2)c([2H])c([Si]2(c3ccccc3)c3ccccc3-c3ccccc32)c([2H])c1[Si]1(c2ccccc2)c2ccccc2-c2ccccc21] |
| Compound 76 | 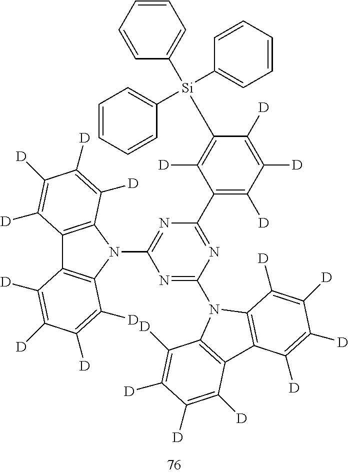 [SMILES: [2H]c1c([2H])c(-c2nc(-n3c4c([2H])c([2H])c([2H])c([2H])c4c4c([2H])c([2H])c([2H])c([2H])c43)nc(-n3c4c([2H])c([2H])c([2H])c([2H])c4c4c([2H])c([2H])c([2H])c([2H])c43)n2)c([2H])c([Si](c2ccccc2)(c2ccccc2)c2ccccc2)c1[2H]] |
| Compound 101 | 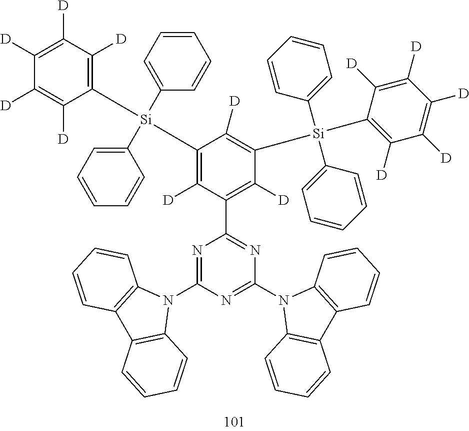 [SMILES: [2H]c1c([2H])c([2H])c([Si](c2ccccc2)(c2ccccc2)c2c([2H])c(-c3nc(-n4c5ccccc5c5ccccc54)nc(-n4c5ccccc5c5ccccc54)n3)c([2H])c([Si](c3ccccc3)(c3ccccc3)c3c([2H])c([2H])c([2H])c([2H])c3[2H])c2[2H])c([2H])c1[2H]] |
| — | — |

### (2) Evaluation of Properties of Light Emitting Elements

In Table 2, the driving voltage, maximum quantum efficiency, and lifetime (T95) of the light emitting elements of the Examples and Comparative Examples are evaluated and shown. The driving voltage and the maximum quantum efficiency were evaluated based on a current density of about 10 mA/cm². The driving voltage and current density were measured using a source meter (Keithley Instrument Co., 2400 series), and the maximum quantum efficiency was measured using an external quantum efficiency measurement apparatus of C9920-2-12 of Hamamatsu Photonics.

In the evaluation of the maximum quantum efficiency, luminance/current density was measured using a luminance meter of which wavelength sensitivity was calibrated, and converting to the maximum quantum efficiency supposing angular luminance distribution (Lambertian) assuming full diffusion reflective surface. The lifetime (T95) was obtained by measuring time consumed for reducing an initial luminance to 95% by using a luminance meter.

TABLE 2

| | | | Current | Maximum | Life- | |
|---|---|---|---|---|---|---|
| | | Driving | density | quantum | time | Emiss- |
| | | voltage | (mA/ | efficiency | (T95, | ion |
| Division | Host | (V) | cm²) | (%) | hr) | color |
| Example | Compound | 3.6 | 10 | 18.9 | 100 | Blue |
| 1 | 3 | | | | | |
| Example | Compound | 3.8 | 10 | 19.2 | 110 | Blue |
| 2 | 4 | | | | | |
| Example | Compound | 4.1 | 10 | 18.3 | 120 | Blue |
| 3 | 8 | | | | | |
| Example | Compound | 4.5 | 10 | 20.2 | 110 | Blue |
| 4 | 18 | | | | | |
| Example | Compound | 3.9 | 10 | 22.3 | 108 | Blue |
| 5 | 22 | | | | | |
| Example | Compound | 4.1 | 10 | 20.1 | 110 | Blue |
| 6 | 116 | | | | | |
| Example | Compound | 4.3 | 10 | 21.5 | 100 | Blue |
| 7 | 59 | | | | | |
| Example | Compound | 4.1 | 10 | 22.5 | 132 | Blue |
| 8 | 76 | | | | | |
| Example | Compound | 4.5 | 10 | 20.0 | 112 | Blue |
| 9 | 101 | | | | | |
| Comparative | Comparative | 4.1 | 10 | 20.0 | 82 | Blue |
| Example | Compound | | | | | |
| 1 | CX1 | | | | | |
| Comparative | Comparative | 5.1 | 10 | 17.0 | 22 | Blue |
| Example | Compound | | | | | |
| 2 | CX2 | | | | | |
| Comparative | Comparative | 4.1 | 10 | 19.0 | 46 | Blue |
| Example | Compound | | | | | |
| 3 | CX3 | | | | | |
| Comparative | Comparative | 5.2 | 10 | 9.2 | 8 | Blue |
| Example | Compound | | | | | |
| 4 | CX4 | | | | | |
| Comparative | Comparative | 4.9 | 10 | 12.4 | 62 | Blue |
| Example | Compound | | | | | |
| 5 | CX5 | | | | | |
| Comparative | Comparative | 4.8 | 10 | 20.2 | 88 | Blue |
| Example | Compound | | | | | |
| 6 | CX6 | | | | | |

Referring to Table 2, it could be found that the lifetime was long for the light emitting elements of Examples 1 to 9 when compared to the light emitting elements of Comparative Examples 1 to 6. The light emitting elements of Example 1 to 9 include Compounds 3, 4, 8, 18, 22, 116, 59, 76 and 101, and Compounds 3, 4, 8, 18, 22, 116, 59, 76 and 101 are nitrogen-containing compounds of the present embodiments. The nitrogen-containing compound of one or more embodiments may include at least one deuterium atom as a substituent. It is believed therefore, that the light emitting element including the nitrogen-containing compound of one or more embodiments may show long-life characteristics.

The light emitting element of Comparative Example 1 includes Comparative Compound CX1, and the light emitting element of Comparative Example 2 includes Comparative Compound CX2. Different from the nitrogen-containing compound of one or more embodiments, Comparative Compounds CX1 and CX2 do not include a deuterium atom. The light emitting element of Comparative Example 3 includes Comparative Compound CX3, and the light emitting element of Comparative Example 4 includes Comparative Compound CX4. Different from the nitrogen-containing compound of one or more embodiments, Comparative Compounds CX3 and CX4 do not include a silyl group. The light emitting element of Comparative Example 5 includes Comparative Compound CX5, and the light emitting element of Comparative Example 6 includes Comparative Compound CX6. Different from the nitrogen-containing compound of one or more embodiments, Comparative Compounds CX5 and CX6 do not include a deuterium atom. It is believed that the light emitting elements of Comparative Examples 1 to 6, which include compounds that do not have the deuterium substituent or the silyl group substituent, show relatively short lifetime.

The light emitting element of one or more embodiments may include a first electrode, a second electrode provided on the first electrode, and an emission layer provided between the first electrode and the second electrode. The emission layer may include the nitrogen-containing compound of one or more embodiments. The nitrogen-containing compound of one or more embodiments may include a hexagonal single ring including N as a ring-forming atom, as a core structure. To the hexagonal single ring, at least one deuterium atom may be directly or indirectly bonded. For example, the nitrogen-containing compound of one or more embodiments may include at least one deuterium atom as the substituent of the hexagonal single ring. The nitrogen-containing compound may also include at least one silyl group substituent. The light emitting element including the nitrogen-containing compound of one or more embodiments may show long-life characteristics.

The light emitting element of one or more embodiments includes the nitrogen-containing compound of one or more embodiments and may show long-life characteristics.

The nitrogen-containing compound of one or more embodiments may contribute to the increase of the lifetime of a light emitting element.

Although the embodiments of the present disclosure have been described, it is understood that the present disclosure should not be limited to these embodiments, but various changes and modifications can be made by one ordinary skilled in the art within the spirit and scope of the present disclosure as hereinafter claimed by the following claims and their equivalents.

What is claimed is:

1. A light emitting element, comprising:
a first electrode;
a second electrode provided on the first electrode; and
an emission layer provided between the first electrode and the second electrode, the emission layer comprising a first compound represented by Formula 1: 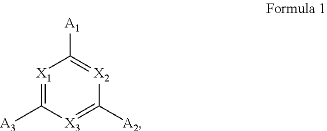
in Formula 1,
at least one among X₁ to X₃ is N, and remaining ones of X₁ to X₃ are CH,
A₁ to A₃ are each independently is a substituted or unsubstituted amine group, a substituted or unsubstituted aryl group of 6 to 60 ring-forming carbon atoms, or a substituted or unsubstituted heteroaryl group or 2 to 60 ring-forming carbon atoms, where at least one among A₁ to A₃ comprises a substituted or unsubstituted silyl group as a first substituent, and
at least one among hydrogen atoms in A₁ to A₃ and hydrogen atoms in X₁ to X₃, is substituted with a deuterium atom.

2. The light emitting element of claim 1, wherein,
in Formula 1, when at least one among the hydrogen atoms in A₁ to A₃ is substituted with a deuterium atom,
the at least one among A₁ to A₃ substituted with the deuterium atom comprises the first substituent, or
at least one among remaining ones of A₁ to A₃ not substituted with the deuterium atom comprises the first substituent.

3. The light emitting element of claim 1, wherein Formula 1 is represented by Formula 1-1A or Formula 1-1B: 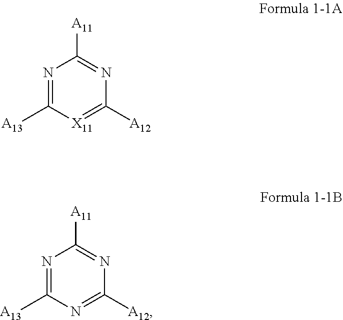
in Formula 1-1A and Formula 1-1B,
A₁₁ to A₁₃ are each independently a substituted or unsubstituted amine group, a substituted or unsubstituted aryl group of 6 to 60 ring-forming carbon atoms, or a substituted or unsubstituted heteroaryl group of 2 to 60 ring-forming carbon atoms, and
at least one among A₁₁ to A₁₃ comprises the first substituent,
in Formula 1-1A,
X₁₁ is CH or CD, and
when X₁₁ is CH, at least one among A₁₁ to A₁₃ comprises a deuterium atom as a substituent, and
in Formula 1-1B,
at least one among A₁₁ to A₁₃ comprises a deuterium atom as a substituent.

4. The light emitting element of claim 1, wherein, in Formula 1, A₁ to A₃ are each independently a substituted or unsubstituted aryl amine group, a substituted or unsubstituted phenyl group, a substituted or unsubstituted dibenzoazasiline group, a substituted or unsubstituted carbazole group, a substituted or unsubstituted dibenzofuran group, a substituted or unsubstituted dibenzothiophene group, a substituted or unsubstituted phenoxazine group, or a substituted or unsubstituted phenothiazine group, and
when any one among A₁ to A₃ is a substituted phenyl group, a substituted carbazole group, a substituted dibenzofuran group, or a substituted dibenzothiophene group, the any one among A₁ to A₃ comprises a deuterium atom and the first substituent.

5. The light emitting element of claim 1, wherein, in Formula 1, A₁ to A₃ are each independently represented by any one among Formula A-1 to Formula A-4: 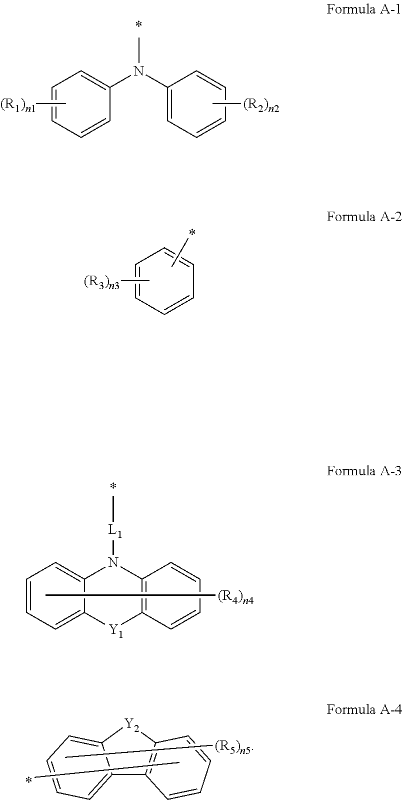
in Formula A-1 and Formula A-2,
n1 to n3 are each independently an integer of 0 to 5,
in Formula A-3,
L₁ is a direct linkage, or a substituted or unsubstituted arylene group of 6 to 60 ring-forming carbon atoms,
Y₁ is a direct linkage, SiR₆R₇, O, or S, and
n4 is an integer of 0 to 8,
in Formula A-4,
Y₂ is NR₈, O or S, and
n5 is an integer of 0 to 7,
in Formula A-1 to Formula A-4,
R₁ to R₈ are each independently a hydrogen atom, a deuterium atom, a cyano group, a substituted or unsubstituted silyl group, a substituted or unsubstituted alkyl group of 1 to 30 carbon atoms, a substituted or unsubstituted aryl group of 6 to 60 ring-forming carbon atoms, or a substituted or unsubstituted heteroaryl group of 2 to 60 ring-forming carbon atoms, and
when any one among A₁ to A₃ is represented by any one among Formula A-2 to Formula A-4, at least one among R₃ to R₈ comprises a deuterium atom.

6. The light emitting element of claim 5, wherein, in Formula A-2, R₃ is a deuterium atom, a substituted or unsubstituted silyl group, a substituted or unsubstituted cyclohexyl group, a substituted or unsubstituted phenyl group, a substituted or unsubstituted carbazole group, a substituted or unsubstituted dibenzofuran group, a substituted or unsubstituted dibenzo oxaborinine group, or a substituted or unsubstituted dibenzosilole group.

7. The light emitting element of claim 1, wherein Formula 1 is represented by any one among Formula 1-2A to Formula 1-2C: 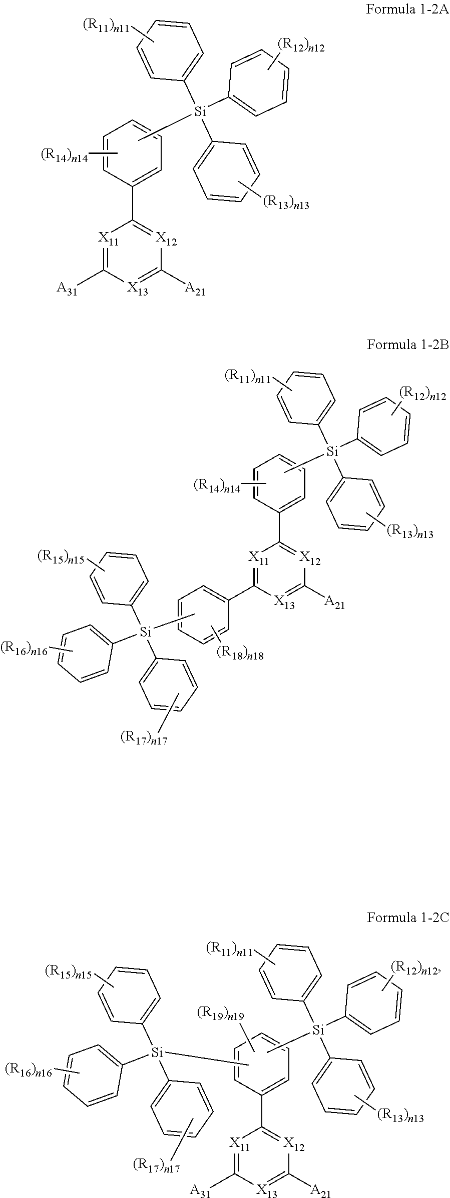
in Formula 1-2A to Formula 1-2C,
n11 to n13, and n15 to n17 are each independently an integer of 0 to 5,
n14 and n18 are each independently an integer of 0 to 4,
n19 is an integer of 0 to 3,
R₁₁ to R₁₈ are each independently a hydrogen atom, a deuterium atom, a cyano group, a substituted or unsubstituted silyl group, a substituted or unsubstituted alkyl group of 1 to 30 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring,
at least one among X₁₁ to X₁₃ is N, and remaining ones of X₁₁ to X₁₃ are CH,
A₂₁ and A₃₁ are each independently a substituted or unsubstituted aryl group of 6 to 60 ring-forming carbon atoms, or a substituted or unsubstituted heteroaryl group of 2 to 60 ring-forming carbon atoms, and
at least one among hydrogen atoms in A₂₁, hydrogen atoms in A₃₁, hydrogen atoms in X₁₁ to X₁₃, and hydrogen atoms in R₁₁ to R₁₈, is substituted with a deuterium atom.

8. The light emitting element of claim 7, wherein Formula 1-2A is represented by Formula 1-2AA or Formula 1-2AB: 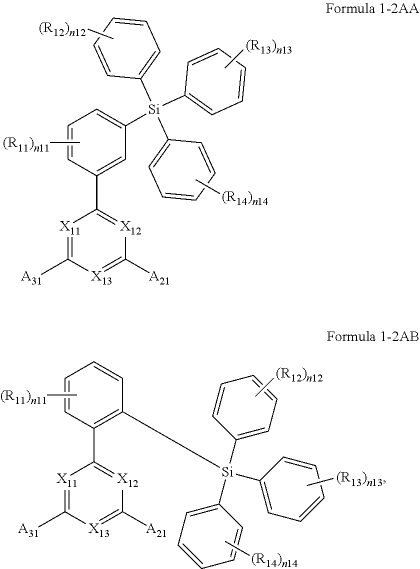
in Formula 1-2AA and Formula 1-2AB,
n11 to n14, R₁₁ to R₁₄, A₂₁, A₃₁, and X₁₁ to X₁₃ are the same as defined in Formula 1-2A.

9. The light emitting element of claim 7, wherein Formula 1-2A is represented by Formula 1-2AC: 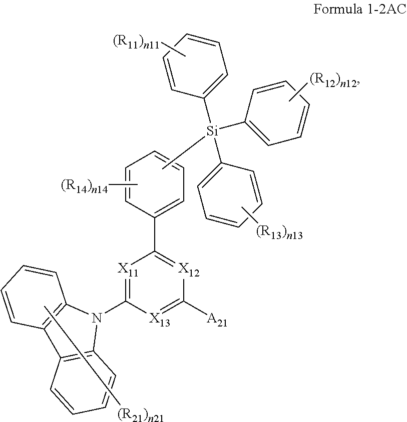
in Formula 1-2AC,
n21 is an integer of 0 to 8,
R₂₁ is a hydrogen atom, a deuterium atom, a cyano group, a substituted or unsubstituted silyl group, a substituted or unsubstituted alkyl group of 1 to 10 carbon atoms, a substituted or unsubstituted aryl group of 6 to 30 ring-forming carbon atoms, or a substituted or unsubstituted heteroaryl group of 2 to 30 ring-forming carbon atoms,
at least one among hydrogen atoms in A₂₁, hydrogen atoms in X₁₁ to X₁₃, hydrogen atoms in R₁₁ to R₁₄, and hydrogen atoms in R₂₁, is substituted with a deuterium atom, and
n11 to n14, R₁₁ to R₁₄, A₂₁, and X₁₁ to X₁₃ are the same as defined in Formula 1-2A.

10. The light emitting element of claim 1, wherein, in Formula 1, one or two among A₁ to A₃ comprise triphenylsilyl groups substituted with deuterium atoms, and at least one among remaining ones of A₁ to A₃ comprises a carbazole group substituted with a deuterium atom.

11. The light emitting element of claim 1, wherein the emission layer comprises a host and a dopant, and
the host comprises the first compound.

12. The light emitting element of claim 1, wherein the emission layer further comprises a second compound represented by Formula HT-1: 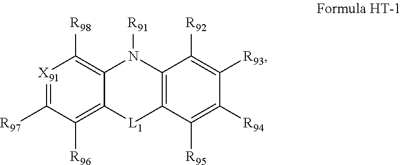
in Formula HT-1,
L₁ is a direct linkage, CR₉₉R₁₀₀, or SiR₁₀₁R₁₀₂,
X₉₁ is N or CR₁₀₃, and
R₉₁ to R₁₀₃ are each independently a hydrogen atom, a deuterium atom, a cyano group, a substituted or unsubstituted silyl group, a substituted or unsubstituted oxy group, a substituted or unsubstituted alkyl group having 1 to 60 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring.

13. The light emitting element of claim 1, wherein the emission layer further comprises a third compound represented by Formula M-a: 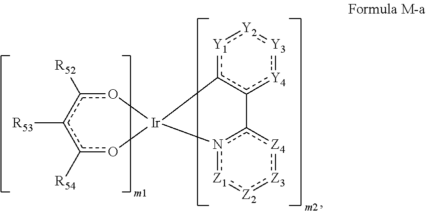
in Formula M-a,
Y₁ to Y₄, and Z₁ to Z₄ are each independently CR₅₁ or N,
R₅₁ to R₅₄ are each independently a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring,
m1 is 0 or 1, m2 is 2 or 3,
when m1 is 0, m2 is 3, and
when m1 is 1, m2 is 2.

14. The light emitting element of claim 1, wherein the first compound is represented by any one among compounds in Compound Group 1: 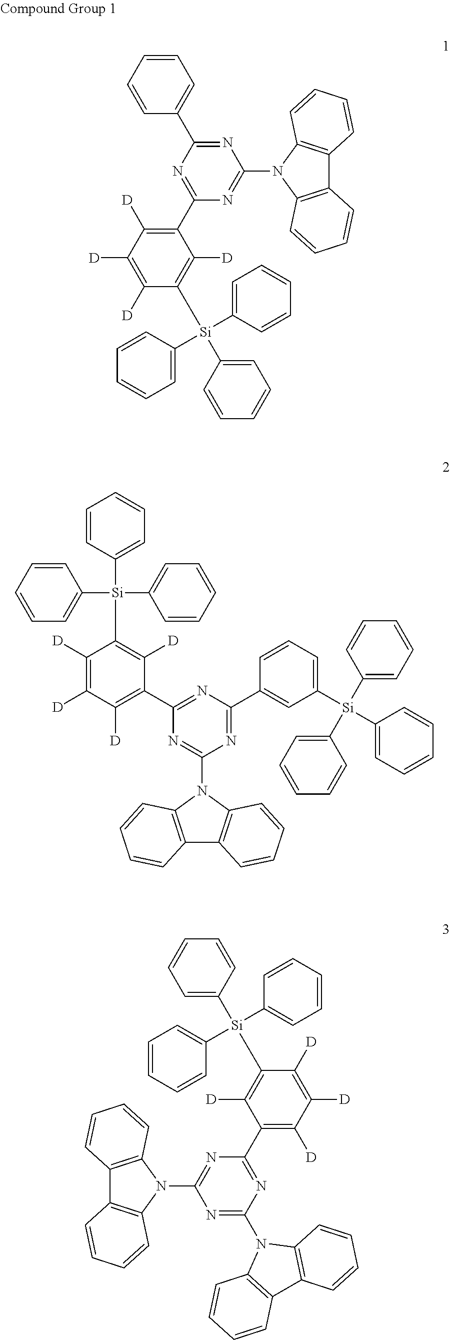 [SMILES: [2H]c1c([2H])c(-c2nc(-c3ccccc3)nc(-n3c4ccccc4c4ccccc43)n2)c([2H])c([Si](c2ccccc2)(c2ccccc2)c2ccccc2)c1[2H] ; [2H]c1c([2H])c(-c2nc(-c3cccc([Si](c4ccccc4)(c4ccccc4)c4ccccc4)c3)nc(-n3c4ccccc4c4ccccc43)n2)c([2H])c([Si](c2ccccc2)(c2ccccc2)c2ccccc2)c1[2H] ; [2H]c1c([2H])c(-c2nc(-n3c4ccccc4c4ccccc43)nc(-n3c4ccccc4c4ccccc43)n2)c([2H])c([Si](c2ccccc2)(c2ccccc2)c2ccccc2)c1[2H]] 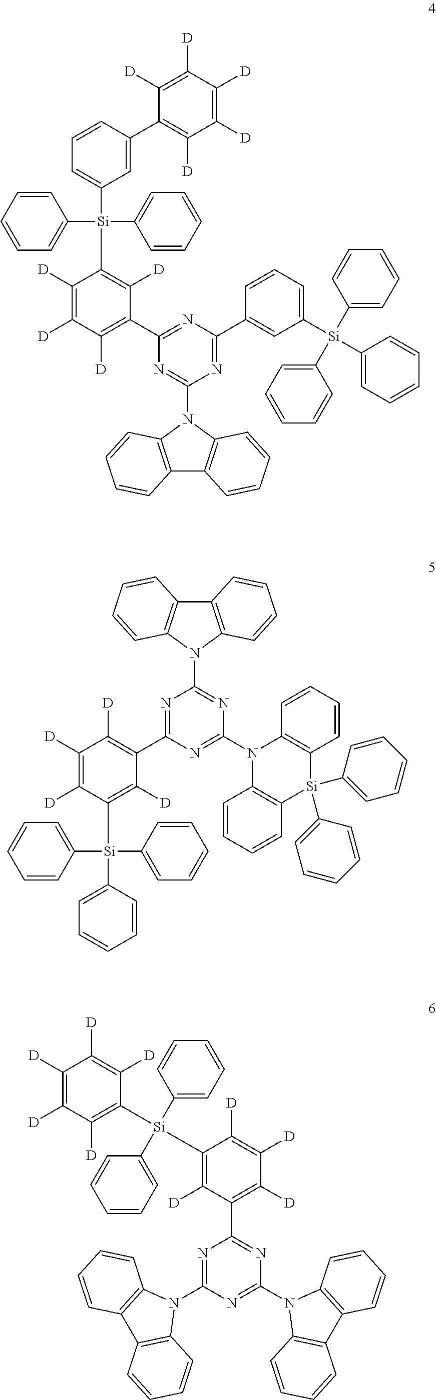 [SMILES: [2H]c1c([2H])c([2H])c(-c2cccc([Si](c3ccccc3)(c3ccccc3)c3c([2H])c([2H])c([2H])c(-c4nc(-c5cccc([Si](c6ccccc6)(c6ccccc6)c6ccccc6)c5)nc(-n5c6ccccc6c6ccccc65)n4)c3[2H])c2)c([2H])c1[2H] ; [2H]c1c([2H])c(-c2nc(N3c4ccccc4[Si](c4ccccc4)(c4ccccc4)c4ccccc43)nc(-n3c4ccccc4c4ccccc43)n2)c([2H])c([Si](c2ccccc2)(c2ccccc2)c2ccccc2)c1[2H] ; [2H]c1c([2H])c([2H])c([Si](c2ccccc2)(c2ccccc2)c2c([2H])c([2H])c([2H])c(-c3nc(-n4c5ccccc5c5ccccc54)nc(-n4c5ccccc5c5ccccc54)n3)c2[2H])c([2H])c1[2H]] 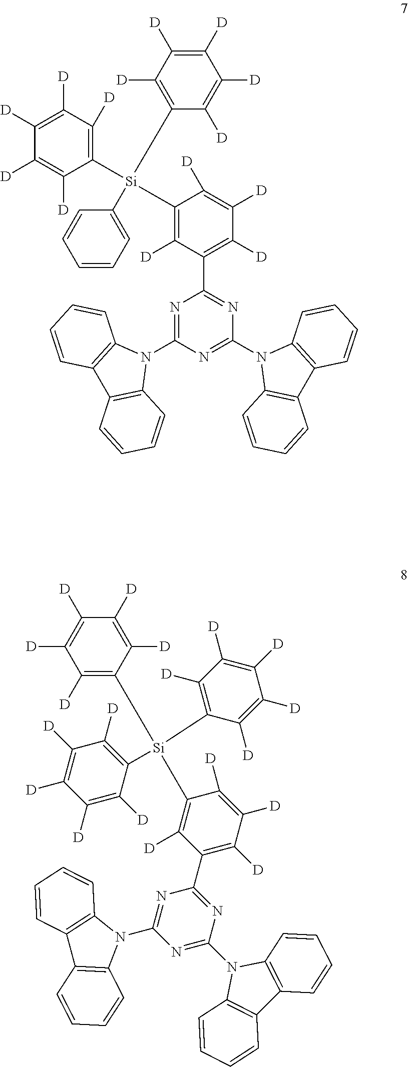 [SMILES: [2H]c1c([2H])c([2H])c([Si](c2ccccc2)(c2c([2H])c([2H])c([2H])c([2H])c2[2H])c2c([2H])c([2H])c([2H])c(-c3nc(-n4c5ccccc5c5ccccc54)nc(-n4c5ccccc5c5ccccc54)n3)c2[2H])c([2H])c1[2H] ; [2H]c1c([2H])c([2H])c([Si](c2c([2H])c([2H])c([2H])c([2H])c2[2H])(c2c([2H])c([2H])c([2H])c([2H])c2[2H])c2c([2H])c([2H])c([2H])c(-c3nc(-n4c5ccccc5c5ccccc54)nc(-n4c5ccccc5c5ccccc54)n3)c2[2H])c([2H])c1[2H]] 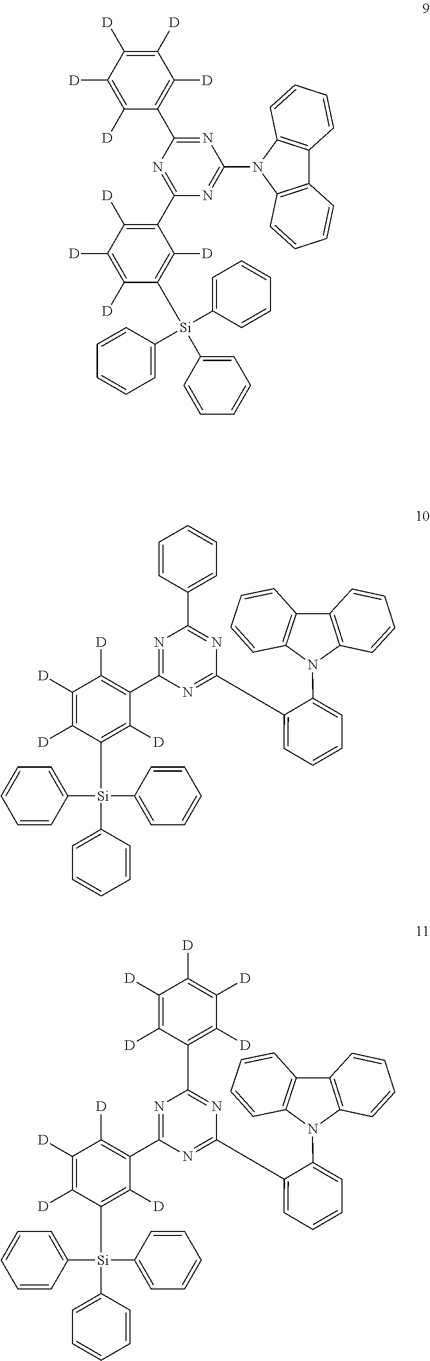 [SMILES: [2H]c1c([2H])c([2H])c(-c2nc(-c3c([2H])c([2H])c([2H])c([Si](c4ccccc4)(c4ccccc4)c4ccccc4)c3[2H])nc(-n3c4ccccc4c4ccccc43)n2)c([2H])c1[2H] ; [2H]c1c([2H])c(-c2nc(-c3ccccc3)nc(-c3ccccc3-n3c4ccccc4c4ccccc43)n2)c([2H])c([Si](c2ccccc2)(c2ccccc2)c2ccccc2)c1[2H] ; [2H]c1c([2H])c([2H])c(-c2nc(-c3ccccc3-n3c4ccccc4c4ccccc43)nc(-c3c([2H])c([2H])c([2H])c([Si](c4ccccc4)(c4ccccc4)c4ccccc4)c3[2H])n2)c([2H])c1[2H]] 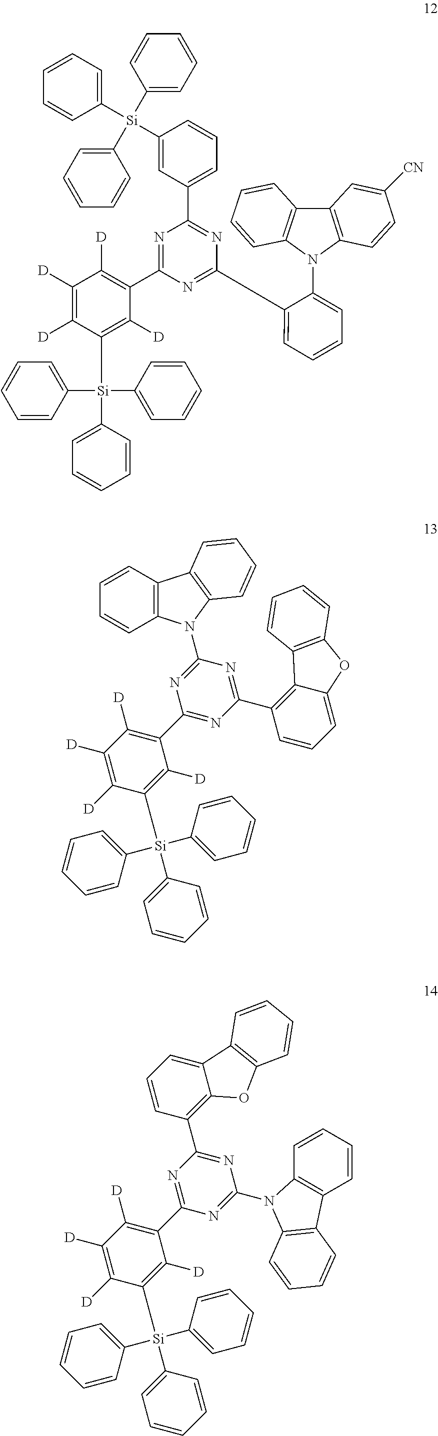 [SMILES: [2H]c1c([2H])c(-c2nc(-c3cccc([Si](c4ccccc4)(c4ccccc4)c4ccccc4)c3)nc(-c3ccccc3-n3c4ccccc4c4cc(C#N)ccc43)n2)c([2H])c([Si](c2ccccc2)(c2ccccc2)c2ccccc2)c1[2H] ; [2H]c1c([2H])c(-c2nc(-c3cccc4oc5ccccc5c34)nc(-n3c4ccccc4c4ccccc43)n2)c([2H])c([Si](c2ccccc2)(c2ccccc2)c2ccccc2)c1[2H] ; [2H]c1c([2H])c(-c2nc(-c3cccc4c3oc3ccccc34)nc(-n3c4ccccc4c4ccccc43)n2)c([2H])c([Si](c2ccccc2)(c2ccccc2)c2ccccc2)c1[2H]] 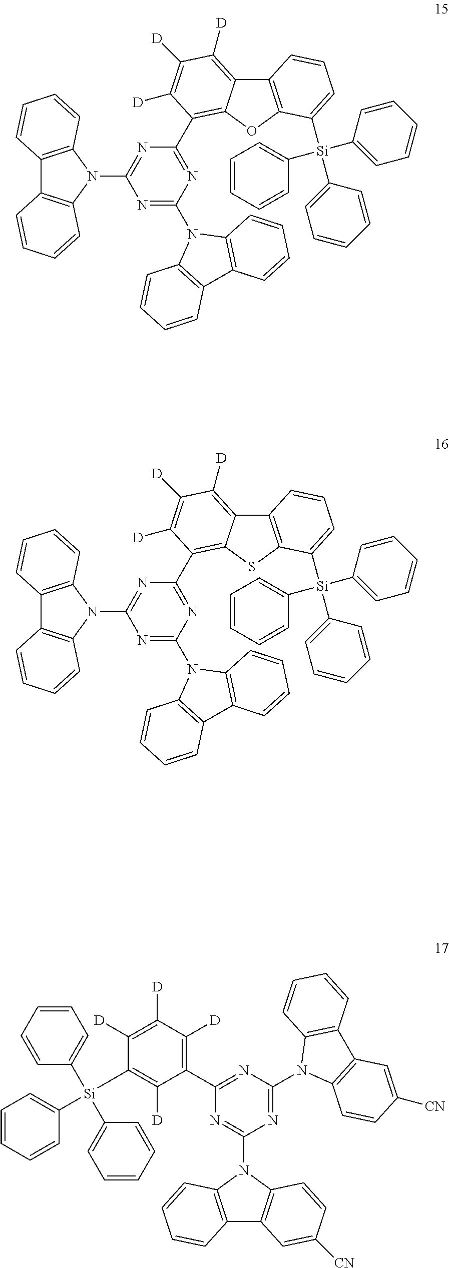 [SMILES: [2H]c1c([2H])c([2H])c2c(oc3c([Si](c4ccccc4)(c4ccccc4)c4ccccc4)cccc32)c1-c1nc(-n2c3ccccc3c3ccccc32)nc(-n2c3ccccc3c3ccccc32)n1 ; [2H]c1c([2H])c([2H])c2c(sc3c([Si](c4ccccc4)(c4ccccc4)c4ccccc4)cccc32)c1-c1nc(-n2c3ccccc3c3ccccc32)nc(-n2c3ccccc3c3ccccc32)n1 ; [2H]c1c([2H])c(-c2nc(-n3c4ccccc4c4cc(C#N)ccc43)nc(-n3c4ccccc4c4cc(C#N)ccc43)n2)c([2H])c([Si](c2ccccc2)(c2ccccc2)c2ccccc2)c1[2H]] 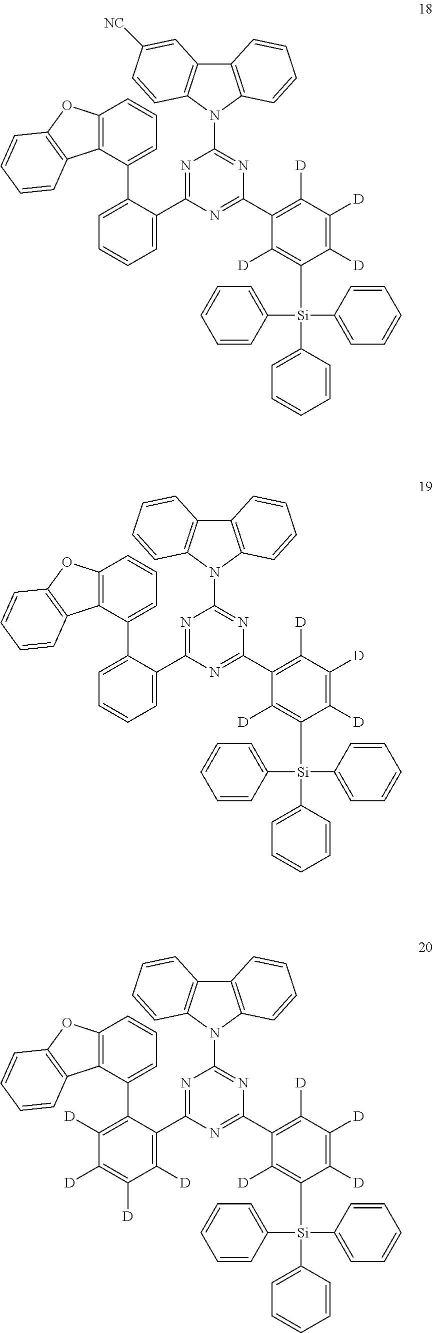 [SMILES: [2H]c1c([2H])c(-c2nc(-c3ccccc3-c3cccc4oc5ccccc5c34)nc(-n3c4ccccc4c4cc(C#N)ccc43)n2)c([2H])c([Si](c2ccccc2)(c2ccccc2)c2ccccc2)c1[2H] ; [2H]c1c([2H])c(-c2nc(-c3ccccc3-c3cccc4oc5ccccc5c34)nc(-n3c4ccccc4c4ccccc43)n2)c([2H])c([Si](c2ccccc2)(c2ccccc2)c2ccccc2)c1[2H] ; [2H]c1c([2H])c([2H])c(-c2cccc3oc4ccccc4c23)c(-c2nc(-c3c([2H])c([2H])c([2H])c([Si](c4ccccc4)(c4ccccc4)c4ccccc4)c3[2H])nc(-n3c4ccccc4c4ccccc43)n2)c1[2H]] 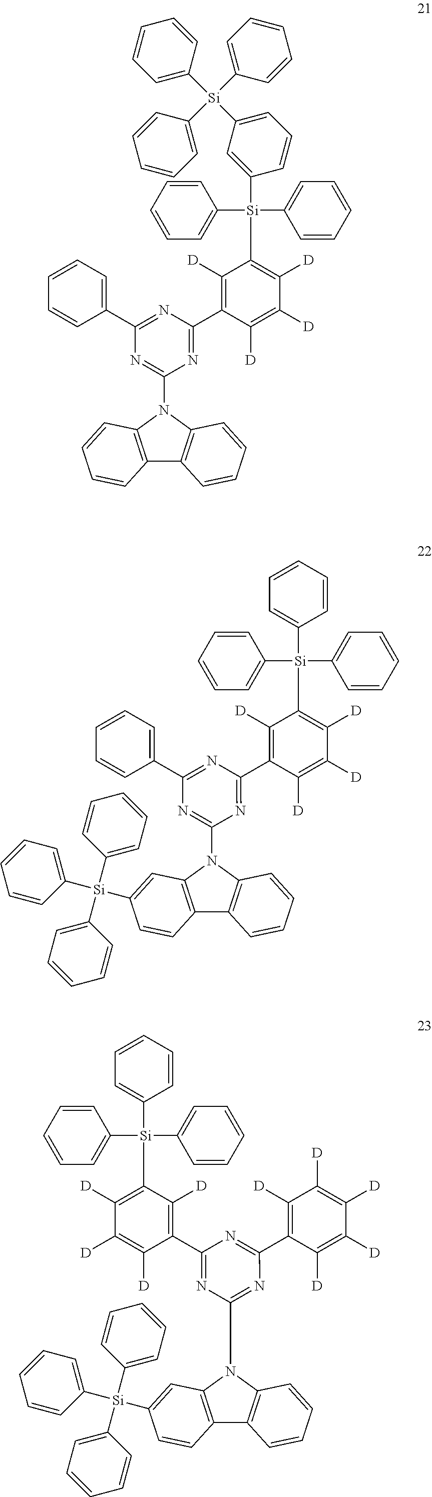 [SMILES: [2H]c1c([2H])c(-c2nc(-c3ccccc3)nc(-n3c4ccccc4c4ccccc43)n2)c([2H])c([Si](c2ccccc2)(c2ccccc2)c2cccc([Si](c3ccccc3)(c3ccccc3)c3ccccc3)c2)c1[2H] ; [2H]c1c([2H])c(-c2nc(-c3ccccc3)nc(-n3c4ccccc4c4ccc([Si](c5ccccc5)(c5ccccc5)c5ccccc5)cc43)n2)c([2H])c([Si](c2ccccc2)(c2ccccc2)c2ccccc2)c1[2H] ; [2H]c1c([2H])c([2H])c(-c2nc(-c3c([2H])c([2H])c([2H])c([Si](c4ccccc4)(c4ccccc4)c4ccccc4)c3[2H])nc(-n3c4ccccc4c4ccc([Si](c5ccccc5)(c5ccccc5)c5ccccc5)cc43)n2)c([2H])c1[2H]] 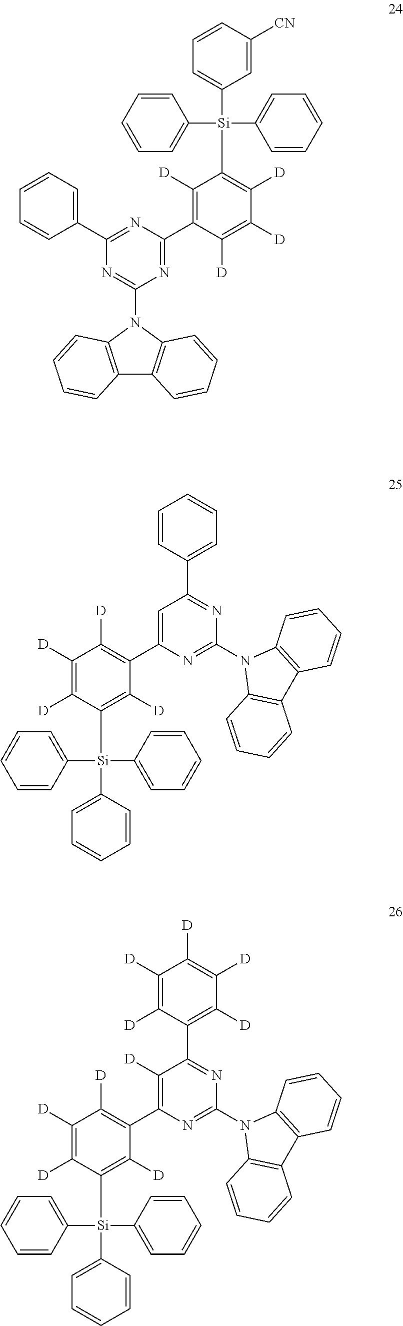 [SMILES: [2H]c1c([2H])c(-c2nc(-c3ccccc3)nc(-n3c4ccccc4c4ccccc43)n2)c([2H])c([Si](c2ccccc2)(c2ccccc2)c2cccc(C#N)c2)c1[2H] ; [2H]c1c([2H])c(-c2cc(-c3ccccc3)nc(-n3c4ccccc4c4ccccc43)n2)c([2H])c([Si](c2ccccc2)(c2ccccc2)c2ccccc2)c1[2H] ; [2H]c1c(-c2c([2H])c([2H])c([2H])c([2H])c2[2H])nc(-n2c3ccccc3c3ccccc32)nc1-c1c([2H])c([2H])c([2H])c([Si](c2ccccc2)(c2ccccc2)c2ccccc2)c1[2H]] 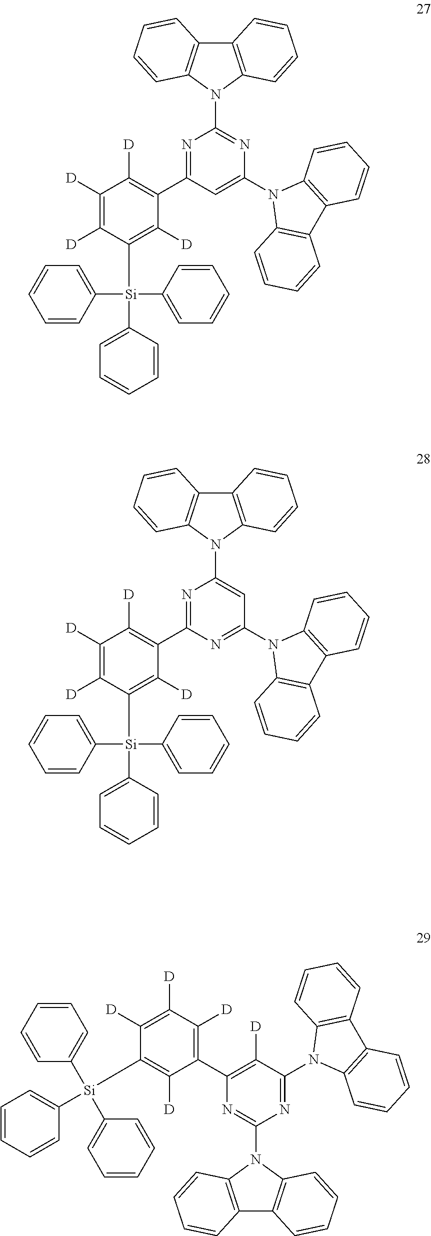 [SMILES: [2H]c1c([2H])c(-c2cc(-n3c4ccccc4c4ccccc43)nc(-n3c4ccccc4c4ccccc43)n2)c([2H])c([Si](c2ccccc2)(c2ccccc2)c2ccccc2)c1[2H] ; [2H]c1c([2H])c(-c2nc(-n3c4ccccc4c4ccccc43)cc(-n3c4ccccc4c4ccccc43)n2)c([2H])c([Si](c2ccccc2)(c2ccccc2)c2ccccc2)c1[2H] ; [2H]c1c(-c2c([2H])c([2H])c([2H])c([Si](c3ccccc3)(c3ccccc3)c3ccccc3)c2[2H])nc(-n2c3ccccc3c3ccccc32)nc1-n1c2ccccc2c2ccccc21] 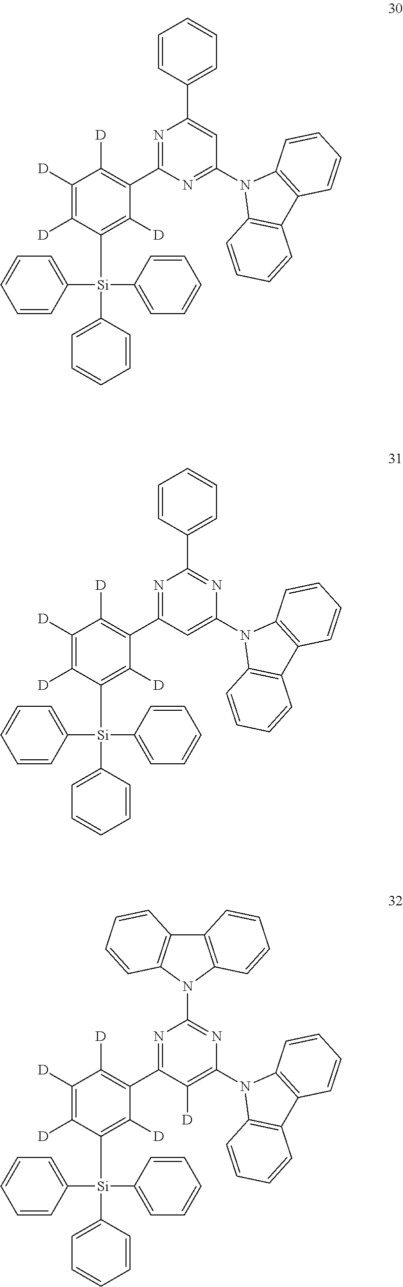 [SMILES: [2H]c1c([2H])c(-c2nc(-c3ccccc3)cc(-n3c4ccccc4c4ccccc43)n2)c([2H])c([Si](c2ccccc2)(c2ccccc2)c2ccccc2)c1[2H] ; [2H]c1c([2H])c(-c2cc(-n3c4ccccc4c4ccccc43)nc(-c3ccccc3)n2)c([2H])c([Si](c2ccccc2)(c2ccccc2)c2ccccc2)c1[2H] ; [2H]c1c(-c2c([2H])c([2H])c([2H])c([Si](c3ccccc3)(c3ccccc3)c3ccccc3)c2[2H])nc(-n2c3ccccc3c3ccccc32)nc1-n1c2ccccc2c2ccccc21] 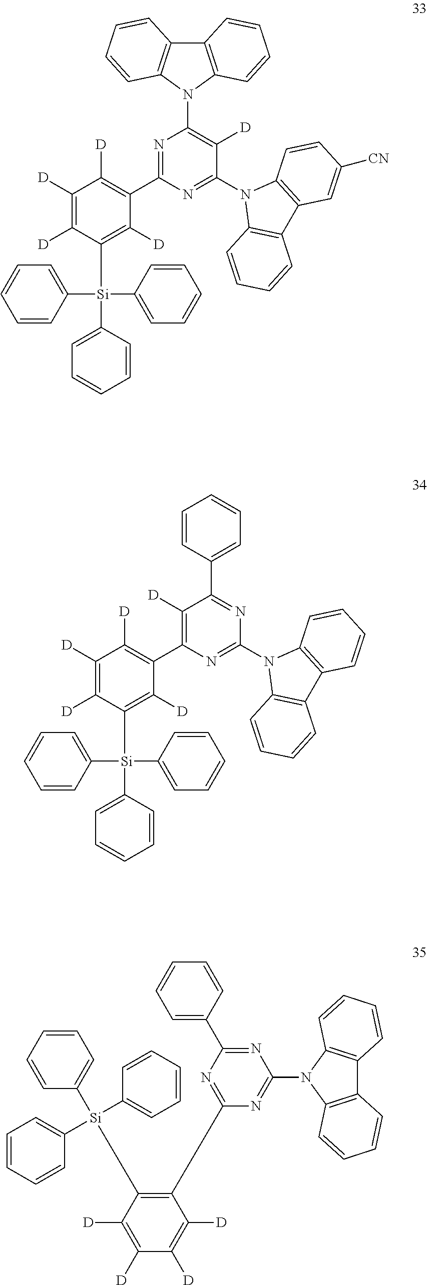 [SMILES: [2H]c1c(-n2c3ccccc3c3ccccc32)nc(-c2c([2H])c([2H])c([2H])c([Si](c3ccccc3)(c3ccccc3)c3ccccc3)c2[2H])nc1-n1c2ccccc2c2cc(C#N)ccc21 ; [2H]c1c(-c2ccccc2)nc(-n2c3ccccc3c3ccccc32)nc1-c1c([2H])c([2H])c([2H])c([Si](c2ccccc2)(c2ccccc2)c2ccccc2)c1[2H] ; [2H]c1c([2H])c([2H])c([Si](c2ccccc2)(c2ccccc2)c2ccccc2)c(-c2nc(-c3ccccc3)nc(-n3c4ccccc4c4ccccc43)n2)c1[2H]] 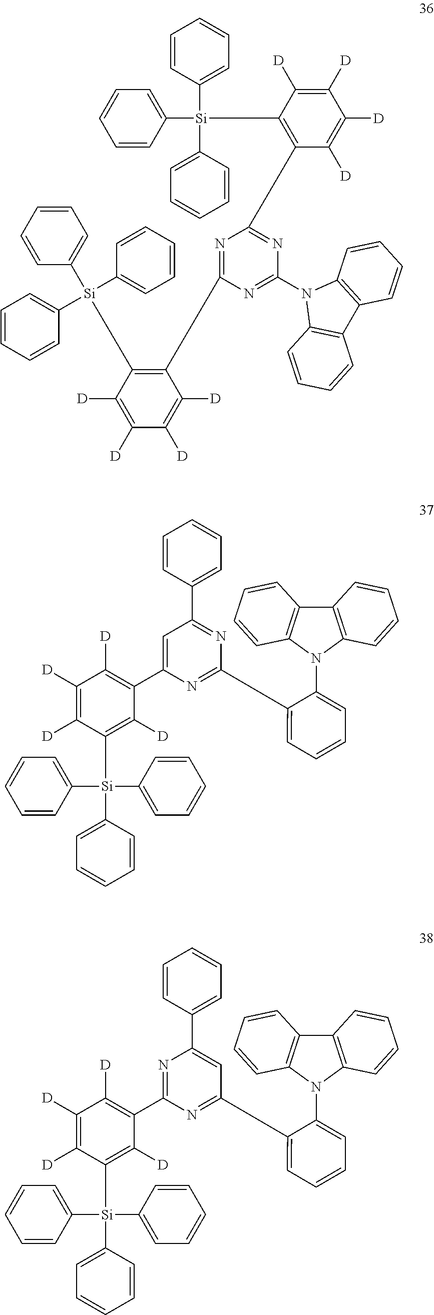 [SMILES: [2H]c1c([2H])c([2H])c([Si](c2ccccc2)(c2ccccc2)c2ccccc2)c(-c2nc(-c3c([2H])c([2H])c([2H])c([2H])c3[Si](c3ccccc3)(c3ccccc3)c3ccccc3)nc(-n3c4ccccc4c4ccccc43)n2)c1[2H] ; [2H]c1c([2H])c(-c2cc(-c3ccccc3)nc(-c3ccccc3-n3c4ccccc4c4ccccc43)n2)c([2H])c([Si](c2ccccc2)(c2ccccc2)c2ccccc2)c1[2H] ; [2H]c1c([2H])c(-c2nc(-c3ccccc3)cc(-c3ccccc3-n3c4ccccc4c4ccccc43)n2)c([2H])c([Si](c2ccccc2)(c2ccccc2)c2ccccc2)c1[2H]] 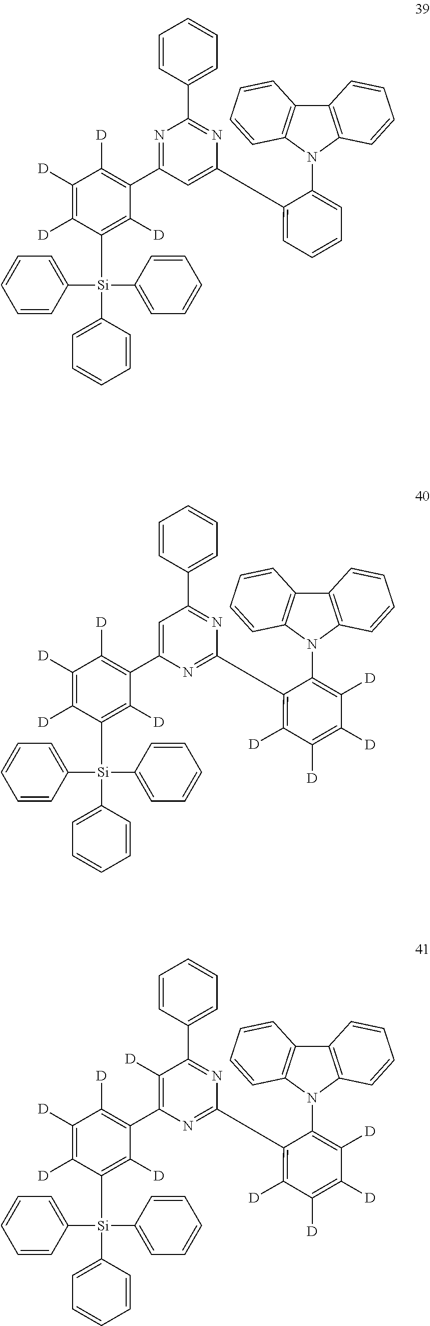 [SMILES: [2H]c1c([2H])c(-c2cc(-c3ccccc3-n3c4ccccc4c4ccccc43)nc(-c3ccccc3)n2)c([2H])c([Si](c2ccccc2)(c2ccccc2)c2ccccc2)c1[2H] ; [2H]c1c([2H])c([2H])c(-n2c3ccccc3c3ccccc32)c(-c2nc(-c3ccccc3)cc(-c3c([2H])c([2H])c([2H])c([Si](c4ccccc4)(c4ccccc4)c4ccccc4)c3[2H])n2)c1[2H] ; [2H]c1c(-c2ccccc2)nc(-c2c([2H])c([2H])c([2H])c([2H])c2-n2c3ccccc3c3ccccc32)nc1-c1c([2H])c([2H])c([2H])c([Si](c2ccccc2)(c2ccccc2)c2ccccc2)c1[2H]] 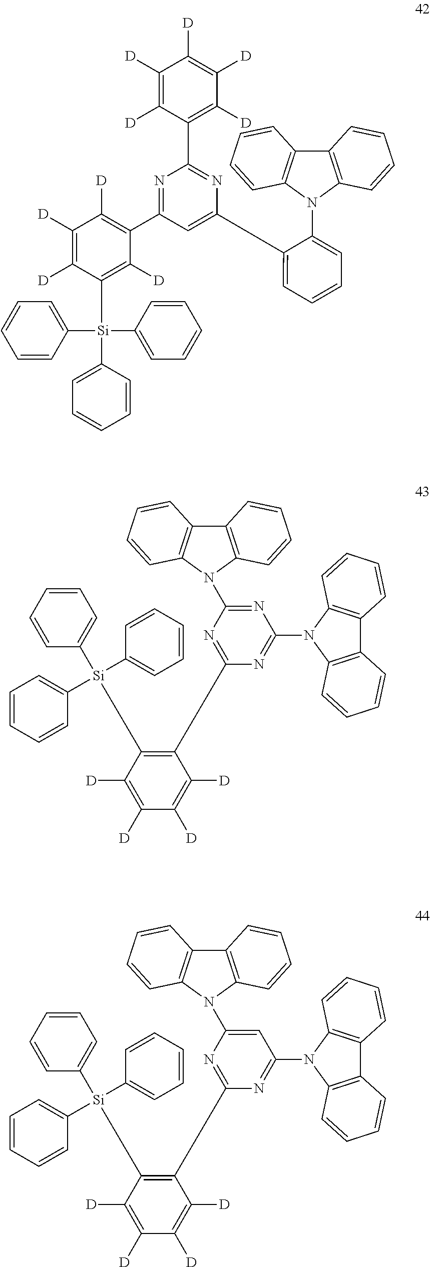 [SMILES: [2H]c1c([2H])c([2H])c(-c2nc(-c3ccccc3-n3c4ccccc4c4ccccc43)cc(-c3c([2H])c([2H])c([2H])c([Si](c4ccccc4)(c4ccccc4)c4ccccc4)c3[2H])n2)c([2H])c1[2H] ; [2H]c1c([2H])c([2H])c([Si](c2ccccc2)(c2ccccc2)c2ccccc2)c(-c2nc(-n3c4ccccc4c4ccccc43)nc(-n3c4ccccc4c4ccccc43)n2)c1[2H] ; [2H]c1c([2H])c([2H])c([Si](c2ccccc2)(c2ccccc2)c2ccccc2)c(-c2nc(-n3c4ccccc4c4ccccc43)cc(-n3c4ccccc4c4ccccc43)n2)c1[2H]] 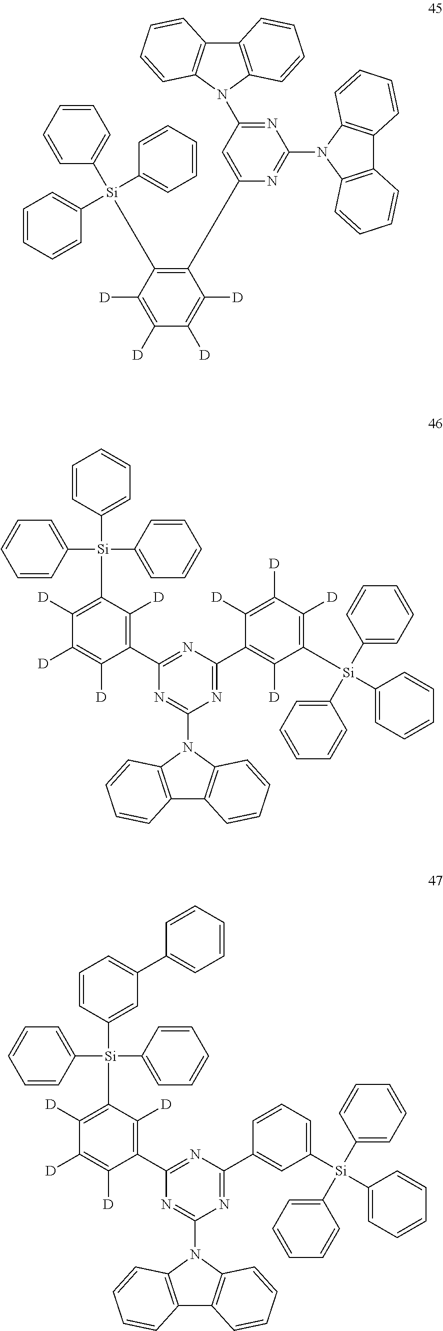 [SMILES: [2H]c1c([2H])c([2H])c([Si](c2ccccc2)(c2ccccc2)c2ccccc2)c(-c2cc(-n3c4ccccc4c4ccccc43)nc(-n3c4ccccc4c4ccccc43)n2)c1[2H] ; [2H]c1c([2H])c(-c2nc(-c3c([2H])c([2H])c([2H])c([Si](c4ccccc4)(c4ccccc4)c4ccccc4)c3[2H])nc(-n3c4ccccc4c4ccccc43)n2)c([2H])c([Si](c2ccccc2)(c2ccccc2)c2ccccc2)c1[2H] ; [2H]c1c([2H])c(-c2nc(-c3cccc([Si](c4ccccc4)(c4ccccc4)c4ccccc4)c3)nc(-n3c4ccccc4c4ccccc43)n2)c([2H])c([Si](c2ccccc2)(c2ccccc2)c2cccc(-c3ccccc3)c2)c1[2H]] 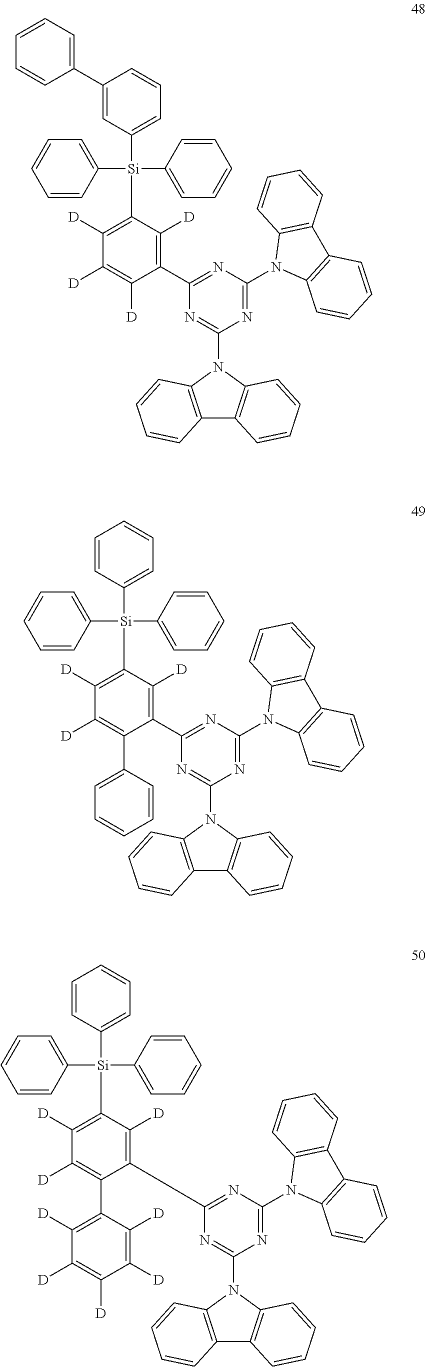 [SMILES: [2H]c1c([2H])c(-c2nc(-n3c4ccccc4c4ccccc43)nc(-n3c4ccccc4c4ccccc43)n2)c([2H])c([Si](c2ccccc2)(c2ccccc2)c2cccc(-c3ccccc3)c2)c1[2H] ; [2H]c1c([2H])c([Si](c2ccccc2)(c2ccccc2)c2ccccc2)c([2H])c(-c2nc(-n3c4ccccc4c4ccccc43)nc(-n3c4ccccc4c4ccccc43)n2)c1-c1ccccc1 ; [2H]c1c([2H])c([2H])c(-c2c([2H])c([2H])c([Si](c3ccccc3)(c3ccccc3)c3ccccc3)c([2H])c2-c2nc(-n3c4ccccc4c4ccccc43)nc(-n3c4ccccc4c4ccccc43)n2)c([2H])c1[2H]] 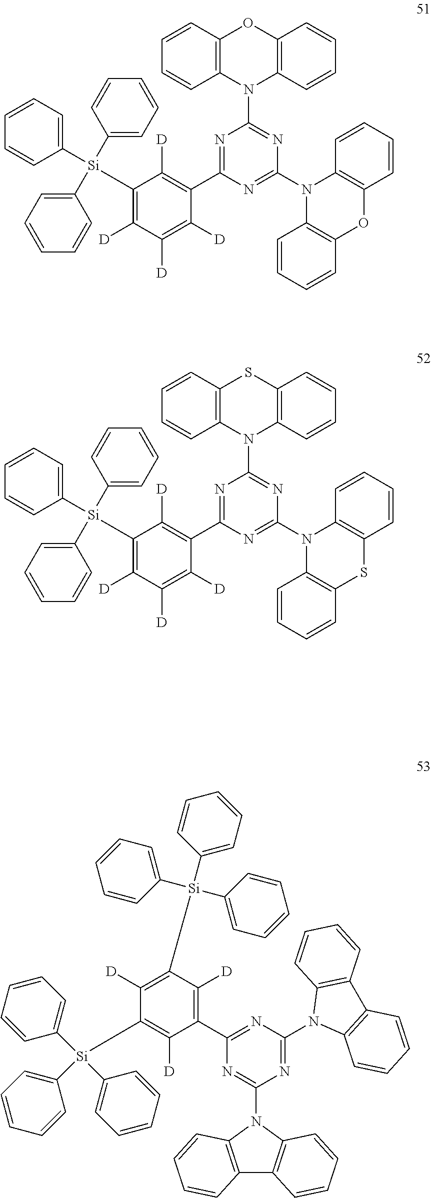 [SMILES: [2H]c1c([2H])c(-c2nc(N3c4ccccc4Oc4ccccc43)nc(N3c4ccccc4Oc4ccccc43)n2)c([2H])c([Si](c2ccccc2)(c2ccccc2)c2ccccc2)c1[2H] ; [2H]c1c([2H])c(-c2nc(N3c4ccccc4Sc4ccccc43)nc(N3c4ccccc4Sc4ccccc43)n2)c([2H])c([Si](c2ccccc2)(c2ccccc2)c2ccccc2)c1[2H] ; [2H]c1c(-c2nc(-n3c4ccccc4c4ccccc43)nc(-n3c4ccccc4c4ccccc43)n2)c([2H])c([Si](c2ccccc2)(c2ccccc2)c2ccccc2)c([2H])c1[Si](c1ccccc1)(c1ccccc1)c1ccccc1] 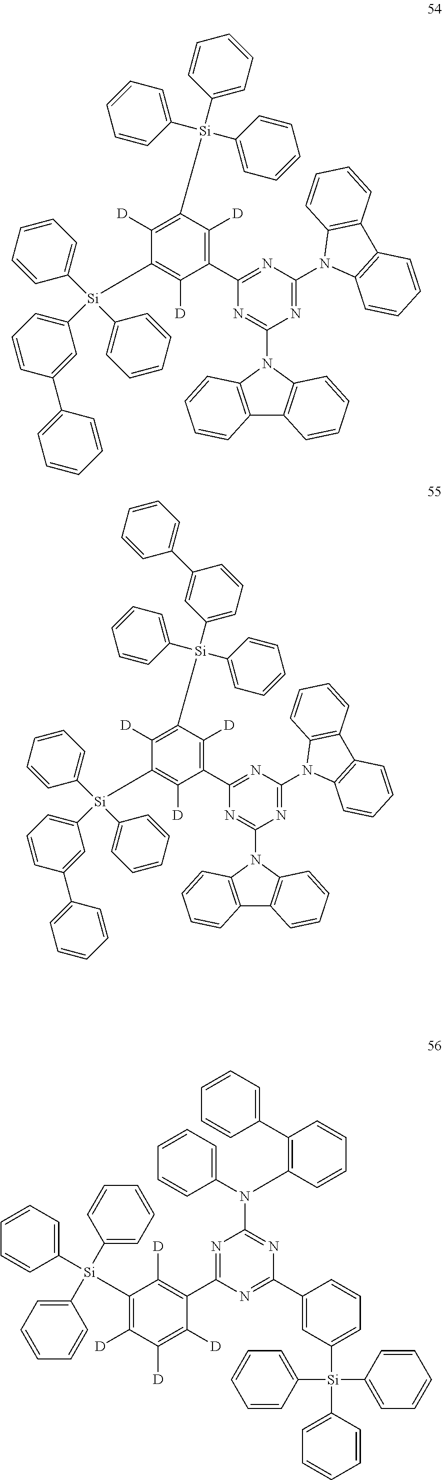 [SMILES: [2H]c1c(-c2nc(-n3c4ccccc4c4ccccc43)nc(-n3c4ccccc4c4ccccc43)n2)c([2H])c([Si](c2ccccc2)(c2ccccc2)c2cccc(-c3ccccc3)c2)c([2H])c1[Si](c1ccccc1)(c1ccccc1)c1ccccc1 ; [2H]c1c(-c2nc(-n3c4ccccc4c4ccccc43)nc(-n3c4ccccc4c4ccccc43)n2)c([2H])c([Si](c2ccccc2)(c2ccccc2)c2cccc(-c3ccccc3)c2)c([2H])c1[Si](c1ccccc1)(c1ccccc1)c1cccc(-c2ccccc2)c1 ; [2H]c1c([2H])c(-c2nc(-c3cccc([Si](c4ccccc4)(c4ccccc4)c4ccccc4)c3)nc(N(c3ccccc3)c3ccccc3-c3ccccc3)n2)c([2H])c([Si](c2ccccc2)(c2ccccc2)c2ccccc2)c1[2H]] 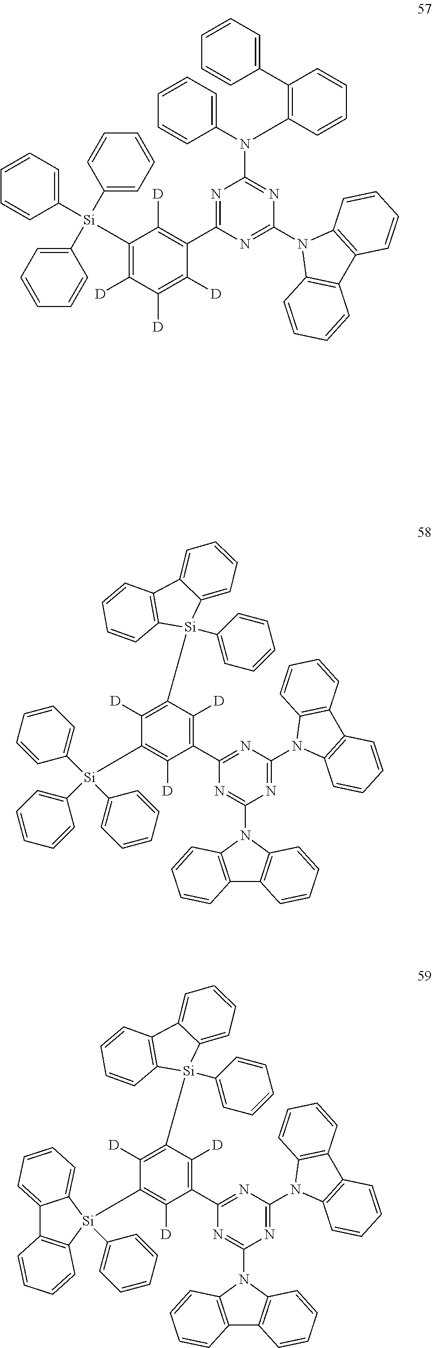 [SMILES: [2H]c1c([2H])c(-c2nc(N(c3ccccc3)c3ccccc3-c3ccccc3)nc(-n3c4ccccc4c4ccccc43)n2)c([2H])c([Si](c2ccccc2)(c2ccccc2)c2ccccc2)c1[2H] ; [2H]c1c(-c2nc(-n3c4ccccc4c4ccccc43)nc(-n3c4ccccc4c4ccccc43)n2)c([2H])c([Si]2(c3ccccc3)c3ccccc3-c3ccccc32)c([2H])c1[Si](c1ccccc1)(c1ccccc1)c1ccccc1 ; [2H]c1c(-c2nc(-n3c4ccccc4c4ccccc43)nc(-n3c4ccccc4c4ccccc43)n2)c([2H])c([Si]2(c3ccccc3)c3ccccc3-c3ccccc32)c([2H])c1[Si]1(c2ccccc2)c2ccccc2-c2ccccc21] 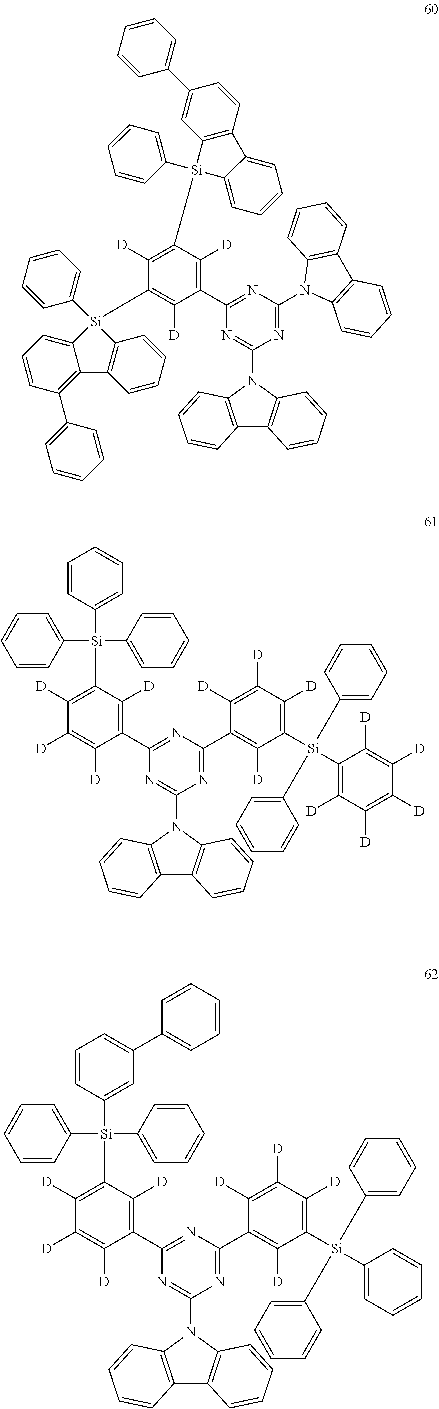 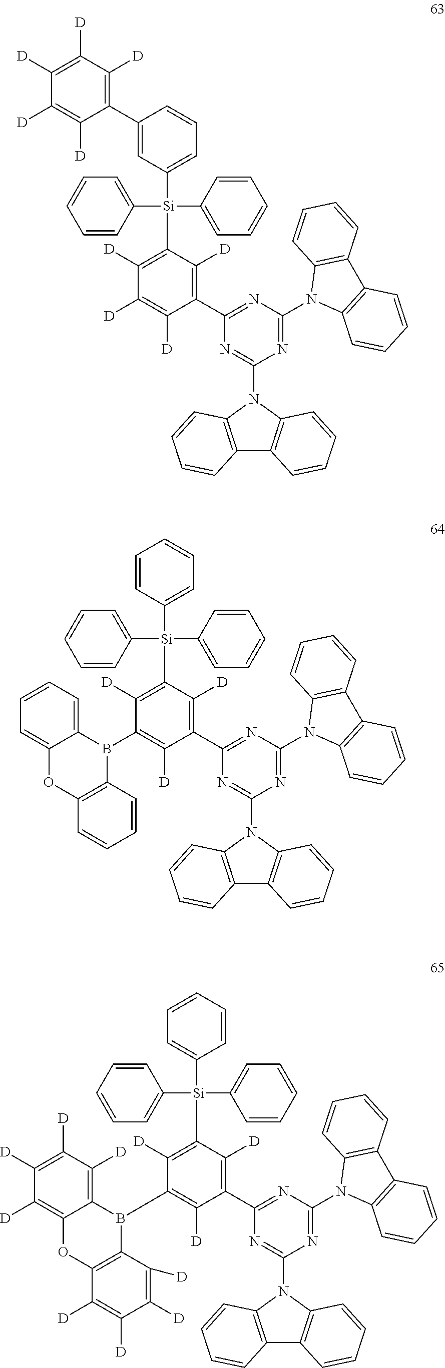 [SMILES: [2H]c1c([2H])c([2H])c(-c2cccc([Si](c3ccccc3)(c3ccccc3)c3c([2H])c([2H])c([2H])c(-c4nc(-n5c6ccccc6c6ccccc65)nc(-n5c6ccccc6c6ccccc65)n4)c3[2H])c2)c([2H])c1[2H] ; [2H]c1c(B2c3ccccc3Oc3ccccc32)c([2H])c([Si](c2ccccc2)(c2ccccc2)c2ccccc2)c([2H])c1-c1nc(-n2c3ccccc3c3ccccc32)nc(-n2c3ccccc3c3ccccc32)n1 ; [2H]c1c([2H])c([2H])c2c(c1[2H])Oc1c([2H])c([2H])c([2H])c([2H])c1B2c1c([2H])c(-c2nc(-n3c4ccccc4c4ccccc43)nc(-n3c4ccccc4c4ccccc43)n2)c([2H])c([Si](c2ccccc2)(c2ccccc2)c2ccccc2)c1[2H]] 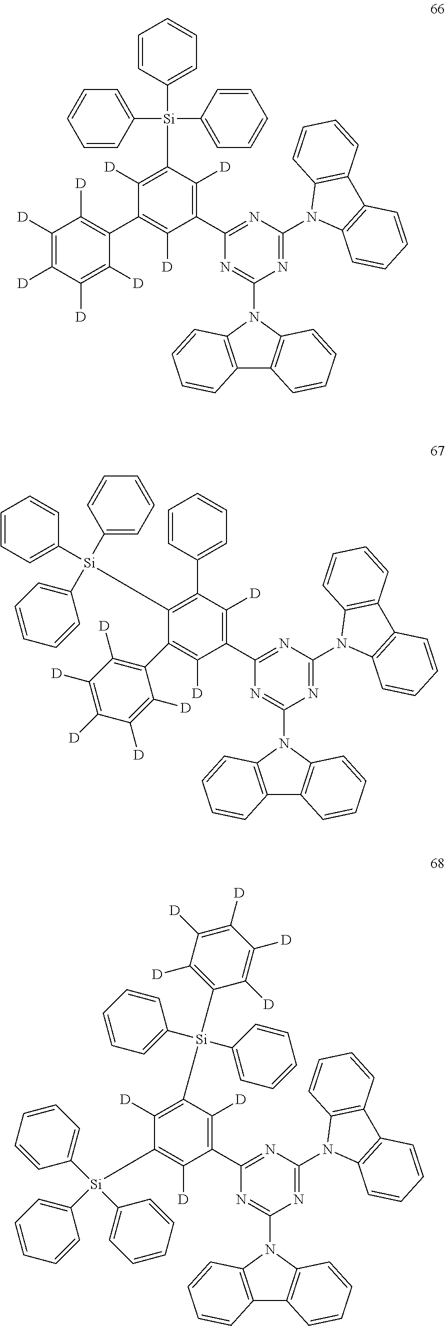 [SMILES: [2H]c1c([2H])c([2H])c(-c2c([2H])c(-c3nc(-n4c5ccccc5c5ccccc54)nc(-n4c5ccccc5c5ccccc54)n3)c([2H])c([Si](c3ccccc3)(c3ccccc3)c3ccccc3)c2[2H])c([2H])c1[2H] ; [2H]c1c([2H])c([2H])c(-c2c([2H])c(-c3nc(-n4c5ccccc5c5ccccc54)nc(-n4c5ccccc5c5ccccc54)n3)c([2H])c(-c3ccccc3)c2[Si](c2ccccc2)(c2ccccc2)c2ccccc2)c([2H])c1[2H] ; [2H]c1c([2H])c([2H])c([Si](c2ccccc2)(c2ccccc2)c2c([2H])c(-c3nc(-n4c5ccccc5c5ccccc54)nc(-n4c5ccccc5c5ccccc54)n3)c([2H])c([Si](c3ccccc3)(c3ccccc3)c3ccccc3)c2[2H])c([2H])c1[2H]] 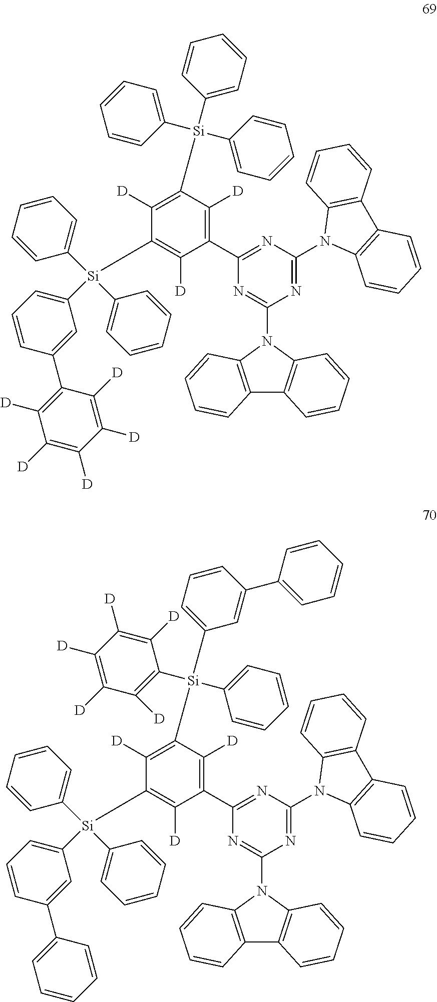 [SMILES: [2H]c1c([2H])c([2H])c(-c2cccc([Si](c3ccccc3)(c3ccccc3)c3c([2H])c(-c4nc(-n5c6ccccc6c6ccccc65)nc(-n5c6ccccc6c6ccccc65)n4)c([2H])c([Si](c4ccccc4)(c4ccccc4)c4ccccc4)c3[2H])c2)c([2H])c1[2H] ; [2H]c1c([2H])c([2H])c([Si](c2ccccc2)(c2cccc(-c3ccccc3)c2)c2c([2H])c(-c3nc(-n4c5ccccc5c5ccccc54)nc(-n4c5ccccc5c5ccccc54)n3)c([2H])c([Si](c3ccccc3)(c3ccccc3)c3cccc(-c4ccccc4)c3)c2[2H])c([2H])c1[2H]] 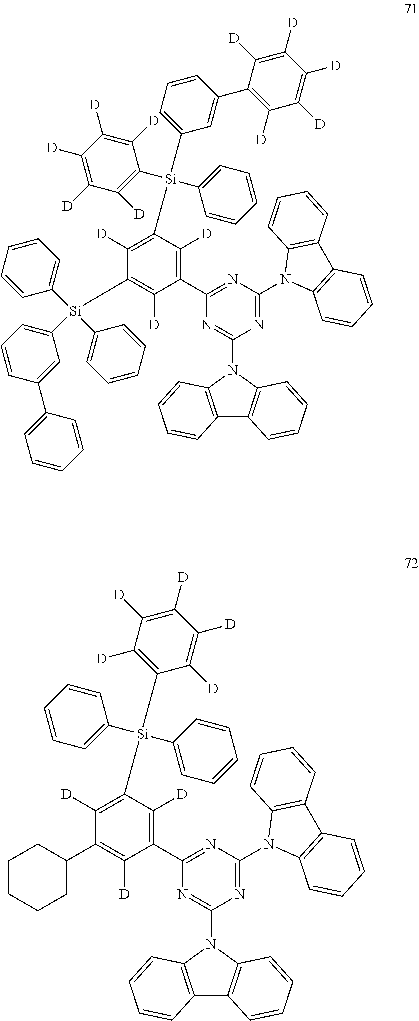 [SMILES: [2H]c1c([2H])c([2H])c(-c2cccc([Si](c3ccccc3)(c3c([2H])c([2H])c([2H])c([2H])c3[2H])c3c([2H])c(-c4nc(-n5c6ccccc6c6ccccc65)nc(-n5c6ccccc6c6ccccc65)n4)c([2H])c([Si](c4ccccc4)(c4ccccc4)c4cccc(-c5ccccc5)c4)c3[2H])c2)c([2H])c1[2H] ; [2H]c1c([2H])c([2H])c([Si](c2ccccc2)(c2ccccc2)c2c([2H])c(-c3nc(-n4c5ccccc5c5ccccc54)nc(-n4c5ccccc5c5ccccc54)n3)c([2H])c(C3CCCCC3)c2[2H])c([2H])c1[2H]] 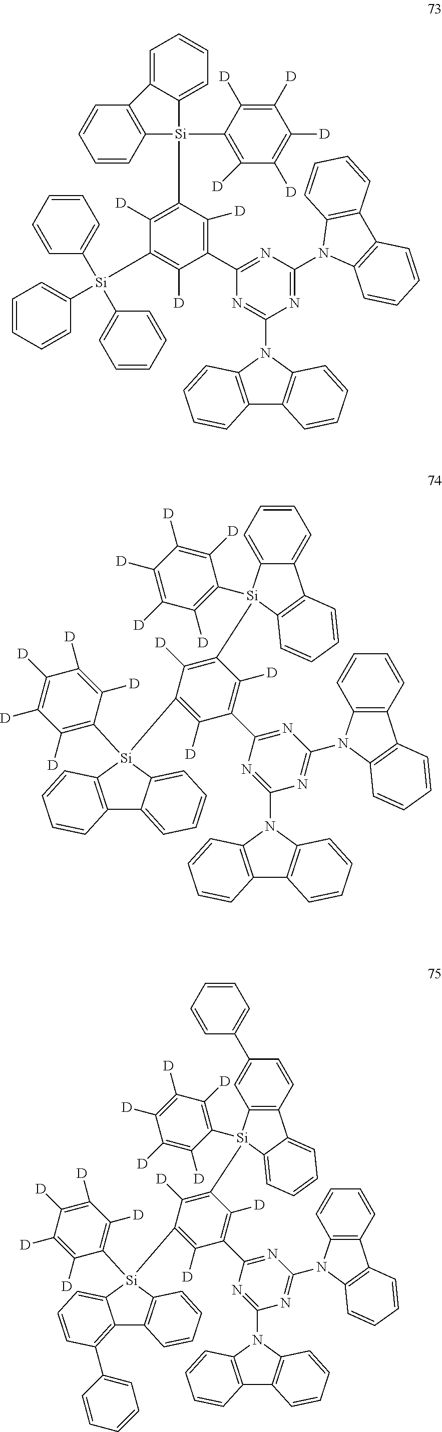 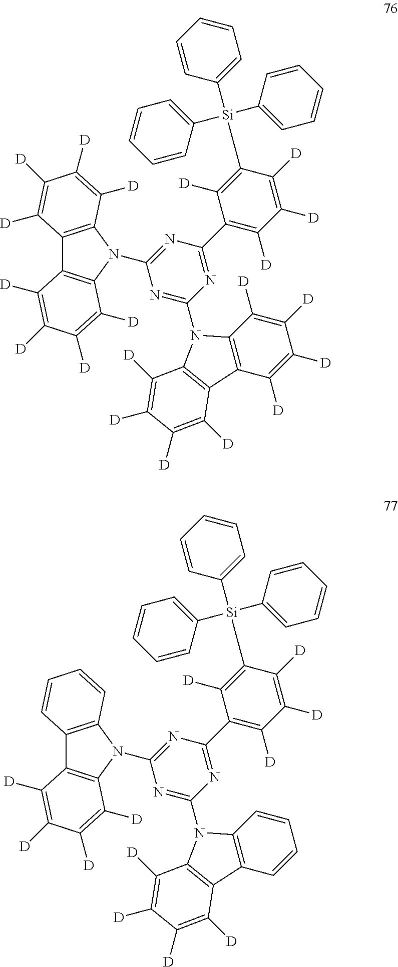 [SMILES: [2H]c1c([2H])c(-c2nc(-n3c4c([2H])c([2H])c([2H])c([2H])c4c4c([2H])c([2H])c([2H])c([2H])c43)nc(-n3c4c([2H])c([2H])c([2H])c([2H])c4c4c([2H])c([2H])c([2H])c([2H])c43)n2)c([2H])c([Si](c2ccccc2)(c2ccccc2)c2ccccc2)c1[2H] ; [2H]c1c([2H])c(-c2nc(-n3c4ccccc4c4c([2H])c([2H])c([2H])c([2H])c43)nc(-n3c4ccccc4c4c([2H])c([2H])c([2H])c([2H])c43)n2)c([2H])c([Si](c2ccccc2)(c2ccccc2)c2ccccc2)c1[2H]] 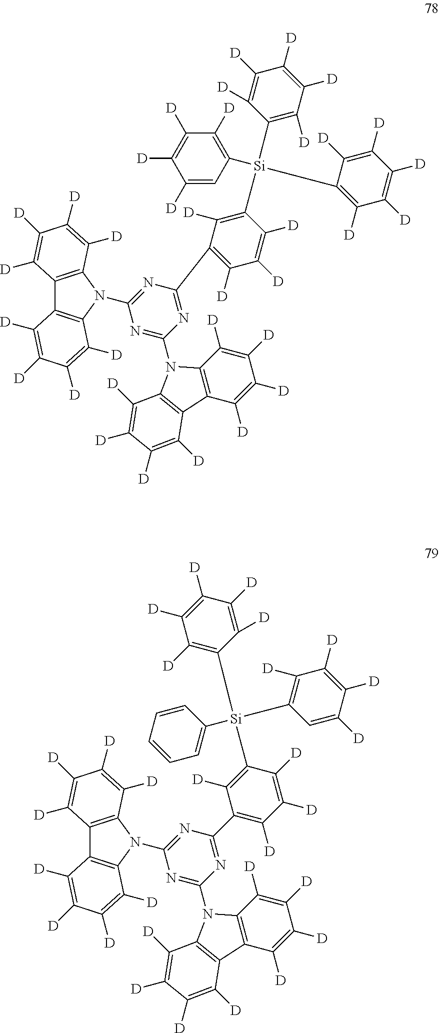 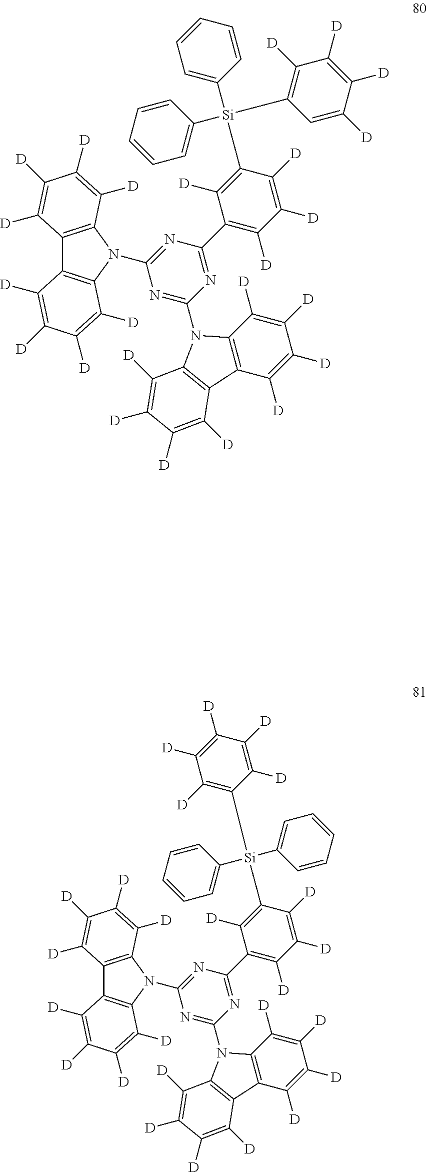 [SMILES: [2H]c1cc([Si](c2ccccc2)(c2ccccc2)c2c([2H])c([2H])c([2H])c(-c3nc(-n4c5c([2H])c([2H])c([2H])c([2H])c5c5c([2H])c([2H])c([2H])c([2H])c54)nc(-n4c5c([2H])c([2H])c([2H])c([2H])c5c5c([2H])c([2H])c([2H])c([2H])c54)n3)c2[2H])c([2H])c([2H])c1[2H] ; [2H]c1c([2H])c([2H])c([Si](c2ccccc2)(c2ccccc2)c2c([2H])c([2H])c([2H])c(-c3nc(-n4c5c([2H])c([2H])c([2H])c([2H])c5c5c([2H])c([2H])c([2H])c([2H])c54)nc(-n4c5c([2H])c([2H])c([2H])c([2H])c5c5c([2H])c([2H])c([2H])c([2H])c54)n3)c2[2H])c([2H])c1[2H]] 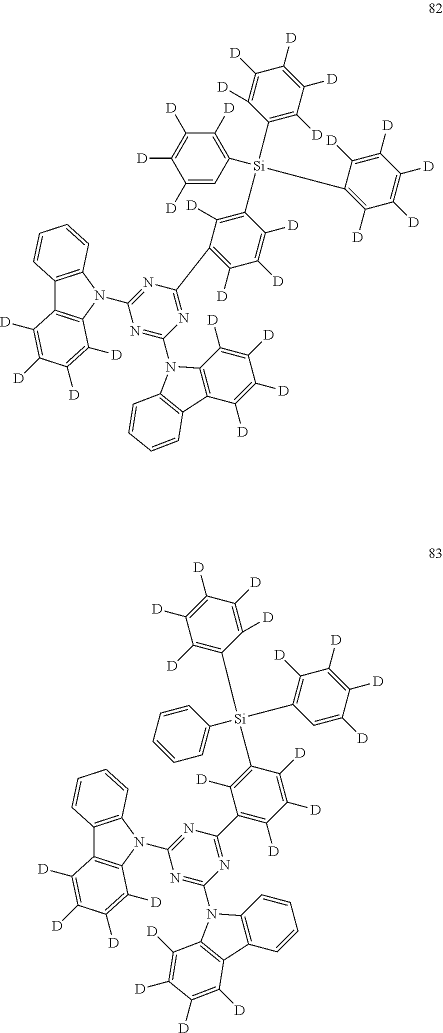 [SMILES: [2H]c1cc([Si](c2c([2H])c([2H])c([2H])c([2H])c2[2H])(c2c([2H])c([2H])c([2H])c([2H])c2[2H])c2c([2H])c([2H])c([2H])c(-c3nc(-n4c5ccccc5c5c([2H])c([2H])c([2H])c([2H])c54)nc(-n4c5ccccc5c5c([2H])c([2H])c([2H])c([2H])c54)n3)c2[2H])c([2H])c([2H])c1[2H] ; [2H]c1cc([Si](c2ccccc2)(c2c([2H])c([2H])c([2H])c([2H])c2[2H])c2c([2H])c([2H])c([2H])c(-c3nc(-n4c5ccccc5c5c([2H])c([2H])c([2H])c([2H])c54)nc(-n4c5ccccc5c5c([2H])c([2H])c([2H])c([2H])c54)n3)c2[2H])c([2H])c([2H])c1[2H]] 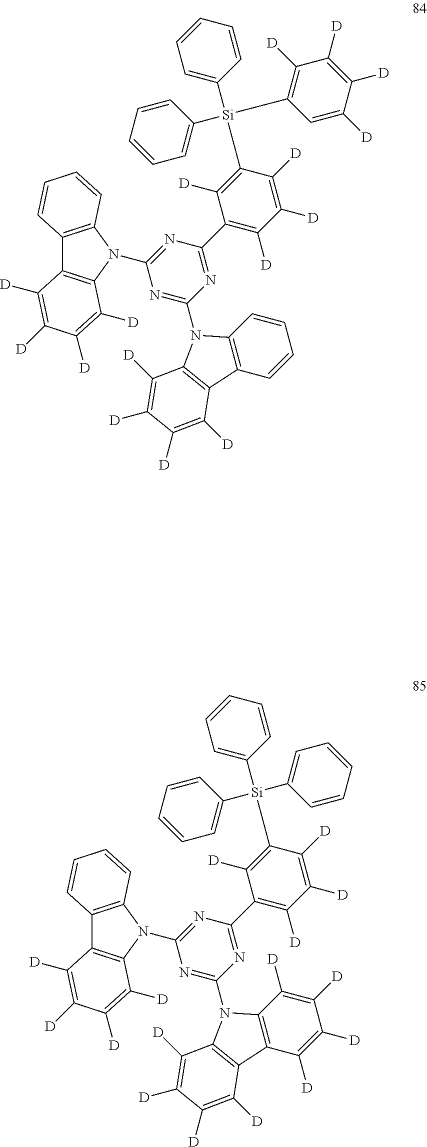 [SMILES: [2H]c1cc([Si](c2ccccc2)(c2ccccc2)c2c([2H])c([2H])c([2H])c(-c3nc(-n4c5ccccc5c5c([2H])c([2H])c([2H])c([2H])c54)nc(-n4c5ccccc5c5c([2H])c([2H])c([2H])c([2H])c54)n3)c2[2H])c([2H])c([2H])c1[2H] ; [2H]c1c([2H])c(-c2nc(-n3c4ccccc4c4c([2H])c([2H])c([2H])c([2H])c43)nc(-n3c4c([2H])c([2H])c([2H])c([2H])c4c4c([2H])c([2H])c([2H])c([2H])c43)n2)c([2H])c([Si](c2ccccc2)(c2ccccc2)c2ccccc2)c1[2H]] 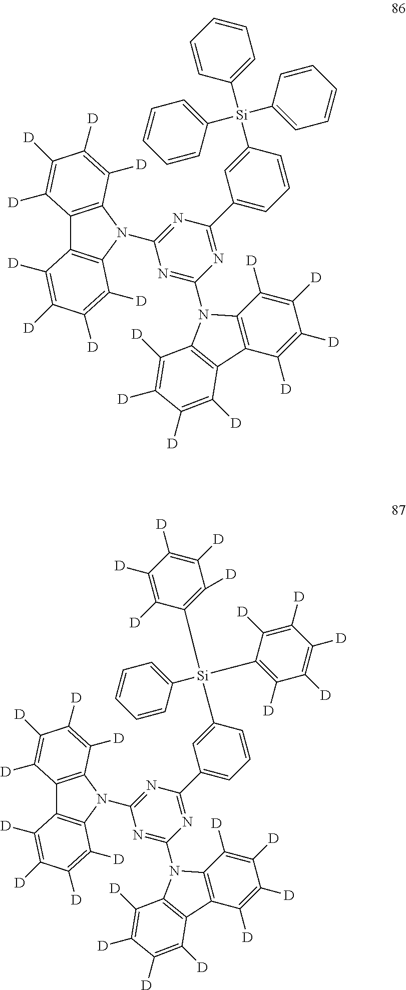 [SMILES: [2H]c1c([2H])c([2H])c2c(c1[2H])c1c([2H])c([2H])c([2H])c([2H])c1n2-c1nc(-c2cccc([Si](c3ccccc3)(c3ccccc3)c3ccccc3)c2)nc(-n2c3c([2H])c([2H])c([2H])c([2H])c3c3c([2H])c([2H])c([2H])c([2H])c32)n1 ; [2H]c1c([2H])c([2H])c([Si](c2ccccc2)(c2cccc(-c3nc(-n4c5c([2H])c([2H])c([2H])c([2H])c5c5c([2H])c([2H])c([2H])c([2H])c54)nc(-n4c5c([2H])c([2H])c([2H])c([2H])c5c5c([2H])c([2H])c([2H])c([2H])c54)n3)c2)c2c([2H])c([2H])c([2H])c([2H])c2[2H])c([2H])c1[2H]] 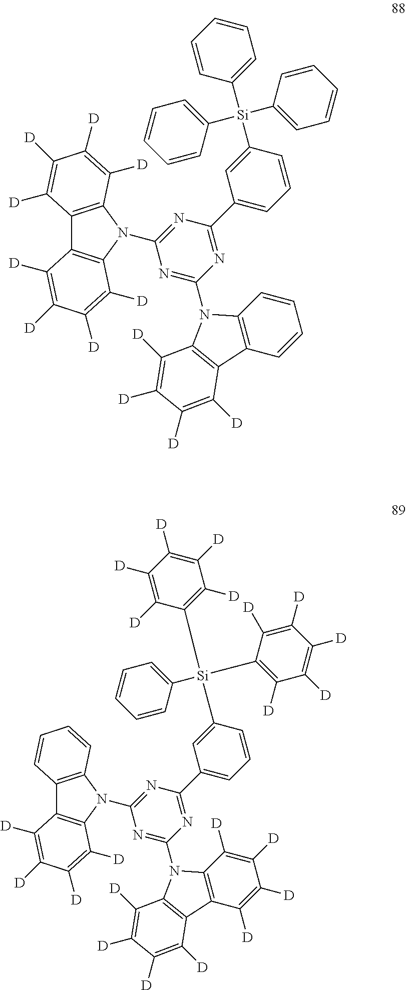 [SMILES: [2H]c1c([2H])c([2H])c2c(c1[2H])c1ccccc1n2-c1nc(-c2cccc([Si](c3ccccc3)(c3ccccc3)c3ccccc3)c2)nc(-n2c3c([2H])c([2H])c([2H])c([2H])c3c3c([2H])c([2H])c([2H])c([2H])c32)n1 ; [2H]c1c([2H])c([2H])c([Si](c2ccccc2)(c2cccc(-c3nc(-n4c5ccccc5c5c([2H])c([2H])c([2H])c([2H])c54)nc(-n4c5c([2H])c([2H])c([2H])c([2H])c5c5c([2H])c([2H])c([2H])c([2H])c54)n3)c2)c2c([2H])c([2H])c([2H])c([2H])c2[2H])c([2H])c1[2H]] 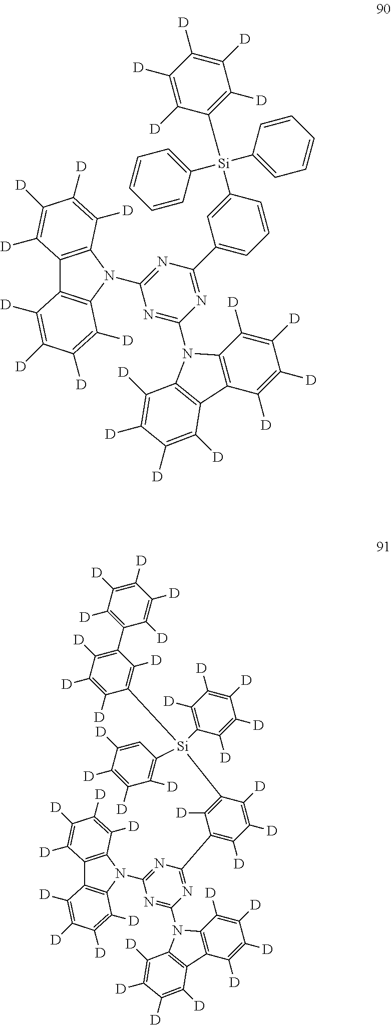 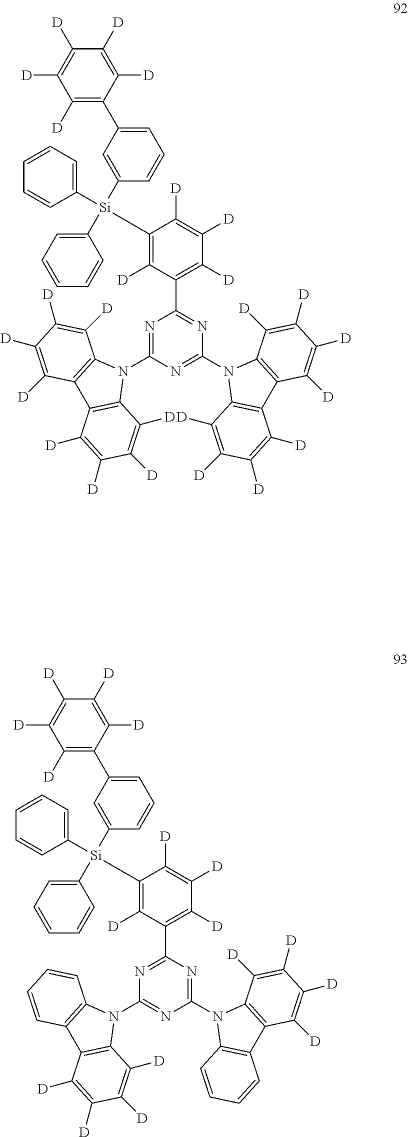 [SMILES: [2H]c1c([2H])c([2H])c(-c2cccc([Si](c3ccccc3)(c3ccccc3)c3c([2H])c([2H])c([2H])c(-c4nc(-n5c6c([2H])c([2H])c([2H])c([2H])c6c6c([2H])c([2H])c([2H])c([2H])c65)nc(-n5c6c([2H])c([2H])c([2H])c([2H])c6c6c([2H])c([2H])c([2H])c([2H])c65)n4)c3[2H])c2)c([2H])c1[2H] ; [2H]c1c([2H])c([2H])c(-c2cccc([Si](c3ccccc3)(c3ccccc3)c3c([2H])c([2H])c([2H])c(-c4nc(-n5c6ccccc6c6c([2H])c([2H])c([2H])c([2H])c65)nc(-n5c6ccccc6c6c([2H])c([2H])c([2H])c([2H])c65)n4)c3[2H])c2)c([2H])c1[2H]] 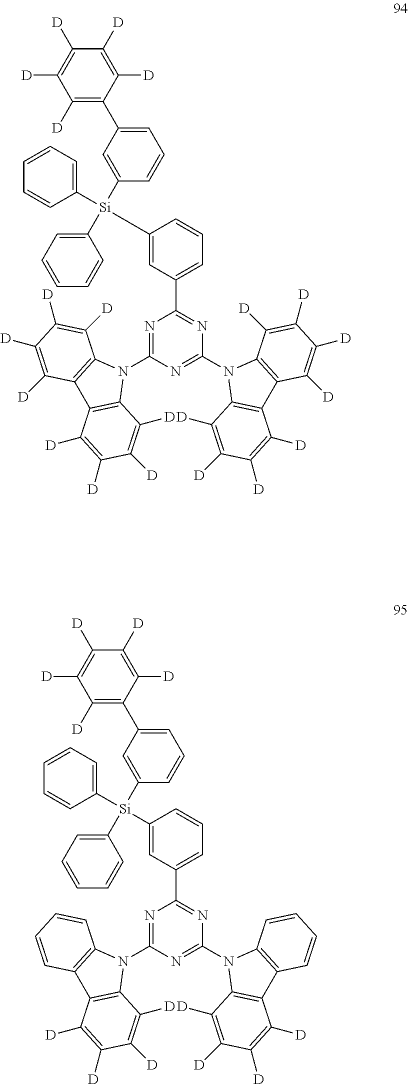 [SMILES: [2H]c1c([2H])c([2H])c(-c2cccc([Si](c3ccccc3)(c3ccccc3)c3cccc(-c4nc(-n5c6c([2H])c([2H])c([2H])c([2H])c6c6c([2H])c([2H])c([2H])c([2H])c65)nc(-n5c6c([2H])c([2H])c([2H])c([2H])c6c6c([2H])c([2H])c([2H])c([2H])c65)n4)c3)c2)c([2H])c1[2H] ; [2H]c1c([2H])c([2H])c(-c2cccc([Si](c3ccccc3)(c3ccccc3)c3cccc(-c4nc(-n5c6ccccc6c6c([2H])c([2H])c([2H])c([2H])c65)nc(-n5c6ccccc6c6c([2H])c([2H])c([2H])c([2H])c65)n4)c3)c2)c([2H])c1[2H]] 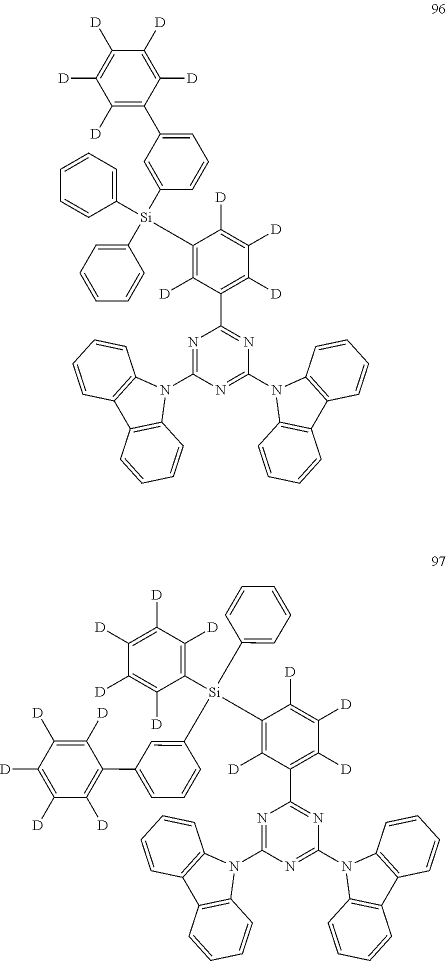 [SMILES: [2H]c1c([2H])c([2H])c(-c2cccc([Si](c3ccccc3)(c3ccccc3)c3c([2H])c([2H])c([2H])c(-c4nc(-n5c6ccccc6c6ccccc65)nc(-n5c6ccccc6c6ccccc65)n4)c3[2H])c2)c([2H])c1[2H] ; [2H]c1c([2H])c([2H])c(-c2cccc([Si](c3ccccc3)(c3c([2H])c([2H])c([2H])c([2H])c3[2H])c3c([2H])c([2H])c([2H])c(-c4nc(-n5c6ccccc6c6ccccc65)nc(-n5c6ccccc6c6ccccc65)n4)c3[2H])c2)c([2H])c1[2H]] 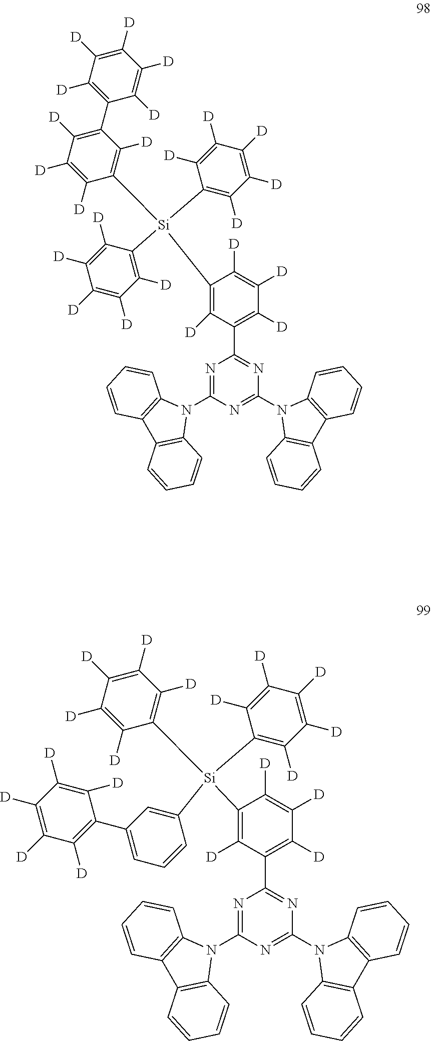 [SMILES: [2H]c1c([2H])c([2H])c(-c2c([2H])c([2H])c([2H])c([Si](c3c([2H])c([2H])c([2H])c([2H])c3[2H])(c3c([2H])c([2H])c([2H])c([2H])c3[2H])c3c([2H])c([2H])c([2H])c(-c4nc(-n5c6ccccc6c6ccccc65)nc(-n5c6ccccc6c6ccccc65)n4)c3[2H])c2[2H])c([2H])c1[2H] ; [2H]c1c([2H])c([2H])c(-c2cccc([Si](c3c([2H])c([2H])c([2H])c([2H])c3[2H])(c3c([2H])c([2H])c([2H])c([2H])c3[2H])c3c([2H])c([2H])c([2H])c(-c4nc(-n5c6ccccc6c6ccccc65)nc(-n5c6ccccc6c6ccccc65)n4)c3[2H])c2)c([2H])c1[2H]] 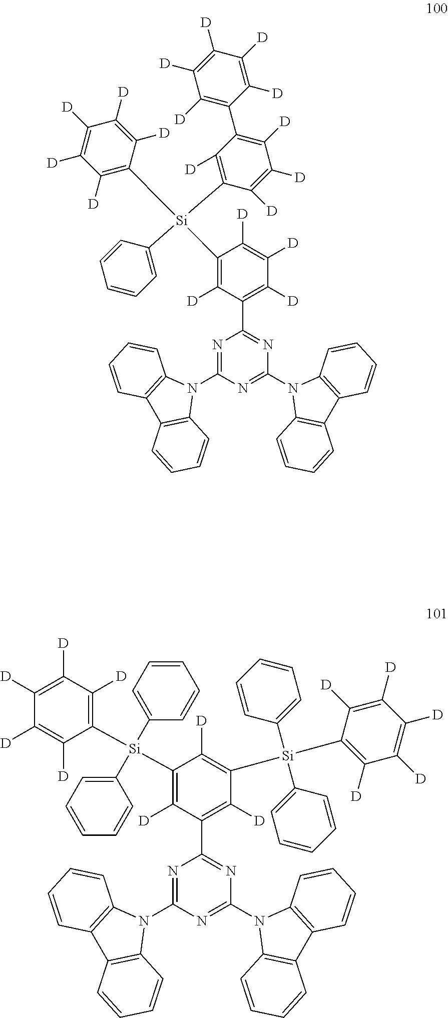 [SMILES: [2H]c1c([2H])c([2H])c(-c2c([2H])c([2H])c([2H])c([Si](c3ccccc3)(c3c([2H])c([2H])c([2H])c([2H])c3[2H])c3c([2H])c([2H])c([2H])c(-c4nc(-n5c6ccccc6c6ccccc65)nc(-n5c6ccccc6c6ccccc65)n4)c3[2H])c2[2H])c([2H])c1[2H] ; [2H]c1c([2H])c([2H])c([Si](c2ccccc2)(c2ccccc2)c2c([2H])c(-c3nc(-n4c5ccccc5c5ccccc54)nc(-n4c5ccccc5c5ccccc54)n3)c([2H])c([Si](c3ccccc3)(c3ccccc3)c3c([2H])c([2H])c([2H])c([2H])c3[2H])c2[2H])c([2H])c1[2H]] 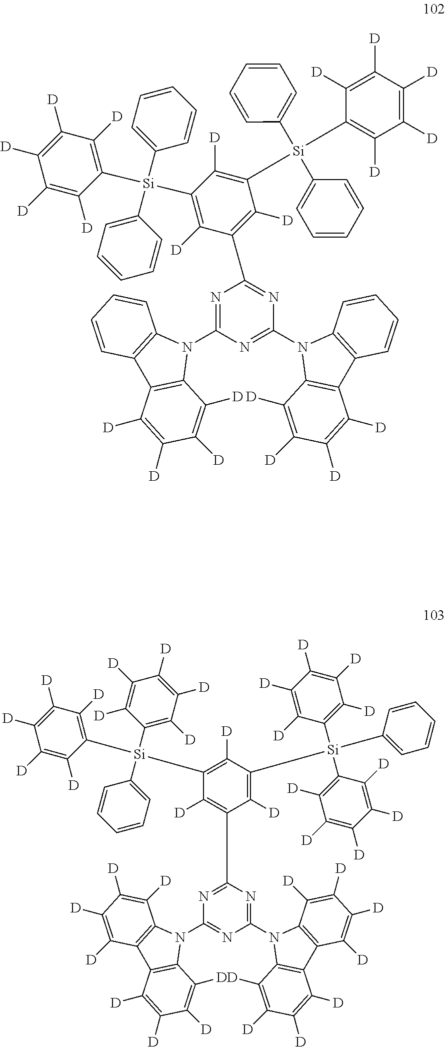 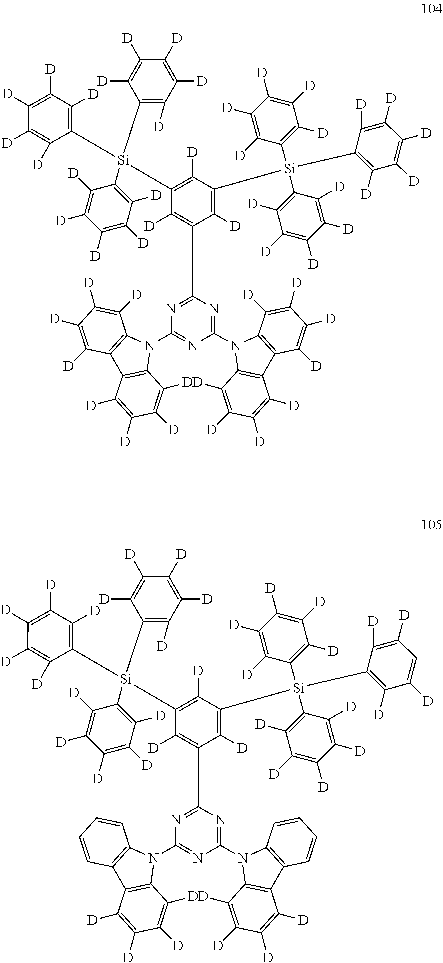 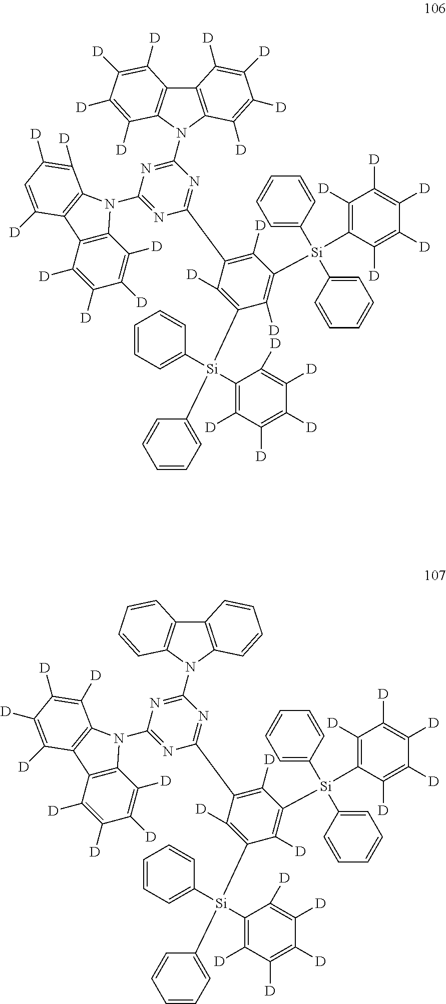 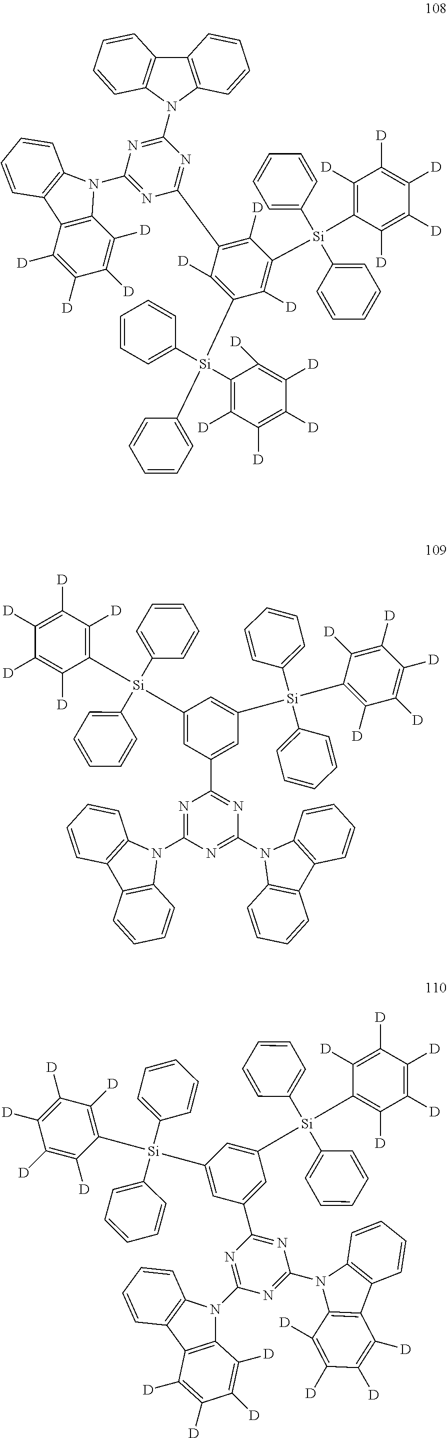 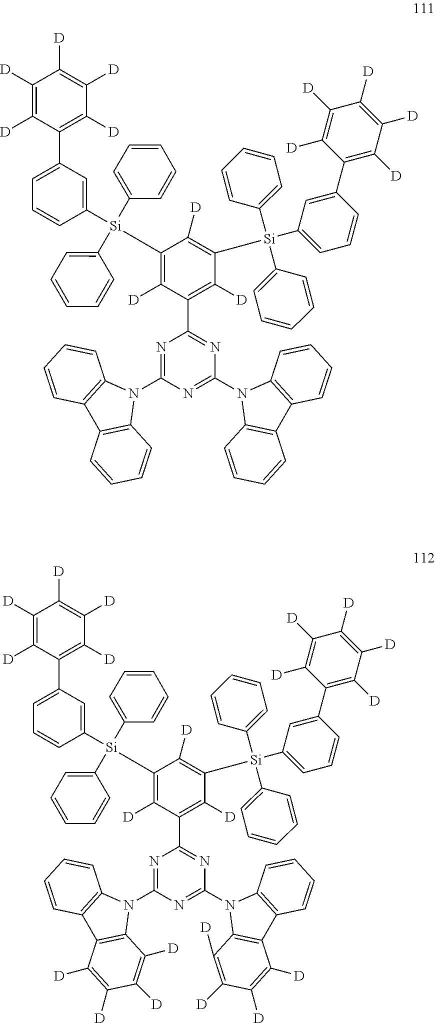 [SMILES: [2H]c1c([2H])c([2H])c(-c2cccc([Si](c3ccccc3)(c3ccccc3)c3c([2H])c(-c4nc(-n5c6ccccc6c6ccccc65)nc(-n5c6ccccc6c6ccccc65)n4)c([2H])c([Si](c4ccccc4)(c4ccccc4)c4cccc(-c5c([2H])c([2H])c([2H])c([2H])c5[2H])c4)c3[2H])c2)c([2H])c1[2H] ; [2H]c1c([2H])c([2H])c(-c2cccc([Si](c3ccccc3)(c3ccccc3)c3c([2H])c(-c4nc(-n5c6ccccc6c6c([2H])c([2H])c([2H])c([2H])c65)nc(-n5c6ccccc6c6c([2H])c([2H])c([2H])c([2H])c65)n4)c([2H])c([Si](c4ccccc4)(c4ccccc4)c4cccc(-c5c([2H])c([2H])c([2H])c([2H])c5[2H])c4)c3[2H])c2)c([2H])c1[2H]] 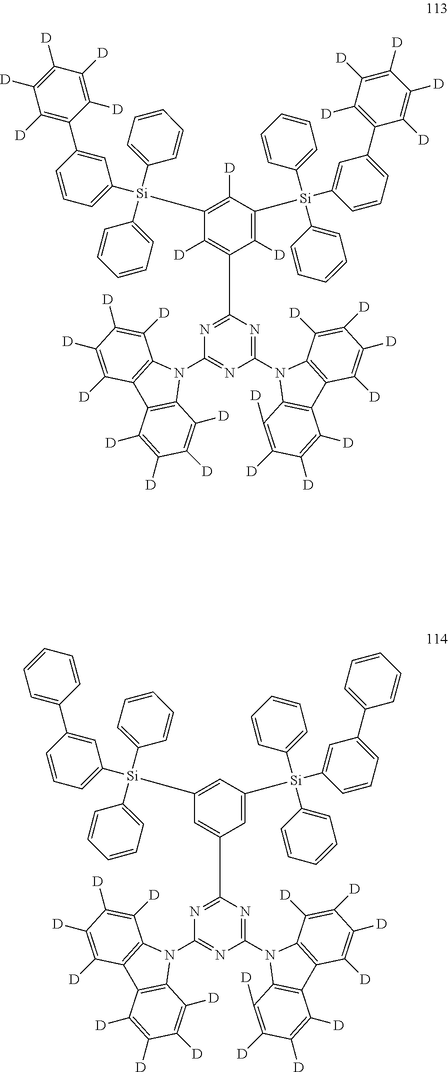 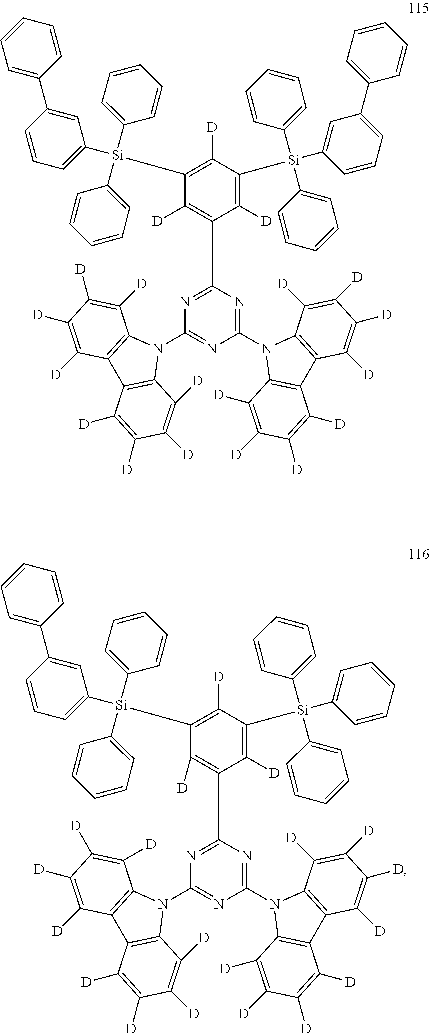
in Compound Group 1, D is a deuterium atom.

15. A nitrogen-containing compound represented by Formula 1: 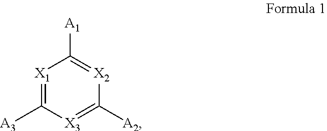
in Formula 1,
at least one among X₁ to X₃ is N, and remaining ones of X₁ to X₃ are OH,
A₁ to A₃ are each independently is a substituted or unsubstituted amine group, a substituted or unsubstituted aryl group of 6 to 60 ring-forming carbon atoms, or a substituted or unsubstituted heteroaryl group or 2 to 60 ring-forming carbon atoms, where at least one among A₁ to A₃ comprises a substituted or unsubstituted silyl group as a first substituent, and
at least one among hydrogen atoms in A₁ to A₃ and hydrogen atoms in X₁ to X₃, is substituted with a deuterium atom.

16. The nitrogen-containing compound of claim 15, wherein, in Formula 1, when at least one among A₁ to A₃ is substituted with a deuterium atom,
the at least one among A₁ to A₃ substituted with the deuterium atom comprises the first substituent, or
at least one among remaining ones of A₁ to A₃ not substituted with the deuterium atom comprises the first substituent.

17. The nitrogen-containing compound of claim 15, wherein Formula 1 is represented by Formula 1-1A or Formula 1-1B: 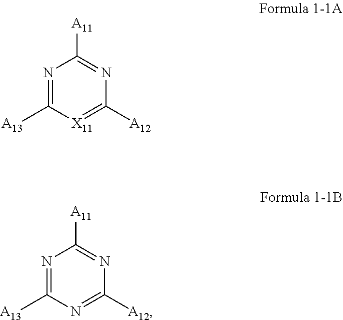
in Formula 1-1A and Formula 1-1B,
A₁₁ to A₁₃ are each independently a substituted or unsubstituted amine group, a substituted or unsubstituted aryl group of 6 to 60 ring-forming carbon atoms, or a substituted or unsubstituted heteroaryl group of 2 to 60 ring-forming carbon atoms, and
at least one among A₁₁ to A₁₃ comprises the first substituent,
in Formula 1-1A,
X₁₁ is CH or CD, and
when X₁₁ is CH, at least one among A₁₁ to A₁₃ comprises a deuterium atom as a substituent, and
in Formula 1-1B,
at least one among A₁₁ to A₁₃ comprises a deuterium atom as a substituent.

18. The nitrogen-containing compound of claim 15, wherein, in Formula 1, A₁ to A₃ are each independently a substituted or unsubstituted aryl amine group, a substituted or unsubstituted phenyl group, a substituted or unsubstituted dibenzoazasiline group, a substituted or unsubstituted carbazole group, a substituted or unsubstituted dibenzofuran group, a substituted or unsubstituted dibenzothiophene group, a substituted or unsubstituted phenoxazine group, or a substituted or unsubstituted phenothiazine group, and
when any one among A₁ to A₃ is a substituted phenyl group, a substituted carbazole group, a substituted dibenzofuran group, or a substituted dibenzothiophene group, the any one among A₁ to A₃ comprises a deuterium atom and the first substituent.

19. The nitrogen-containing compound of claim 15, wherein, in Formula 1, A₁ to A₃ are each independently represented by any one among Formula A-1 to Formula A-4: 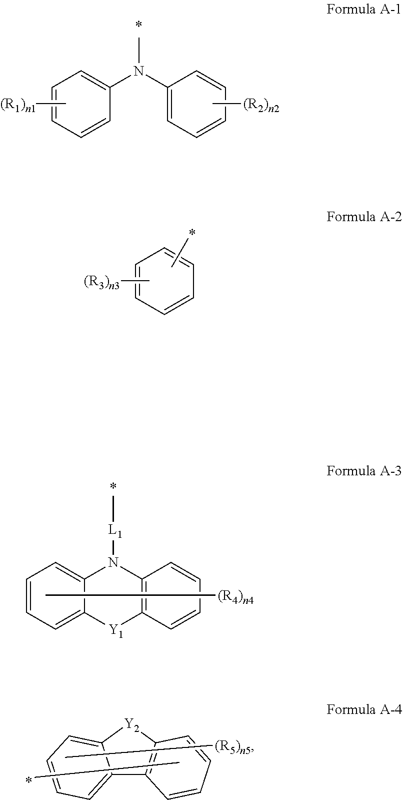
in Formula A-1 and Formula A-2,
n1 to n3 are each independently an integer of 0 to 5,
in Formula A-3,
L₁ is a direct linkage, or a substituted or unsubstituted arylene group of 6 to 60 ring-forming carbon atoms,
Y₁ is a direct linkage, SiR₆R₇, O, or S, and
n4 is an integer of 0 to 8,
in Formula A-4,
Y₂ is NRs, O or S, and
n5 is an integer of 0 to 7,
in Formula A-1 to Formula A-4,
R₁ to R₈ are each independently a hydrogen atom, a deuterium atom, a cyano group, a substituted or unsubstituted silyl group, a substituted or unsubstituted alkyl group of 1 to 30 carbon atoms, a substituted or unsubstituted aryl group of 6 to 60 ring-forming carbon atoms, or a substituted or unsubstituted heteroaryl group of 2 to 60 ring-forming carbon atoms, and
when any one among A₁ to A₃ is represented by any one among Formula A-2 to Formula A-4, at least one among R₃ to R₈ comprises a deuterium atom.

20. The nitrogen-containing compound of claim 19, wherein, in Formula A-2, R₃ is a deuterium atom, a substituted or unsubstituted silyl group, a substituted or unsubstituted cyclohexyl group, a substituted or unsubstituted phenyl group, a substituted or unsubstituted carbazole group, a substituted or unsubstituted dibenzofuran group, a substituted or unsubstituted dibenzo oxaborinine group, or a substituted or unsubstituted dibenzosilole group.

21. The nitrogen-containing compound of claim 15, wherein Formula 1 is represented by any one among Formula 1-2A to Formula 1-2C: 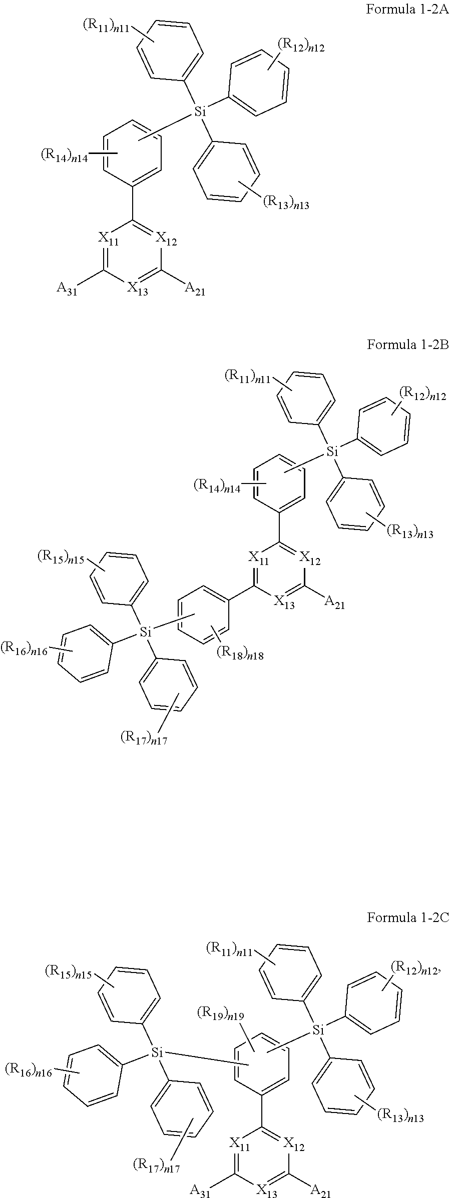
in Formula 1-2A to Formula 1-2C,
n11 to n13, and n15 to n17 are each independently an integer of 0 to 5,
n14 and n18 are each independently an integer of 0 to 4,
n19 is an integer of 0 to 3,
R₁₁ to R₁₈ are each independently a hydrogen atom, a deuterium atom, a cyano group, a substituted or unsubstituted silyl group, a substituted or unsubstituted alkyl group of 1 to 30 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring,
at least one among X₁₁ to X₁₃ is N, and remaining ones of X₁₁ to X₁₃ are CH,
A₂₁ and A₃₁ are each independently a substituted or unsubstituted aryl group of 6 to 60 ring-forming carbon atoms, or a substituted or unsubstituted heteroaryl group of 2 to 60 ring-forming carbon atoms, and
at least one among hydrogen atoms in A₂₁, hydrogen atoms in A₃₁, hydrogen atoms in X₁₁ to X₁₃, and hydrogen atoms in R₁₁ to R₁₈, is substituted with a deuterium atom.

22. The nitrogen-containing compound of claim 21, wherein Formula 1-2A is represented by Formula 1-2AA or Formula 1-2AB: 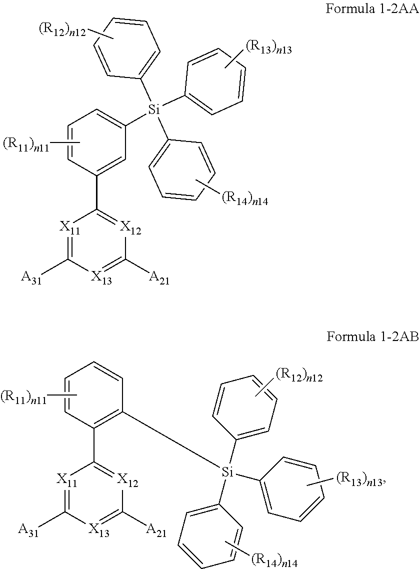
in Formula 1-2AA to Formula 1-2AB,
n11 to n14, R₁₁ to R₁₄, A₂₁, A₃₁, and X₁₁ to X₁₃ are the same as defined in Formula 1-2A.

23. The nitrogen-containing compound of claim 21, wherein Formula 1-2A is represented by Formula 1-2AC: 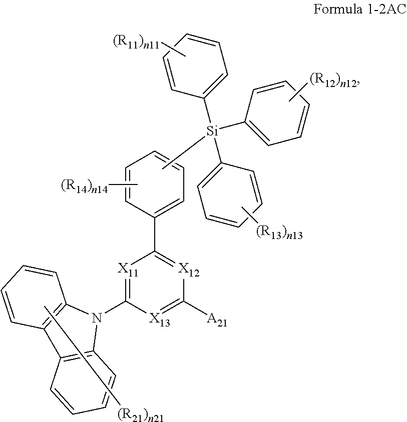
in Formula 1-2AC
n21 is an integer of 0 to 8,
R₂₁ is a hydrogen atom, a deuterium atom, a cyano group, a substituted or unsubstituted silyl group, a substituted or unsubstituted alkyl group of 1 to 10 carbon atoms, a substituted or unsubstituted aryl group of 6 to 30 ring-forming carbon atoms, or a substituted or unsubstituted heteroaryl group of 2 to 30 ring-forming carbon atoms,
at least one among hydrogen atoms in A₂₁, hydrogen atoms in X₁₁ to X₁₃, hydrogen atoms in R₁₁ to R₁₄, and hydrogen atoms in R₂₁, is substituted with a deuterium atom, and
n11 to n14, R₁₁ to R₁₄, A₂₁, and X₁₁ to X₁₃ are the same as defined in Formula 1-2A.

24. The nitrogen-containing compound of claim 15, wherein, in Formula 1, one or two among A₁ to A₃ comprises a triphenylsilyl group substituted with deuterium atoms, and at least one among remaining ones of A₁ to A₃ comprises a carbazole group substituted with a deuterium atom.

25. The nitrogen-containing compound of claim 15, wherein the Formula 1 is represented by any one among compounds in Compound Group 1: 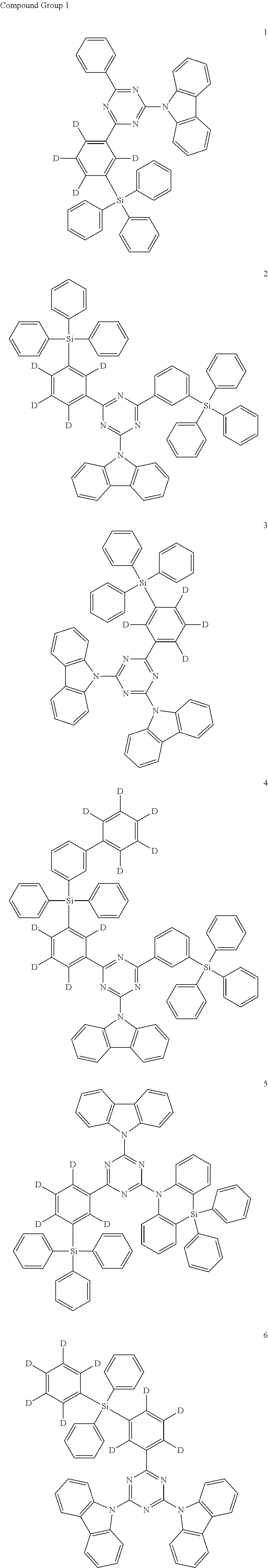 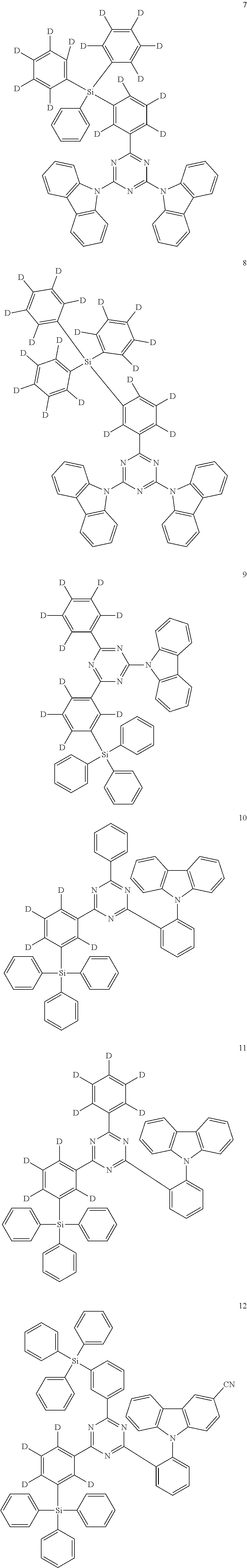 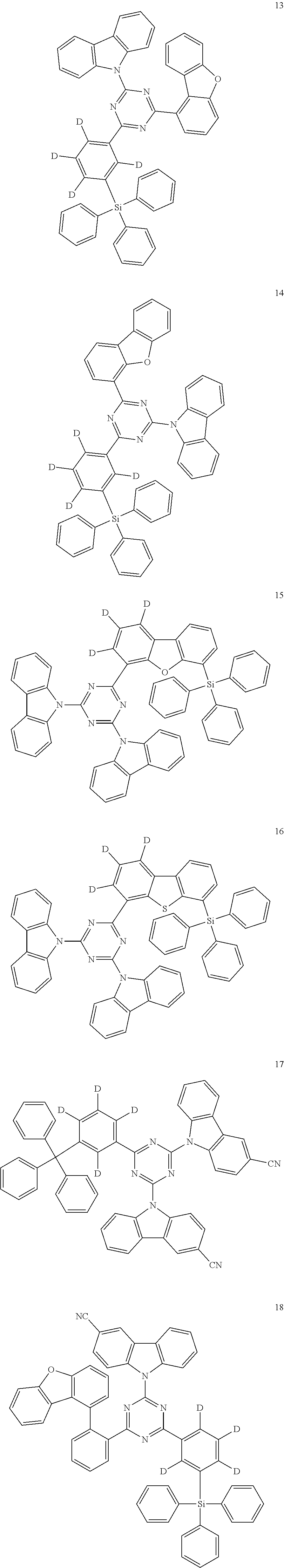 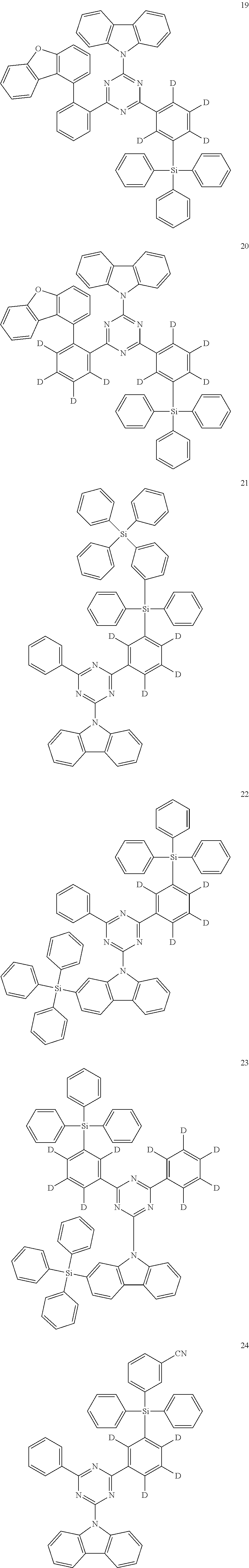 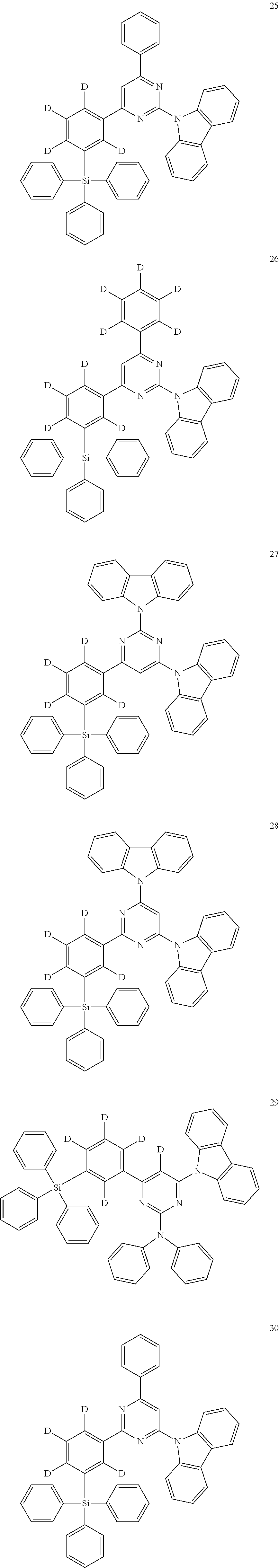 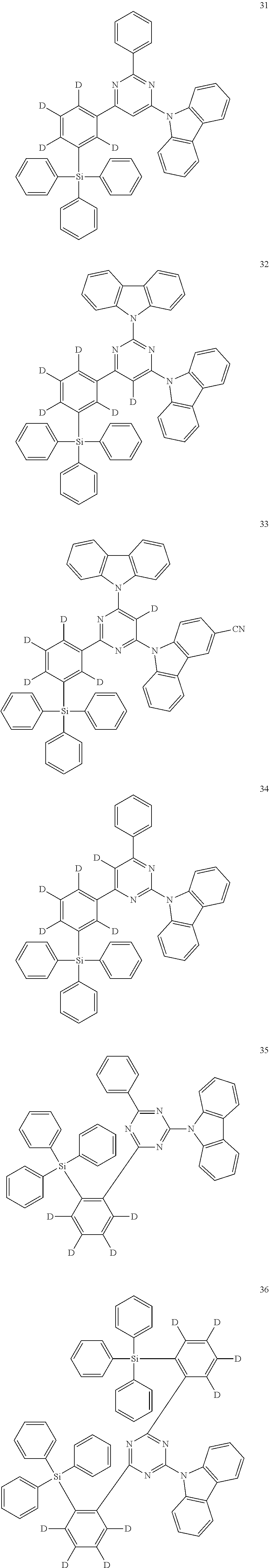 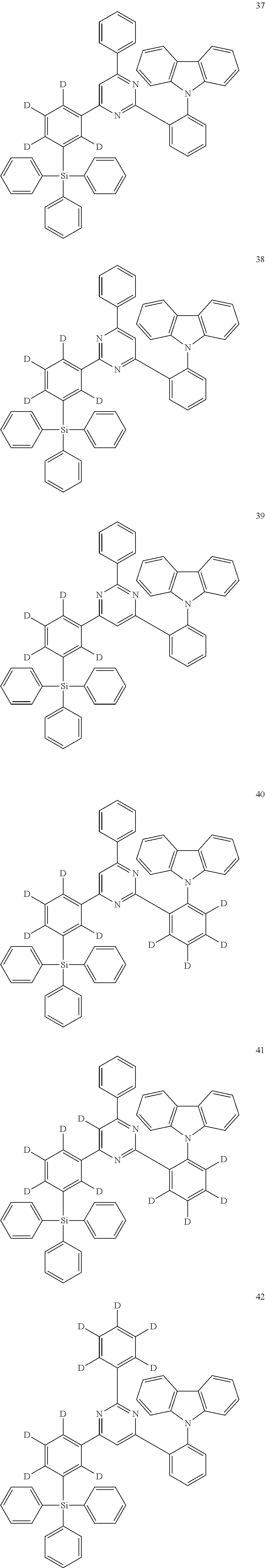 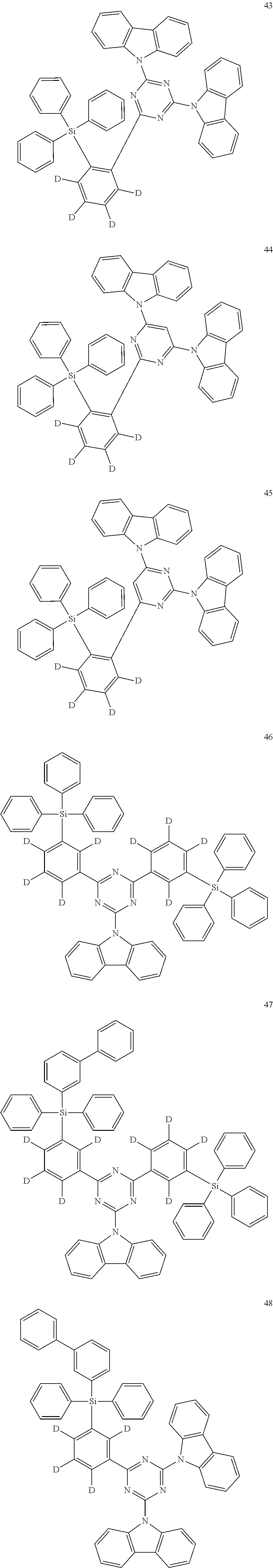 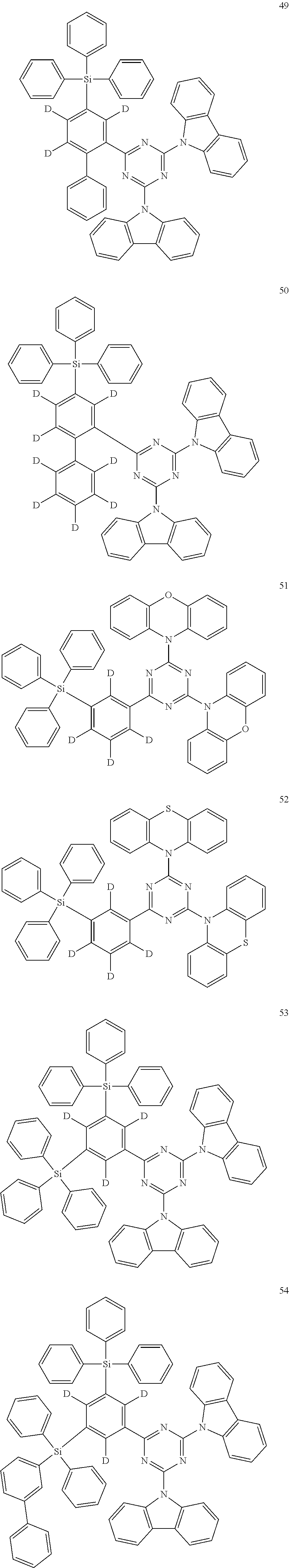 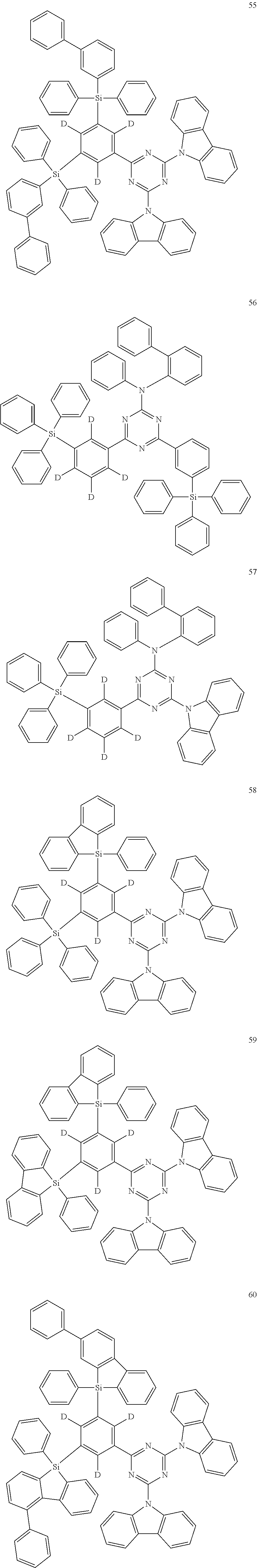 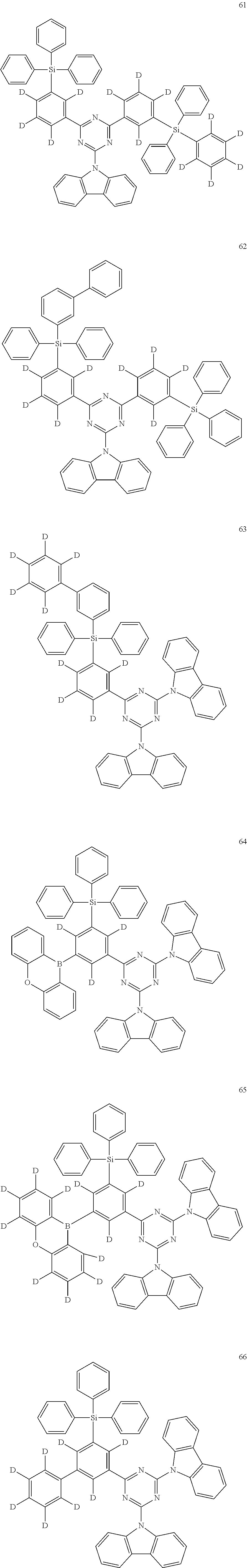 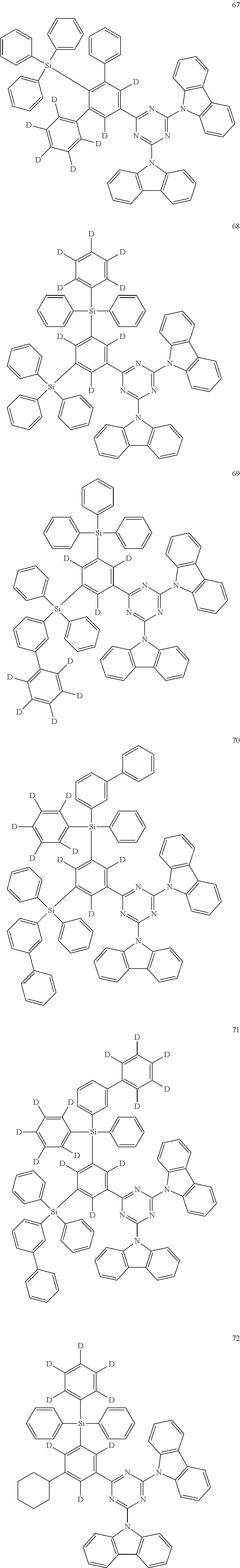 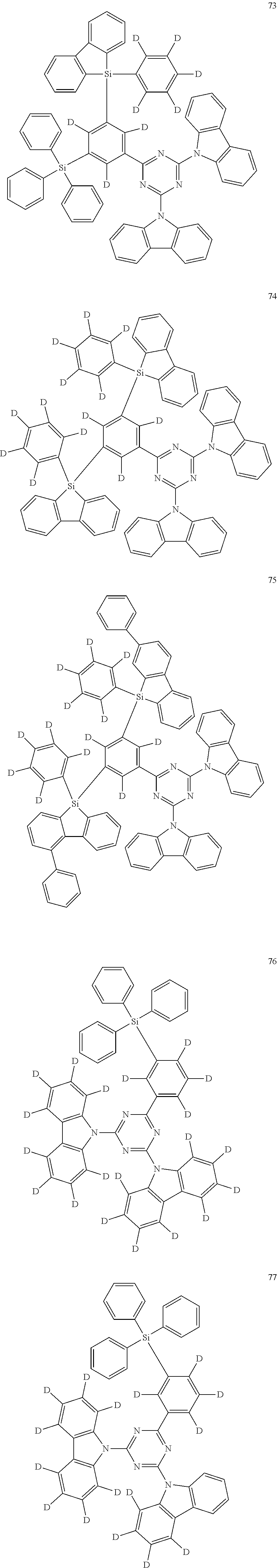 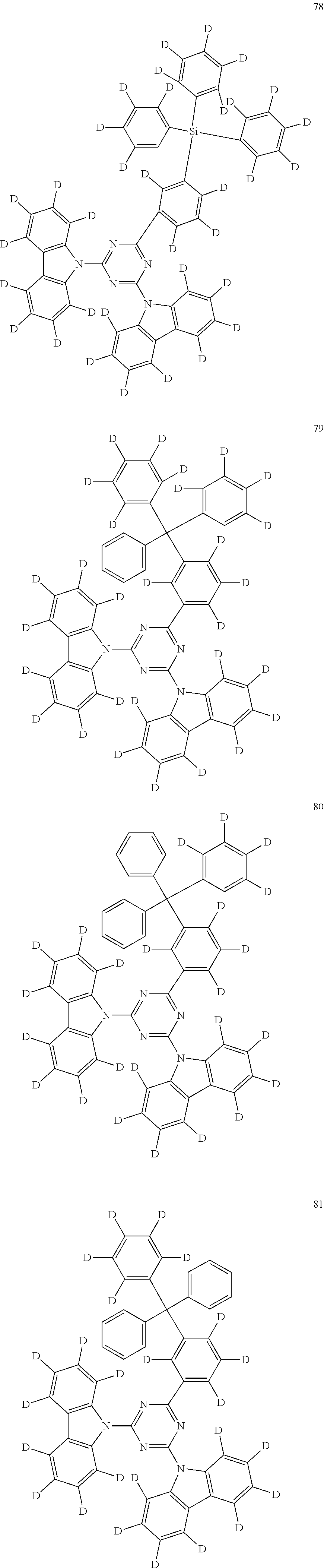 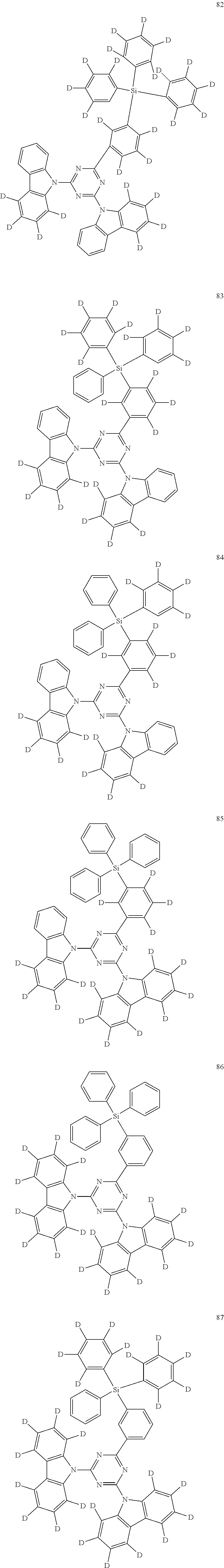 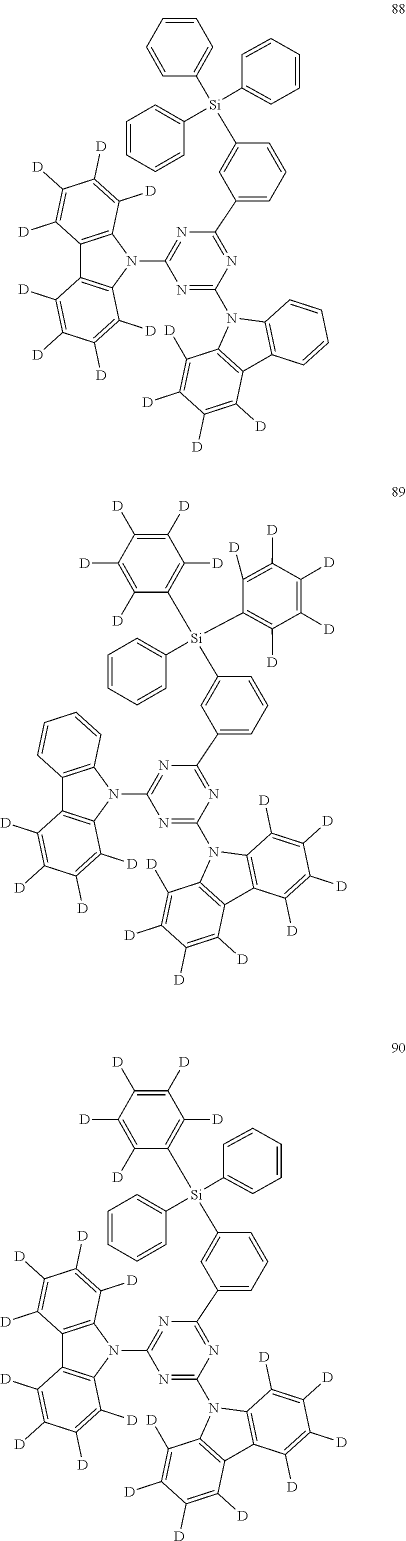 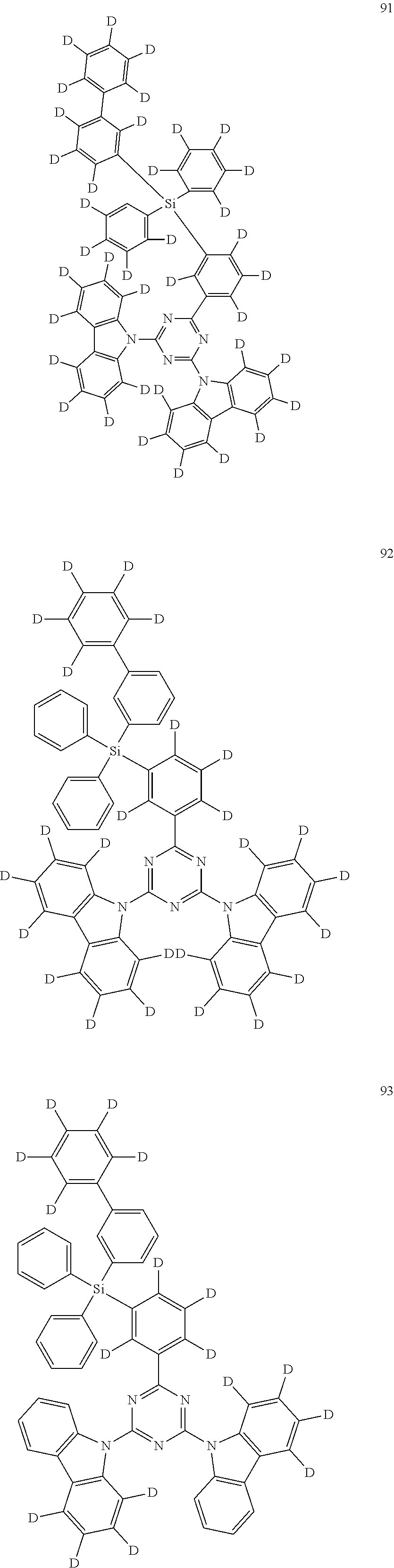 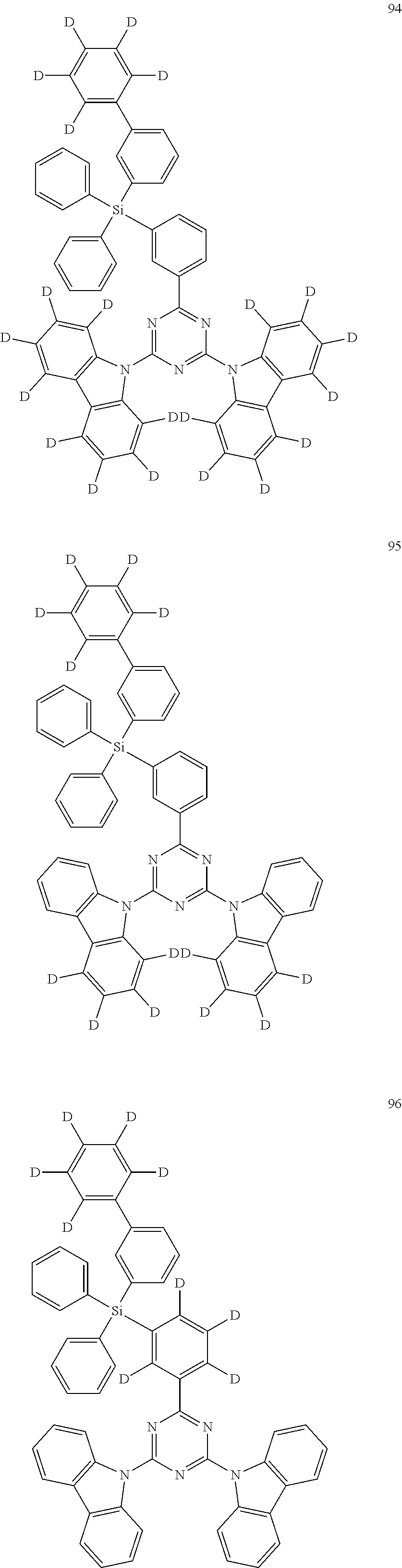 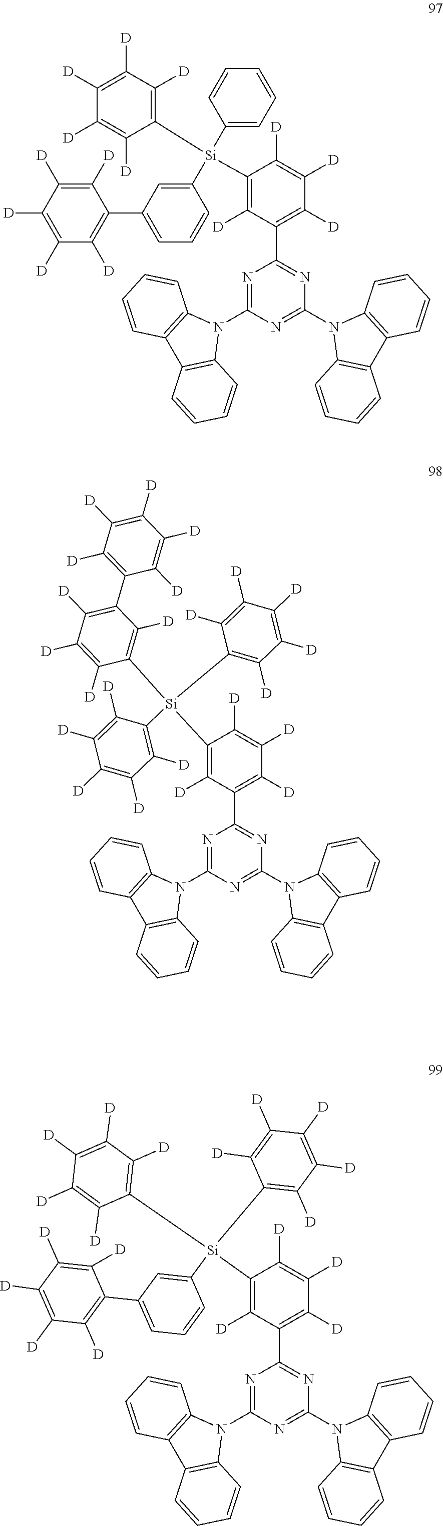 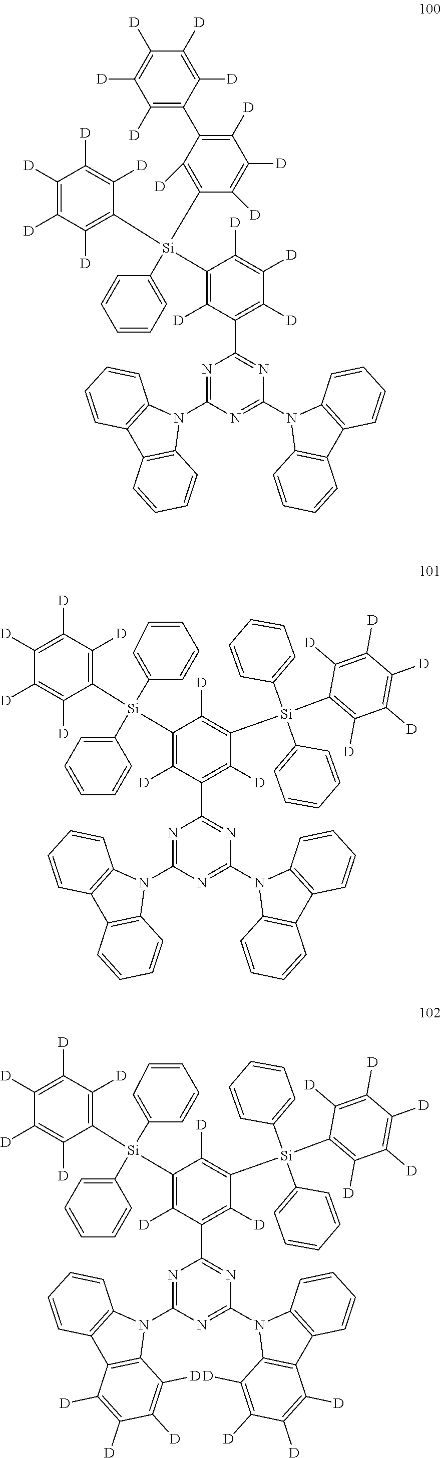 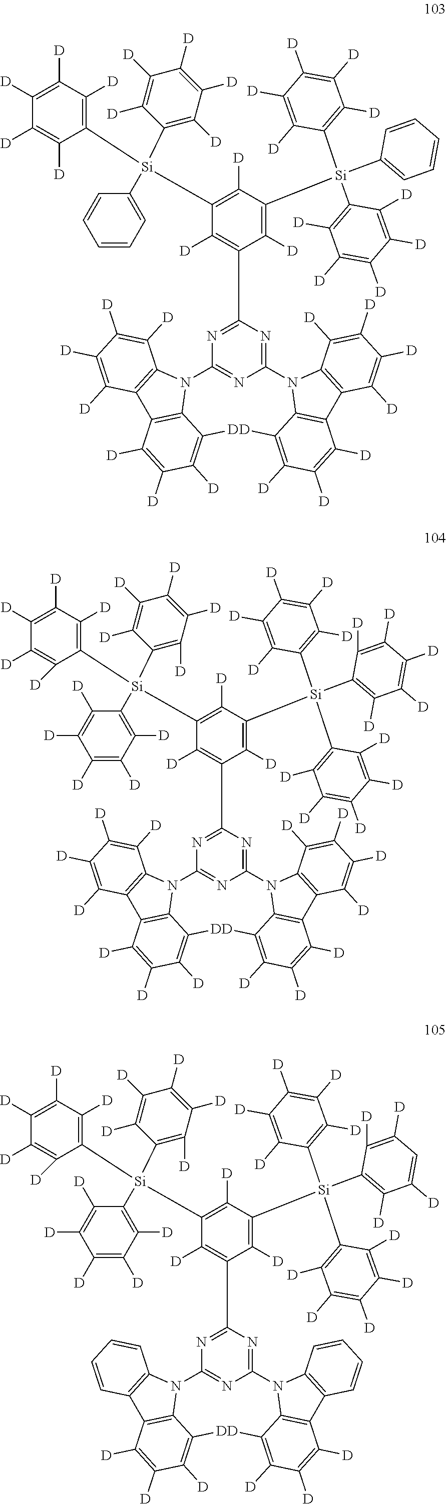 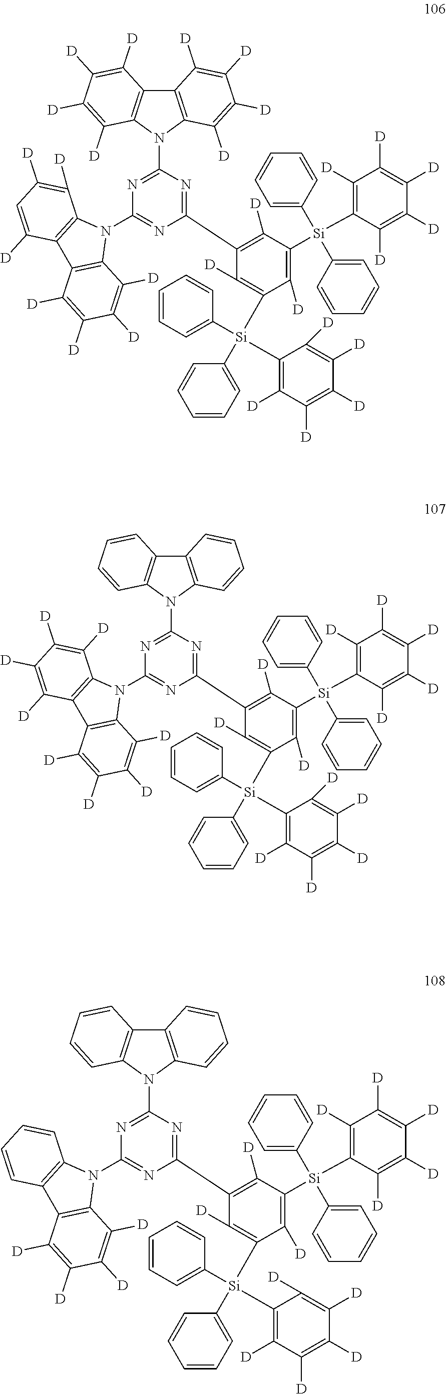 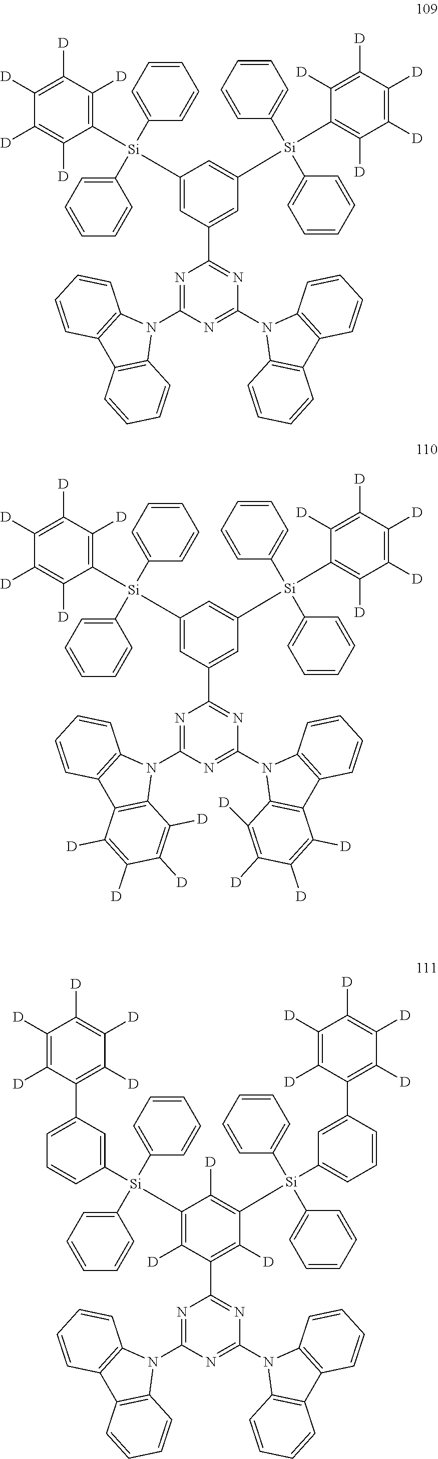 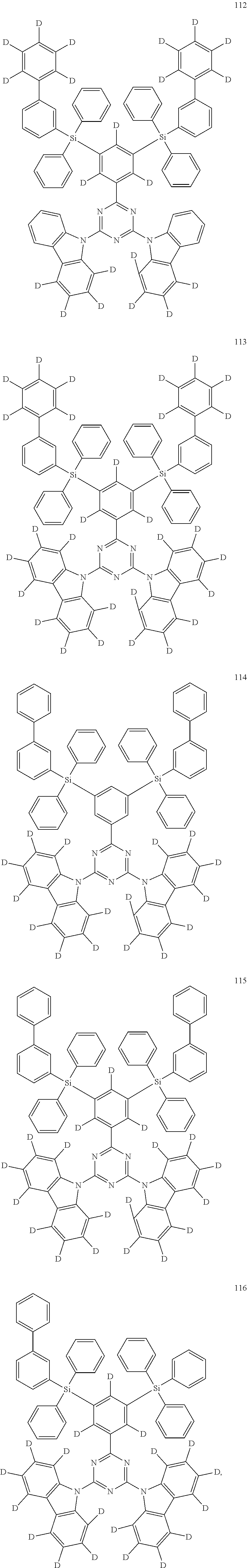
in Compound Group 1, D is a deuterium atom.
